(19) United States
(12) Patent Application Publication
(10) Pub. No.: US 2006/0099451 A1
(43) Pub. Date: May 11, 2006

(54) Organic electroluminescent device

(75) Inventor: Tatsuya Igarashi, Kanagawa (JP)

Correspondence Address: BIRCH STEWART KOLASCH & BIRCH, PO BOX 747, FALLS CHURCH, VA, 22040-0747, US

(73) Assignee: FUJI PHOTO FILM CO., LTD.

(21) Appl. No.: 11/269,809

(22) Filed: Nov. 9, 2005

(30) Foreign Application Priority Data
Nov. 10, 2004 (JP) 2004-326053

(51) Int. Cl. H01L 51/54; H05B 33/14

(52) U.S. Cl. 428/690; 428/917; 313/504; 313/506; 257/102; 257/103; 257/E51.044

(57) ABSTRACT

An organic electroluminescent device, comprising at least one organic compound layer containing a luminescent layer between a pair of electrodes, wherein the luminescent layer contains a fluorescence-emitting compound emitting fluorescence when voltage is applied thereto, the emission when voltage is applied is mainly derived from the fluorescence-emitting compound, and wherein the luminescent layer further comprises an amplifying agent functioning to increase the number of singlet excitons generated and thus amplifying the light intensity when voltage is applied, and the amplifying agent is a metal complex having a tridentate or higher ligand.

### CROSS-REFERENCE TO RELATED APPLICATION

This application claims priority under 35 USC 119 from Japanese Patent Application No. 2004-326053, the disclosure of which is incorporated by reference herein.

### BACKGROUND OF THE INVENTION

1. Field of the Invention

The present invention relates to an organic electroluminescent device (hereinafter, also referred to as “organic EL device”, “EL device” or “luminescent device”) which can emit light through the conversion of electric energy to light.

2. Description of the Related Art

Organic electroluminescent (EL) devices have attracted attention because emission can be obtained with high brightness at low voltage. One of the most important characteristic values of organic electroluminescent devices is external quantum efficiency. The external quantum efficiency is calculated according to the Formula:
“External quantum efficiency f=(number of photons emitted from device)/(number of electrons injected into device),

and a greater value is advantageous for the device, from the viewpoint of power consumption.

The external quantum efficiency of an organic electroluminescent device is also expressed by the following Formula:
“External quantum efficiency f=Internal quantum efficiency×light output efficiency”.

The threshold values of the internal quantum efficiency and the light output efficiency for organic EL devices that use the fluorescence of organic compounds are respectively 25% and about 20%, and thus, the threshold value of the external quantum efficiency is considered to be approximately 5%.

A device using a triplet luminescent material (phosphorescence-emitting material) has been reported as a method aimed at improving the internal quantum efficiency and thus the external quantum efficiency of an organic electroluminescent device of (see, for example, WO No. 00/70655). With this device it is possible to improve external quantum efficiency compared to conventional devices (singlet luminescent devices) that utilize fluorescence, and the maximum value of the external quantum efficiency reaches as high as 8% (external quantum efficiency: 7.5% at 100 cd/m²), but the device uses the phosphorescent emission from a heavy metal complex and thus, is slower in emission response and needs improvement in durability.

As a method of overcoming these problems, a singlet luminescent device that utilizes the energy transfer from triplet excitons to singlet excitons has been proposed (see, for example, WO No. 01/08230).

However, the device described in this document has a lower external quantum efficiency and emitts only a red light, and further improvement is required.

In the document, Ir(ppy)₃ (trisphenylpyridine iridium complex) is used as the compound having the functions of increasing the number of singlet excitons generated and amplifying the light intensity when voltage is applied (amplifying agent), but the luminescent device still required further improvement in durability.

### SUMMARY OF THE INVENTION

The present invention has been made in view of the above-described circumstances and provides an organic electroluminescent device having superior luminous efficiency and durability.

A first aspect of the invention provides an organic electroluminescent device, comprising at least one organic compound layer containing a luminescent layer between a pair of electrodes, wherein the luminescent layer contains a fluorescence-emitting compound emitting fluorescence when voltage is applied thereto, the emission when voltage is applied is mainly derived from the fluorescence-emitting compound, and wherein the luminescent layer further comprises an amplifying agent functioning to increase the number of singlet excitons generated and thus amplifying the light intensity when voltage is applied, and the amplifying agent is a metal complex having a tridentate or higher ligand.

In a second aspect of the invention, the organic electroluminescent device according to the first aspect is provided, wherein the ligand contained in the metal complex is a chained ligand.

In a third aspect of the invention, the organic electroluminescent device according to the second aspect is provided, wherein the metal complex is a compound represented by the following Formula (I): 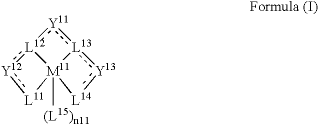
wherein, M¹¹ represents a metal ion; L¹¹ to L¹⁵ each represent a ligand coordinating to M¹¹; there is no additional atom group forming a cyclic ligand between L¹¹ and L¹⁴; L¹⁵ does not bind to both L¹¹ and L¹⁴ to form a cyclic ligand; Y¹¹, Y¹², and Y¹³ each represent a connecting group or a single or double bond; when Y¹¹, Y¹², or Y¹³ is a connecting group, the bonds between L¹¹ and Y¹², Y¹² and L¹², L¹² and Y¹¹, Y¹¹ and L¹³, L¹³ and Y¹³, and Y¹³ and L¹⁴ each independently represent a single or double bond; and n¹¹ is a number of 0 to 4.

In a fourth aspect of the invention, the organic electroluminescent device according to the second aspect is provided, wherein the metal complex is a compound represented by the following Formula (II): 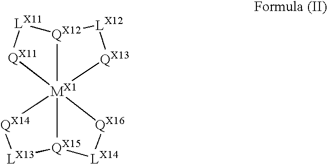
wherein, M^{X1} represents a metal ion; Q^{X11} to Q^{X16} each represent an atom coordinating to M^{X1} or an atom group containing an atom coordinating to M^{X1}; L^{X11} to L^{X14} each represent a single or double bond or a connecting group, i.e., each of the atom group of Q^{X11}-L^{X11}-Q^{X12}-L^{X12}-Q^{X13} and the atom group of Q^{X14}-L^{X13}-Q^{X15}-L^{X14}-Q^{X16} is a tridentate ligand; and each of the bonds of M^{X1} and Q^{X11} to Q^{X16} may be a coordination or covalent bond.

In a 5th aspect of the invention, the organic electroluminescent device according to the first aspect is provided, wherein the ligand contained in the metal complex is a cyclic ligand.

In a 6th aspect of the invention, the organic electroluminescent device according to the 5th aspect is provided, wherein the metal complex is represented by the following Formula (III): 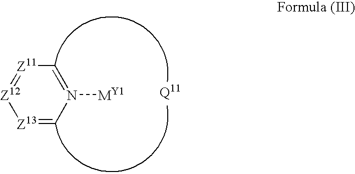
wherein, Q¹¹ represents an atom group forming a nitrogen-containing heterocyclic ring; Z¹¹, Z¹², and Z¹³ each represent a substituted or unsubstituted carbon or nitrogen atom; and M^{Y1} represents a metal ion that may have a ligand additionally.

In a 7th aspect of the invention, the organic electroluminescent device according to the first aspect is provided, wherein the luminescent layer contains at least two fluorescence-emitting compounds.

In an 8th aspect of the invention, the organic electroluminescent device according to the first aspect is provided, wherein the concentration of the fluorescence-emitting compound in the luminescent layer is from 0.1% to 10%.

In a 9th aspect of the invention, the organic electroluminescent device according to the first aspect is provided, wherein the fluorescent quantum yield of the fluorescence-emitting compound in the luminescent layer is 50% or more.

In a 10th aspect of the invention, the organic electroluminescent device according to the first aspect is provided, wherein the emission spectrum of the amplifying agent and the absorption spectrum of the fluorescence-emitting compound overlap at least partially.

In an 11th aspect of the invention, the organic electroluminescent device according to the first aspect is provided, wherein the phosphorescent quantum yield of the amplifying agent is 20% or more.

In a 12th aspect of the invention, the organic electroluminescent device according to the first aspect is provided, wherein the phosphorescence lifetime of the amplifying agent is 10 μs or less.

In a 13th aspect of the invention, the organic electroluminescent device according to the first aspect is provided, wherein the T₁ level (energy level of lowest excited triplet state) of the layer in the luminescent layer close to the cathode is from 50 Kcal/mol (209.2 KJ/mol) to 90 Kcal/mol (377.1 KJ/mol).

In a 14th aspect of the invention, the organic electroluminescent device according to the first aspect is provided, wherein the T₁ level (energy level of lowest excited triplet state) of the layer in the luminescent layer close to the anode is from 50 Kcal/mol (209.2 KJ/mol) to 90 Kcal/mol (377.1 KJ/mol).

In a 15th aspect of the invention, the organic electroluminescent device according to the first aspect is provided, wherein the fluorescence-emitting compound is a distyrylarylene derivative, oligoarylene derivative, aromatic nitrogen-containing heterocyclic compound, sulfur-containing heterocyclic ring compound, metal complex, oxo-substituted heterocyclic ring compound, organic silicon compound, triarylamine derivative, or condensed aromatic compound.

In a 16th aspect of the invention, the organic electroluminescent device according to the first aspect, wherein the external quantum efficiency of the device is 6% or more.

In a 17th aspect of the invention, the organic electroluminescent device according to the first aspect is provided, wherein the internal quantum efficiency of the device is 30% or more.

In an 18th aspect of the invention, the organic electroluminescent device according to the first aspect is provided, wherein the maximum emission wavelength of the light emitted from the fluorescence-emitting compound is 580 nm or less.

In a 19th aspect of the invention, the organic electroluminescent device according to the first aspect is provided, wherein the luminescent layer contains at least one host material, and the host material is one or more compounds selected from metal complexes, nitrogen-containing heterocyclic ring compounds, and aromatic hydrocarbon compounds.

In a 20th aspect of the invention, the organic electroluminescent device according to the first aspect, wherein the organic compound layer contains an electron-transporting layer and the electron-transporting layer contains a metal complex compound or a nitrogen-containing heterocyclic ring compound.

In a 21th aspect of the invention, the organic electroluminescent device according to the first aspect is provided, wherein the fluorescence-emitting compound has a substituent that lowers the efficiency of the Dexter-type energy transfer from a triplet exciton of the amplifying agent to a triplet exciton of the fluorescence-emitting compound.

In a 22th aspect of the invention, the organic electroluminescent device according to the first aspect is provided, wherein the maximum phosphorescence wavelength of the amplifying agent is 500 nm or less.

### DESCRIPTION OF THE PRESENT INVENTION

Hereinafter, the invention will be described in more detail.

The organic electroluminescent device according to the invention comprises at least one organic compound layer containing a luminescent layer between a pair of electrodes, wherein the luminescent layer contains a fluorescence-emitting compound emitting fluorescence when voltage is applied thereto, the emission when voltage is applied is mainly derived from the fluorescence-emitting compound, and wherein the luminescent layer further comprises an amplifying agent functioning to increase the number of singlet excitons generated and thus amplifying the light intensity when voltage is applied, and the amplifying agent is a metal complex having a tridentate or higher ligand.

The organic electroluminescent device according to the invention with the configuration above is a luminescent device improved in luminous efficiency and additionally superior in durability.

In other words, the phrase “the emission when voltage is applied is mainly derived from the fluorescence-emitting compound” means that 50% or more light (fluorescence) is emitted from singlet exciton of the device, and the remaining of the light (phosphorescence) is emitted from triplet exciton of the device; preferably, 70% or more light from the device, are fluorescence and 30% or less are phosphorescence; more preferably, 80% or more light from the device are fluorescence and 20% or less are phosphorescence; and still more preferably 90% or more are fluorescence and 10% or less are phosphorescence. Emission mainly of fluorescence is preferable from the viewpoints of improvement in the response and durability during emission and decrease in deterioration of the efficiency at a higher brightness (e.g., 1,000 cd/m² or more).

The amplifying agent for use in the invention is a compound functioning to increase the number of the singlet excitons generated and thus the light intensity when voltage is applied.

Hereinafter, the metal complex having a tridentate or higher dentate ligand, which is the amplifying agent in the present invention will be described.

The atom in the metal complex coordinating to the metal ion is not particularly limited, but preferably an oxygen, nitrogen, carbon, or sulfur atom, more preferably an oxygen, nitrogen, or carbon atom, and still more preferably a nitrogen or carbon atom.

The metal ion in the metal complex is not particularly limited, and preferable examples thereof include iridium, platinum, rhenium, tungsten, rhodium, ruthenium, osmium, rare-earth metal (e.g., europium, gadolinium, terbium), palladium, copper, cobalt, magnesium, zinc, nickel, lead, and aluminum ions.

The metal complex in the invention is preferably a metal complex having a tridentate to hexadentate ligand, more preferably a metal complex having a tridentate or quadridentate ligand, and particularly preferably a metal complex having a quadridentate ligand.

The ligand contained in the metal complex for use in the invention is preferably a chained or cyclic, and preferably has at least one nitrogen-containing heterocyclic ring (e.g., a pyridine ring, a quinoline ring, or a pyrrole ring) that coordinates to the central metal (e.g., M¹¹ in the compound represented by formula (I) described below) via the nitrogen. The nitrogen-containing heterocyclic ring is more preferably a nitrogen-containing six-membered heterocyclic ring.

The term “chained” used herein for the ligand contained in the metal complex described above refers to a structure of the ligand not encircling the central metal completely (e.g., terpyridyl ligand). The term “cyclic” used for the ligand contained in the metal complex refers to a closed structure of the ligand encircling the central metal (e.g., phthalocyanine or crown ether ligand).

When the ligand of the metal complex in the invention is chained, the metal complex is preferably a compound represented by formula (I) or (II) described in detail below.

The compound represented by formula (I) will be described first.

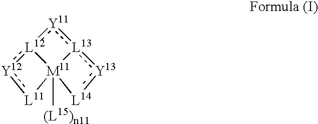

In formula (I), M¹¹ represents a metal ion, and L¹¹ to L¹⁵ each represent a moiety coordinating to M¹¹. There is no additional atomic group forming a cyclic ligand between L¹¹ and L¹⁴. L¹⁵ does not bind to both L¹¹ and L¹⁴ to form a cyclic ligand. Y¹¹, Y¹², or Y¹³ each independently represent a connecting group, or a single or double bond. When Y¹¹, Y¹², or Y¹³ is a connecting group, the bonds between L¹¹ and Y¹², Y¹² and L¹², L¹² and Y¹¹, Y¹¹ and L¹³, L¹³ and yl3, and Y¹³ and L¹⁴ each independently represent a single or double bond. n¹¹ represents an integer of 0 to 4.

The compound represented by formula (I) will be described in detail below.

In formula (I), M¹¹ represents a metal ion. The metal ion is not particularly limited, but preferably a divalent or trivalent metal ion. The divalent or trivalent metal ion is preferably a platinum, iridium, rhenium, palladium, rhodium, ruthenium, copper, europium, gadolinium, or terbium ion, more preferably a platinum, iridium, or europium ion, still more preferably a platinum or iridium ion, and particularly preferably a platinum ion.

In formula (I), L¹¹, L¹², L¹³, and L¹⁴ each independently represent a moiety coordinating to M¹¹. The atom coordinating to M contained in L¹¹, L¹², L¹³, or L¹⁴ is preferably a nitrogen, oxygen, sulfur, or carbon atom, and more preferably a nitrogen, oxygen, or carbon atom.

The bonds between M¹¹ and L¹¹, between M¹¹ and L¹², between M¹¹ and L¹³, between M¹¹ and L¹⁴ each may be independently selected from a covalent bond, an ionic bond, and a coordination bond. In this specification, the terms “ligand” and “coordinate” are used also when the bond between the central metal and the ligand is a bond (an ionic bond or a covalent bond) other than a coordination bond, as well as when the bond between the central metal and the ligand is a coordination bond, for convenience of the explanation.

The entire ligand comprising L¹¹, Y¹², L¹², Y¹¹, L¹³, Y¹³, and L¹⁴ is preferably an anionic ligand. The term “anionic ligand” used herein refers to a ligand having at least one anion bonded to the metal. The number of anions in the anionic ligand is preferably 1 to 3, more preferably 1 or 2, and still more preferably 2.

When the moiety represented by any of L¹¹, L¹², L¹³, and L¹⁴ coordinates to M¹¹ via a carbon atom, the moiety is not particularly limited, and examples thereof include imino ligands, aromatic carbon ring ligands (e.g., a benzene ligand, a naphthalene ligand, an anthracene ligand, and a phenanthrene ligand), and heterocyclic ligands [e.g., a thiophene ligand, a pyridine ligand, a pyrazine ligand, a pyrimidine ligand, a thiazole ligand, an oxazole ligand, a pyrrole ligand, an imidazole ligand, and a pyrazole ligand, ring-condensation products thereof (e.g., a quinoline ligand and a benzothiazole ligand), and tautomers thereof].

When the moiety represented by any of L¹¹, L¹², L¹³, and L¹⁴ coordinates to M¹¹ via a nitrogen atom, the moiety is not particularly limited, and examples thereof include nitrogen-containing heterocyclic ligands such as a pyridine ligand, a pyrazine ligand, a pyrimidine ligand, a pyridazine ligand, a triazine ligand, a thiazole ligand, an oxazole ligand, a pyrrole ligand, an imidazole ligand, a pyrazole ligand, a triazole ligand, an oxadiazole ligand, and a thiadiazole ligand, and ring-condensation products thereof (e.g., a quinoline ligand, a benzoxazole ligand, and a benzimidazole ligand), and tautomers thereof [in the invention, the following ligands (pyrrole tautomers) are also included in tautomers, in addition to normal isomers: the five-membered heterocyclic ligand of compound (24), the terminal five-membered heterocyclic ligand of compound (64), and the five-membered heterocyclic ring ligand of compound (145), the compounds (24), (64), (145) being shown below as typical examples of the compound represented by formula (I)]; amino ligands such as alkylamino ligands (preferably having 2 to 30 carbon atoms, more preferably 2 to 20 carbon atoms, and particularly preferably 2 to 10 carbon atoms, such as methylamino), arylamino ligands (e.g., phenylamino), acylamino ligands (preferably having 2 to 30 carbon atoms, more preferably 2 to 20 carbon atoms, and particularly preferably 2 to 10 carbon atoms, such as acetylamino and benzoylamino), alkoxycarbonylamino ligands (preferably having 2 to 30 carbon atoms, more preferably 2 to 20 carbon atoms, and particularly preferably 2 to 12 carbon atoms, such as methoxycarbonylamino), aryloxycarbonylamino ligands (preferably having 7 to 30 carbon atoms, more preferably 7 to 20 carbon atoms, and particularly preferably 7 to 12 carbon atoms, such as phenyloxycarbonylamino), sulfonylamino ligands (preferably having 1 to 30 carbon atoms, more preferably 1 to 20 carbon atoms, and particularly preferably 1 to 12 carbon atoms, such as methanesulfonylamino and benzenesulfonylarnino), and imino ligands. These ligands may be substituted.

When the moiety represented by any of L¹¹, L¹², L¹³, and L¹⁴ coordinates to M¹¹ via an oxygen atom, the moiety is not particularly limited, and examples thereof include alkoxy ligands (preferably having 1 to 30 carbon atoms, more preferably 1 to 20 carbon atoms, and particularly preferably 1 to 10 carbon atoms, such as methoxy, ethoxy, butoxy, and 2-ethylhexyloxy), aryloxy ligands (preferably having 6 to 30 carbon atoms, more preferably 6 to 20 carbon atoms, and particularly preferably 6 to 12 carbon atoms, such as phenyloxy, 1-naphthyloxy, and 2-naphthyloxy), heterocyclic oxy ligands (preferably having 1 to 30 carbon atoms, more preferably 1 to 20 carbon atoms, and particularly preferably 1 to 12 carbon atoms, such as pyridyloxy, pyrazyloxy, pyrimidyloxy, and quinolyloxy), acyloxy ligands (preferably having 2 to 30 carbon atoms, more preferably 2 to 20 carbon atoms, and particularly preferably 2 to 10 carbon atoms, such as acetoxy and benzoyloxy), silyloxy ligands (preferably having 3 to 40 carbon atoms, more preferably 3 to 30 carbon atoms, and particularly preferably 3 to 24 carbon atoms, such as trimethylsilyloxy and triphenylsilyloxy), carbonyl ligands (e.g., ketone ligands, ester ligands, and amido ligands), and ether ligands (e.g., dialkylether ligands, diarylether ligands, and furyl ligands).

When the moiety represented by any of L¹¹, L¹², L¹³, and L¹⁴ coordinates to M¹¹ via a sulfur atom, the moiety is not particularly limited, and examples thereof include alkylthio ligands (preferably having 1 to 30 carbon atoms, more preferably 1 to 20 carbon atoms, and particularly preferably 1 to 12 carbon atoms, such as methylthio and ethylthio), arylthio ligands (preferably having 6 to 30 carbon atoms, more preferably 6 to 20 carbon atoms, and particularly preferably 6 to 12 carbon atoms, such as phenylthio), heterocyclic thio ligands (preferably having 1 to 30 carbon atoms, more preferably 1 to 20 carbon atoms, and particularly preferably 1 to 12 carbon atoms, such as pyridylthio, 2-benzimidazolylthio, 2-benzoxazolylthio, and 2-benzothiazolylthio), thiocarbonyl ligands (e.g., thioketone ligands and thioester ligands), and thioether ligands (e.g., dialkylthioether ligands, diarylthioether ligands, and thiofuryl ligands). These substituted ligands may themselves be substituted.

In a preferable embodiment, L¹¹ and L¹⁴ each independently represent a moiety selected from an aromatic carbon ring ligand, an alkyloxy ligand, an aryloxy ligand, an ether ligand, an alkylthio ligand, an arylthio ligand, an alkylamino ligand, an arylamino ligand, an acylamino ligand, or a nitrogen-containing heterocyclic ligand [e.g., a pyridine ligand, a pyrazine ligand, a pyrimidine ligand, a pyridazine ligand, a triazine ligand, a thiazole ligand, an oxazole ligand, a pyrrole ligand, an imidazole ligand, a pyrazole ligand, a triazole ligand, an oxadiazole ligand, a thiadiazole ligand, or a condensed ring ligand containing one or more of the above ligands (e.g., a quinoline ligand, a benzoxazole ligand, or a benzimidazole ligand), or a tautomer of any of the above ligands]; more preferably, an aromatic carbon ring ligand, an aryloxy ligand, an arylthio ligand, an arylamino ligand, a pyridine ligand, a pyrazine ligand, an imidazole ligand, a condensed ring ligand containing one or more of the above ligands (e.g., a quinoline ligand, a quinoxaline ligand, or a benzimidazole ligand), or a tautomer of any of the above ligands; still more preferably, an aromatic carbon ring ligand or an aryloxy ligand, an arylthio ligand, or an arylamino ligand; and particularly preferably, an aromatic carbon ring ligand or an aryloxy ligand.

In a preferable embodiment, L¹² and L¹³ each independently represent a ligand forming a coordination bond with M¹¹. The ligands forming a coordination bond with M¹¹ is preferably a pyridine, pyrazine, pyrimidine, triazine, thiazole, oxazole, pyrrole or triazole ring, a condensed ring containing one or more of the above rings (e.g., a quinoline ring, a benzoxazole ring, a benzimidazole ring, an indolenine ring), or a tautomer of any of the above rings; more preferably a pyridine, pyrazine, pyrimidine, or pyrrole ring, a condensed ring containing one or more of the above rings (e.g., a quinoline ring, a benzopyrrole ring), or a tautomer of any of the above rings; still more preferably a pyridine, pyrazine or pyrimidine ring, or a condensed ring containing one or more of the above rings (e.g., quinoline ring); particularly preferably a pyridine ring or a condensed ring containing a pyridine ring (e.g., a quinoline ring).

In formula (I), L¹⁵ represents a ligand coordinating to M¹¹. L¹⁵ is preferably a monodentate to quadridentate ligand and more preferably a monodentate to quadridentate anionic ligand. The monodentate to quadridentate anionic ligand is not particularly limited, but is preferably a halogen ligand, a 1,3-diketone ligand (e.g., an acetylacetone ligand), a monoanionic bidentate ligand containing a pyridine ligand [e.g., a picolinic acid ligand or a 2-(2-hydroxyphenyl)-pyridine ligand], or a quadridentate ligand of L¹, Y¹², L¹², Y¹¹, L¹³, Y¹³, and L¹⁴ can form; more preferably, a 1,3-diketone ligand (e.g., an acetylacetone ligand), a monoanionic bidentate ligand containing a pyridine ligand [e.g., a picolinic acid ligand or a 2-(2-hydroxyphenyl)-pyridine ligand], or a quadridentate ligand of L¹¹, Y¹², L¹³, Y¹², L¹³, Y¹³, and L¹⁴ can form; still more preferably, a 1,3-diketone ligand (e.g., an acetylacetone ligand) or a monoanionic bidentate ligand containing a pyridine ligand [e.g., a picolinic acid ligand or a 2-(2-hydroxyphenyl)-pyridine ligand); and particularly preferably, a 1,3-diketone ligand (e.g., an acetylacetone ligand). The number of coordination sites and the number of ligands do not exceed the valency of the metal. L¹⁵ does not bind to both L¹¹ and L¹⁴ to form a cyclic ligand.

In formula (I), Y¹¹, Y¹² and Y¹³ each independently represent a connecting group or a single or double bond. The connecting group is not particularly limited, and examples thereof include a carbonyl connecting group, a thiocarbonyl connecting group, an alkylene group, an alkenylene group, an arylene group, a heteroarylene group, an oxygen atom connecting group, a nitrogen atom connecting group, and a silicon atom connecting group, and connecting groups comprising combinations of connecting groups selected from the above. When Y¹¹ is a connecting group, the bond between L¹² and Y¹¹ and the bond between Y¹¹ and L¹³ are each independently a single or double bond. When Y¹² is a connecting group, the bond between L¹¹ and Y¹² and the bond between Y¹² and L¹² are each independently a single or double bond. When Y¹³ is a connecting group, the bond between L¹³ and Y¹³ and the bond between Y¹³ and L¹⁴ are each independently a single or double bond.

Preferably, Y¹¹, Y¹¹, and Y¹³ each independently represent a single bond, a double bond, a carbonyl connecting group, an alkylene connecting group, or an alkenylene group. Y¹¹ is more preferably a single bond or an alkylene group, and still more preferably an alkylene group. Each of Y¹² and Y¹³ is more preferably a single bond or an alkenylene group and still more preferably a single bond.

The ring formed by Y¹², L¹¹, L¹², and M¹¹, the ring formed by Y¹¹, L¹², L¹³, and M¹¹, and the ring formed by Y¹³, L¹³, L¹⁴, and M¹¹ are each preferably a four- to ten-membered ring, more preferably a five- to seven-membered ring, and still more preferably a five- to six-membered ring.

In formula (I), n¹¹ represents an integer of 0 to 4. When M¹¹ is a tetravalent metal, n¹¹ is 0, but when M¹¹ is a hexavalent metal, n¹¹ is preferably 1 or 2 and more preferably 1. When M¹¹ is a hexavalent metal and n¹¹ is 1, L¹⁵ represents a bidentate ligand. When M¹¹ is a hexavalent metal and n¹¹ is 2, L¹⁵ represents a monodentate ligand. When M¹¹ is an octavalent metal, nil is preferably 1 to 4, more preferably, 1 or 2, and still more preferably 1. When M¹¹ is an octavalent metal and n¹¹ is 1, L¹⁵ represents a quadridentate ligand. When M¹¹ is an octavalent metal and n¹¹ is 2, L¹⁵ represents a bidentate ligand. When n¹¹ is 2 or larger, there are plural L¹⁵'s, and the L¹⁵'s may be the same as or different from each other.

The compound represented by formula (II) will be described below.

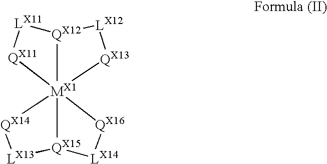

In formula (II), M^{X1} represents a metal ion. Q^{X1} to Q^{X16} each represent an atom coordinating to M^{X1} or an atomic group containing an atom coordinating to M^{X1}. L^{X11} to L¹⁴ each represent a single or double bond or a connecting group.

In formula (II), the atomic group comprising Q^{X11}-L^{X11}-Q^{X12}-L^{X12}-Q^{X13} and the atomic group comprising Q^{X14}-L^{X13}-Q^{X15}-L^{X14}-Q^{X16} each form a tridentate ligand.

In addition, each of the bonds of M^{X1} and Q^{X1} to Q^{X16} may be a coordination or covalent bond.

The compound represented by formula (II) will be described in detail below.

In formula (II), M^{X1} represents a metal ion. The metal ion is not particularly limited, but is preferably a monovalent to trivalent metal ion, more preferably a divalent or trivalent metal ion, and still more preferably a trivalent metal ion. Specifically, platinum, iridium, rhenium, palladium, rhodium, ruthenium, copper, europium, gadolinium, and terbium ions are preferable; iridium and europium ions are more preferable; and an iridium ion is still more preferable.

Q^{X11} to Q^{X16} each represent an atom coordinating to M^{X1} or an atomic group containing an atom coordinating to M^{X1}.

When any of Q^{X11} to Q^{X16} is an atom coordinating to M^{X1}, the atom may be, for example, a carbon, nitrogen, oxygen, silicon, phosphorus, or sulfur atom, preferably a nitrogen, oxygen, sulfur, or phosphorus atom; and more preferably a nitrogen or oxygen atom.

When any of Q^{X11} to Q^{X16} is an atomic group containing a carbon atom coordinating to M^{X1}, examples of the atomic group coordinating to M^{X1} via a carbon atom include imino groups, aromatic hydrocarbon ring groups (such as benzene and naphthalene), heterocyclic groups (such as thiophene, pyridine, pyrazine, pyrimidine, pyridazine, triazine, thiazole, oxazole, pyrrole, imidazole, pyrazole, and triazole), condensed rings containing one or more of the above rings, and tautomers thereof.

When any of Q^{X11} to Q^{X16} is an atomic group containing a nitrogen atom coordinating to M^{X1}, examples of the atomic group coordinating to M^{X1} via a nitrogen atom include nitrogen-containing heterocyclic groups (such as pyridine, pyrazine, pyrimidine, pyridazine, triazine, thiazole, oxazole, pyrrole, imidazole, pyrazole, and triazole), amino groups [alkylamino groups (preferably having 2 to 30 carbon atoms, more preferably 2 to 20 carbon atoms, and particularly preferably 2 to 10 carbon atoms, such as methylamino) and arylamino groups (e.g., phenylamino)], acylamino groups (preferably having 2 to 30 carbon atoms, more preferably 2 to 20 carbon atoms, and particularly preferably 2 to 10 carbon atoms, such as acetylamino and benzoylamino), alkoxycarbonylamino groups (preferably having 2 to 30 carbon atoms, more preferably 2 to 20 carbon atoms, and particularly preferably 2 to 12 carbon atoms, such as methoxycarbonylamino), aryloxycarbonylamino groups (preferably having 7 to 30 carbon atoms, more preferably 7 to 20 carbon atoms, and particularly preferably 7 to 12 carbon atoms, such as phenyloxycarbonylamino), sulfonylamino groups (preferably having 1 to 30 carbon atoms, more preferably 1 to 20 carbon atoms, and particularly preferably 1 to 12 carbon atoms, such as methanesulfonylamino and benzenesulfonylamino), and imino groups. These groups may be substituted.

When any of Q^{X11} to Q^{X16} is an atomic group containing an oxygen atom coordinating to M^{X1}, examples of the atomic groups coordinating to M^{X1} via an oxygen atom include alkoxy groups (preferably having 1 to 30 carbon atoms, more preferably 1 to 20 carbon atoms, and particularly preferably 1 to 10 carbon atoms, such as methoxy, ethoxy, butoxy, and 2-ethylhexyloxy), aryloxy groups (preferably having 6 to 30 carbon atoms, more preferably 6 to 20 carbon atoms, and particularly preferably 6 to 12 carbon atoms, such as phenyloxy, 1-naphthyloxy, and 2-naphthyloxy), heterocyclic oxy groups (preferably having 1 to 30 carbon atoms, more preferably 1 to 20 carbon atoms, and particularly preferably 1 to 12 carbon atoms, such as pyridyloxy, pyrazyloxy, pyrimidyloxy, and quinolyloxy), acyloxy groups (preferably having 2 to 30 carbon atoms, more preferably 2 to 20 carbon atoms, and particularly preferably 2 to 10 carbon atoms, such as acetoxy and benzoyloxy), silyloxy groups (preferably having 3 to 40 carbon atoms, more preferably 3 to 30 carbon atoms, and particularly preferably 3 to 24 carbon atoms, such as trimethylsilyloxy and triphenylsilyloxy), carbonyl groups (e.g., ketone groups, ester groups, and amido groups), and ether groups (e.g., dialkylether groups, diarylether groups, and furyl groups).

When any of Q^{X11} to Q^{X16} is an atomic group containing a silicon atom coordinating to M^{X1}, examples of the atomic group coordinating to M^{X1} via a silicon atom include alkylsilyl groups (preferably having 3 to 30 carbon atoms, such as a trimethylsilyl group), and arylsilyl groups (preferably, having 18 to 30 carbon atoms, such as a triphenylsilyl group). These groups may be substituted.

When any of Q^{X11} to Q^{X16} is an atomic group containing a sulfur atom coordinating to M^{X1}, examples of the atomic group coordinating to M^{X1} via a sulfur atom include alkylthio groups (preferably having 1 to 30 carbon atoms, more preferably 1 to 20 carbon atoms, and particularly preferably 1 to 12 carbon atoms, such as methylthio and ethylthio), arylthio groups (preferably having 6 to 30 carbon atoms, more preferably 6 to 20 carbon atoms, and particularly preferably 6 to 12 carbon atoms, such as phenylthio), heterocyclic thio groups (preferably having 1 to 30 carbon atoms, more preferably 1 to 20 carbon atoms, and particularly preferably 1 to 12 carbon atoms, such as pyridylthio, 2-benzimidazolylthio, 2-benzoxazolylthio, and 2-benzothiazolylthio), thiocarbonyl groups (e.g., a thioketone group and a thioester group), and thioether groups (e.g., a dialkylthioether group, a diarylthioether group, and a thiofuryl group).

When any of Q^{X11} to Q^{X16} is an atomic group containing a phosphorus atom coordinating to M^{X1}, examples of the atomic group coordinating to M^{X1} via a phosphorus atom include dialkylphosphino groups, diarylphosphino groups, trialkyl phosphines, triaryl phosphines, and phosphinine groups. These groups may be substituted.

The atomic groups represented by Q^{X11} to Q^{X16} are each preferably an aromatic hydrocarbon ring group containing a carbon atom coordinating to M^{X1}, an aromatic heterocyclic group containing a carbon atom coordinating to M^{X1}, a nitrogen-containing aromatic heterocyclic group containing a nitrogen atom coordinating to M^{X1}, an alkyloxy group, an aryloxy group, an alkylthio group, an arylthio group, or an dialkylphosphino group, and more preferably an aromatic hydrocarbon ring group containing a carbon atom coordinating to M^{X1}, an aromatic heterocyclic group containing a carbon atom coordinating to M^{X1}, or a nitrogen-containing aromatic heterocyclic group containing a nitrogen atom coordinating to M^{X1}.

The bonds between M^{X1} and each of Q^{X11} to Q^{X16} may be a coordination bond or a covalent bond.

In formula (II), L^{X11} to L^{X14} each represent a single or double bond or a connecting group. The connecting group is not particularly limited, but preferably a connecting group containing one or more atoms selected from carbon, nitrogen, oxygen, sulfur, and silicon. Examples of the connecting group are shown below.

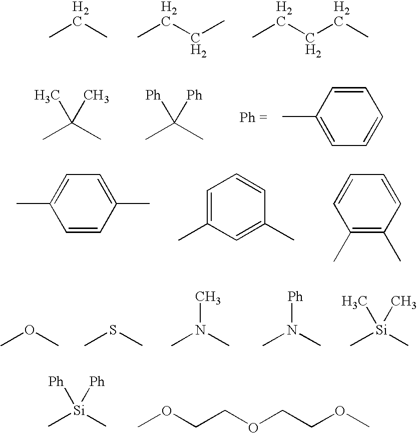

These connecting groups may be substituted, and the substituent may be selected from the examples of the substituents represented by R²¹ to R²⁴ in the following formula (1), and the preferable range thereof is also the same as in formula (1). L^{X11} to L^{X14} are each preferably a single bond, a dimethylmethylene group, or a dimethylsilylene group.

Preferable examples of the compound represented by formula (I) are compounds represented by formulae (1), (2), (3), and (4) described below.

The compound represented by formula (1) is described first.

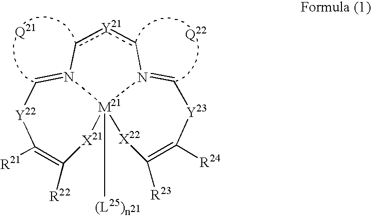

In formula (1), M²¹ represents a metal ion, and Y²¹ represents a connecting group or a single or double bond. Y²² and Y²³ each represent a single bond or a connecting group. Q²¹ and Q²² each represent an atomic group forming a nitrogen-containing heterocyclic ring, and the bond between Y²¹ and the ring containing Q²¹ and the bond between Y²¹ and the ring containing Q²² are each a single or double bond. X²¹ and X²² each independently represent an oxygen atom, a sulfur atom, or a substituted or unsubstituted nitrogen atom. R²¹, R²², R²³, and R²⁴ each independently represent a hydrogen atom or a substituent. R²¹ and R²² may be bonded to each other to form a ring, and R²³ and R²⁴ may be bonded to each other to form a ring. L²⁵ represents a ligand coordinating to M²¹, and n²¹ represents an integer of 0 to 4.

The compound represented by formula (1) will be described in detail.

In formula (1), the definition of M²¹ is the same as the definition of M¹¹ in formula (I), and their preferable ranges are also the same.

Q²¹ and Q²² each independently represent an atomic group forming a nitrogen-containing heterocyclic ring (ring containing a nitrogen atom coordinating to M²¹). The nitrogen-containing heterocyclic rings formed by Q²¹ and Q²² are not particularly limited, and may be selected, for example from pyridine, pyrazine, pyrimidine, triazine, thiazole, oxazole, pyrrole, and triazole rings, condensed rings containing one or more of the above rings (e.g., quinoline, benzoxazole, benzimidazole, and indolenine rings), and tautomers thereof.

The nitrogen-containing heterocyclic rings formed by Q²¹ and Q²² are preferably selected from pyridine, pyrazine, pyrimidine, pyridazine, triazine, pyrazole, imidazole, oxazole, pyrrole, and benzazole rings, condensed rings containing one or more of the above rings (e.g., quinoline, benzoxazole, and benzimidazole rings) and tautomers thereof; more preferably from pyridine, pyrazine, pyrimidine, imidazole, and pyrrole rings, condensed rings containing one or more of the above rings (e.g., a quinoline ring), and tautomers thereof; still more preferably from a pyridine ring and condensed rings containing a pyridine ring (e.g., quinoline ring); particularly preferably from a pyridine ring.

X²¹ and X²² each independently represent an oxygen atom, a sulfur atom, or a substituted or unsubstituted nitrogen atom. X²¹ and X²² are each preferably an oxygen atom, a sulfur atom, or a substituted nitrogen atom, more preferably an oxygen or sulfur atom, and particularly preferably an oxygen atom.

The definition of Y²¹ is the same as that of Y¹¹ in formula (I), and their preferable ranges are also the same.

Y²² and Y²³ each independently represent a single bond or a connecting group, preferably a single bond. The connecting group is not particularly limited, and examples thereof include a carbonyl connecting group, a thiocarbonyl connecting group, an alkylene group, an alkenylene group, an arylene group, a heteroarylene group, an oxygen atom connecting group, a nitrogen atom connecting group, and connecting groups comprising combinations of connecting groups selected from the above.

The connecting group represented by Y²² or Y²³ is preferably a carbonyl, alkylene, or alkenylene connecting group, more preferably a carbonyl or alkenylene connecting group, and still more preferably a carbonyl connecting group.

R²¹, R²², R²³, and R²⁴ each independently represent a hydrogen atom or a substituent. The substituent is not particularly limited, and examples thereof include alkyl groups (preferably having 1 to 30 carbon atoms, more preferably 1 to 20 carbon atoms, and particularly preferably 1 to 10 carbon atoms, such as methyl, ethyl, iso-propyl, tert-butyl, n-octyl, n-decyl, n-hexadecyl, cyclopropyl, cyclopentyl, and cyclohexyl), alkenyl groups (preferably having 2 to 30 carbon atoms, more preferably 2 to 20 carbon atoms, and particularly preferably 2 to 10 carbon atoms, such as vinyl, allyl, 2-butenyl, and 3-pentenyl), alkynyl groups (preferably having 2 to 30 carbon atoms, more preferably 2 to 20 carbon atoms, and particularly preferably 2 to 10 carbon atoms, such as propargyl and 3-pentynyl), aryl groups (preferably having 6 to 30 carbon atoms, more preferably 6 to 20 carbon atoms, and particularly preferably 6 to 12 carbon atoms, such as phenyl, p-methylphenyl, naphthyl, and anthranyl), amino groups (preferably having 0 to 30 carbon atoms, more preferably 0 to 20 carbon atoms, and particularly preferably 0 to 10 carbon atoms, such as amino, methylamino, dimethylamino, diethylamino, dibenzylamino, diphenylamino, and ditolylamino), alkoxy groups (preferably having 1 to 30 carbon atoms, more preferably 1 to 20 carbon atoms, and particularly preferably 1 to 10 carbon atoms, such as methoxy, ethoxy, butoxy, and 2-ethylhexyloxy), aryloxy groups (preferably having 6 to 30 carbon atoms, more preferably 6 to 20 carbon atoms, and particularly preferably 6 to 12 carbon atoms, such as phenyloxy, 1-naphthyloxy, and 2-naphthyloxy), heterocyclic oxy groups (preferably having 1 to 30 carbon atoms, more preferably 1 to 20 carbon atoms, and particularly preferably 1 to 12 carbon atoms, such as pyridyloxy, pyrazyloxy, pyrimidyloxy, and quinolyloxy), acyl groups (preferably having 1 to 30 carbon atoms, more preferably 1 to 20 carbon atoms, and particularly preferably 1 to 12 carbon atoms, such as acetyl, benzoyl, formyl, and pivaloyl), alkoxycarbonyl groups (preferably having 2 to 30 carbon atoms, more preferably 2 to 20 carbon atoms, and particularly preferably 2 to 12 carbon atoms, such as methoxycarbonyl and ethoxycarbonyl), aryloxycarbonyl groups (preferably having 7 to 30 carbon atoms, more preferably 7 to 20 carbon atoms, and particularly preferably 7 to 12 carbon atoms, such as phenyloxycarbonyl), acyloxy groups (preferably having 2 to 30 carbon atoms, more preferably 2 to 20 carbon atoms, and particularly preferably 2 to 10 carbon atoms, such as acetoxy and benzoyloxy), acylamino groups (preferably having 2 to 30 carbon atoms, more preferably 2 to 20 carbon atoms, and particularly preferably 2 to 10 carbon atoms, such as acetylamino and benzoylamino), alkoxycarbonylamino groups (preferably having 2 to 30 carbon atoms, more preferably 2 to 20 carbon atoms, and particularly preferably 2 to 12 carbon atoms, such as methoxycarbonylamino), aryloxycarbonylamino groups (preferably having 7 to 30 carbon atoms, more preferably 7 to 20 carbon atoms, and particularly preferably 7 to 12 carbon atoms, such as phenyloxycarbonylamino), sulfonylamino groups (preferably having 1 to 30 carbon atoms, more preferably 1 to 20 carbon atoms, and particularly preferably 1 to 12 carbon atoms, such as methanesulfonylamino and benzenesulfonylamino), sulfamoyl groups (preferably having 0 to 30 carbon atoms, more preferably 0 to 20 carbon atoms, and particularly preferably 0 to 12 carbon atoms, such as sulfamoyl, methylsulfamoyl, dimethylsulfamoyl, and phenylsulfamoyl), carbamoyl groups (preferably having 1 to 30 carbon atoms, more preferably 1 to 20 carbon atoms, and particularly preferably 1 to 12 carbon atoms, such as carbamoyl, methylcarbamoyl, diethylcarbamoyl, and phenylcarbamoyl), alkylthio groups (preferably having 1 to 30 carbon atoms, more preferably 1 to 20 carbon atoms, and particularly preferably 1 to 12 carbon atoms, such as methylthio and ethylthio), arylthio groups (preferably having 6 to 30 carbon atoms, more preferably 6 to 20 carbon atoms, and particularly preferably 6 to 12 carbon atoms, such as phenylthio), heterocyclic thio groups (preferably having 1 to 30 carbon atoms, more preferably 1 to 20 carbon atoms, and particularly preferably 1 to 12 carbon atoms, such as pyridylthio, 2-benzimidazolylthio, 2-benzoxazolylthio, and 2-benzothiazolylthio), sulfonyl groups (preferably having 1 to 30 carbon atoms, more preferably 1 to 20 carbon atoms, and particularly preferably 1 to 12 carbon atoms, such as mesyl and tosyl), sulfinyl groups (preferably having 1 to 30 carbon atoms, more preferably 1 to 20 carbon atoms, and particularly preferably 1 to 12 carbon atoms, such as methanesulfinyl and benzenesulfinyl), ureido groups (preferably having 1 to 30 carbon atoms, more preferably 1 to 20 carbon atoms, and particularly preferably 1 to 12 carbon atoms, such as ureido, methylureido, and phenylureido), phosphoric amide groups (preferably having 1 to 30 carbon atoms, more preferably 1 to 20 carbon atoms, and particularly preferably 1 to 12 carbon atoms, such as diethylphosphoric amide and phenylphosphoric amide), a hydroxy group, a mercapto group, halogen atoms (e.g., fluorine, chlorine, bromine, and iodine), a cyano group, a sulfo group, a carboxyl group, a nitro group, a hydroxamic acid group, sulfino groups, hydrazino groups, imino groups, heterocyclic groups (preferably having 1 to 30 carbon atoms and more preferably 1 to 12 carbon atoms; the heteroatom(s) may be selected from nitrogen, oxygen, and sulfur atoms), such as imidazolyl, pyridyl, quinolyl, furyl, thienyl, piperidyl, morpholino, benzoxazolyl, benzimidazolyl, benzothiazolyl, carbazolyl, and azepinyl, silyl groups (preferably having 3 to 40 carbon atoms, more preferably 3 to 30 carbon atoms, and particularly preferably 3 to 24 carbon atoms, such as trimethylsilyl and triphenylsilyl), and silyloxy groups (preferably having 3 to 40 carbon atoms, more preferably 3 to 30 carbon atoms, and particularly preferably 3 to 24 carbon atoms, such as trimethylsilyloxy and triphenylsilyloxy). These substituents may be substituted.

In a preferable embodiment, R²¹, R²², R²³, and R²⁴ are each independently selected from alkyl groups or aryl groups, or R²¹ and R²² bind to each other to form a ring structure (e.g., a benzo-condensed ring or a pyridine-condensed ring), and/or R²³ and R²⁴ bind to each other to form a ring structure or ring structures (e.g., a benzo-condensed ring or a pyridine-condensed ring). In a more preferable embodiment, R²¹ and R²² bind to each other to form a ring structure (e.g., a benzo-condensed ring or a pyridine-condensed ring), and/or R²³ and R²⁴ bind to each other to form a ring structure or ring structures (e.g., a benzo-condensed ring or a pyridine-condensed ring).

The definition of L²⁵ is the same as that of L¹⁵ in formula (I), and their preferable ranges are also the same.

The definition of n²¹ is the same as that of n¹¹ in formula (I), and their preferable ranges are also the same.

In formula (1), examples of preferable embodiments are described below:
(1) the rings formed by Q²¹ and Q²² are pyridine rings, Y²¹ is a connecting group;
(2) the rings formed by Q²¹ and Q²² are pyridine rings, Y²¹ is a single or double bond, and X²¹ and X²² are selected from sulfur atoms, substituted nitrogen atoms, and unsubstituted nitrogen atom;
(3) the rings formed by Q²¹ and Q²² are each a five-membered nitrogen-containing heterocyclic ring, or a nitrogen-containing six-membered ring containing two or more nitrogen atoms.

Preferable examples of compounds represented by formula (1) are compounds represented by the following formula (1-A).

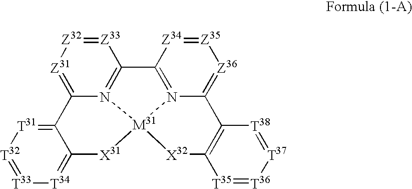

The compound represented by formula (1-A) will be described below.

In formula (1-A), the definition of M³¹ is the same as that of M¹¹ in formula (I), and their preferable ranges are also the same.

Z³¹, Z³², Z³³, Z³⁴, Z³⁵, and Z³⁶ each independently represent a substituted or unsubstituted carbon or nitrogen atom, and preferably a substituted or unsubstituted carbon atom. The substituent on the carbon may be selected from the substituents described as examples of R²¹ in formula (1). Z³¹ and Z³² may be bonded to each other via a connecting group to form a condensed ring (e.g., a benzo-condensed ring or a pyridine-condensed ring). Z³² and Z³³ may be bonded to each other via a connecting group to form a condensed ring (e.g., a benzo-condensed ring or a pyridine-condensed ring). Z³³ and Z³⁴ may be bonded to each other via a connecting group to form a condensed ring (e.g., a benzo-condensed ring or a pyridine-condensed ring). Z³⁴ and Z³⁵ may be bonded to each other via a connecting group to form a condensed ring (e.g., a benzo-condensed ring or a pyridine-condensed ring). Z³⁵ and Z³⁶ may be bonded to each other via a connecting group to form a condensed ring (e.g., a benzo-condensed ring or a pyridine-condensed ring). Z³¹ and T³¹ may be bonded to each other via a connecting group to form a condensed ring (e.g., a benzo-condensed ring or a pyridine-condensed ring). Z³⁶ and T³⁸ may be bonded to each other via a connecting group to form a condensed ring (e.g., a benzo-condensed ring or a pyridine-condensed ring).

The substituent on the carbon is preferably an alkyl group, an alkoxy group, an alkylamino group, an aryl group, a group capable of forming a condensed ring (e.g., a benzo-condensed ring or a pyridine-condensed ring), or a halogen atom, more preferably an alkylamino group, an aryl group, or a group capable of forming a condensed ring (e.g., a benzo-condensed ring or a pyridine-condensed ring), still more preferably an aryl group or a group capable of forming a condensed ring (e.g., a benzo-condensed ring or a pyridine-condensed ring), and particularly preferably a group capable of forming a condensed ring (e.g., a benzo-condensed ring or a pyridine-condensed ring).

T³¹, T³², T³³, T³⁴, T³⁵, T³⁶, T³⁷, and T³⁸ each independently represent a substituted or unsubstituted carbon or nitrogen atom, and more preferably a substituted or unsubstituted carbon atom. Examples of the substituents on the carbon include the groups described as examples of R²¹ in formula (1); T³¹ and T³² may be bonded to each other via a connecting group to form a condensed ring (e.g., a benzo-condensed ring). T³² and T³³ may be bonded to each other via a connecting group to form a condensed ring (e.g., a benzo-condensed ring). T³³ and T³⁴ may be bonded to each other via a connecting group to form a condensed ring (e.g., a benzo-condensed ring). T³⁵ and T³⁶ may be bonded to each other via a connecting group to form a condensed ring (e.g., a benzo-condensed ring). T³⁶ and T³⁷ may be bonded to each other via a connecting group to form a condensed ring (e.g., a benzo-condensed ring). T³⁷ and T³⁸ may be bonded to each other via a connecting group to form a condensed ring (e.g., a benzo-condensed ring).

The substituent on the carbon is preferably an alkyl group, an alkoxy group, an alkylamino group, an aryl group, a group capable of forming a condensed ring (e.g., a benzo-condensed ring or a pyridine-condensed ring), or a halogen atom; more preferably an aryl group, a group capable of forming a condensed ring (e.g., a benzo-condensed ring or pyridine-condensed ring), or a halogen atom; still more preferably an aryl group or a halogen atom, and particularly preferably an aryl group.

The definitions and preferable ranges of X³¹ and X³² are the same as the definitions and preferable ranges of X²¹ and X²² in formula (1), respectively.

The compound represented by formula (2) will be described below.

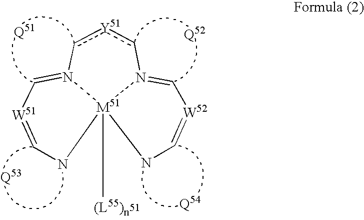

In formula (2), the definition of M⁵¹ is the same as that of M¹¹ in formula (I), and their preferable ranges are also the same.

The definitions of Q⁵¹ and Q⁵² are the same as the definitions of Q²¹ and Q²² in formula (1), and their preferable ranges are also the same.

Q⁵³ and Q⁵⁴ each independently represent a group forming a nitrogen-containing heterocyclic ring (ring containing a nitrogen coordinating to M⁵¹). The nitrogen-containing heterocyclic rings formed by Q⁵³ and Q⁵⁴ are not particularly limited, and are preferably selected from tautomers of pyrrole derivatives, tautomers of imidazole derivatives (e.g., the five-membered heterocyclic ligand contained in the compound (29) shown below as a specific example of the compound represented by formula (I)), tautomers of thiazole derivatives (e.g., the five-membered heterocyclic ligand contained in the compound (30) shown below as a specific example of the compound represented by formula (I)), and tautomers of oxazole derivatives (e.g., the five-membered heterocyclic ligand contained in the compound (31) shown below as a specific example of the compound represented by formula (I)), more preferably selected from tautomers of pyrrole, imidazole, and thiazole derivatives; still more preferably selected from tautomers of pyrrole and imidazole derivatives; and particularly preferably selected from tautomers of pyrrole derivatives.

The definition of Y⁵¹ is the same as that of Y¹¹ in formula (1), and their preferable range are also the same. The definition of L⁵⁵ is the same as that of L¹⁵ in formula (I), and their preferable ranges are also the same. The definition of n⁵¹ is the same as that of n¹¹ in formula (I), and their preferable ranges are also the same.

W⁵¹ and W⁵² each independently represent a substituted or unsubstituted carbon or nitrogen atom, more preferably an unsubstituted carbon or nitrogen atom, and still more preferably an unsubstituted carbon atom.

The compound represented by formula (3) will be described below.

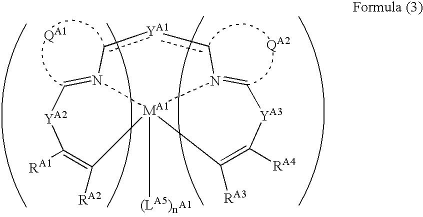

In formula (3), the definitions and preferable ranges of M^{A1}, Q^{A1}, Q^{A2}, Y^{A1}, Y^{A2}, Y^{A3}, R^{A1}, R^{A2}, R^{A3}, R^{A4}, L^{A5}, and n^{A1} are the same as the definitions and preferable ranges of M²¹, Q²¹, Q²²Y²¹, Y²², Y²³, R²¹, R²², R²³, R²⁴, L²⁵, and n²¹ in formula (1) respectively.

Preferable examples of compounds represented by formula (3) are compounds represented by the following formulae (3-A) and (3-B).

The compound represented by formula (3-A) will be described first.

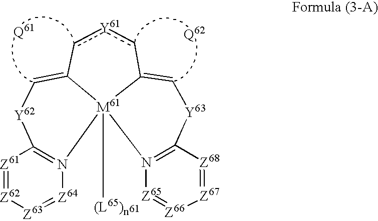

In formula (3-A), the definitions of M⁶¹ is the same as that of M¹¹ in formula (I), and their preferable ranges are also the same.

Q⁶¹ and Q⁶² each independently represent a ring-forming group. The rings formed by Q⁶¹ and Q⁶² are not particularly limited, and examples thereof include benzene, pyridine, pyridazine, pyrimidine, thiophene, isothiazole, furan, and isoxazole rings, and condensed rings thereof.

Each of the rings formed by Q⁶¹ and Q⁶² is preferably a benzene ring, a pyridine ring, a thiophene ring, a thiazole ring, or a condensed ring containing one or more of the above rings; more preferably a benzene ring, a pyridine ring, or a condensed ring containing one or more of the above rings; and still more preferably a benzene or a condensed ring containing a benzene ring.

The definition of Y⁶¹ is the same as that of Y¹¹ in formula (1), and their preferable ranges are also the same.

Y⁶² and Y⁶³ each independently represent a connecting group or a single bond. The connecting group is not particularly limited, and examples thereof include a carbonyl connecting group, a thiocarbonyl connecting group, alkylene groups, alkenylene groups, arylene groups, heteroarylene groups, an oxygen atom connecting groups, a nitrogen atom connecting groups, and connecting groups comprising combinations of connecting groups selected from the above.

Y⁶² and Y⁶³ are each independently selected, preferably from a single bond, a carbonyl connecting group, an alkylene connecting group, and an alkenylene group, more preferably from a single bond and an alkenylene group, and still more preferably from a single bond.

The definition of L⁶⁵ is the same as that of L¹⁵ in formula (I), and their preferable ranges are also the same. The definition of n⁶¹ is the same as the definition of n¹¹ in formula (I), and their preferable ranges are also the same.

Z⁶¹, Z⁶², Z⁶³, Z⁶⁴, Z⁶⁵, Z⁶⁶, Z⁶⁷, and Z⁶⁸ each independently represent a substituted or unsubstituted carbon or nitrogen atom, and preferably a substituted or unsubstituted carbon atom. Examples of the substituent on the carbon include the groups described as examples of R²¹ in formula (1). Z⁶¹ and Z⁶² may be bonded to each other via a connecting group to form a condensed ring (e.g., a benzo-condensed ring or a pyridine-condensed ring). Z⁶² and Z⁶³ may be bonded to each other via a connecting group to form a condensed ring (e.g., a benzo-condensed ring or a pyridine-condensed ring). Z⁶³ and Z⁶⁴ may be bonded to each other via a connecting group to form a condensed ring (e.g., a benzo-condensed ring or a pyridine-condensed ring). Z⁶⁵ and Z⁶⁶ may be bonded to each other via a connecting group to form a condensed ring (e.g., a benzo-condensed ring or a pyridine-condensed ring). Z⁶⁶ and Z⁶⁷ may be bonded to each other via a connecting group to form a condensed ring (e.g., a benzo-condensed ring or a pyridine-condensed ring). Z⁶⁷ and Z⁶⁸ may be bonded to each other via a connecting group to form a condensed ring (e.g., a benzo-condensed ring or a pyridine-condensed ring). The ring formed by Q⁶¹ may be bonded to Z⁶¹ via a connecting group to form a ring. The ring formed by Q⁶² may be bonded to Z⁶⁸ via a connecting group to form a ring.

The substituent on the carbon is preferably an alkyl group, an alkoxy group, an alkylamino group, an aryl group, a group capable of forming a condensed ring (e.g., benzo-condensed ring or pyridine-condensed ring), or a halogen atom, more preferably an alkylamino group, an aryl group, or a group capable of forming a condensed ring (e.g., benzo-condensed ring or pyridine-condensed ring), still more preferably an aryl group or a group capable of forming a condensed ring (e.g., benzo-condensed ring or pyridine-condensed ring), and particularly preferably a group capable of forming a condensed ring (e.g., benzo-condensed ring or pyridine-condensed ring).

The compound represented by formula (3-B) will be described below.

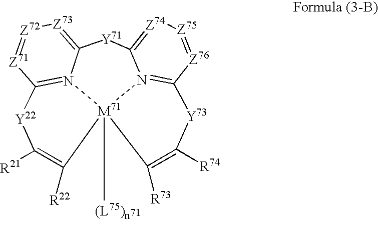

In formula (3-B), the definition of M⁷¹ is the same as the definition of M¹¹ in formula (I), and their preferable ranges are also the same.

The definitions and preferable ranges of Y⁷¹, Y⁷², and Y⁷³ are the same as the definitions and preferable range of Y⁶¹, Y⁶² and Y⁶³in formula (3-A). Y⁷¹, Y⁷², and Y⁷³ may be the same as each other or different from each other.

The definition of L⁷⁵ is the same as that of L¹⁵ in formula (I), and their preferable ranges are also the same.

The definition of n⁷¹ is the same as that of n¹¹ in formula (I), and their preferable ranges are also the same.

Z⁷¹, Z⁷², Z⁷³, Z⁷⁴, Z⁷⁵, and Z⁷⁶ each independently represent a substituted or unsubstituted carbon or nitrogen atom, and more preferably a substituted or unsubstituted carbon atom. Examples of the substituent on the carbon include the groups described as examples of R²¹ in formula (1). In addition, Z⁷¹ and Z⁷² may be bonded to each other via a connecting group to form a ring (e.g., a benzene ring or a pyridine ring). Z⁷² and Z⁷³ may be bonded to each other via a connecting group to form a ring (e.g., a benzene ring or a pyridine ring). Z⁷³ and Z⁷⁴may be bonded to each other via a connecting group to form a ring (e.g., a benzene ring or a pyridine ring). Z⁷⁴ and Z⁷⁵ may be bonded to each other via a connecting group to form a ring (e.g., a benzene ring or a pyridine ring). Z⁷⁵ and Z⁷⁶ may be bonded to each other via a connecting group to form a ring (e.g., a benzene ring or a pyridine ring). The definitions and preferable ranges of R⁷¹ to R⁷⁴ are the same as the definitions of R²¹ to R²⁴ in formula (1), respectively.

Preferable examples of compounds represented by formula (3-B) include compounds represented by the following formula (3-C).

The compound represented by formula (3-C) will be described below.

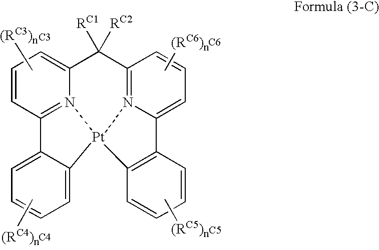

In formula (3-C), R^{C1} and R^{C2} each independently represent a hydrogen atom or a substituent, and the substituent may be selected from the alkyl groups and aryl groups described as examples of R²¹ to R²⁴ in formula (1). The definitions of R^{C3}, R^{C4}, R^{C5}, and R^{C6} are the same as the definitions of R²¹ to R²⁴ in formula (1). Each of n^{C3} and n^{C6} represents an integer of 0 to 3; each of n^{C4} and n^{C5} represents an integer of 0 to 4; when there are plural R^{C3}'s, R^{C4}'s, R^{C5}'s, or R^{C6}'s, the plural R^{C3}'s, R^{C4}'s , R^{C5}'s, or R^{C6}'s may be the same as each other or different from each other, and may be bonded to each other to form a ring. R^{C3}, R^{C4}, R^{C5}, and R^{C6} each preferably represent an alkyl, aryl, or heteroaryl group, or a halogen atom.

The compound represented by formula (4) will be described below.

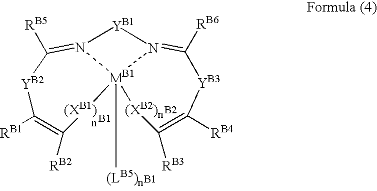

In formula (4), the definitions and preferable ranges of M^{B1}, Y^{B2}, Y^{B3}, R^{B1}, R^{B2}, R^{B3}, R^{B4}, L^{B5}, n^{B3}, X^{B1}, and X^{B2} are the same as the definitions of M²¹, Y²², Y²³, R²¹, R²², R²³, R²⁴, L²⁵, n²¹, X²¹, X²² in formula (1), respectively.

Y^{B1} represents a connecting group whose definition is the same as that of Y²¹ in formula (1). Y^{B1} is preferably a vinyl group substituted at 1- or 2-position, a phenylene ring, a pyridine ring, a pyrazine ring, a pyrimidine ring, or a methylene group having 2 to 8 carbons.

R^{B5} and R^{B6} each independently represent a hydrogen atom or a substituent, and the substituent may be selected from the alkyl groups, aryl groups, and heterocyclic groups described as examples of R²¹ to R²⁴ in formula (1). However, Y^{B1} is not bonded to R^{B1} or R^{B6}. n^{B1} and n^{B2} each independently represent an integer of 0 or 1.

Preferable examples of the compound represented by formula (4) include compounds represented by the following formula (4-A).

The compound represented by formula (4-A) will be described below.

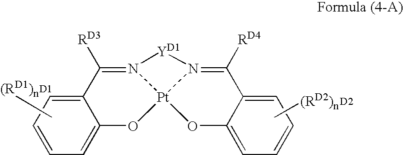

In formula (4-A), R^{D3} and R^{D4} each independently represent a hydrogen atom or a substituent, and R^{D1} and R^{D2} each represent a substituent. The substituents represented by R^{D1}, R^{D2}, R^{D3}, and R^{D4} may be selected from the substituents described as examples of R^{B5} and R^{B6} in formula (4), and have the same preferable range as R^{B5} and R^{B6} in formula (4). n^{D1} and n^{D2} each represent an integer of 0 to 4. When there are plural R^{D1}'s, the plural R^{D1}'S may be the same as or different from each other or may be bonded to each other to form a ring. When there are plural R^{D2}'s, the plural R^{D2}'S may be the same as or different from each other or may be bonded to each other to form a ring. y^{D1} represents a vinyl group substituted at 1- or 2-position, a phenylene ring, a pyridine ring, a pyrazine ring, a pyrimidine ring, or a methylene group having 1 to 8 carbons.

Preferable examples of the metal complex having a tridentate ligand in the present invention include compounds represented by the following formula (5).

The compound represented by formula (5) will be described below.

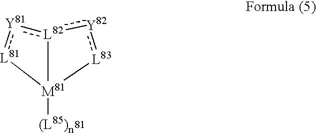

In formula (5), the definition of M⁸¹ is the same as that of M¹¹ in formula (I), and their preferable ranges are also the same.

The definitions and preferable ranges of L⁸¹, L⁸², and L⁸³ are the same as the definitions and preferable ranges of L¹¹, L¹², and L¹⁴ in formula (I), respectively.

The definitions and preferable ranges of Y⁸¹ and Y⁸² are the same as the definitions and preferable ranges of Y¹¹ and Y¹² in formula (I), respectively.

L⁸⁵ represents a ligand coordinating to M⁸¹. L⁸⁵ is preferably a monodentate to tridentate ligand and more preferably a monodentate to tridentate anionic ligand. The monodentate to tridentate anionic ligand is not particularly limited, but is preferably a halogen ligand or a tridentate ligand of L⁸¹, Y⁸¹, L⁸², Y⁸², and L⁸³ can form, and more preferably a tridentate ligand of L⁸¹, Y⁸¹, L⁸², Y⁸², and L⁸³ can form. L⁸⁵ is not directly bonded to L⁸¹ or L⁸³. The numbers of coordination sites and ligands do not exceed the valency of the metal.

n⁸¹ represents an integer of 0 to 5. When M⁸¹ is a tetravalent metal, n⁸¹ is 1, and L⁸⁵ represents a monodentate ligand. When M⁸¹ is a hexavalent metal, n⁸¹ is preferably 1 to 3, more preferably 1 or 3, and still more preferably 1. When M⁸¹ is hexavalent and n⁸¹ is 1, L⁸⁵ represents a tridentate ligand. When M⁸¹ is hexavalent and n⁸¹ is 2, L⁸⁵ represents a monodentate ligand and a bidentate ligand. When M⁸¹ is hexavalent and n⁸¹ is 3, L⁸⁵ represents a monodentate ligand. When M⁸¹ is an octavalent metal, n⁸¹ is preferably 1 to 5, more preferably 1 or 2, and still more preferably 1. When M⁸¹ is octavalent and n⁸¹ is 1, L⁸⁵ represents a pentadentate ligand. When M⁸¹ is octavalent and n⁸¹ is 2, L⁸⁵ represents a tridentate ligand and a bidentate ligand. When M⁸¹ is octavalent and n⁸ is 3, L⁸⁵ represents a tridentate ligand and two monodentate ligands, or represents two bidentate ligands and one monodentate ligand. When M⁸¹ is octavalent and n⁸¹ is 4, L⁸⁵ represents one bidentate ligand and three monodentate ligands. When M⁸¹ is octavalent and n⁸¹ is 5, L⁸⁵ represents five monodentate ligands. When n⁸¹ is 2 or larger, there are plural L⁸⁵'s, and the plural L⁸⁵'s may be the same as or different from each other.

In a preferable example of the compound represented by formula (5), L⁸¹, L⁸², or L⁸³ each represent an aromatic ring containing a carbon atom coordinating to M⁸¹, a heterocyclic ring containing a carbon atom coordinating to M⁸¹, or a nitrogen-containing heterocyclic ring containing a nitrogen atom coordinating to M⁸¹, wherein at least one of L⁸¹, L⁸², and L⁸³ is a nitrogen-containing heterocyclic ring. Examples of the aromatic ring containing a carbon atom coordinating to M⁸¹, heterocyclic ring containing a carbon atom coordinating to M⁸¹, or nitrogen-containing heterocyclic ring containing a nitrogen atom coordinating to M⁸¹ include the examples of ligands each containing a nitrogen or carbon atom coordinating to M¹¹ in formula (I) described in the explanation of formula (I). Preferable examples thereof are the same as in the description of ligands each containing a nitrogen or carbon atom coordinating to M¹¹ in formula (I). Y⁸¹ and Y⁸² each preferably represent a single bond or a methylene group.

Other preferable examples of compounds represented by formula (5) include compounds represented by the following formulae (5-A) and (5-B).

The compound represented by formula (5-A) will be described first, below.

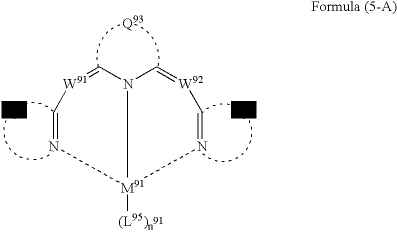

In formula (5-A), the definition of M⁹¹ is the same as that of M⁸¹ in formula (5), and their preferable ranges are also the same.

Q⁹¹ and Q⁹² each represent a group forming a nitrogen-containing heterocyclic ring (ring containing a nitrogen atom coordinating to M⁹¹). The nitrogen-containing heterocyclic rings formed by Q⁹¹ and Q⁹² are not particularly limited, and examples thereof include pyridine, pyrazine, pyrimidine, pyridazine, triazine, thiazole, oxazole, pyrrole, pyrazole, imidazole, and triazole rings, condensed rings containing one or more of the above rings (e.g., quinoline, benzoxazole, benzimidazole, and indolenine rings), and tautomers thereof.

Each of the nitrogen-containing heterocyclic rings formed by Q⁹¹ and Q⁹² is preferably a pyridine, pyrazole, thiazole, imidazole, or pyrrole ring, a condensed ring containing one or more of the above ring (e.g., quinoline, benzothiazole, benzimidazole, or indolenine rings), or a tautomer of any of the above rings; more preferably a pyridine or pyrrole ring, a condensed ring containing one or more of the above rings (e.g., a quinoline ring), or a tautomer of any of the above rings; more preferably a pyridine ring or a condensed ring containing a pyridine ring (e.g., a quinoline ring); and particularly preferably a pyridine ring.

Q⁹³ represents a group forming a nitrogen-containing heterocyclic ring (ring containing a nitrogen atom coordinating to M⁹¹). The nitrogen-containing heterocyclic ring formed by Q⁹³ is not particularly limited, but is preferably a pyrrole ring, an imidazole ring, a tautomer of a triazole ring, or a condensed ring containing one or more of the above rings (e.g., benzopyrrole), and more preferably a tautomer of a pyrrole ring or a tautomer of a condensed ring containing a pyrrole ring (e.g., benzopyrrole).

The definitions and preferable ranges of W⁹¹ and W⁹² are the same as the definitions and preferable ranges of W⁵¹ and W⁵² in formula (2), respectively.

The definition of L⁹⁵ is the same as that of L⁸⁵ in formula (5), and their preferable ranges are also the same.

The definition of n⁹¹ is the same as that of n⁸¹ in formula (5), and their preferable ranges are also the same.

The compound represented by formula (5-B) will be described below.

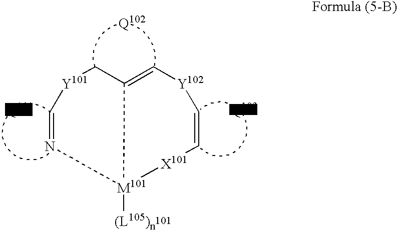

In formula (5-B), the definition of M¹⁰¹ is the same as that of M⁸¹ in formula (5), and their preferable ranges are also the same.

The definition of Q¹⁰² is the same as that of Q²¹ in formula (1), and their preferable ranges are also the same.

The definition of Q¹⁰¹ is the same as that of Q⁹¹ in formula (5-A), and their preferable ranges are also the same.

Q¹⁰³ represents a group forming an aromatic ring. The aromatic ring formed by Q¹⁰³ is not particularly limited, but is preferably a benzene, furan, thiophene, or pyrrole ring, or a condensed ring containing one or more of the above rings (e.g., a naphthalene ring), more preferably a benzene ring or a condensed ring containing a benzene ring (e.g., naphthalene ring), and particularly preferably a benzene ring.

The definitions and preferable ranges of Y¹⁰¹ and Y¹⁰² are the same as the definition and preferable range of Y²² in formula (1). Y¹⁰¹ and Y¹⁰² may be the same as or different from each other.

The definition of L¹⁰⁵ is the same as that of L⁸⁵ in formula (5), and their preferable ranges are also the same.

The definition of n¹⁰¹ is the same as that of n⁸¹ in formula (5), and their preferable ranges are also the same.

The definition of X¹⁰¹ is the same as that of X²¹ in formula (1), and their preferable ranges are also the same.

Other preferable examples of the metal complex having a tridentate ligand in the invention include compounds represented by formula (II). Among compounds represented by formula (H), compounds represented by the following formula (X2) are more preferable, and compounds represented by the following formula (X3) are still more preferable.

The compound represented by formula (X2) is described first.

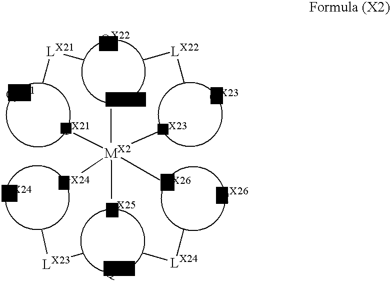

In formula (X2), M^{X2} represents a metal ion. Y^{X21} to Y^{X26} each represent an atom coordinating to M^{X2}; and Q^{X21} to Q^{X26} each represent an atomic group forming an aromatic ring or an aromatic heterocyclic ring respectively with Y^{X21} to Y^{X26}. L^{X21} to L^{X24} each represent a single or double bond or a connecting group. The bonds between M^{X2} and each of Y^{X21} to Y^{X26} may be a coordination bond or a covalent bond.

The compound represented by formula (X2) will be described below in detail.

In formula (X2), the definition of M^{X2} is the same as that of M^{X1} in formula (II), and their preferable ranges are also the same. Y^{X21} to Y^{X26} each represent an atom coordinating to M^{X2}. The bonds between M^{X2} and each of Y^{X21} to Y^{X26} may be a coordination bond or a covalent bond. Each of Y^{X21} to Y^{X26} is a carbon, nitrogen, oxygen, sulfur, phosphorus, or silicon atom, and preferably a carbon or nitrogen atom. Q^{X21} to Q^{X26} represent atomic groups forming rings containing Y^{X21} to Y^{X26}, respectively, and the rings are each independently selected from aromatic hydrocarbon rings and aromatic heterocyclic rings. The aromatic hydrocarbon rings and aromatic heterocyclic rings may be selected from benzene, pyridine, pyrazine, pyrimidine, pyridazine, triazine, pyrrole, pyrazole, imidazole, triazole, oxazole, thiazole, oxadiazole, thiadiazole, thiophene, and furan rings; preferably from benzene, pyridine, pyrazine, pyrimidine, pyrazole, irnidazole, and triazole rings; more preferably from benzene, pyridine, pyrazine, pyrazole, and triazole rings; and particularly preferably from benzene and pyridine rings. The aromatic rings may have a condensed ring or a substituent.

The definitions and preferable ranges of L^{X21} to L^{X24} are the same as the definitions and preferable ranges of L^{X11} to L^{X14} in formula (II), respectively.

Compounds represented by the following formula (X3) are more preferable examples of the compounds represented by formula (II).

The compound represented by formula (X3) will be described below.

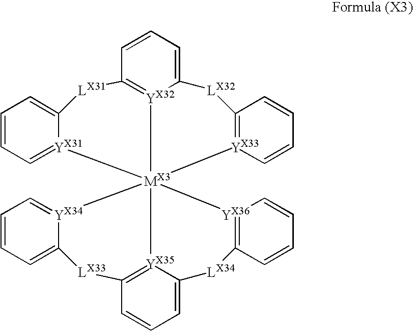

In formula (X3), M^{X3} represents a metal ion. Y^{X31} to Y^{X36} each represent a carbon, nitrogen, or phosphorus atom. L^{X31} to L^{X34} each represent a single or double bond or a connecting group. The bond between M^{X3} and each of Y^{X31} to Y^{X36} may be a coordination bond or a covalent bond.

The definition of M^{X3} is the same as that of M^{X1} in formula (II) above, and their preferable ranges are also the same. Y^{X31} to Y^{X36} each represent an atom coordinating to M^{X3}. The bonds between M^{X3} and each of Y^{X31} to Y^{X36} may be a coordination bond or a covalent bond. Y^{X31} to Y^{X36} each represent a carbon, nitrogen, or phosphorus atom and preferably a carbon or nitrogen atom. The definitions and preferable ranges of L^{X31} to L^{X34} are the same as the definitions and preferable ranges of L^{X11} to L^{X14} in formula (II), respectively.

Specific examples of compounds represented by the formulae (I), (II) and (5) include the compounds (1) to (242) described in Japanese Patent Application No. 2004-162849 (their structures being shown below). The disclosure of Japanese Patent Application No. 2004-162849 is incorporated herein by reference. 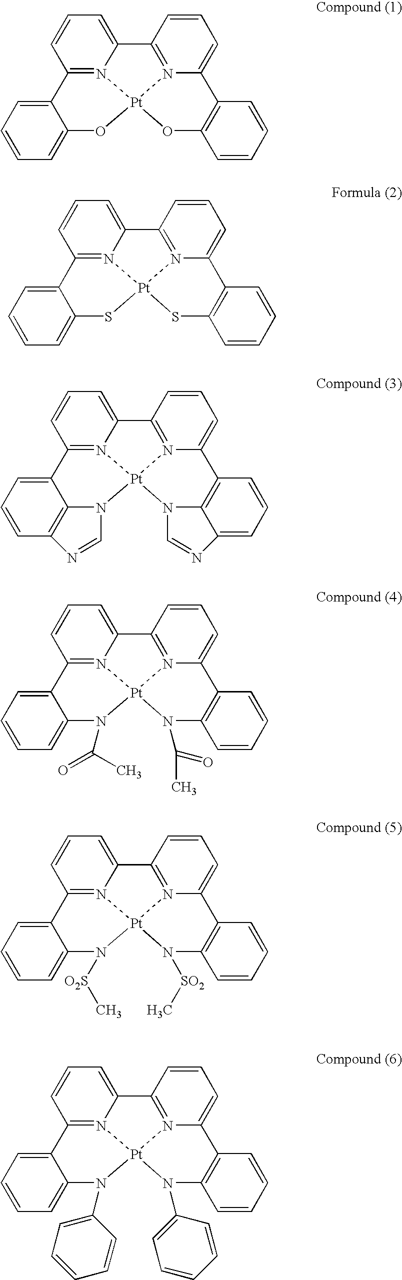 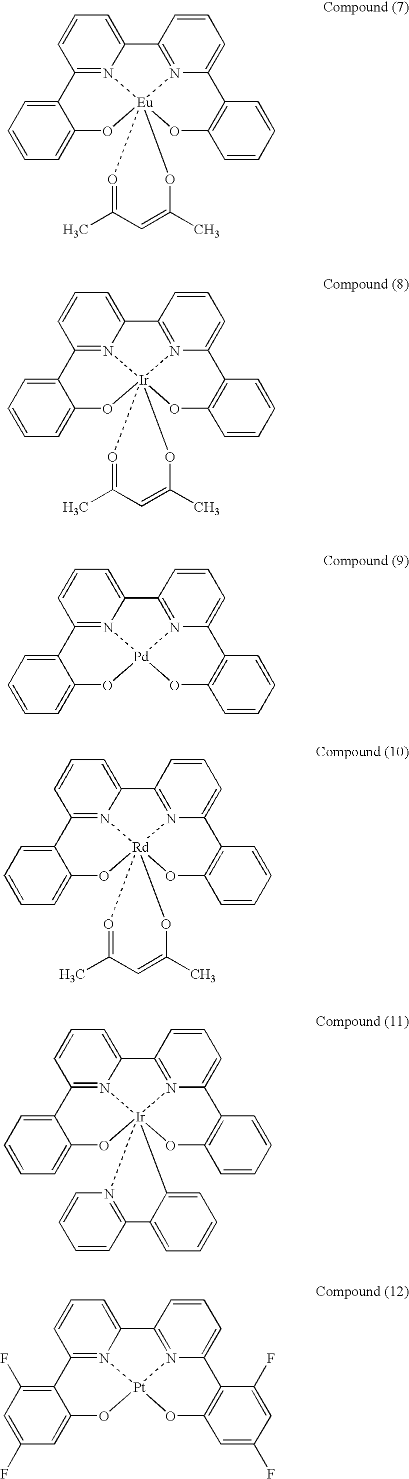 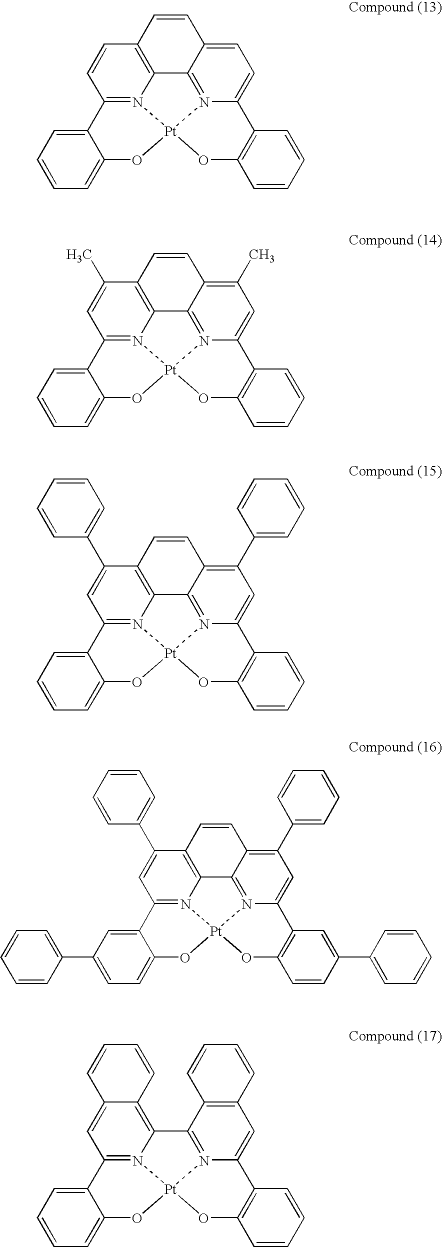 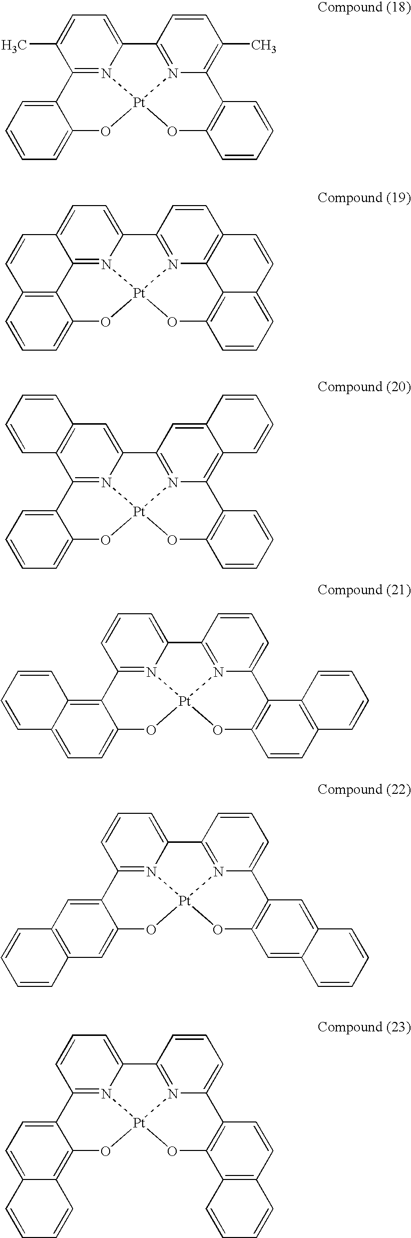 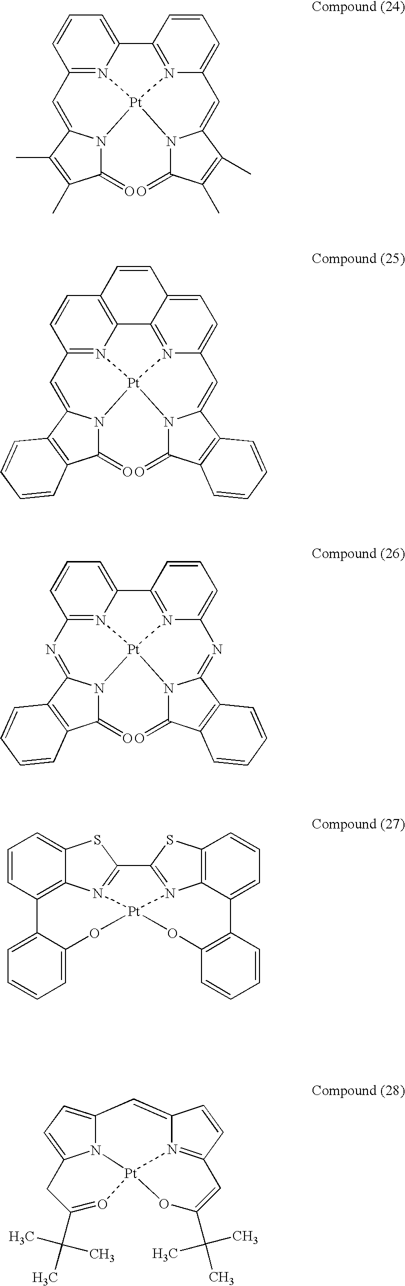 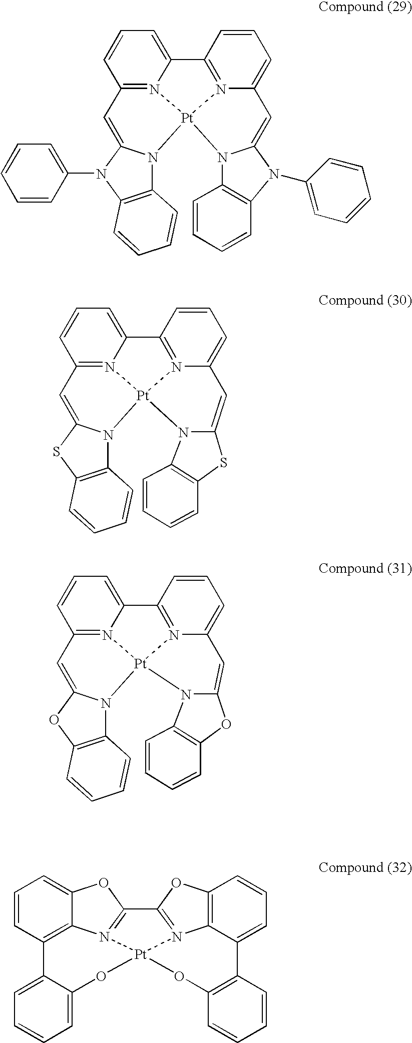 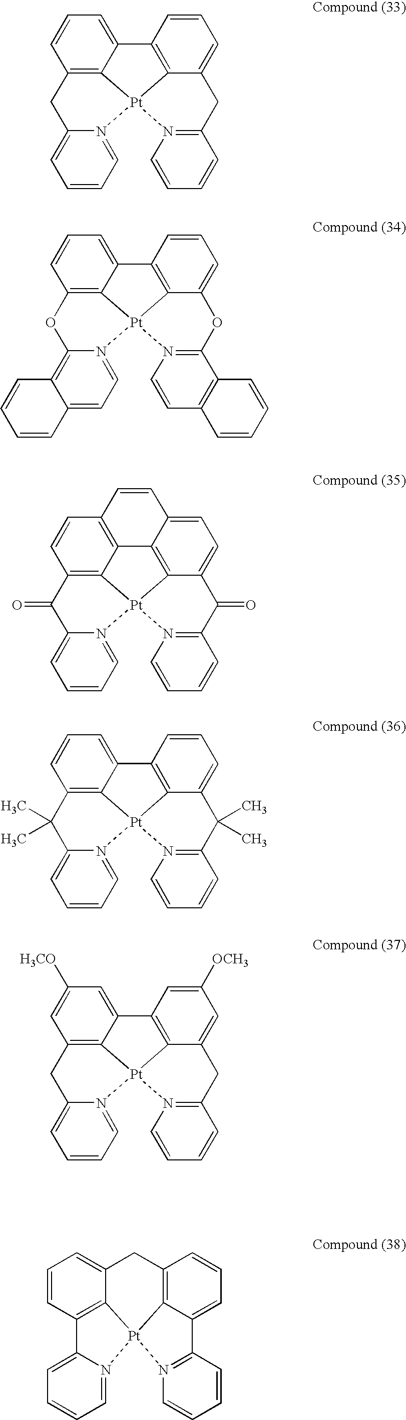 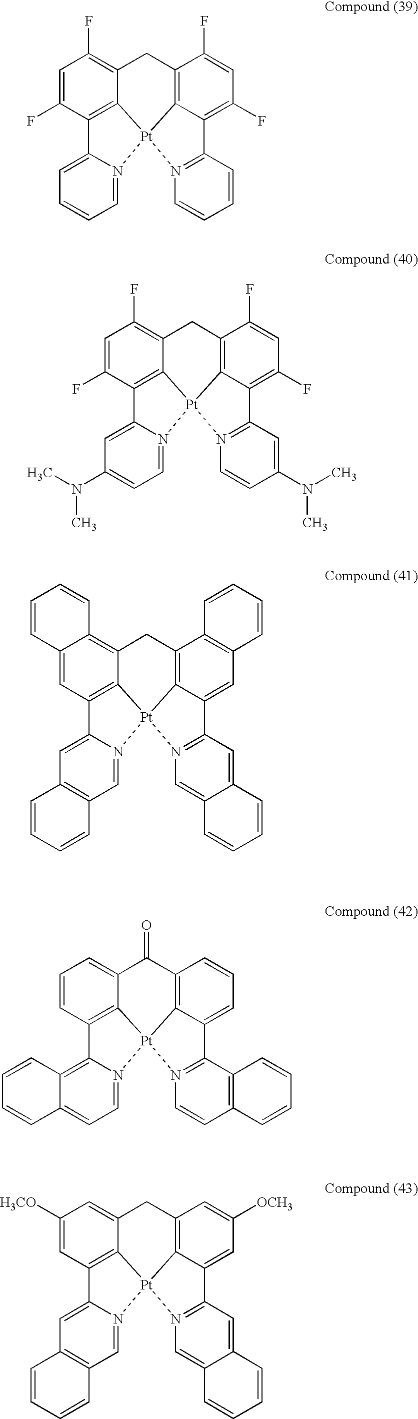 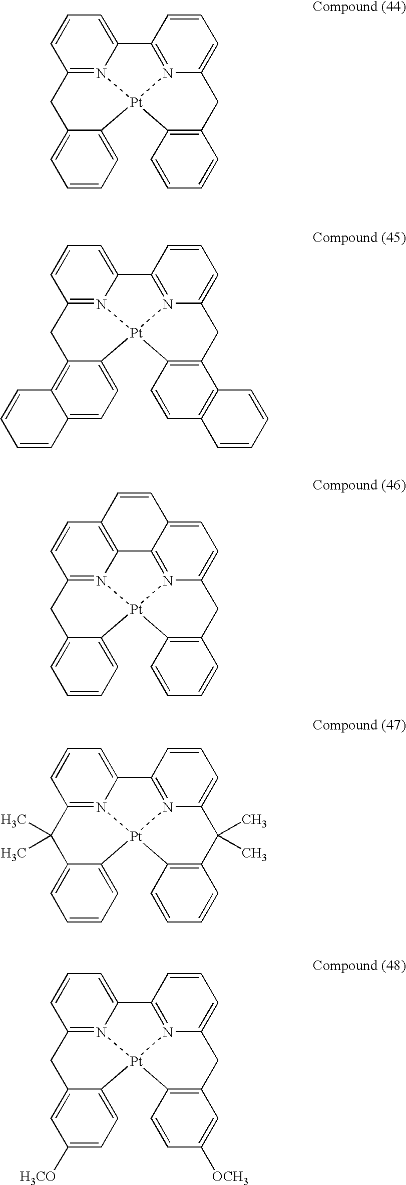 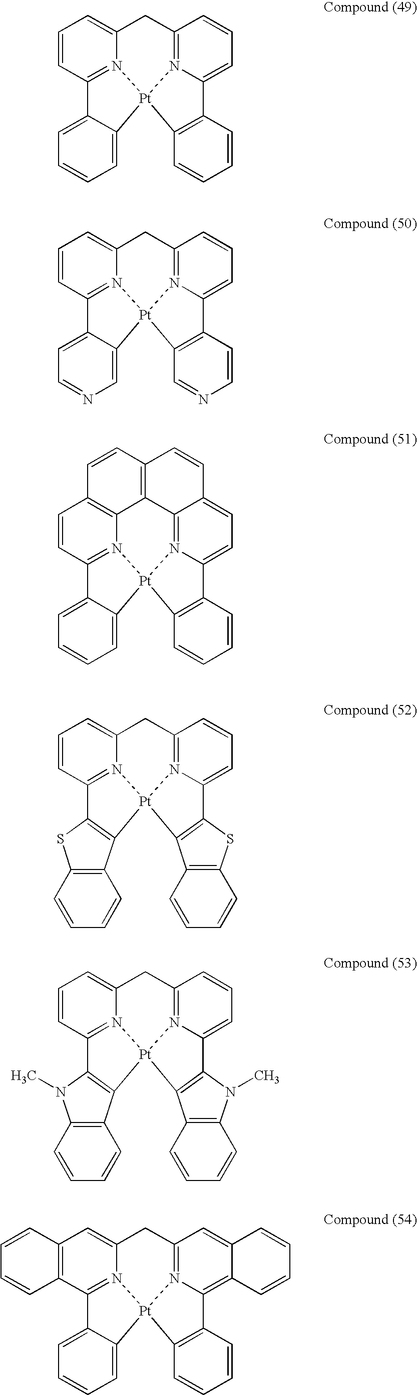 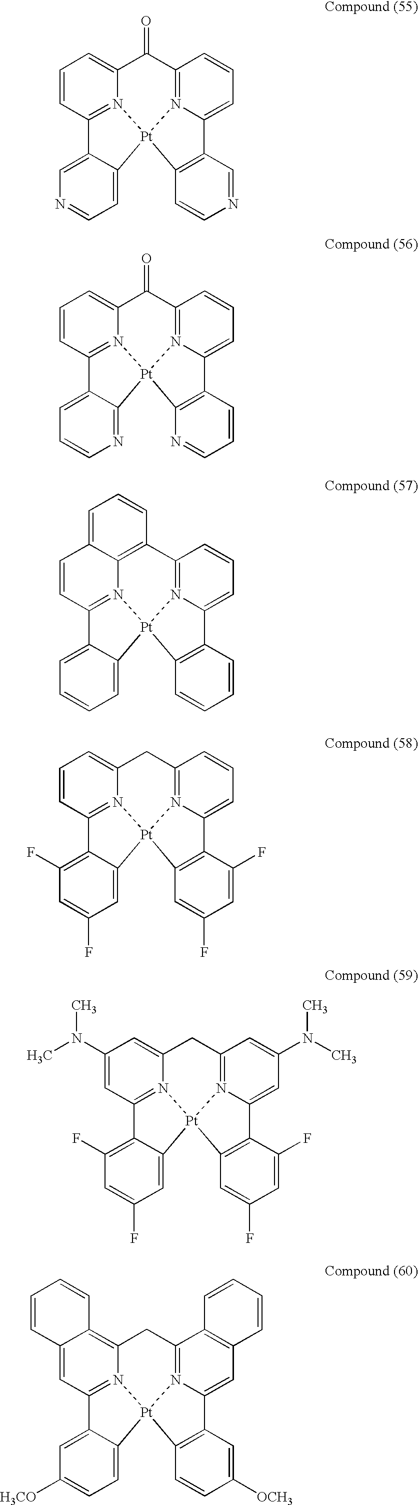 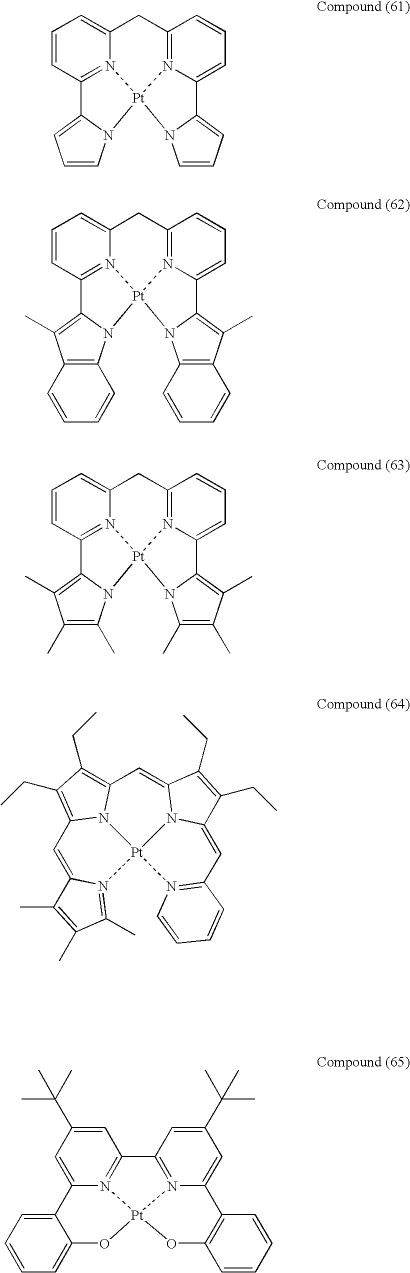 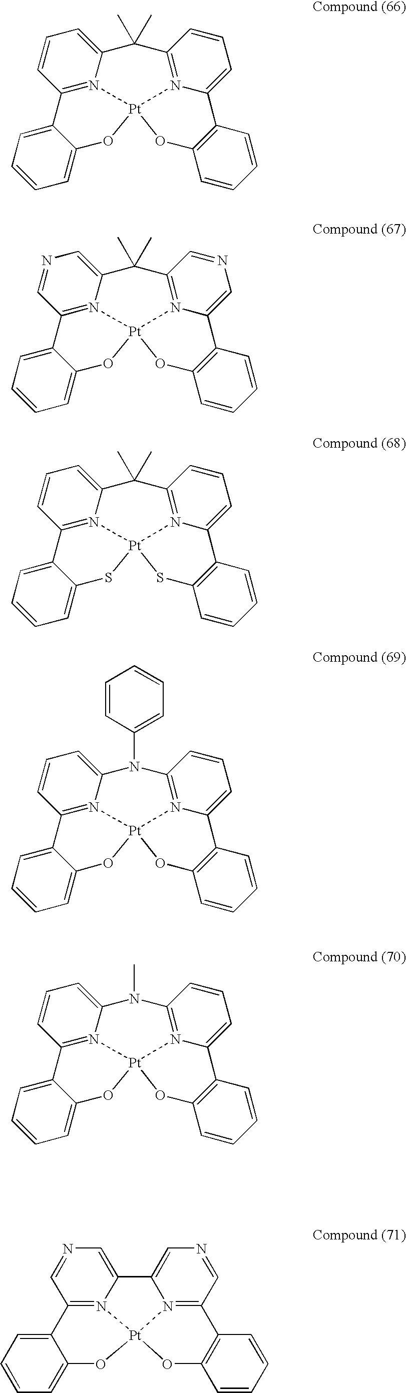 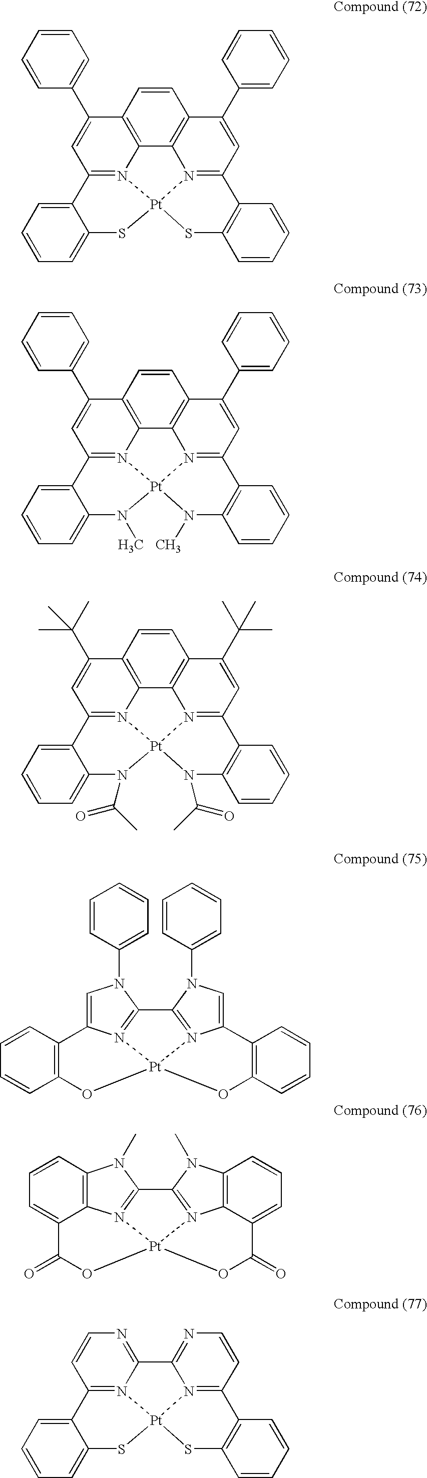 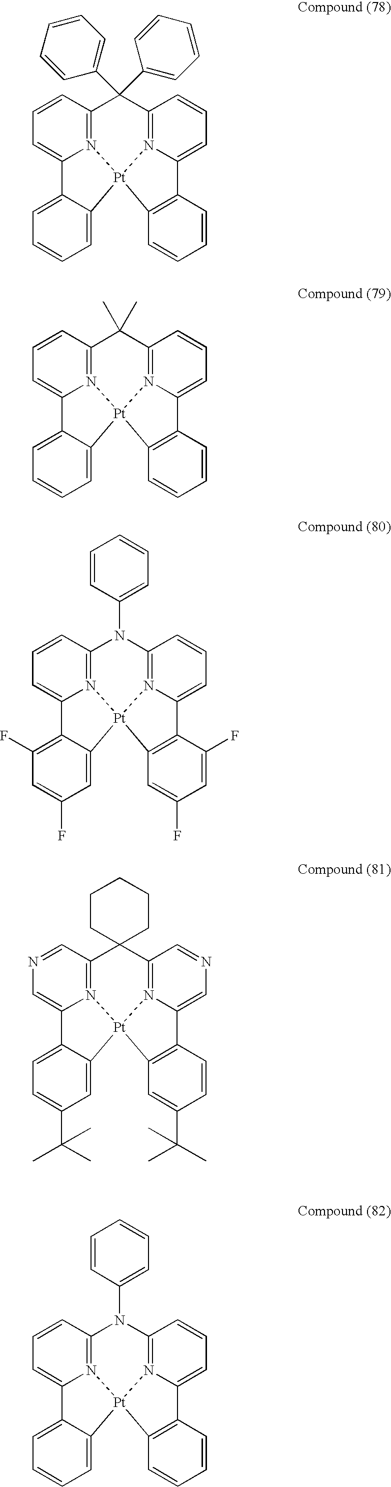 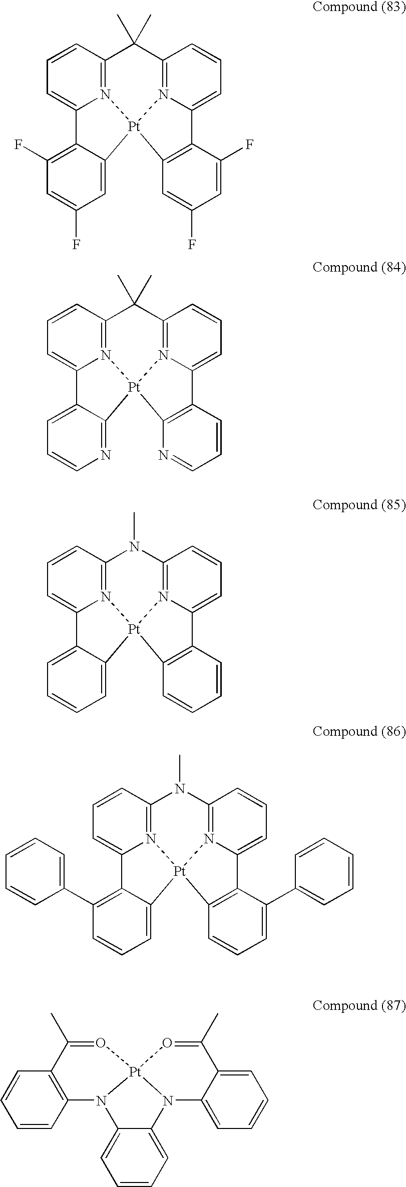 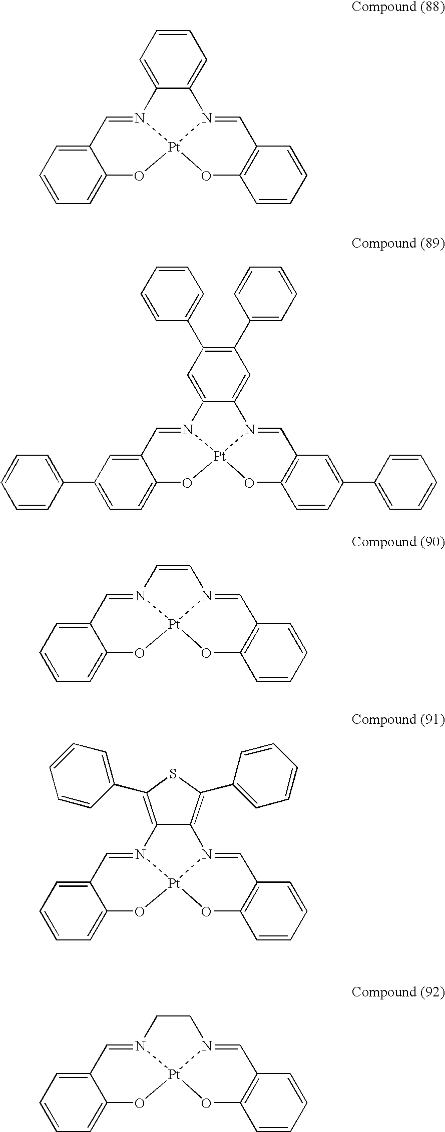 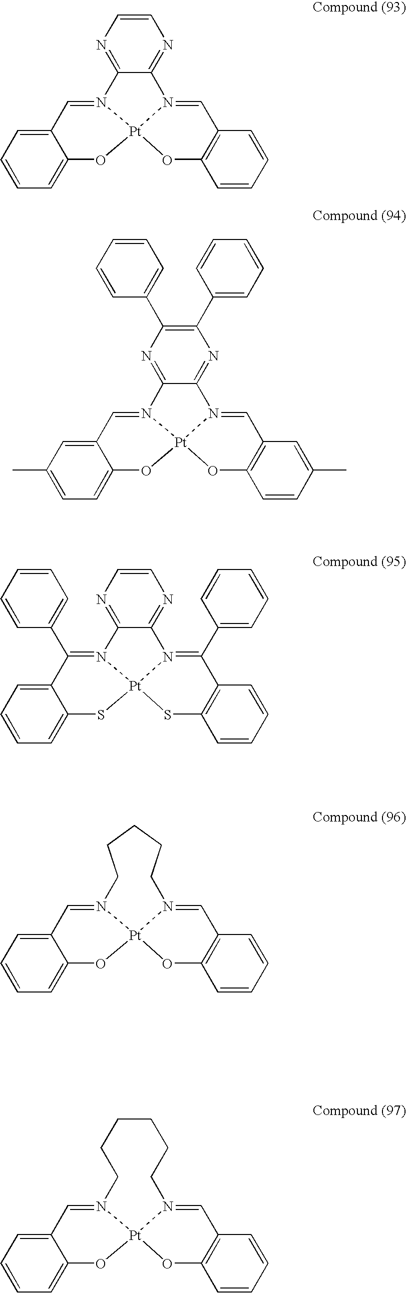 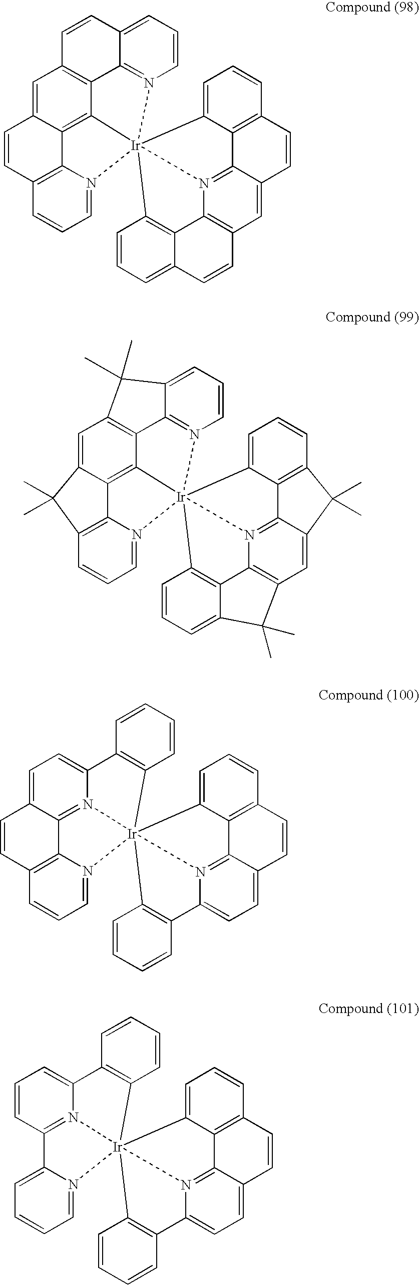 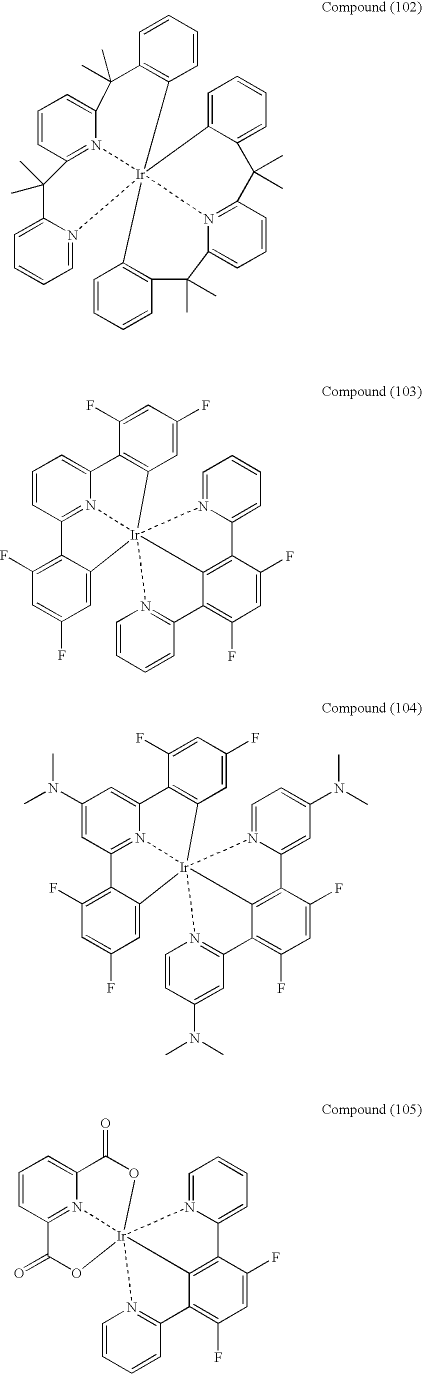 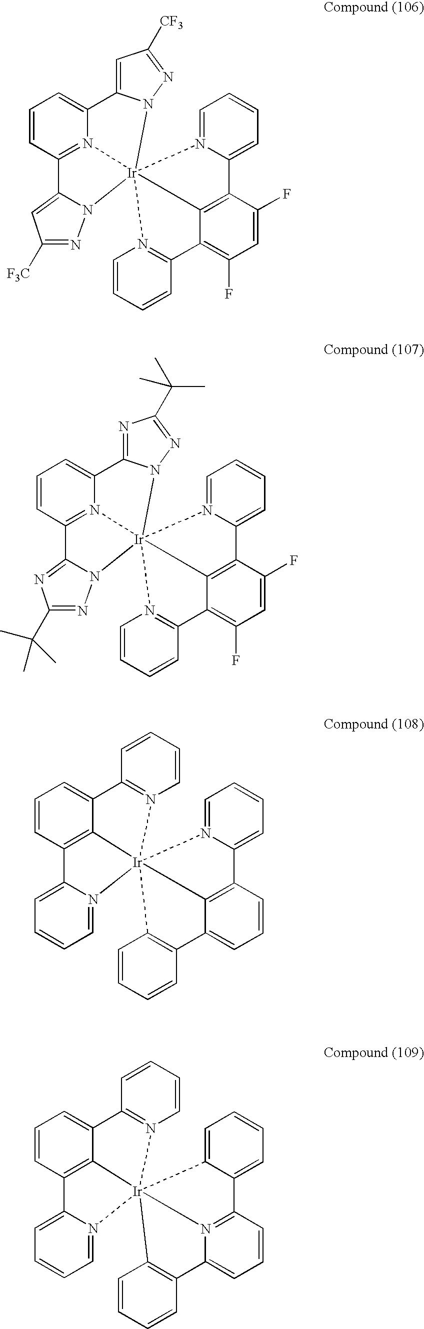 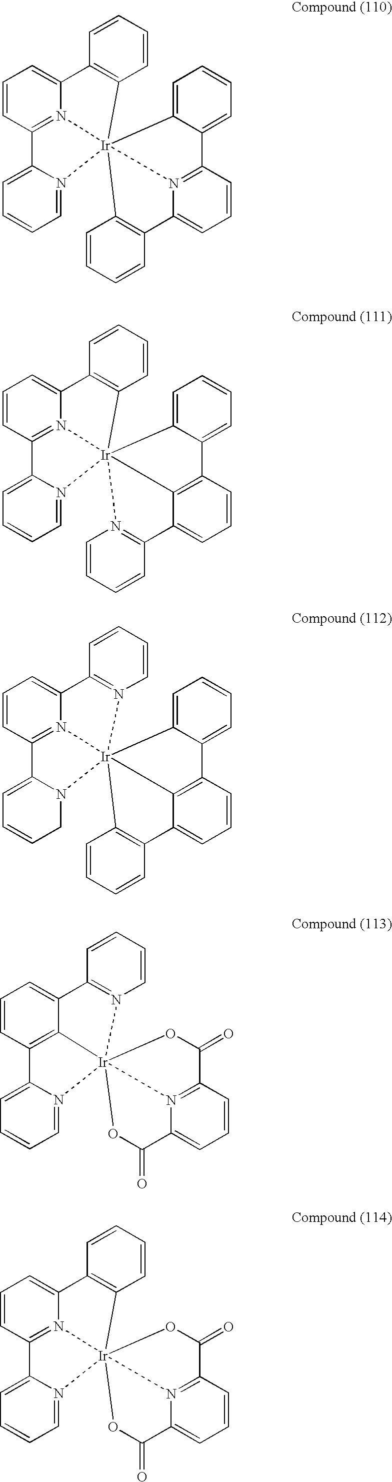 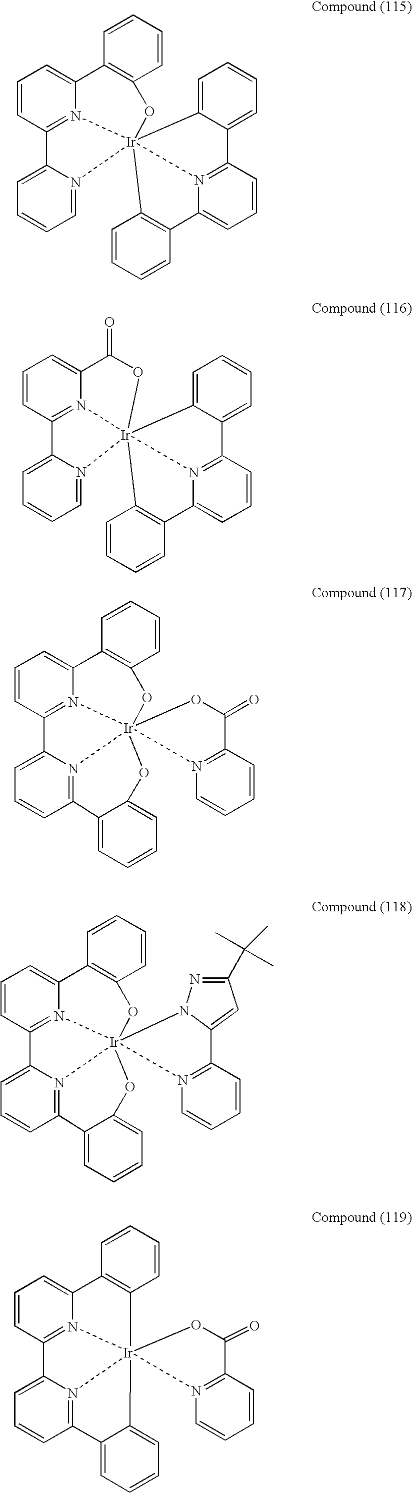 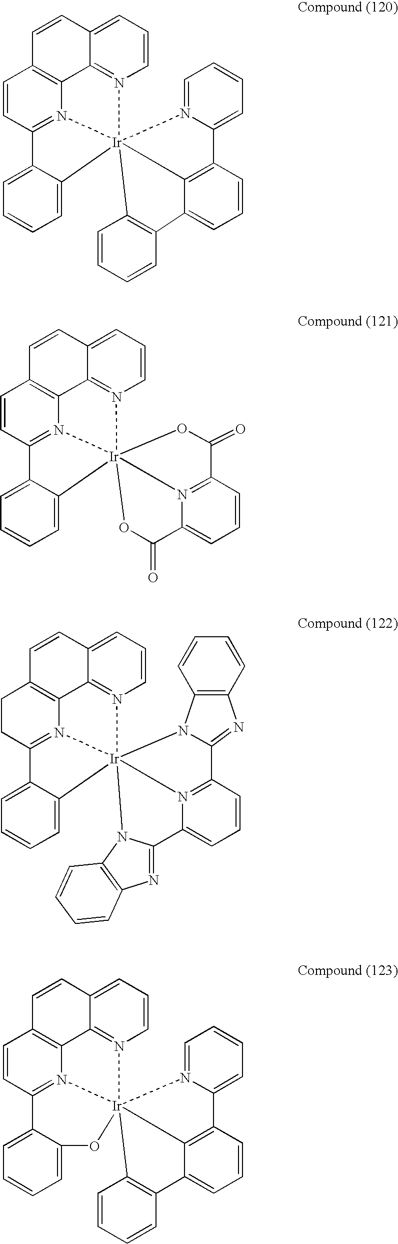 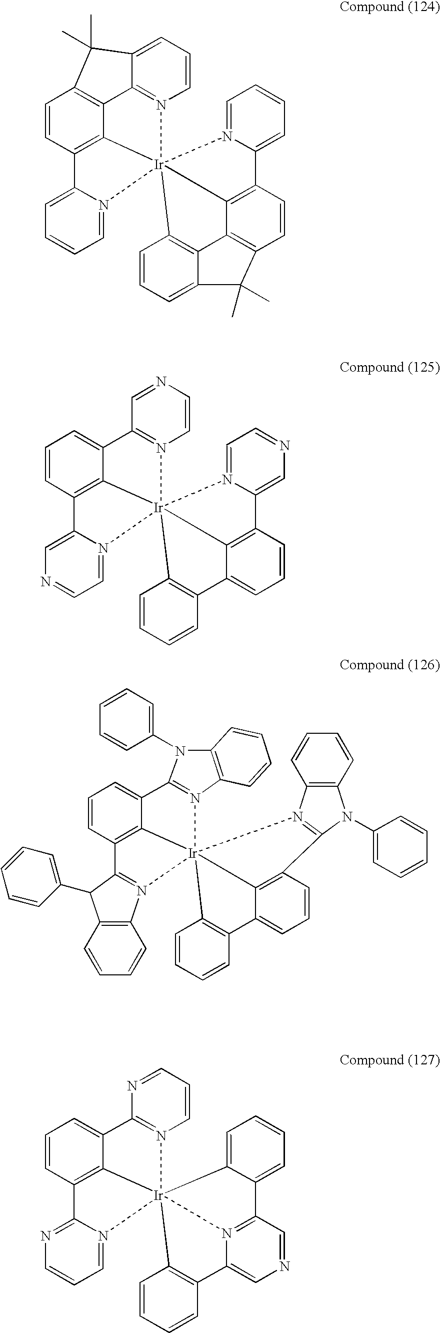 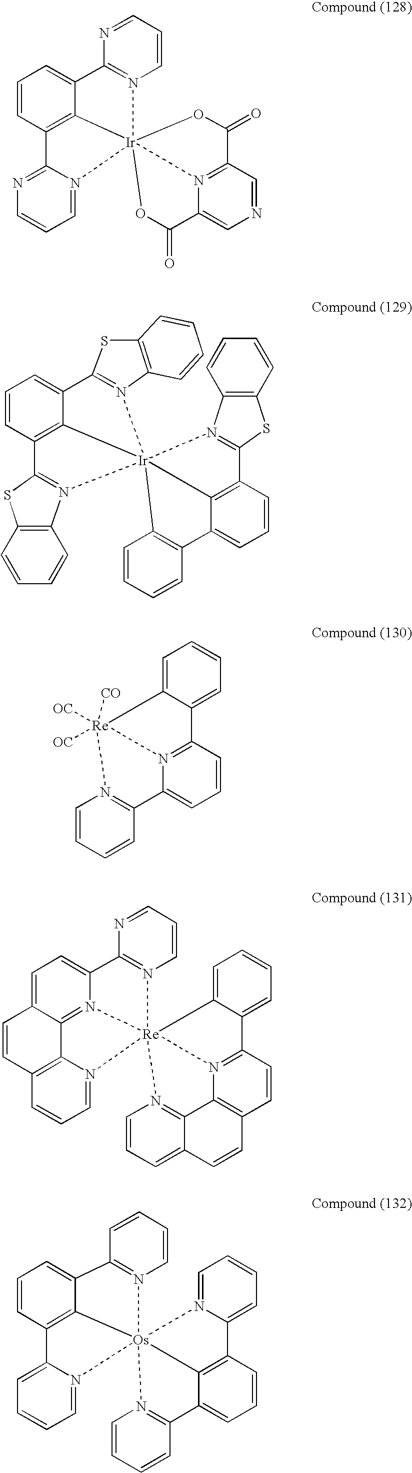 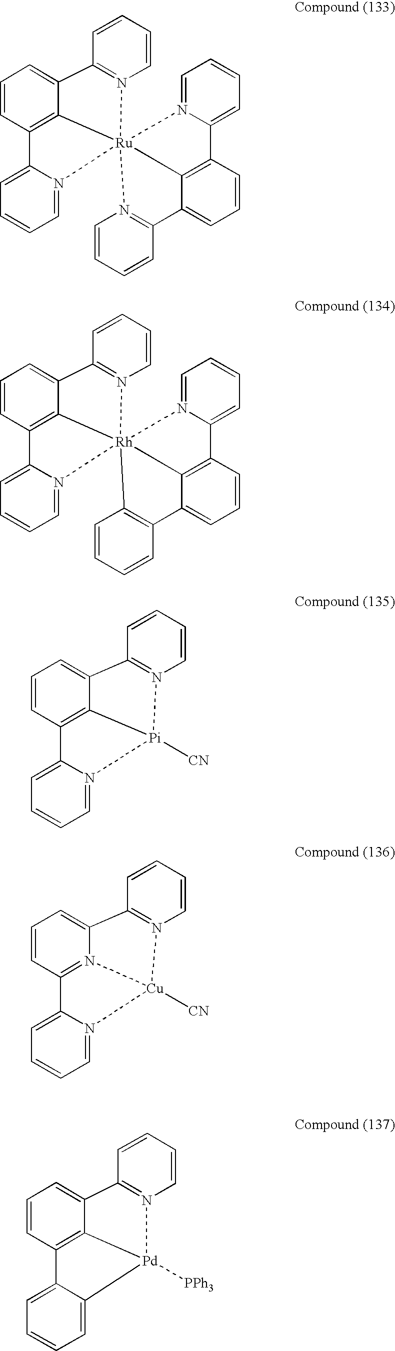 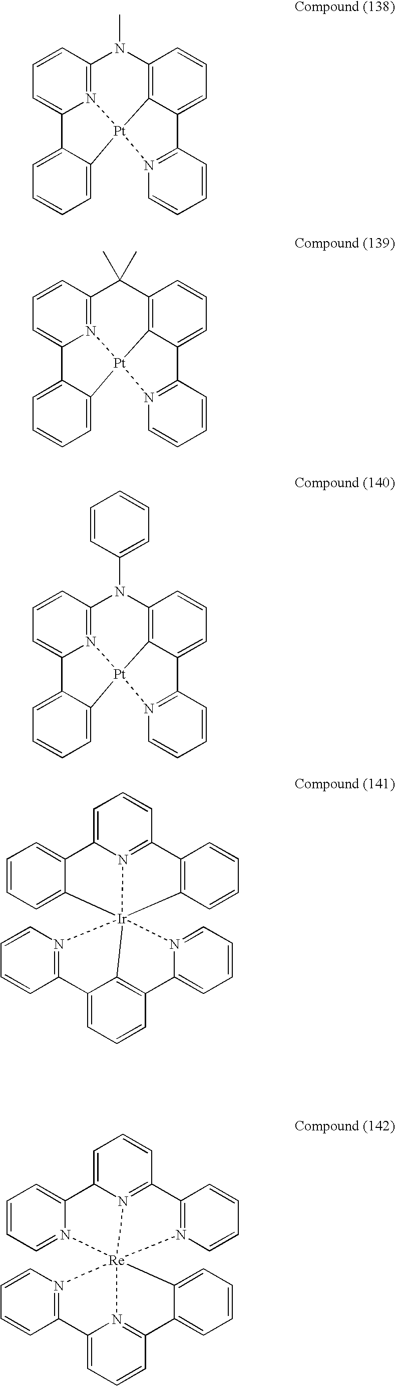 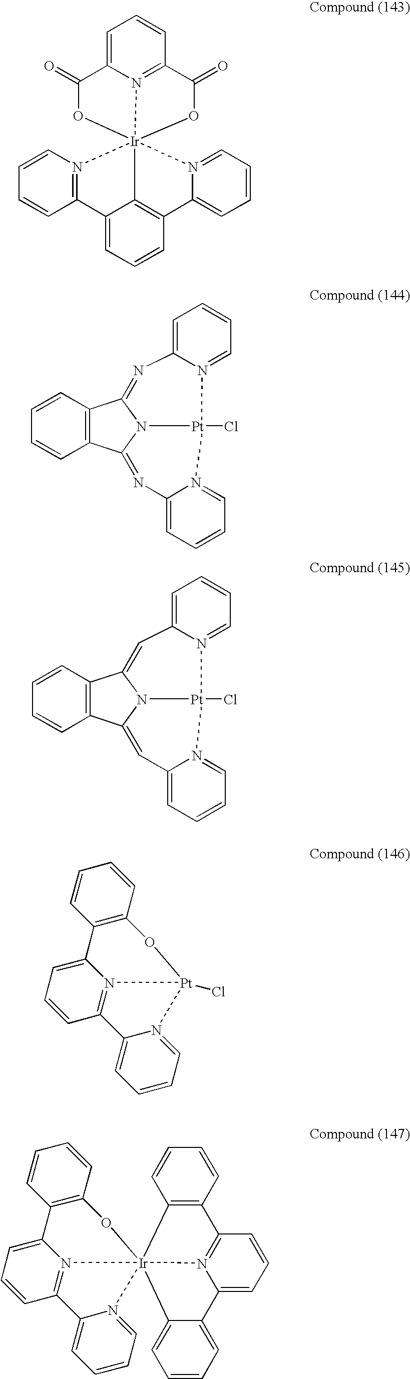 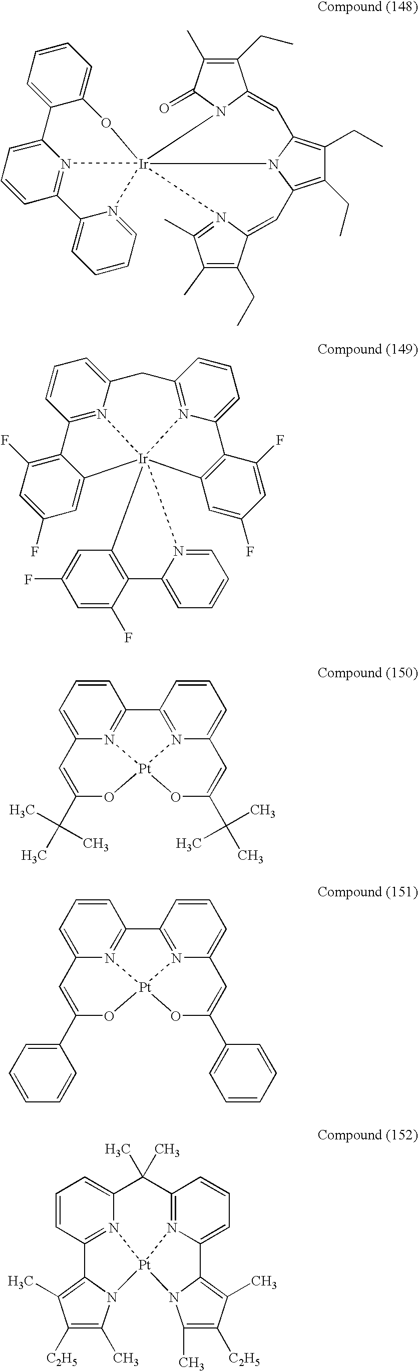 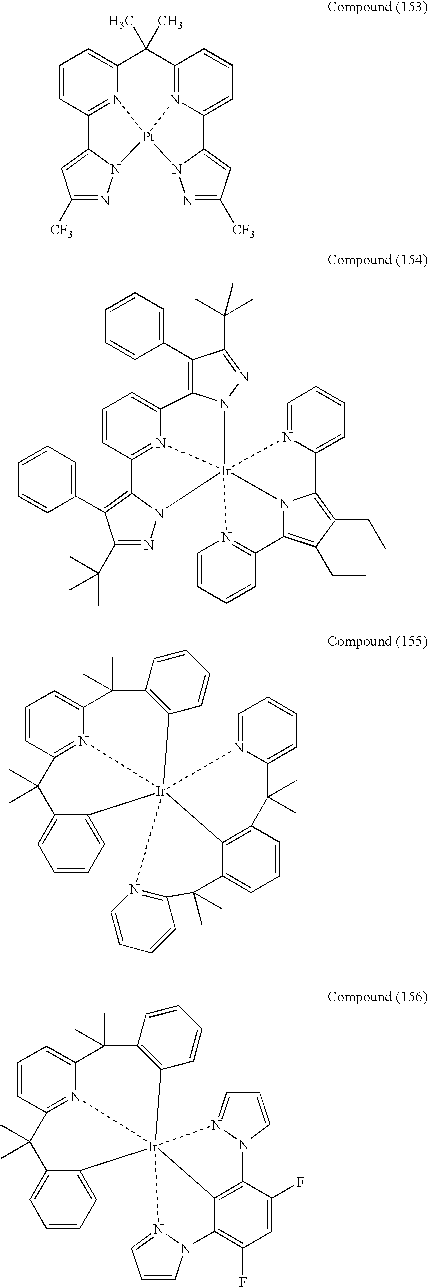 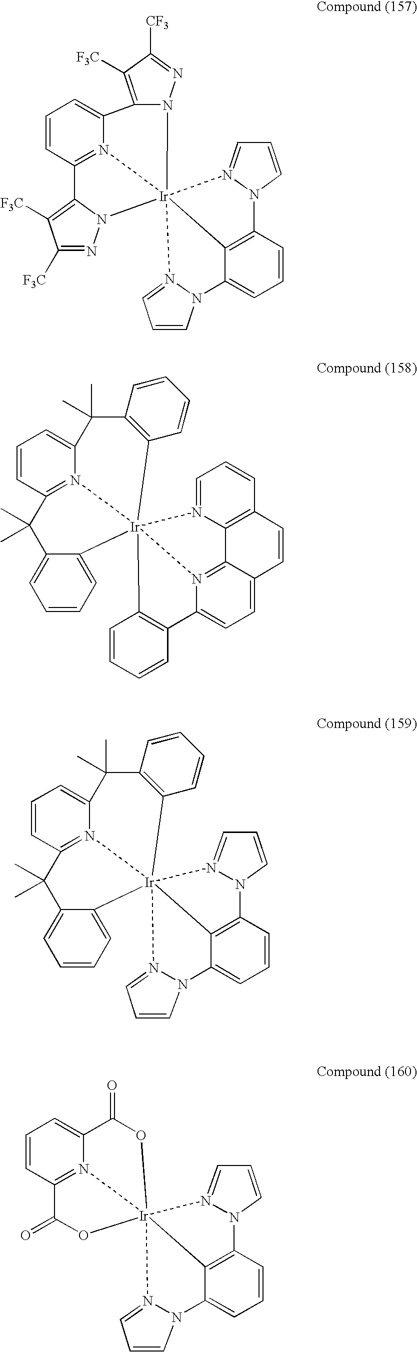 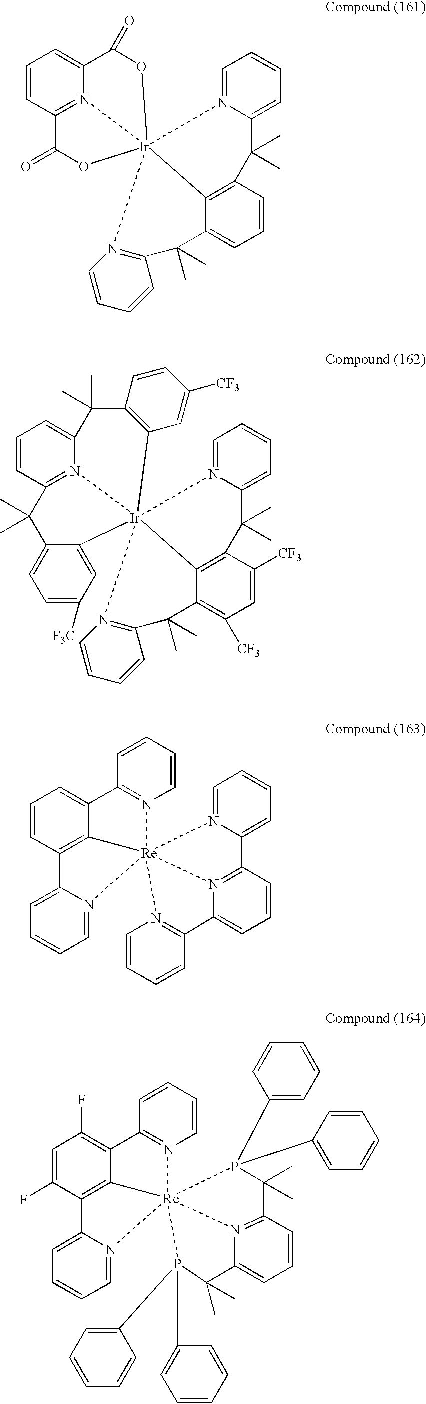 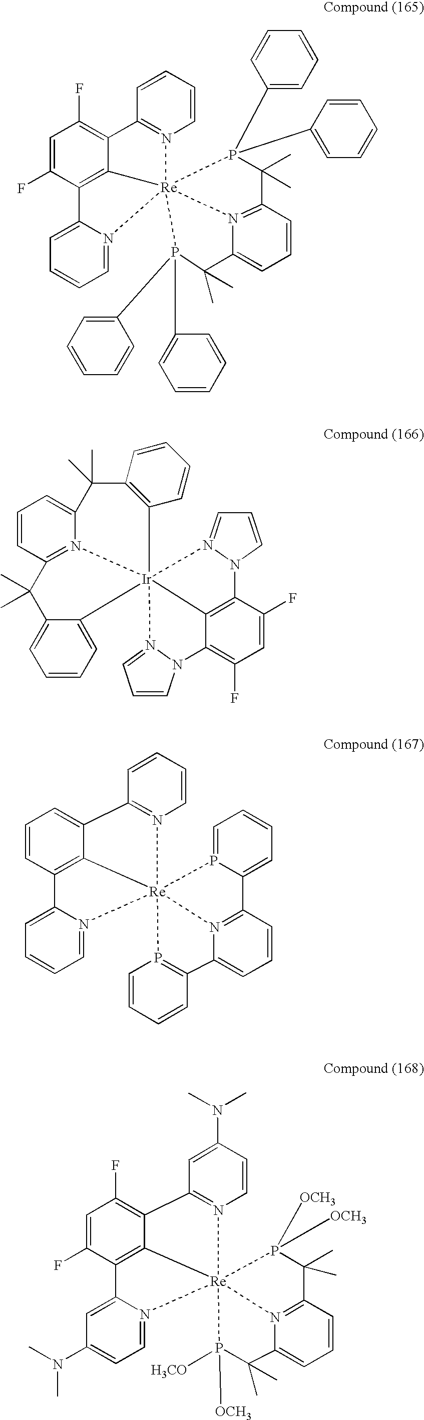 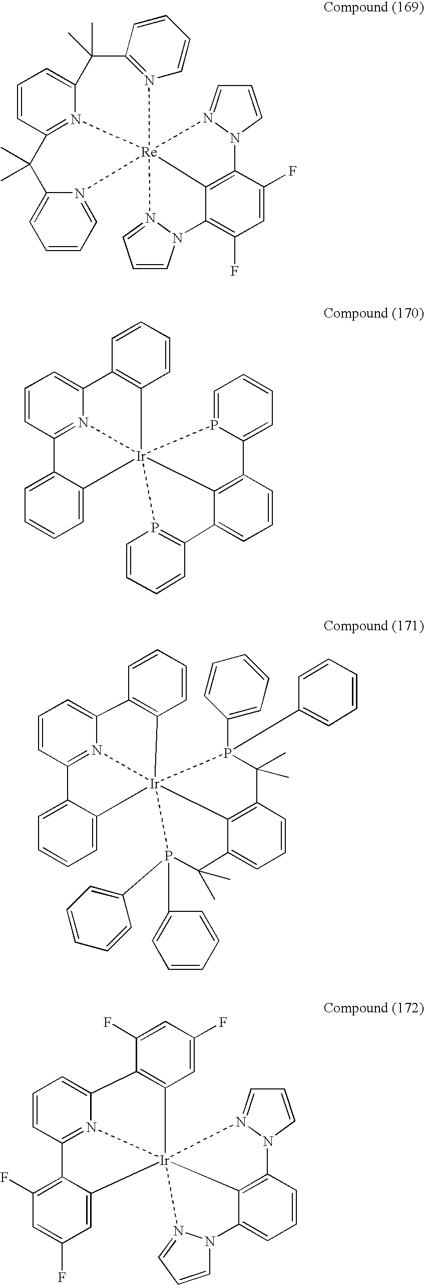 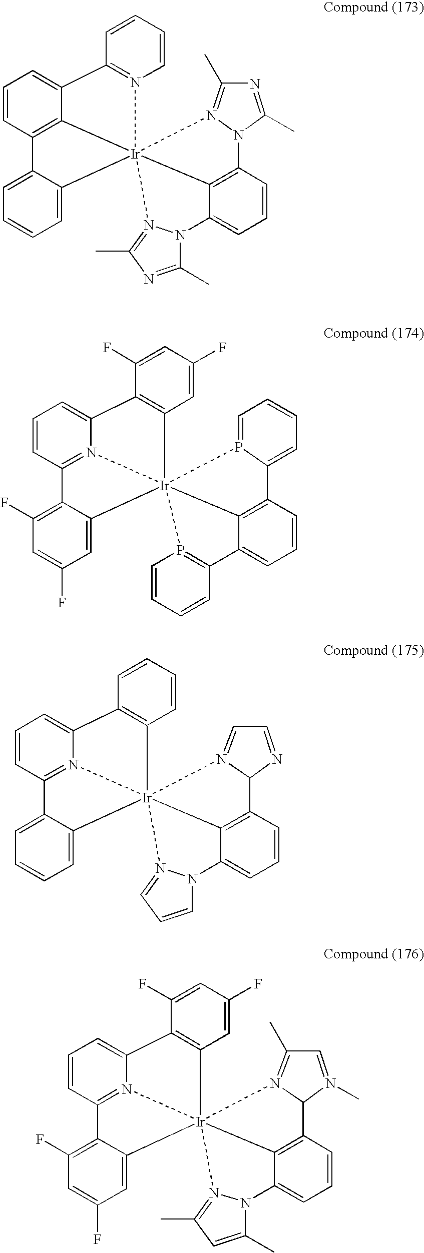 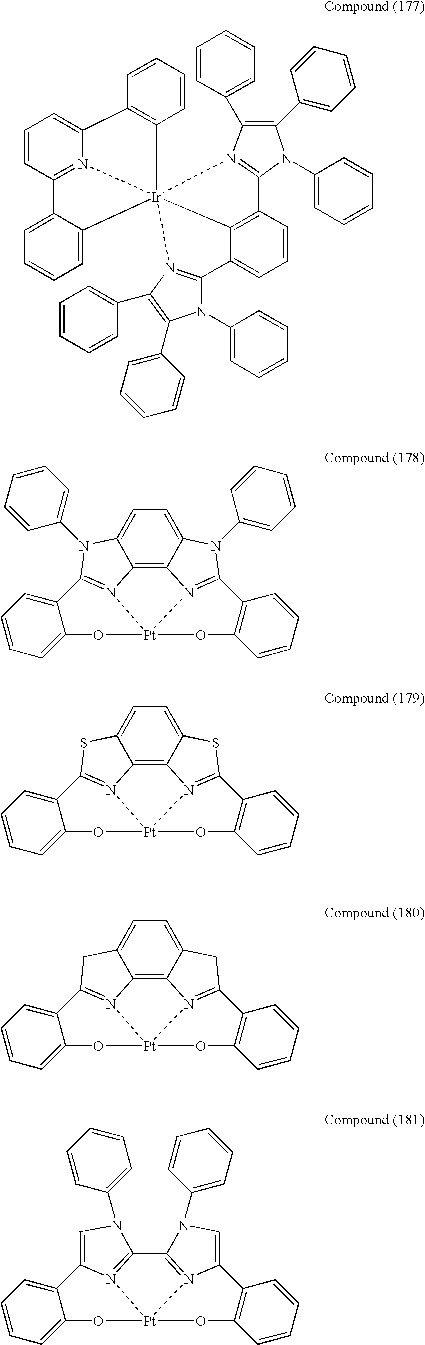 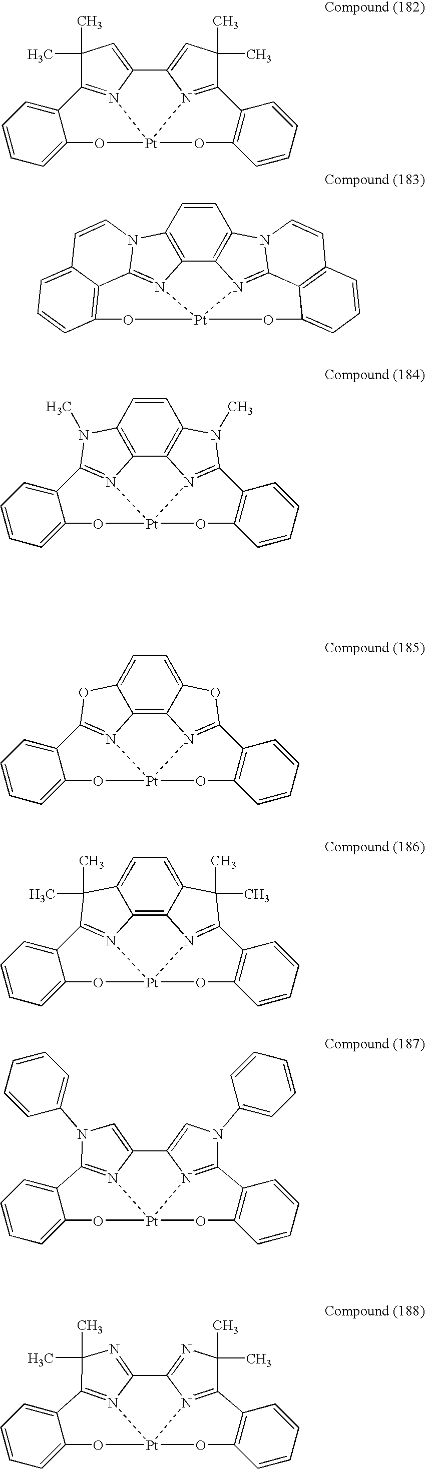 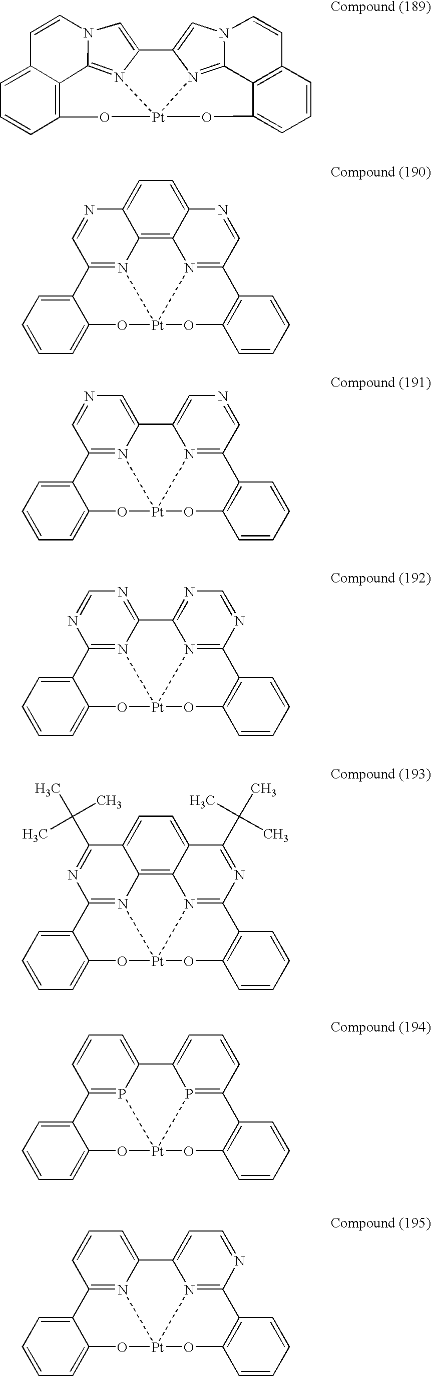 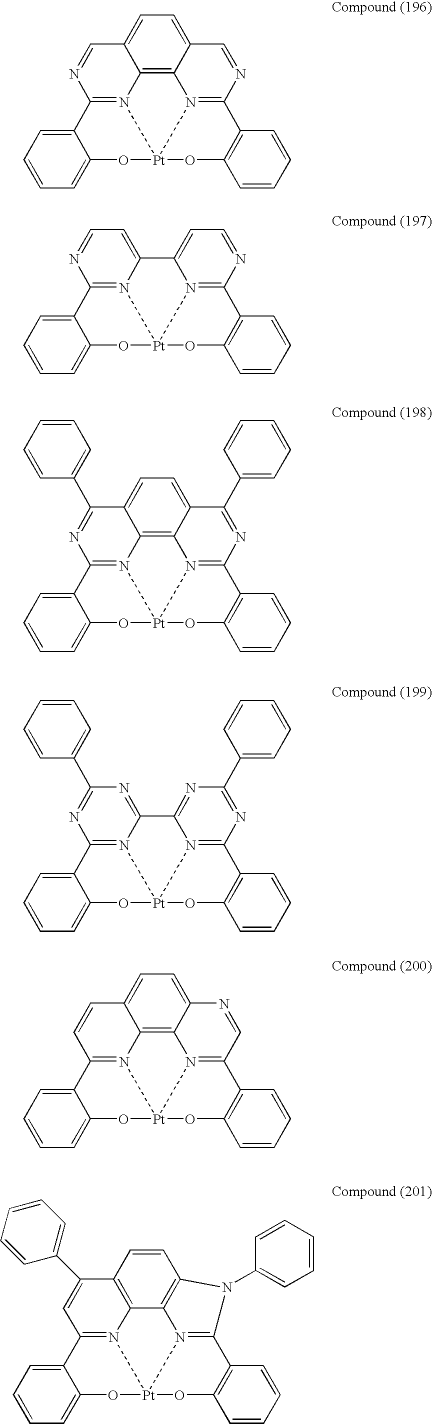 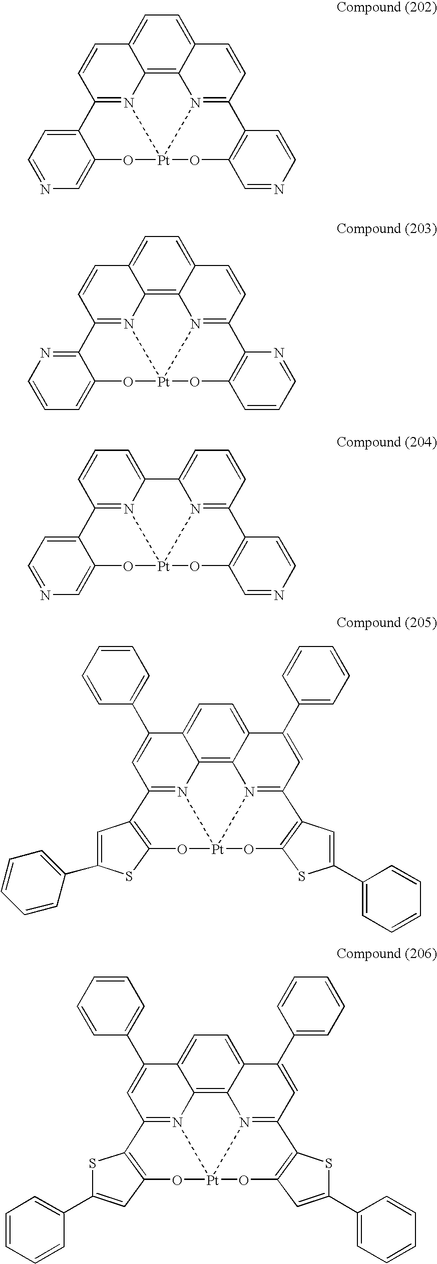 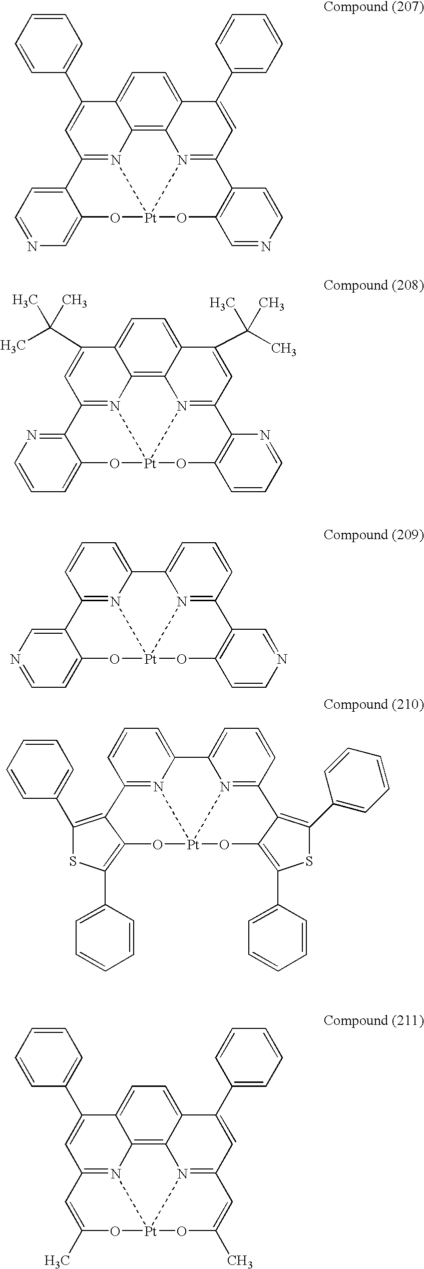 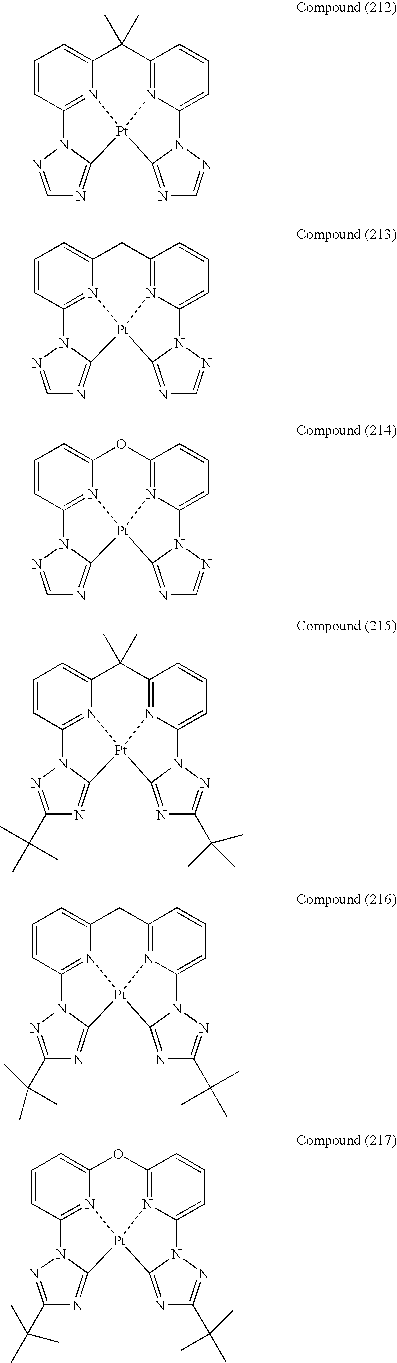 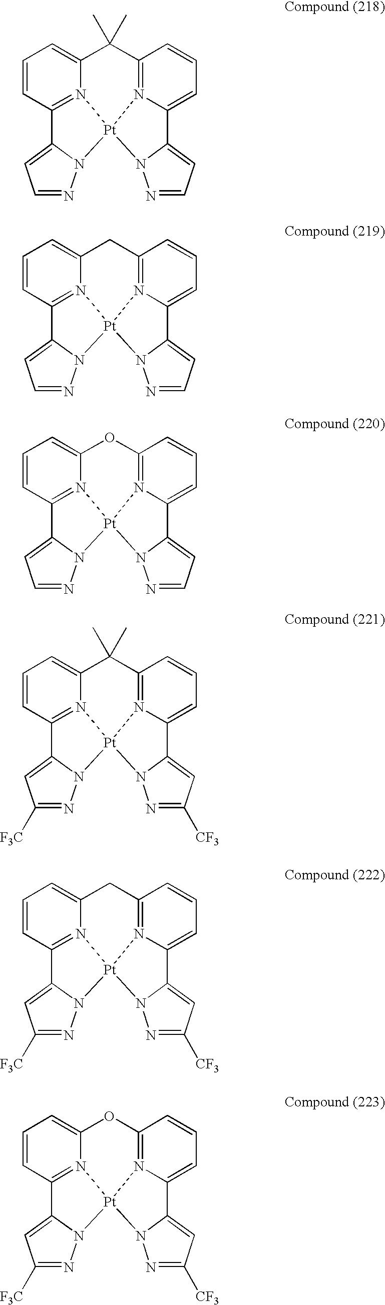 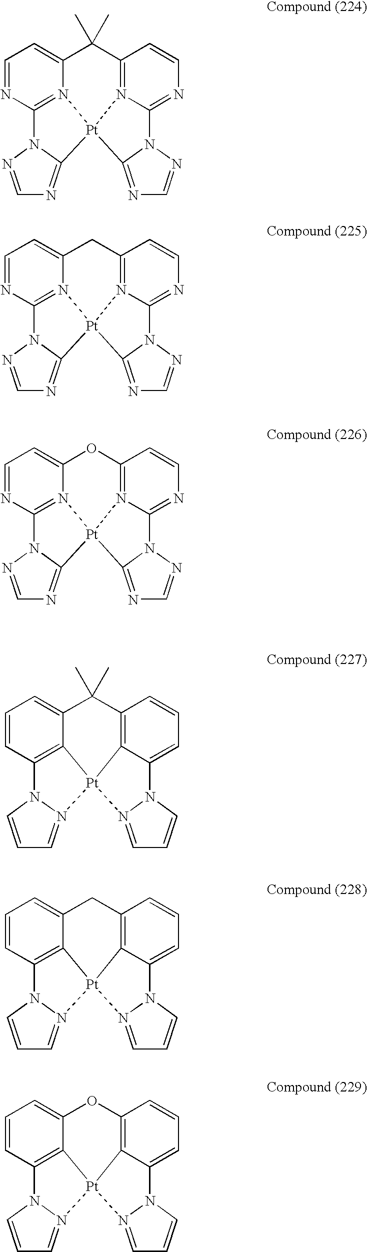 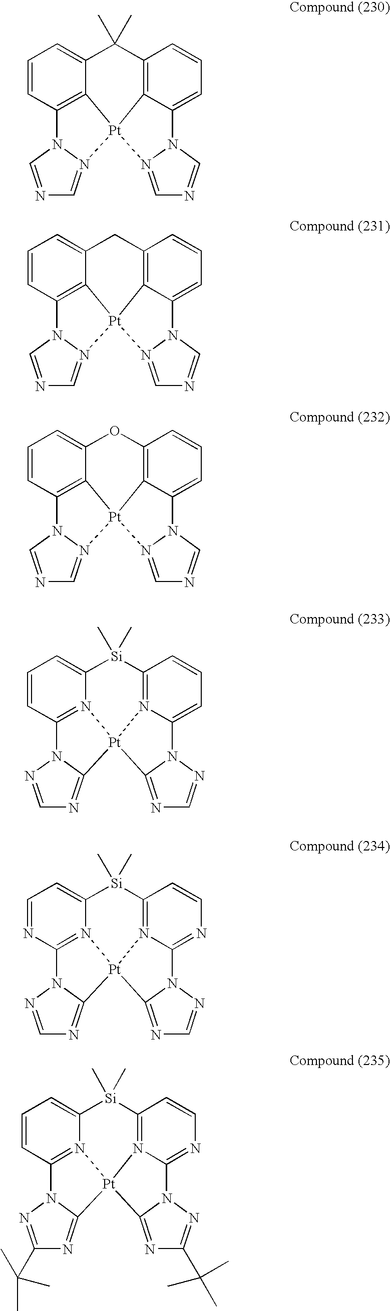 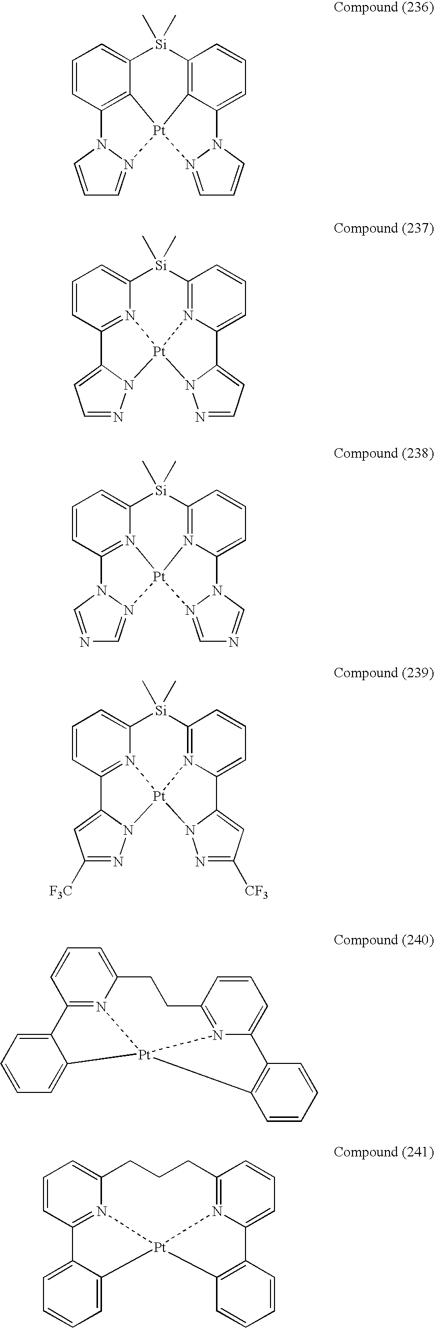 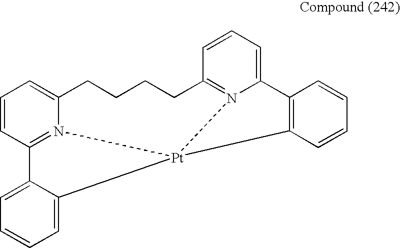
(Method of Preparing the Metal Complex)

The metal complexes according to the invention [compounds represented by formulae (I), (1), (1-A), (2), (3), (3-A), (3-B), (3-C), (4), (4-A), (5), (5-A), and (5-B) and formulae (II), (X2), and (X3)] can be prepared by various methods.

For example, a metal complex within the scope of the invention can be prepared by allowing a ligand or a dissociated form of the ligand to react with a metal compound under heating or at a temperature which is not higher than room temperature, 1) in the presence of a solvent (such as a halogenated solvent, an alcohol solvent, an ether solvent, an ester solvent, a ketone solvent, a nitrile solvent, an amide solvent, a sulfone solvent, a sulfoxide solvent, or water), 2) in the absence of a solvent but in the presence of a base (an inorganic or organic base such as sodium methoxide, potassium t-butoxide, triethylamine, or potassium carbonate), or 3) in the absence of a base. The heating may be conducted efficiently by a normal method or by using a microwave.

The reaction period at the preparation of the metal complex according to the invention may be changed according to the activity of the raw materials and is not particularly limited, but is preferably 1 minute to 5 days, more preferably 5 minutes to 3 days, and still more preferably 10 minutes to 1 day.

The reaction temperature for the preparation of the metal complex according to the invention may be changed according to the reaction activity, and is not particularly limited. The reaction temperature is preferably 0° C. to 300° C., more preferably 5° C. to 250° C., and still more preferably 10° C. to 200° C.

Each of the metal complexes according to the invention, i.e., the compounds represented by formulae (I), (1), (1-A), (2), (3), (3-A), (3-B), (3-C), (4), (4-A), (5), (5-A), and (5-B) and the compound represented by formulae (II), (X2), and (X3), can be prepared by properly selecting a ligand that forms the partial structure of the desirable complex. For example, a compound represented by formula (1-A) can be prepared by adding 6,6′-bis(2-hydroxyphenyl)-2,2′-bipyridyl ligand or a derivative thereof (e.g., 2,9-bis (2-hydroxyphenyl)-1,10-phenanthroline ligand, 2,9-bis(2-hydroxyphenyl)-4,7-diphenyl-1,10-phenanthroline ligand, 6,6′-bis(2-hydroxy-5-tert-butylphenyl)-2,2′-bipyridyl ligand) to a metal compound in an amount of preferably 0.1 to 10 equivalents, more preferably 0.3 to 6 equivalents, and still more preferably 0.5 to 4 equivalents, relative to the quantity of metal compound. The reaction solvent, reaction time, and reaction temperature at the preparation of the compound represented by formula (1-A) are the same as in the method for preparing the metal complexes according to the invention described above.

The derivatives of 6,6′-bis(2-hydroxyphenyl)-2,2′-bipyridyl ligand can be prepared by any one of known preparative methods.

In an embodiment, a derivative is prepared by allowing a 2,2′-bipyridyl derivative (e.g., 1,10-phenanthroline) to react with an anisole derivative (e.g., 4-fluoroanisole) according to the method described in Journal of Organic Chemistry, 741, 11, (1946), the disclosure of which is incorporated herein by reference. In another embodiment, a derivative is prepared by performing Suzuki coupling reaction using a halogenated 2,2′-bipyridyl derivative (e.g., 2,9-dibromo-1,10-phenanthroline) and a 2-methoxyphenylboronic acid derivative (e.g., 2-methoxy-5-fluorophenylboronic acid) as starting materials and then deprotecting the methyl group (according to the method described in Journal of Organic Chemistry, 741, 11, (1946) or under heating in pyridine hydrochloride salt). In another embodiment, a derivative can be prepared by performing Suzuki coupling reaction using a 2,2′-bipyridylboronic acid derivative [e.g., 6,6′-bis(4,4,5,5-tetramethyl-1,3,2-dioxaboronyl)-2,2′-bipyridyl] and a halogenated anisole derivative (e.g., 2-bromoanisole) as starting materials and then deprotecting the methyl group (according to the method described in Journal of Organic Chemistry, 741, 11, (1946) or under heating in pyridine hydrochloride salt).

When the above-mentioned ligand for the metal complex according to the invention is a cyclic ligand, the metal complex is preferably a compound represented by the following formula (II).

Hereinafter, the compound represented by the following formula (III) will be described.

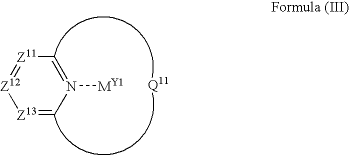

In formula (III), Q¹¹ represents an atomic group forming a nitrogen-containing heterocyclic ring; Z¹¹, Z¹², and Z¹³ each represent a substituted or unsubstituted carbon or nitrogen atom; and M^{Y1} represents a metal ion that may have an additional ligand.

In formula (III), Q¹¹ represents an atomic group forming a nitrogen-containing heterocyclic ring together with the two carbon atoms bonded to Q¹¹ and the nitrogen atom directly bonded to these carbon atoms. The number of the atoms constituting the nitrogen-containing heterocyclic ring containing Q¹¹ is not particularly limited, but is preferably 12 to 20, more preferably 14 to 16, and still more preferably 16.

Z¹¹, Z¹², and Z¹³ each independently represent a substituted or unsubstituted carbon or nitrogen atom. At least one of Z¹¹, Z¹², and Z¹³ is preferably a nitrogen atom.

Examples of the substituent on the carbon atom include alkyl groups (preferably having 1 to 30 carbon atoms, more preferably 1 to 20 carbon atoms, and particularly preferably 1 to 10 carbon atoms, such as methyl, ethyl, iso-propyl, tert-butyl, n-octyl, n-decyl, n-hexadecyl, cyclopropyl, cyclopentyl, and cyclohexyl), alkenyl groups (preferably having 2 to 30 carbon atoms, more preferably 2 to 20 carbon atoms, and particularly preferably 2 to 10 carbon atoms, such as vinyl, allyl, 2-butenyl, and 3-pentenyl), alkynyl groups (preferably having 2 to 30 carbon atoms, more preferably 2 to 20 carbon atoms, and particularly preferably 2 to 10 carbon atoms, such as propargyl and 3-pentynyl), aryl groups (preferably having 6 to 30 carbon atoms, more preferably 6 to 20 carbon atoms, and particularly preferably 6 to 12 carbon atoms, such as phenyl, p-methylphenyl, naphthyl, and anthranyl), amino groups (preferably having 0 to 30 carbon atoms, more preferably 0 to 20 carbon atoms, and particularly preferably 0 to 10 carbon atoms, such as amino, methylamino, dimethylamino, diethylamino, dibenzylamino, diphenylamino, and ditolylamino), alkoxy groups (preferably having 1 to 30 carbon atoms, more preferably 1 to 20 carbon atoms, and particularly preferably 1 to 10 carbon atoms, such as methoxy, ethoxy, butoxy, and 2-ethylhexyloxy), aryloxy groups (preferably having 6 to 30 carbon atoms, more preferably 6 to 20 carbon atoms, and particularly preferably 6 to 12 carbon atoms, such as phenyloxy, 1-naphthyloxy, and 2-naphthyloxy), heterocyclic oxy groups (preferably having 1 to 30 carbon atoms, more preferably 1 to 20 carbon atoms, and particularly preferably 1 to 12 carbon atoms, such as pyridyloxy, pyrazyloxy, pyrimidyloxy, and quinolyloxy), acyl groups (preferably having 1 to 30 carbon atoms, more preferably 1 to 20 carbon atoms, and particularly preferably 1 to 12 carbon atoms, such as acetyl, benzoyl, formyl, and pivaloyl), alkoxycarbonyl groups (preferably having 2 to 30 carbon atoms, more preferably 2 to 20 carbon atoms, and particularly preferably 2 to 12 carbon atoms, such as methoxycarbonyl and ethoxycarbonyl), aryloxycarbonyl groups (preferably having 7 to 30 carbon atoms, more preferably 7 to 20 carbon atoms, and particularly preferably 7 to 12 carbon atoms, such as phenyloxycarbonyl), acyloxy groups (preferably having 2 to 30 carbon atoms, more preferably 2 to 20 carbon atoms, and particularly preferably 2 to 10 carbon atoms, such as acetoxy and benzoyloxy), acylamino groups (preferably having 2 to 30 carbon atoms, more preferably 2 to 20 carbon atoms, and particularly preferably 2 to 10 carbon atoms, such as acetylamino and benzoylamino), alkoxycarbonylamino groups (preferably having 2 to 30 carbon atoms, more preferably 2 to 20 carbon atoms, and particularly preferably 2 to 12 carbon atoms, such as methoxycarbonylamino), aryloxycarbonylamino groups (preferably having 7 to 30 carbon atoms, more preferably 7 to 20 carbon atoms, and particularly preferably 7 to 12 carbon atoms, such as phenyloxycarbonylamino), sulfonylamino groups (preferably having 1 to 30 carbon atoms, more preferably 1 to 20 carbon atoms, and particularly preferably 1 to 12 carbon atoms, such as methanesulfonylamino and benzene sulfonylamino), sulfamoyl groups (preferably having 0 to 30 carbon atoms, more preferably 0 to 20 carbon atoms, and particularly preferably 0 to 12 carbon atoms, such as sulfamoyl, methylsulfamoyl, dimethylsulfamoyl, and phenylsulfamoyl), carbamoyl groups (preferably having 1 to 30 carbon atoms, more preferably 1 to 20 carbon atoms, and particularly preferably 1 to 12 carbon atoms, such as carbamoyl, methylcarbamoyl, diethylcarbamoyl, and phenylcarbamoyl), alkylthio groups (preferably having 1 to 30 carbon atoms, more preferably 1 to 20 carbon atoms, and particularly preferably 1 to 12 carbon atoms, such as methylthio and ethylthio), arylthio groups (preferably having 6 to 30 carbon atoms, more preferably 6 to 20 carbon atoms, and particularly preferably 6 to 12 carbon atoms, such as phenylthio), heterocyclic thio groups (preferably having 1 to 30 carbon atoms, more preferably 1 to 20 carbon atoms, and particularly preferably 1 to 12 carbon atoms, such as pyridylthio, 2-benzimidazolylthio, 2-benzoxazolylthio, and 2-benzothiazolylthio), sulfonyl groups (preferably having 1 to 30 carbon atoms, more preferably 1 to 20 carbon atoms, and particularly preferably 1 to 12 carbon atoms, such as mesyl and tosyl), sulfinyl groups (preferably having 1 to 30 carbon atoms, more preferably 1 to 20 carbon atoms, and particularly preferably 1 to 12 carbon atoms, such as methanesulfinyl and benzenesulfinyl), ureido groups (preferably having 1 to 30 carbon atoms, more preferably 1 to 20 carbon atoms, and particularly preferably 1 to 12 carbon atoms, such as ureido, methylureido, and phenylureido), phosphoric amide groups (preferably having 1 to 30 carbon atoms, more preferably 1 to 20 carbon atoms, and particularly preferably 1 to 12 carbon atoms, such as diethylphosphoric amide and phenylphosphoric amide), a hydroxy group, a mercapto group, halogen atoms (e.g., fluorine, chlorine, bromine, and iodine), a cyano group, a sulfo group, a carboxyl group, a nitro group, a hydroxamic acid group, sulfino groups, hydrazino groups, imino groups, heterocyclic groups (preferably having 1 to 30 carbon atoms, and particularly preferably 1 to 12 carbon atoms; the heteroatom(s) may be selected from nitrogen, oxygen and sulfur atoms; examples of the heterocyclic groups include imidazolyl, pyridyl, quinolyl, furyl, thienyl, piperidyl, morpholino, benzoxazolyl, benzimidazolyl, benzothiazolyl, carbazolyl, and azepinyl), silyl groups (preferably having 3 to 40 carbon atoms, more preferably 3 to 30 carbon atoms, and particularly preferably 3 to 24 carbon atoms, such as trimethylsilyl and triphenylsilyl), silyloxy groups (preferably having 3 to 40 carbon atoms, more preferably 3 to 30 carbon atoms, and particularly preferably 3 to 24 carbon atoms, such as trimethylsilyloxy and triphenylsilyloxy), and the like. These substituents may themselves be substituted.

Among these substituents, the substituent on the carbon atom is preferably an alkyl, aryl, or heterocyclic group or a halogen atom, more preferably an aryl group or a halogen atom, and still more preferably a phenyl group or a fluorine atom.

The substituent on the nitrogen atom may be selected from the substituents described as examples of the substituent on the carbon atom, and have the same preferable range as in the case of the substituent on the carbon atom.

In formula (III), M^{Y1} represents a metal ion that may have an additional ligand, and preferably a metal ion having no ligand.

The metal ion represented by M^{Y1} is not particularly limited, but is preferably a divalent or trivalent metal ion. The divalent or trivalent metal ion is preferably a cobalt, magnesium, zinc, palladium, nickel, copper, platinum, lead, aluminum, iridium, or europium ion, more preferably a cobalt, magnesium, zinc, palladium, nickel, copper, platinum, or lead ion, still more preferably a copper or platinum ion, and particularly preferably a platinum ion. M^{Y1} may or may not be bound to an atom contained in Q¹¹, preferably bound to an atom contained in Q¹¹.

The additional ligand that M^{Y1} may have is not particularly limited, but is preferably a monodentate or bidentate ligand, and more preferably a bidentate ligand. The coordinating atom is not particularly limited, but preferably an oxygen, sulfur, nitrogen, carbon, or phosphorus atom, more preferably an oxygen, nitrogen, or carbon atom, and still more preferably an oxygen or nitrogen atom.

Preferable examples of compounds represented by formula (III) include compounds represented by the following formulae (a) to (j) and the tautomers thereof.

Compounds represented by formula (III) are more preferably selected from compounds represented by formulae (a) and (b) and tautomers thereof, and still more preferably selected from compounds represented by formula (b).

Compounds represented by formula (c) or (g) are also preferable as the compounds represented by formula (III).

A compound represented by formula (c) is preferably a compound represented by formula (d), a tautomer of a compound represented by formula (d), a compound represented by formula (e), a tautomer of a compound represented by formula (e), a compound represented by formula (f) or a tautomer of a compound represented by formula (f); more preferably a compound represented by formula (d), a tautomer of a compound represented by formula (d), a compound represented by formula (e), or a tautomer of a compound represented by formula (e); and still more preferably a compound represented by formula (d) or a tautomer of a compound represented by formula (d).

A compound represented by formula (g) is preferably a compound represented by formula (h), a tautomers of a compound represented by formula (h), a compound represented by formula (i), a tautomer of a compound represented by formula (i), a compounds represented by formula (j) or a tautomer of a compounds represented by formula (j); more preferably a compound represented by formula (h), a tautomers of a compound represented by formula (h), a compound represented by formula (i), or a tautomer of a compound represented by formula (i); and still more preferably a compound represented by formula (h) or a tautomer of a compound represented by formula (h).

Hereinafter, the compounds represented by formulae (a) to (j) will be described in detail.

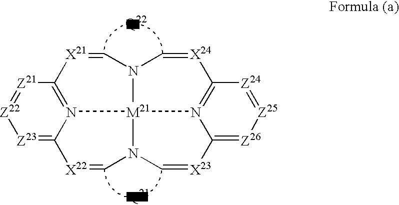

The compound represented by formula (a) will be described below.

In formula (a), the definitions and preferable ranges of Z²¹, Z²², Z²³, Z²⁴, Z²⁵, Z²⁶, and M²¹ are the same as the definitions and preferable ranges of corresponding Z¹¹, Z¹², Z¹³, Z¹¹, Z¹², Z¹³, and M^{Y1} in formula (III), respectively.

Q²¹ and Q²² each represent a group forming a nitrogen-containing heterocyclic ring. Each of the nitrogen-containing heterocyclic rings formed by Q²¹ and Q²² is not particularly limited, but is preferably a pyrrole ring, an imidazole ring, a triazole ring, a condensed ring containing one or more of the above rings (e.g., benzopyrrole), or a tautomer of any of the above rings (e.g., in formula (b) below, the nitrogen-containing five-membered ring substituted by R⁴³ and R⁴⁴, or by R⁴⁵ and R⁴⁶ is defined as a tautomer of pyrrole), and more preferably a pyrrole ring or a condensed ring containing a pyrrole ring (e.g., benzopyrrole).

X²¹, X²², X²³, and X²⁴ each independently represent a substituted or unsubstituted carbon or nitrogen atom, preferably an unsubstituted carbon or nitrogen atom, and more preferably a nitrogen atom.

The compound represented by formula (b) will be described below.

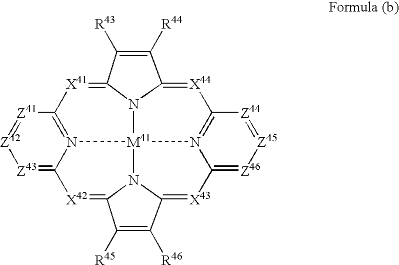

In formula (b), the definitions and preferable ranges of Z⁴¹, Z⁴², Z⁴³, Z⁴⁴, Z⁴⁵, Z⁴⁶, X⁴¹, X⁴², X⁴³, X⁴⁴, and M⁴¹ are the same as the definitions and preferable ranges of Z²¹, Z²², Z²³, Z²⁴, Z²⁵, Z²⁶, X²¹, X²², X²³, X²⁴, and M²¹ in formula (a), respectively.

In an embodiment, R⁴³, R⁴⁴, R⁴⁵, and R⁴⁶ are each selected from a hydrogen atom and the alkyl groups and aryl groups described as examples of the substituent on Z¹¹ or Z¹² in formula (III); or R⁴³ and R⁴⁴ are bonded to each other to form a ring structure (e.g., a benzo-condensed ring or a pyridine-condensed ring) and/or R⁴⁵ and R⁴⁶ are bonded to each other to form a ring structure (e.g., a benzo-condensed ring or a pyridine-condensed ring). In a preferable embodiment, R⁴³, R⁴⁴, R⁴⁵, and R⁴⁶ are each an alkyl group or an aryl group; or R⁴³ and R⁴⁴ are bonded to each other to form a ring structure (e.g., a benzo-condensed ring or a pyridine-condensed ring) and/or R⁴⁵ and R⁴⁶ are bonded to each other to form a ring structure (e.g., a benzo-condensed ring or a pyridine-condensed ring). In a more preferable embodiment, R⁴³ and R⁴⁴ are bonded to each other to form a ring structure (e.g., a benzo-condensed ring or a pyridine-condensed ring) and/or R⁴⁵ and R⁴⁶ are bonded to each other to form a ring structure (e.g., a benzo-condensed ring or a pyridine-condensed ring).

R⁴³, R⁴⁴, R⁴⁵, and R⁴⁶ each independently represent a hydrogen atom or a substituent. Examples of the substituent include the groups described as examples of the substituent on the carbon atom represented by Z¹¹ or Z¹² in formula (III).

The compound represented by formula (c) will be described below.

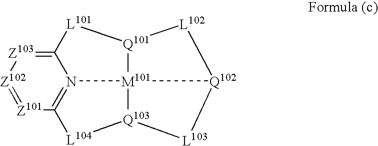

In formula (c), Z¹⁰¹, Z¹⁰², and Z¹⁰³ each independently represent a substituted or unsubstituted carbon or nitrogen atom. At least one of Z¹⁰¹, Z¹⁰², and Z¹⁰³ is preferably a nitrogen atom.

L¹⁰¹, L¹⁰², L¹⁰³, and L¹⁰⁴ each independently represent a single bond or a connecting group. The connecting group is not particularly limited, and examples thereof include a carbonyl connecting group, an alkylene group, an alkenylene group, an arylene group, a heteroarylene group, a nitrogen-containing heterocyclic ring connecting group, an oxygen atom connecting group, an amino connecting group, an imino connecting group, a carbonyl connecting group, and connecting groups comprising combinations thereof.

L¹⁰¹, L¹⁰², L¹⁰³, and L¹⁰⁴ are each preferably a single bond, an alkylene group, an alkenylene group, an amino connecting group, or an imino connecting group, more preferably a single bond, an alkylene connecting group, an alkenylene connecting group, or an imino connecting group, and still more preferably a single bond or an alkylene connecting group.

Q¹⁰¹ and Q¹⁰³ each independently represent a group containing a carbon, nitrogen, phosphorus, oxygen, or sulfur atom coordinating to M¹⁰¹.

The group containing a coordinating carbon atom is preferably an aryl group containing a coordinating carbon atom, a five-membered ring heteroaryl group containing a coordinating carbon atom, or a six-membered ring heteroaryl group containing a coordinating carbon atom; more preferably, an aryl group containing a coordinating carbon atom, a nitrogen-containing five-membered ring heteroaryl group containing a coordinating carbon atom, or a nitrogen-containing six-membered ring heteroaryl group containing a coordinating carbon atom; and still more preferably, an aryl group containing a coordinating carbon atom.

The group containing a coordinating nitrogen atom is preferably a nitrogen-containing five-membered ring heteroaryl group containing a coordinating nitrogen atom or a nitrogen-containing six-membered ring heteroaryl group containing a coordinating nitrogen atom, and more preferably a nitrogen-containing six-membered ring heteroaryl group containing a coordinating nitrogen atom.

The group containing a coordinating phosphorus atom is preferably an alkyl phosphine group containing a coordinating phosphorus atom, an aryl phosphine group containing a coordinating phosphorus atom, an alkoxyphosphine group containing a coordinating phosphorus atom, an aryloxyphosphine group containing a coordinating phosphorus atom, a heteroaryloxyphosphine group containing a coordinating phosphorus atom, a phosphinine group containing a coordinating phosphorus atom, or a phosphor group containing a coordinating phosphorus atom; more preferably, an alkyl phosphine group containing a coordinating phosphorus atom or an aryl phosphine group containing a coordinating phosphorus atom.

The group containing a coordinating oxygen atom is preferably an oxy group or a carbonyl group containing a coordinating oxygen atom, and more preferably an oxy group.

The group containing a coordinating sulfur atom is preferably a sulfide group, a thiophene group, or a thiazole group, and more preferably a thiophene group.

Each of Q¹⁰¹ and Q¹⁰³ is preferably a group containing a carbon, nitrogen, or oxygen atom coordinating to M¹⁰¹; more preferably a group containing a carbon or nitrogen atom coordinating to M¹⁰¹; and still more preferably a group containing a carbon atom coordinating to M¹⁰¹.

Q¹⁰² represents a group containing a nitrogen, phosphorus, oxygen, or sulfur atom coordinating to M¹⁰¹, and preferably a group containing a nitrogen atom coordinating to M¹⁰¹.

The definition of M¹⁰¹ is the same as that of M¹¹ in formula (I), and their preferable ranges are also the same.

The compound represented by formula (d) will be described below.

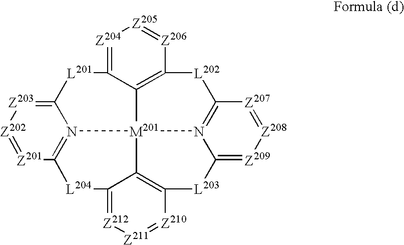

In formula (d), the definitions and preferable ranges of Z²⁰¹, Z²⁰², Z²⁰³, Z²⁰⁷, Z²⁰⁸, Z²⁰⁹, L²⁰¹, L²⁰², L²⁰³, L²⁰⁴, and M²⁰¹ are the same as the definitions and preferable ranges Z¹⁰¹, Z¹⁰², Z¹⁰³, Z¹⁰¹, Z¹⁰², Z¹⁰³, L¹⁰¹, L¹⁰², L¹⁰³, L¹⁰⁴, and M¹⁰¹ in formula (c), respectively. Z²⁰⁴, Z²⁰⁵, Z²⁰⁶, Z²¹⁰, Z²¹¹, and Z²¹² each represent a substituted or unsubstituted carbon or nitrogen atom, and preferably a substituted or unsubstituted carbon atom.

The compound represented by formula (e) will be described below.

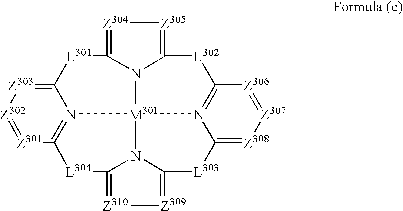

In formula (e), the definitions and preferable ranges of Z³⁰¹, Z³⁰², Z³⁰³, Z³⁰⁴, Z³⁰⁵, Z³⁰⁶, Z³⁰⁷, Z³⁰⁸, Z³⁰⁹, Z³¹⁰, L³⁰¹, L³⁰², L³⁰³, L³⁰⁴, and M³⁰¹ are the same as the definitions and preferable ranges of corresponding Z²⁰¹, Z²⁰², Z²⁰³, Z²⁰⁴, Z²⁰⁶, Z²⁰⁷, Z²⁰⁸, Z²⁰⁹, Z²¹⁰, Z²¹², L¹⁰¹, L¹⁰², L¹⁰³, L¹⁰⁴, and M¹⁰¹ in formulae (d) and (c), respectively.

The compound represented by formula (f) will be described below.

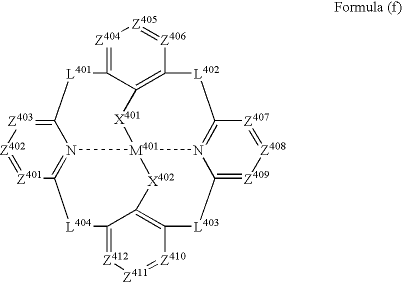

In formula (f), the definitions and preferable ranges of Z⁴⁰¹, Z⁴⁰², Z⁴⁰³, Z⁴⁰⁴, Z⁴⁰⁵, Z⁴⁰⁶, Z⁴⁰⁷, Z⁴⁰⁸, Z⁴⁰⁹, Z⁴¹⁰, Z⁴¹¹, Z⁴¹², L⁴⁰¹, L⁴⁰², L⁴⁰³, L⁴⁰⁴, and M⁴⁰¹ are the same as the definitions and preferable ranges of corresponding Z²⁰¹, Z²⁰², Z²⁰³, Z²⁰⁴, Z²⁰⁵, Z²⁰⁶, Z²⁰⁷, Z²⁰⁸, Z²⁰⁹, Z²¹⁰, Z²¹¹, Z²¹², L¹⁰¹, L¹⁰², L¹⁰³, L¹⁰⁴, and M¹⁰¹ in formulae (d) and (c), respectively. X⁴⁰¹ and X⁴⁰² each represent an oxygen atom or a substituted or unsubstituted nitrogen or sulfur atom, preferably an oxygen atom or a substituted nitrogen atom, and more preferably an oxygen atom.

The compound represented by formula (g) will be described below.

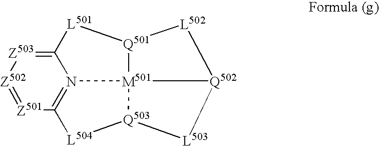

In formula (g), the definitions and preferable ranges of Z⁵⁰¹, Z⁵⁰², Z⁵⁰³, L⁵⁰¹, L⁵⁰², L⁵⁰³, L⁵⁰⁴, Q⁵⁰¹, Q⁵⁰², Q⁵⁰³, and M⁵⁰¹ are the same as the definitions and preferable of corresponding Z¹⁰¹, Z¹⁰², Z¹⁰³, L¹⁰¹, L¹⁰², L¹⁰³, L¹⁰⁴, Q¹⁰¹, Q¹⁰³, Q¹⁰², and M¹⁰¹ in formula (c), respectively

The compound represented by formula (h) will be described below.

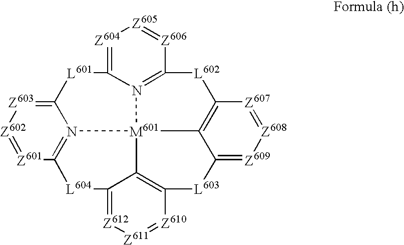

In formula (h), the definitions and preferable ranges of Z⁶⁰¹, Z⁶⁰², Z⁶⁰³, Z⁶⁰⁴, Z⁶⁰⁵, Z⁶⁰⁶, Z⁶⁰⁷, Z⁶⁰⁸, Z⁶⁰⁹, Z⁶¹⁰, Z⁶¹¹, Z⁶¹², L⁶⁰¹, L⁶⁰², L⁶⁰³, L⁶⁰⁴, and M⁶⁰¹ are the same as the definitions and preferable ranges of corresponding Z²⁰¹, Z²⁰², Z²⁰³, Z²⁰⁷, Z²⁰⁸, Z²⁰⁹, Z²⁰⁴, Z²⁰⁵, Z²⁰⁶, Z²¹⁰, Z²¹¹, Z²¹², L¹⁰¹, L¹⁰², L¹⁰³, L¹⁰⁴, and M¹⁰¹ in formulae (d) and (c), respectively.

The compound represented by formula (i) will be described below.

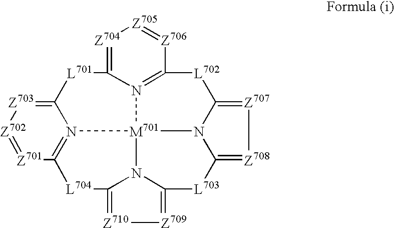

In formula (i), the definitions and preferable ranges of Z⁷⁰¹, Z⁷⁰², Z⁷⁰³, Z⁷⁰⁴, Z⁷⁰⁵, Z⁷⁰⁶, Z⁷⁰⁷, Z⁷⁰⁸, Z⁷⁰⁹, Z⁷¹⁰, L⁷⁰¹, L⁷⁰², L⁷⁰³, L⁷⁰⁴ and M⁷⁰¹ are the same as the definitions and preferable ranges of corresponding Z²⁰¹, Z²⁰², Z²⁰³, Z²⁰⁷, Z²⁰⁸, Z²⁰⁹, Z²⁰⁴, Z²⁰⁶, Z²¹⁰, Z²¹², L¹⁰¹, L¹⁰², L¹⁰³, L¹⁰⁴, and M¹⁰¹ in formulae (d) and (c), respectively.

The compound represented by formula (j) will be described below.

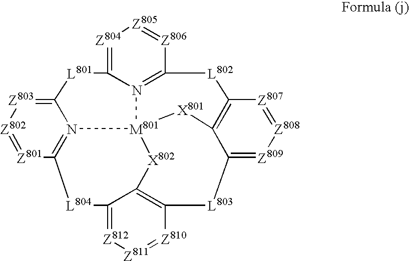

In formula (j), the definitions and preferable ranges of Z⁸⁰¹, Z⁸⁰², Z⁸⁰³, Z⁸⁰⁴, Z⁸⁰⁵, Z⁸⁰⁶, Z⁸⁰⁷, Z⁸⁰⁸, Z⁸⁰⁹, Z⁸¹⁰, Z⁸¹¹, Z⁸¹², L⁸⁰¹, L⁸⁰², L⁸⁰³, L⁸⁰⁴, M⁸⁰¹, X⁸⁰¹, and X⁸⁰² are the same as the definitions and preferable ranges of corresponding Z²⁰¹, Z²⁰², Z²⁰³, Z²⁰⁷, Z²⁰⁸, Z²⁰⁹, Z²⁰⁴, Z²⁰⁵, Z²⁰⁶, Z²¹⁰, Z²¹¹, Z²¹², L¹⁰¹, L¹⁰², L¹⁰³, L¹⁰⁴, M¹⁰¹, X⁴⁰¹, and X⁴⁰² in formulae (d), (c), and (f), respectively.

Specific examples of compounds represented by formula (III) include compounds (2) to (8), compounds (15) to (20), compounds (27) to (32), compounds (36) to (38), compounds (42) to (44), compounds (50) to (52), and compounds (57) to (154) described in Japanese Patent Application No. 2004-88575, the disclosure of which is incorporated herein by reference. The structures of the above compounds are shown below.

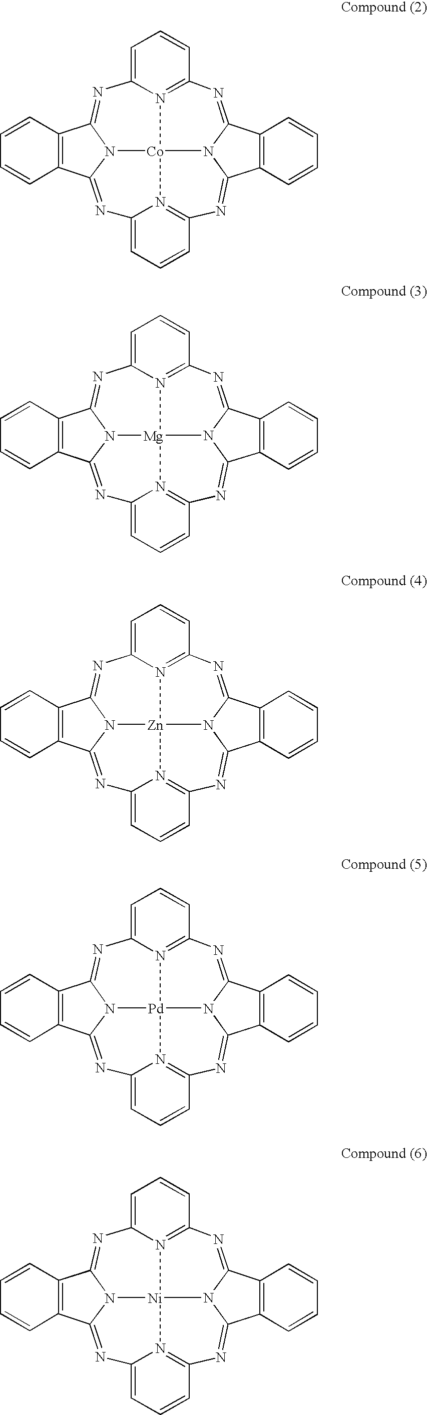

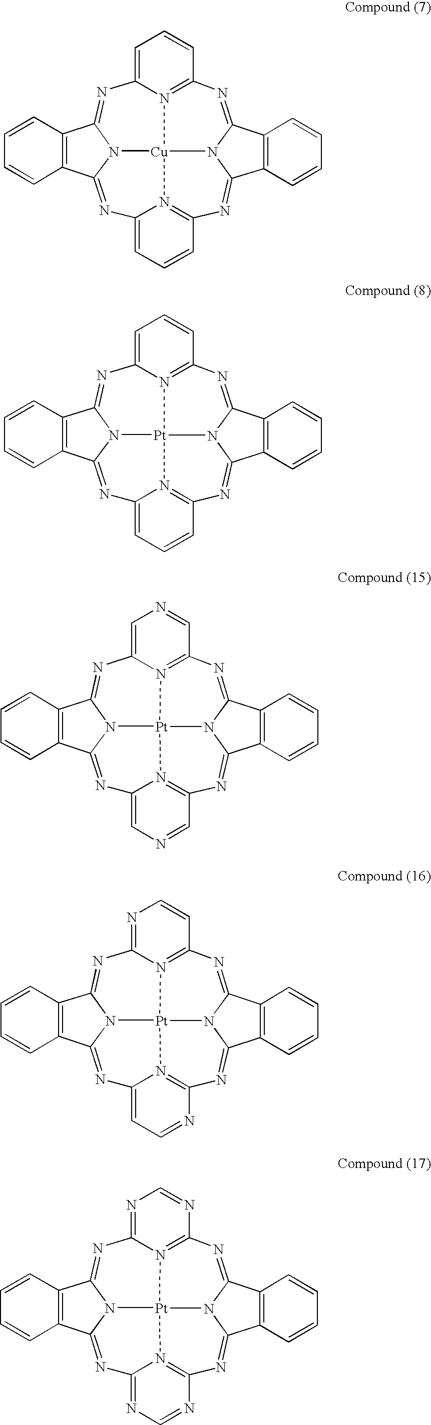

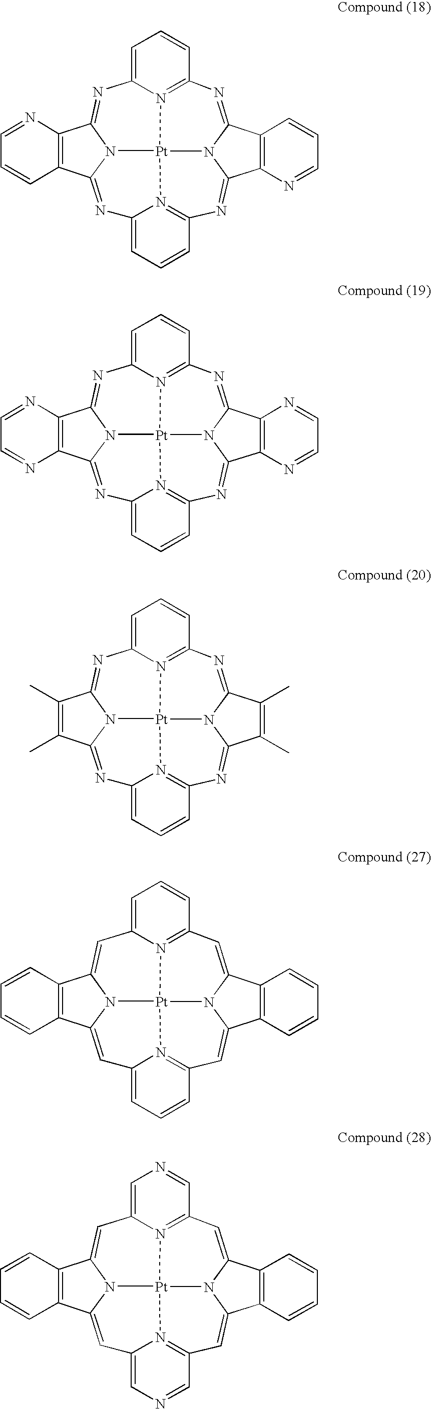

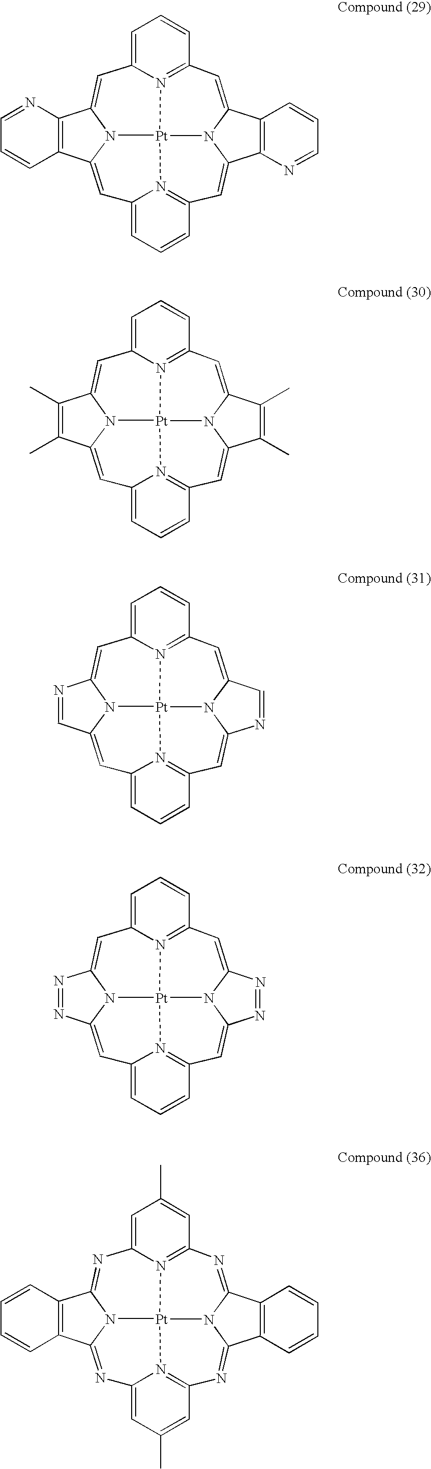

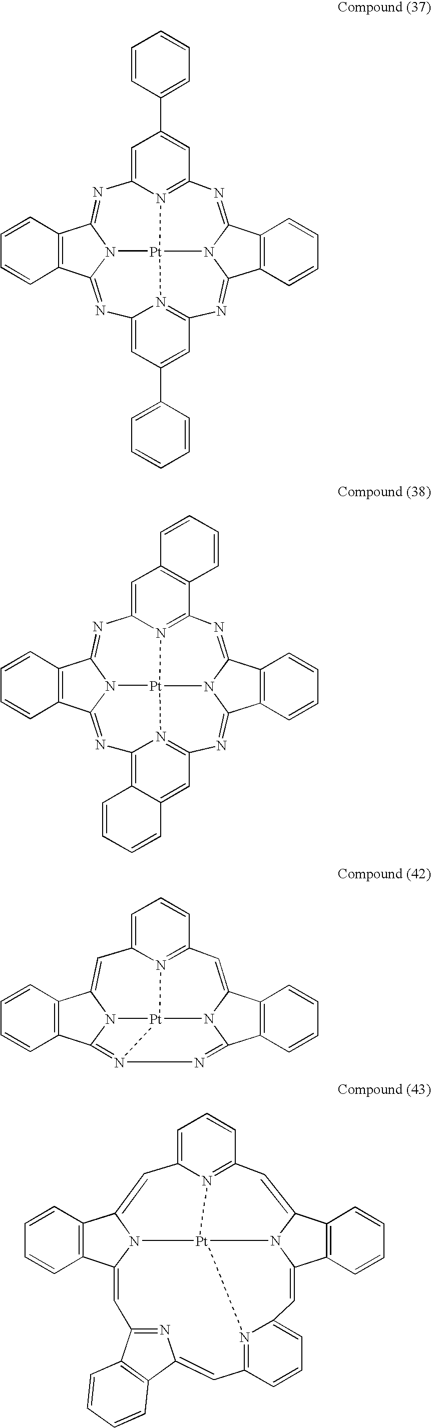

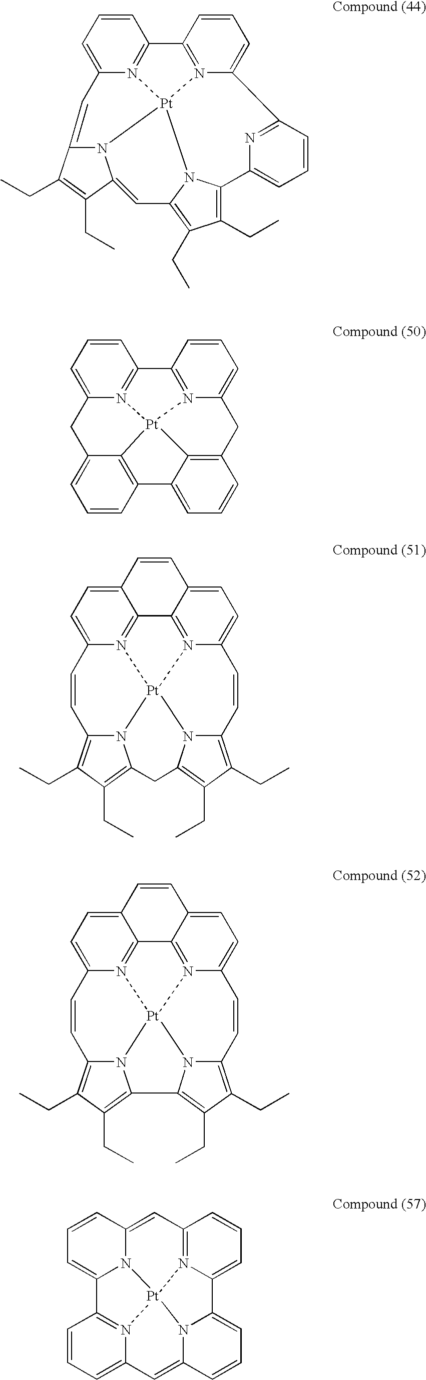

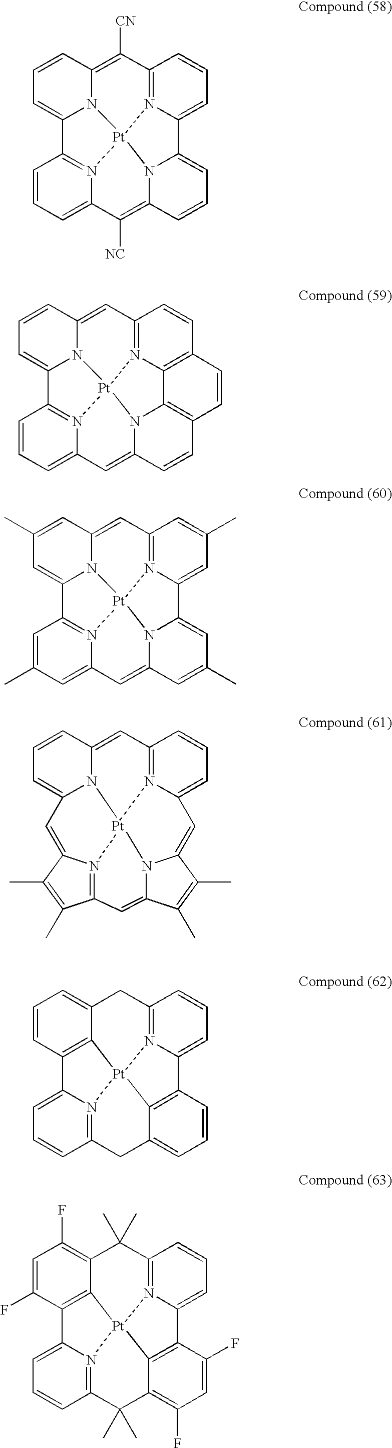

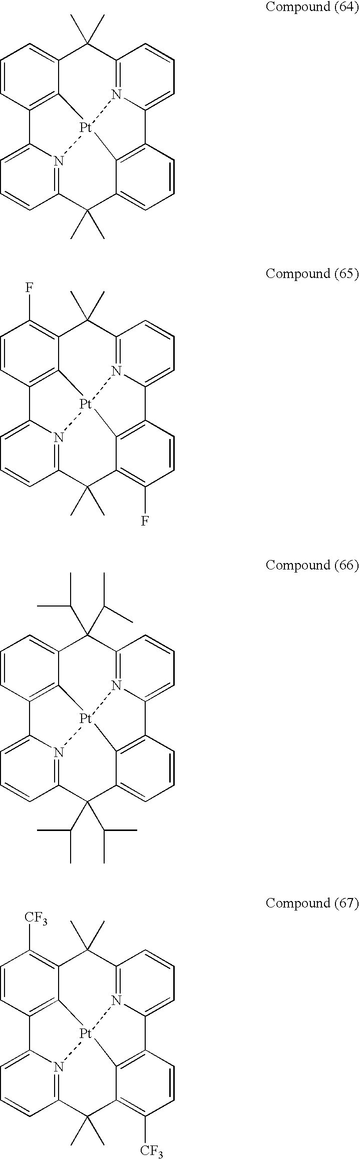

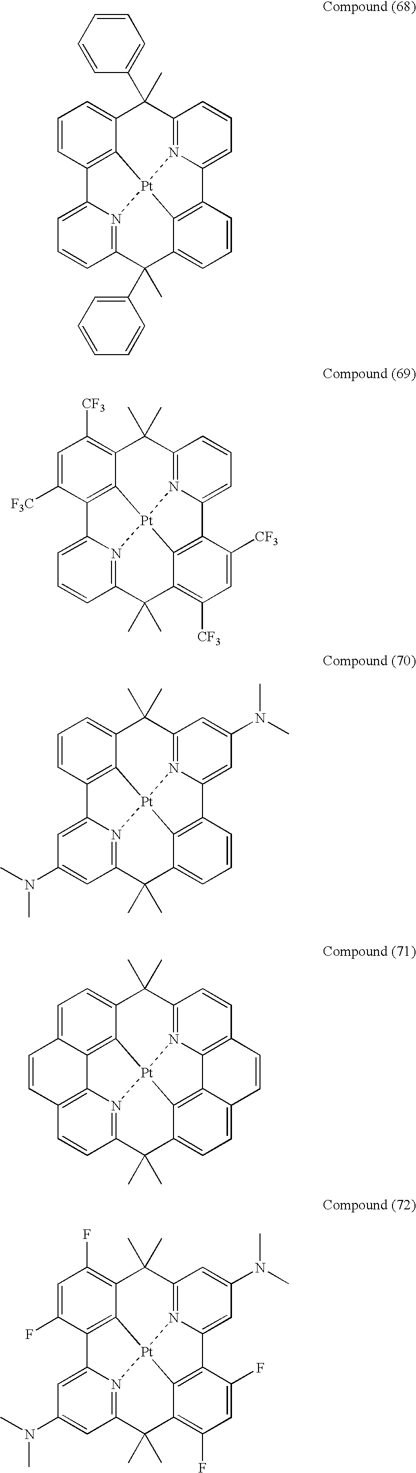

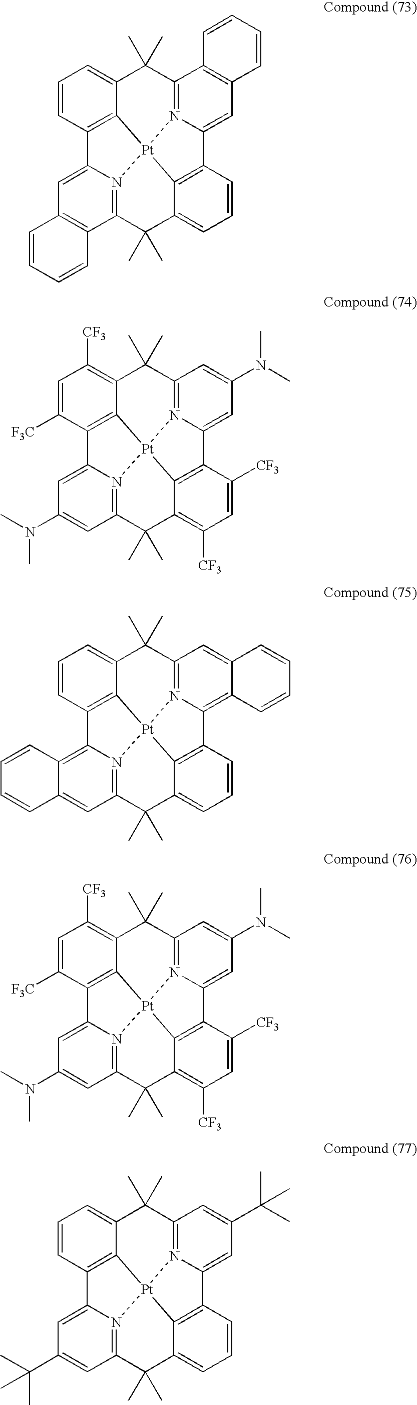

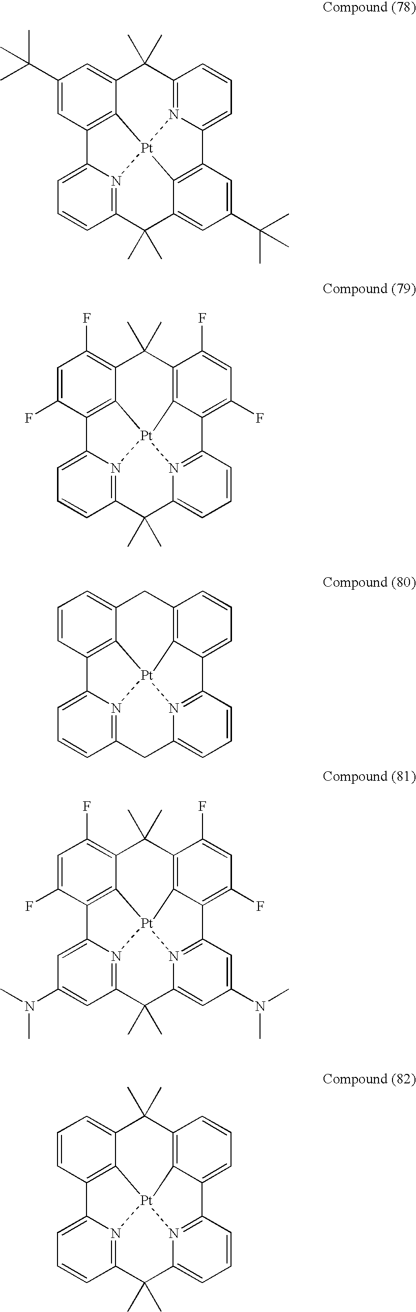

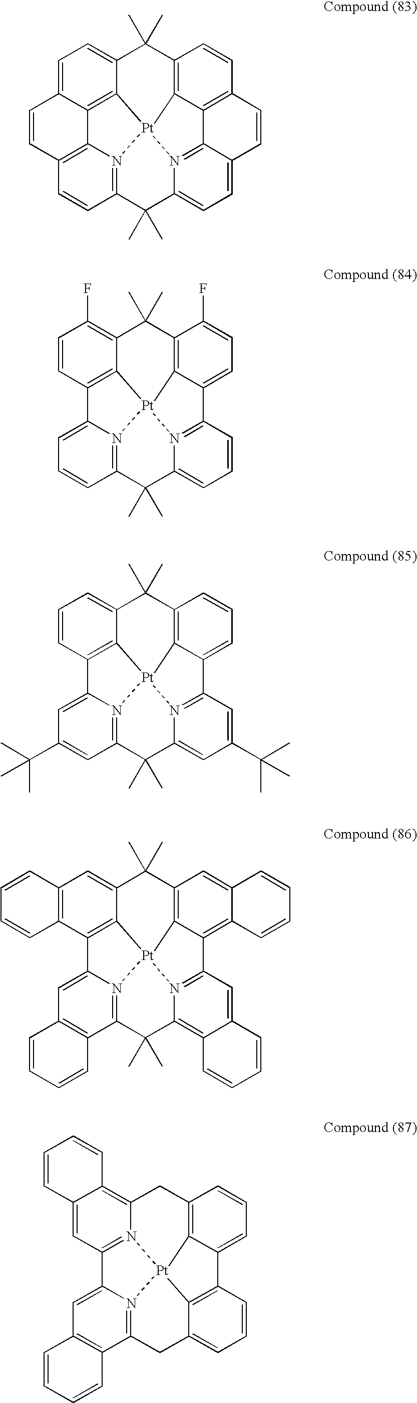

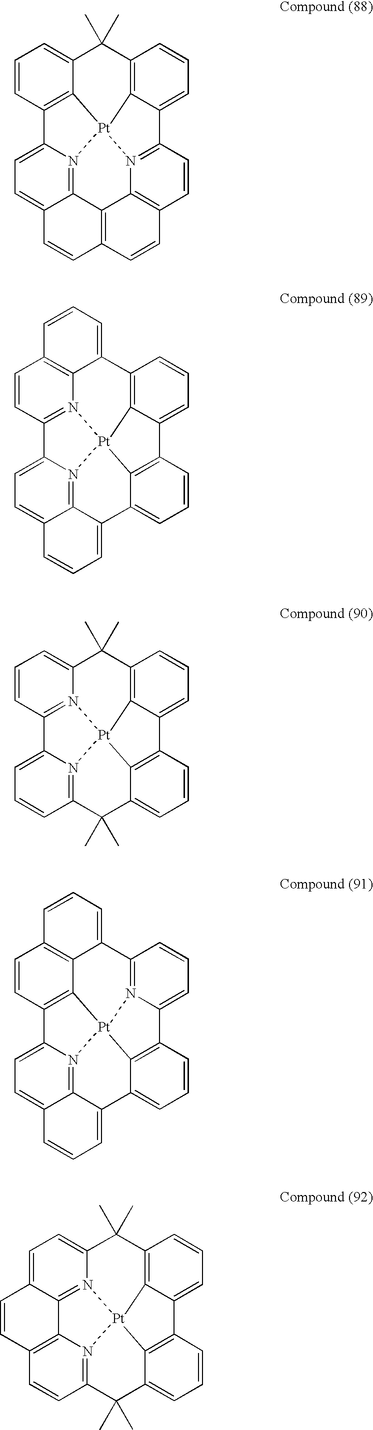

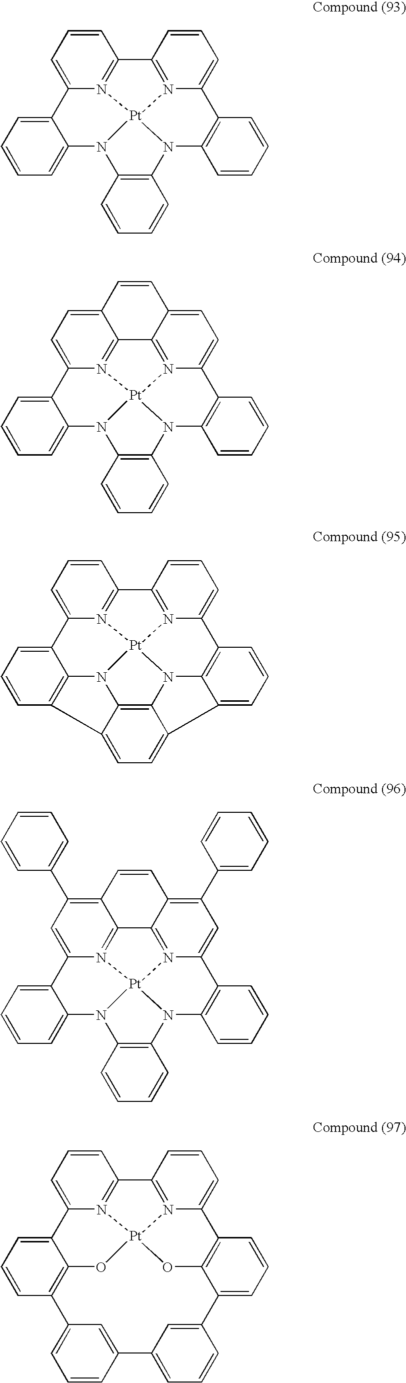

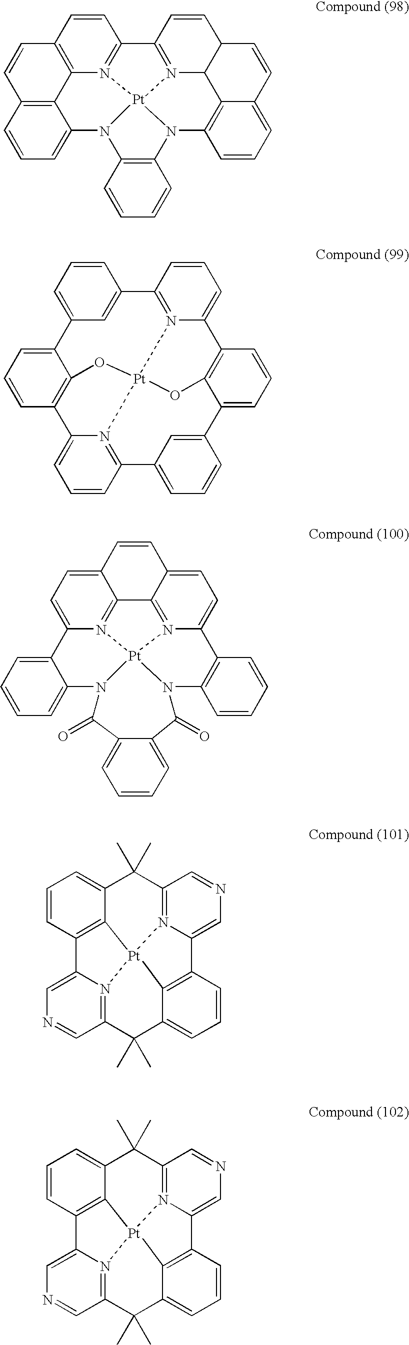

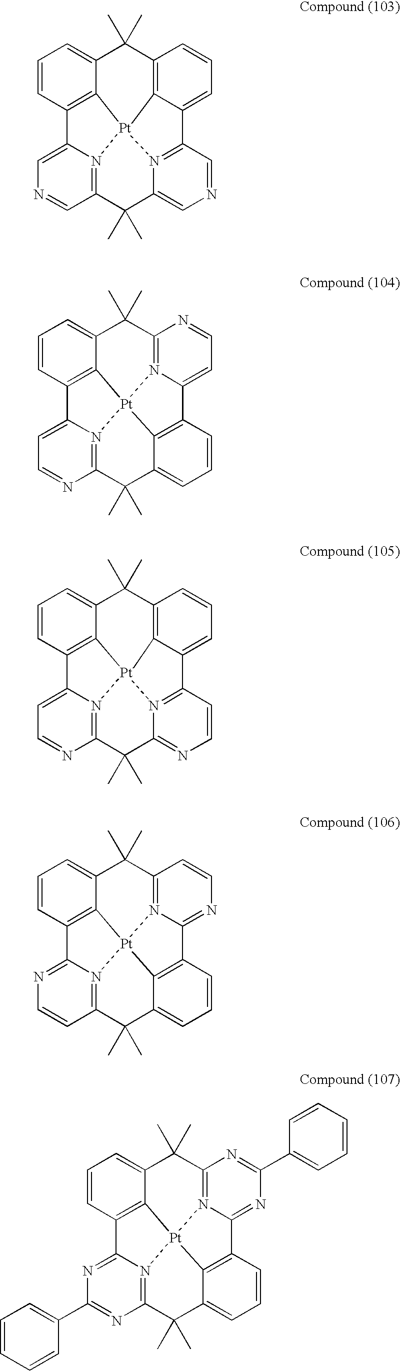

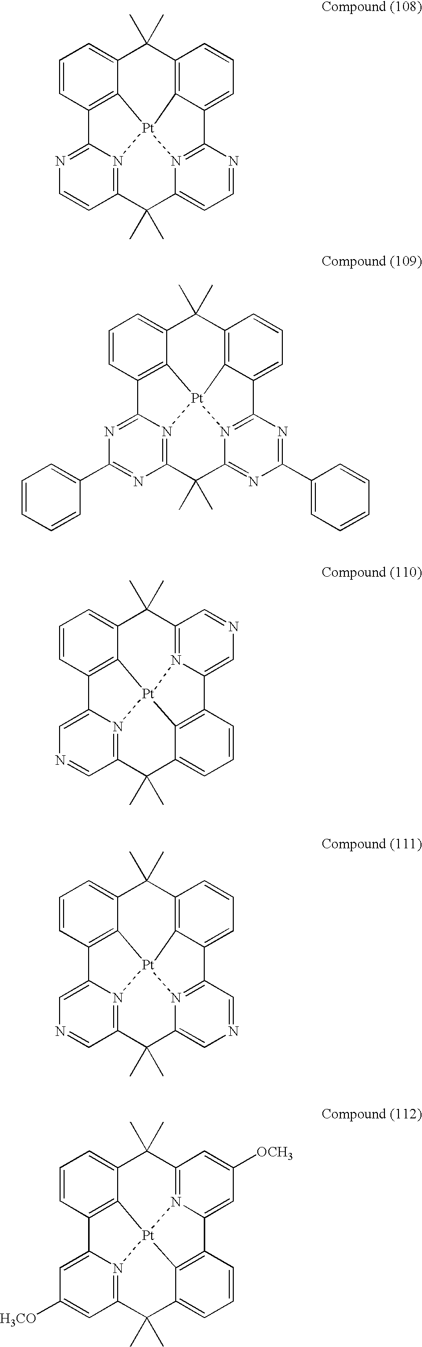

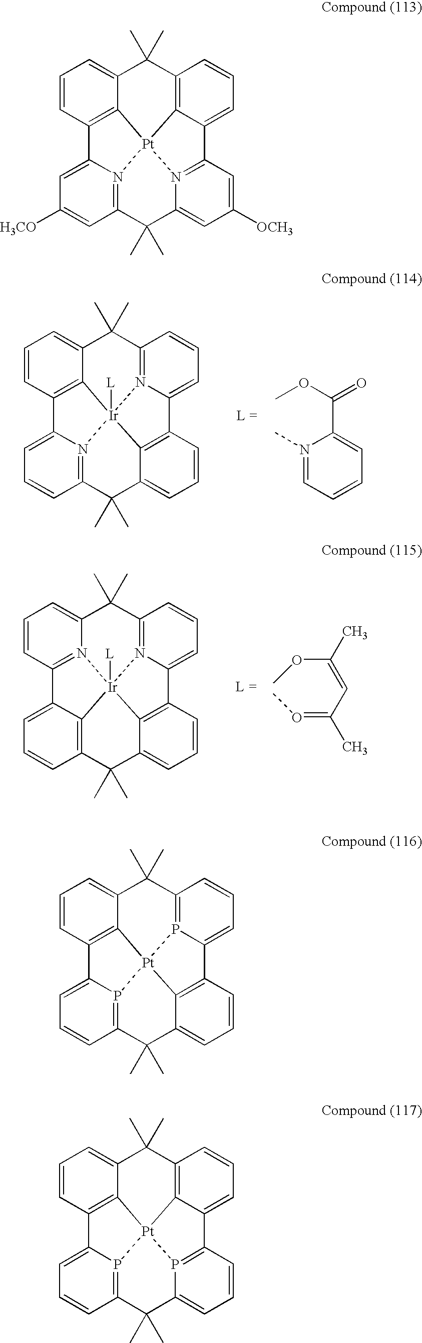

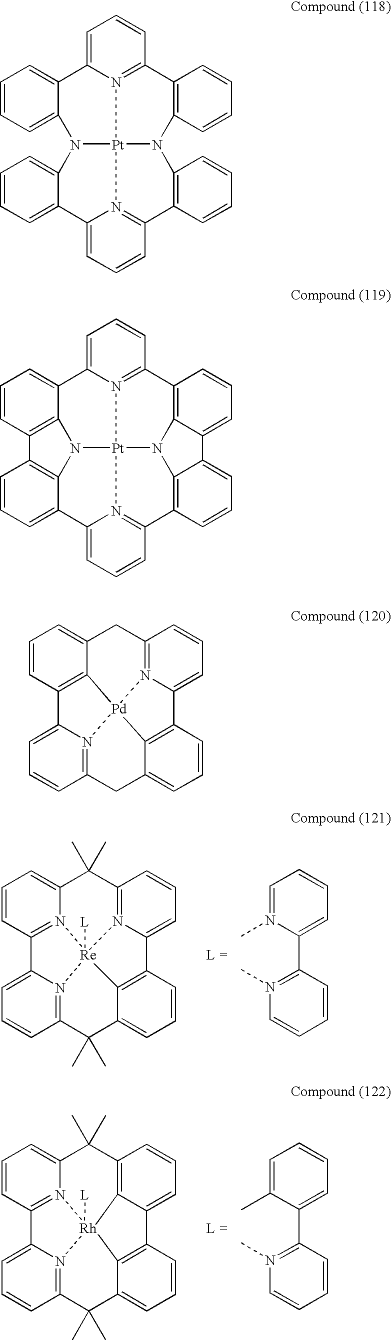

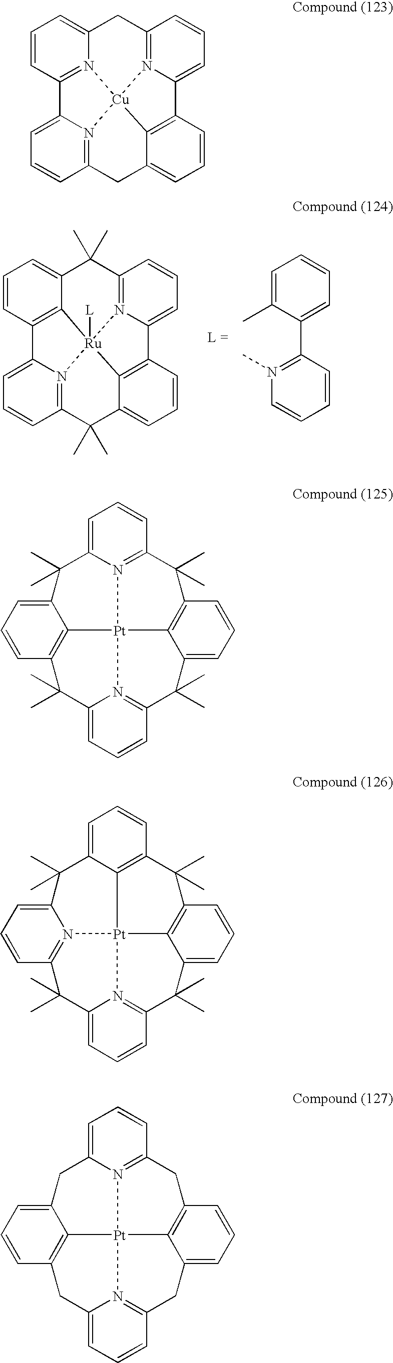

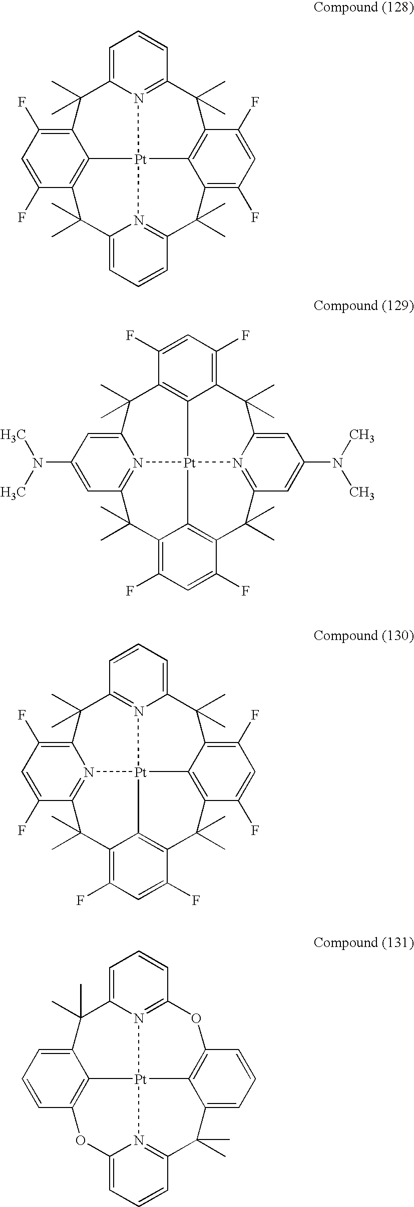

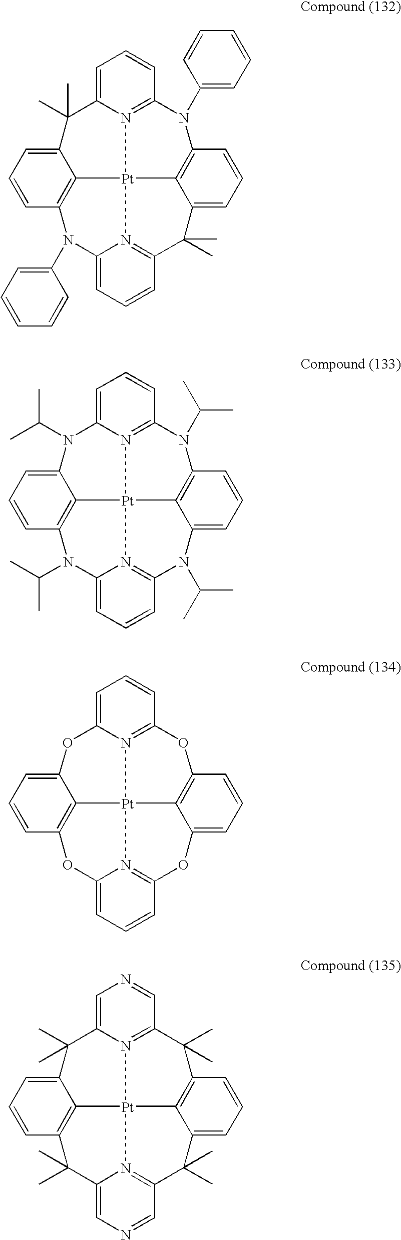

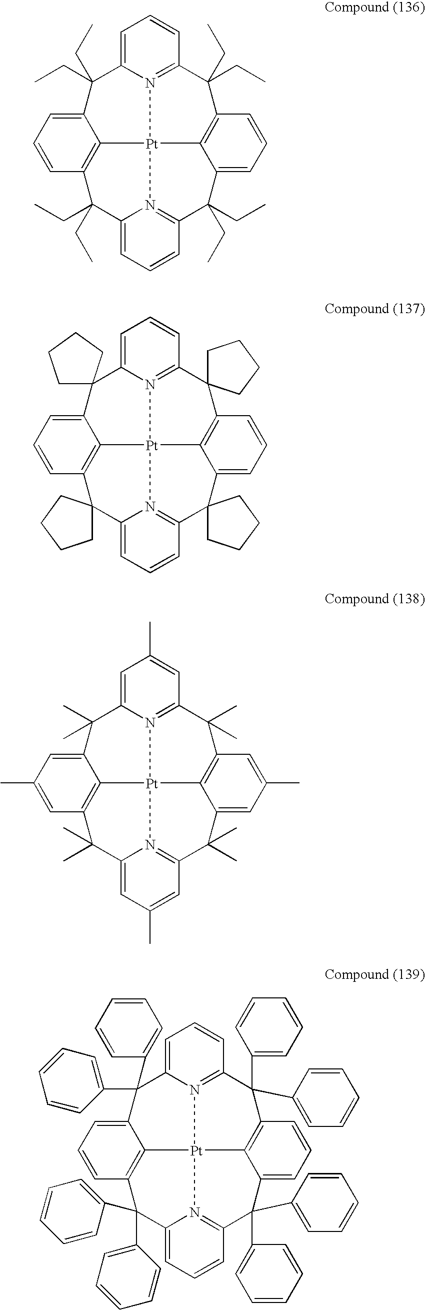

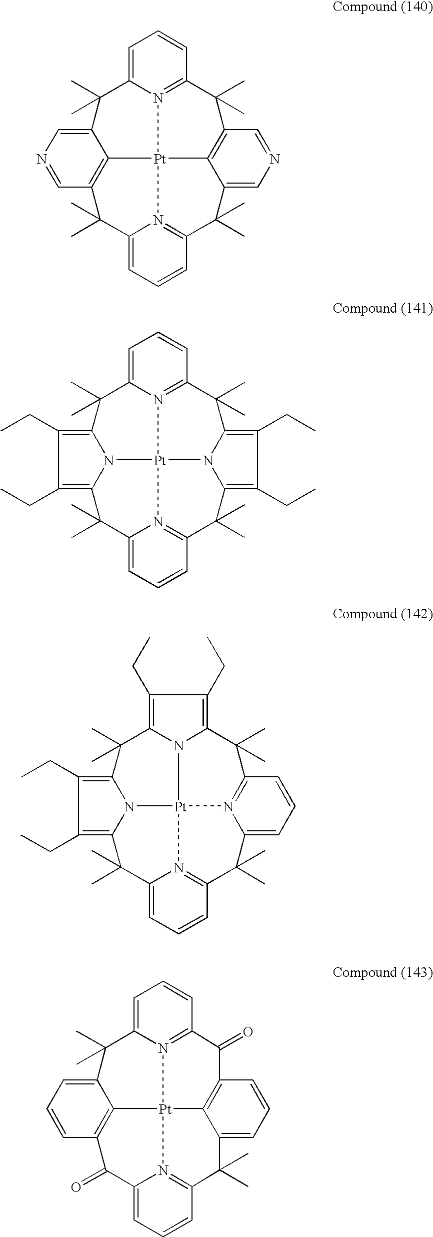

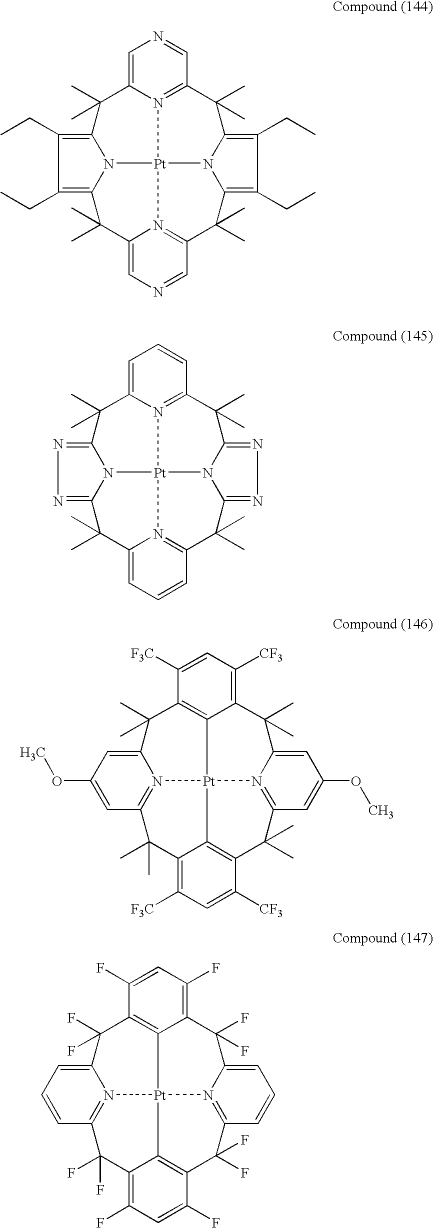

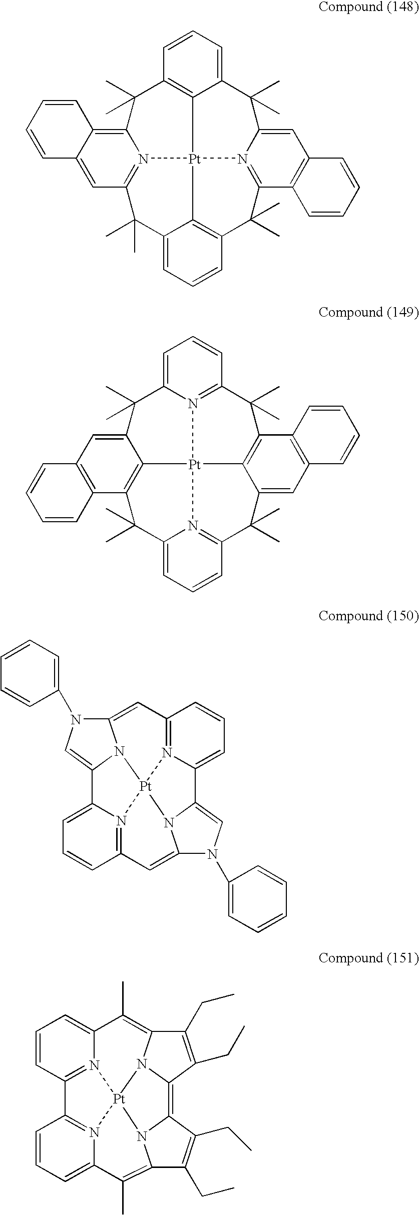

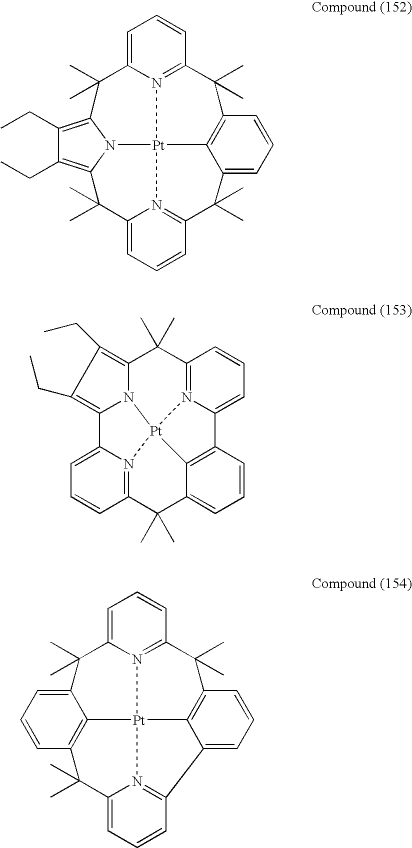

Preferable examples of the metal complex used in the invention include the compounds represented by formulae (A-1), (B-1), (C-1), (D-1), (E-1), and (F-1) described below.

The formula (A-1) will be described below.

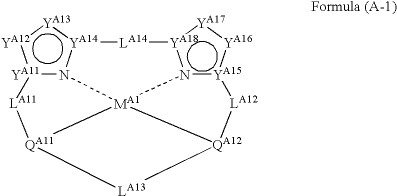

In formula (A-1), M^{A1} represents a metal ion Y^{A11}, Y^{A14}, Y^{A15} and Y^{A18} each independently represent a carbon atom or a nitrogen atom. Y^{A12}, Y^{A13}, Y^{A16} and Y^{A17} each independently represent a substituted or unsubstituted carbon atom, a substituted or unsubstituted nitrogen atom, an oxygen atom or a sulfur atom. L^{A11}, L^{A12}, L^{A13} and L^{A14} each represent a connecting group, and may be the same as each other or different from each other. Q^{A11} and Q^{A12} each independently represent a partial structure containing an atom bonded to M^{A1}. The bond between the atom in the partial structure and M^{A1} may be, for example, a covalent bond.

The compound represented by the formula (A-1) will be described in detail.

M^{A1} represents a metal ion. The metal ion is not particularly limited, but is preferably a divalent metal ion, more preferably Pt²⁺, Pd²⁺, Cu²⁺, Ni²⁺, Co²⁺, Zn²⁺, Mg²⁺ or Pb²⁺, still more preferably Pt²⁺ or Cu²⁺, and further more preferably Pt²⁺.

Y^{A11}, Y^{A14}, Y^{A15} and Y^{A18} each independently represent a carbon atom or a nitrogen atom. Each of Y^{A11}, Y^{A14}, Y^{A15} and Y^{A18} is preferably a carbon atom.

Y^{A12}, Y^{A13}, Y^{A16} and Y^{A17} each independently represent a substituted or unsubstituted carbon atom, a substituted or unsubstituted nitrogen atom, an oxygen atom or a sulfur atom. Each of Y^{A12}, Y^{A13}, Y^{A16} and Y^{A17} is preferably a substituted or unsubstituted carbon atom or a substituted or unsubstituted nitrogen atom.

L^{A11}, L^{A12}, L^{A13} and L^{A14} each independently represent a divalent connecting group. The divalent connecting group represented by L^{A11}, L^{A12}, L^{A13} or L^{A14} may be, for example, a single bond or a connecting group formed of atoms selected from carbon, nitrogen, silicon, sulfur, oxygen, germanium, phosphorus and the like, more preferably a single bond, a substituted or unsubstituted carbon atom, a substituted or unsubstituted nitrogen atom, a substituted silicon atom, an oxygen atom, a sulfur atom, a divalent aromatic hydrocarbon cyclic group or a divalent aromatic heterocyclic group, still more preferably a single bond, a substituted or unsubstituted carbon atom, a substituted or unsubstituted nitrogen atom, a substituted silicon atom, a divalent aromatic hydrocarbon cyclic group or a divalent aromatic heterocyclic group, and particularly more preferably a single bond or a substituted or unsubstituted methylene group. Examples of the divalent connecting group represented by L^{A11}, L^{A12}, L^{A13} or L^{A14} include the following groups:

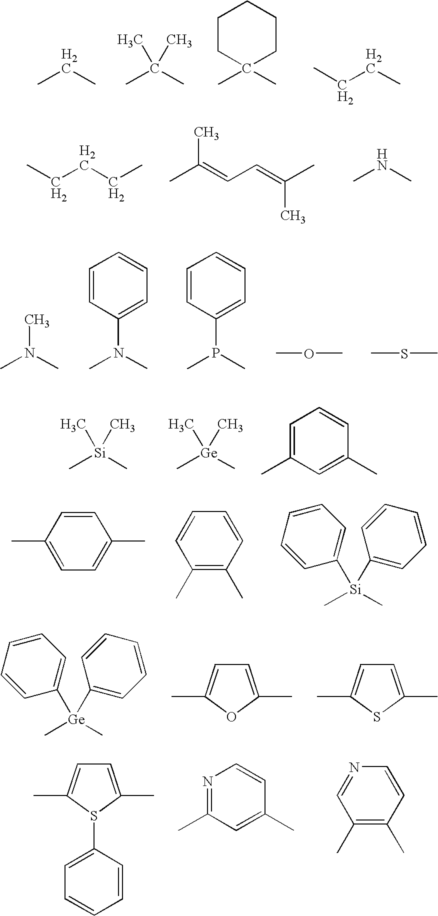

The divalent connecting group represented by L^{A11}, L^{A12}, L^{A13} or L^{A14} may further have a substituent. The substituent which can be introduced into the divalent connecting group may be, for example, an alkyl group (preferably having 1 to 30 carbon atoms, more preferably 1 to 20 carbon atoms, particularly preferably 1 to 10 carbon atoms, for example methyl, ethyl, iso-propyl, tert-butyl, n-octyl, n-decyl, n-hexadecyl, cyclopropyl, cyclopentyl, and cyclohexyl), an alkenyl group (preferably having 2 to 30 carbon atoms, more preferably 2 to 20 carbon atoms, particularly preferably 2 to 10 carbon atoms, for example vinyl, allyl, 2-butenyl, 3-pentenyl), an alkynyl group (preferably having 2 to 30 carbon atoms, more preferably 2 to 20 carbon atoms, particularly preferably 2 to 10 carbon atoms, for example propargyl, 3-pentynyl), an aryl group (preferably having 6 to 30 carbon atoms, more preferably 6 to 20 carbon atoms, particularly preferably 6 to 12 carbon atoms, for example phenyl, p-methylphenyl, naphthyl, anthranyl), an amino group (preferably having 0 to 30 carbon atoms, more preferably 0 to 20 carbon atoms, particularly preferably 0 to 10 carbon atoms, for example amino, methylamino, dimethylamino, diethylamino, dibenzylamino, diphenylamino, ditolylamino), an alkoxy group (preferably having 1 to 30 carbon atoms, more preferably 1 to 20 carbon atoms, particularly preferably 1 to 10 carbon atoms, for example methoxy, ethoxy, butoxy, 2-ethylhexyloxy), an aryloxy group (preferably having 6 to 30 carbon atoms, more preferably 6 to 20 carbon atoms, particularly preferably 6 to 12 carbon atoms, for example phenyloxy, 1-naphthyloxy, 2-naphthyloxy), a heterocyclic oxy group (preferably having 1 to 30 carbon atoms, more preferably 1 to 20 carbon atoms, particularly preferably 1 to 12 carbon atoms, for example pyridyloxy, pyrazyloxy, pyrimidyloxy, quinolyloxy), an acyl group (preferably having 1 to 30 carbon atoms, more preferably 1 to 20 carbon atoms, particularly preferably 1 to 12 carbon atoms, for example acetyl, benzoyl, formyl, pivaloyl), an alkoxycarbonyl group (preferably having 2 to 30 carbon atoms, more preferably 2 to 20 carbon atoms, particularly preferably 2 to 12 carbon atoms, for example methoxycarbonyl, ethoxycarbonyl), an aryloxycarbonyl group (preferably having 7 to 30 carbon atoms, more preferably 7 to 20 carbon atoms, particularly preferably 7 to 12 carbon atoms, for example phenyloxycarbonyl), an acyloxy group (preferably having 2 to 30 carbon atoms, more preferably 2 to 20 carbon atoms, particularly preferably 2 to 10 carbon atoms, for example acetoxy, benzoyloxy), an acylamino group (preferably having 2 to 30 carbon atoms, more preferably 2 to 20 carbon atoms, particularly preferably 2 to 10 carbon atoms, for example acetylamino, benzoylamino), an alkoxycarbonylamino group (preferably having 2 to 30 carbon atoms, more preferably 2 to 20 carbon atoms, particularly preferably 2 to 12 carbon atoms, for example methoxycarbonylamino), an aryloxycarbonylamino group (preferably having 7 to 30 carbon atoms, more preferably 7 to 20 carbon atoms, particularly preferably 7 to 12 carbon atoms, for example phenyloxycarbonylamino), a sulfonylamino group (preferably having 1 to 30 carbon atoms, more preferably 1 to 20 carbon atoms, particularly preferably 1 to 12 carbon atoms, for example methanesulfonylamino, benzenesulfonylamino), a sulfamoyl group (preferably having 0 to 30 carbon atoms, more preferably 0 to 20 carbon atoms, particularly preferably 0 to 12 carbon atoms, for example sulfamoyl, methylsulfamoyl, dimethylsulfamoyl, phenylsulfamoyl), a carbamoyl group (preferably having 1 to 30 carbon atoms, more preferably 1 to 20 carbon atoms, particularly preferably 1 to 12 carbon atoms, for example carbamoyl, methylcarbamoyl, diethylcarbamoyl, phenylcarbamoyl), an alkylthio group (preferably having 1 to 30 carbon atoms, more preferably 1 to 20 carbon atoms, particularly preferably 1 to 12 carbon atoms, for example methylthio, ethylthio), an arylthio group (preferably having 6 to 30 carbon atoms, more preferably 6 to 20 carbon atoms, particularly preferably 6 to 12 carbon atoms, for example phenylthio), a heterocyclic thio group (preferably having 1 to 30 carbon atoms, more preferably 1 to 20 carbon atoms, particularly preferably 1 to 12 carbon atoms, for example pyridylthio, 2-benzimizolylthio, 2-benzoxazolylthio, 2-benzthiazolylthio), a sulfonyl group (preferably having 1 to 30 carbon atoms, more preferably 1 to 20 carbon atoms, particularly preferably 1 to 12 carbon atoms, for example mesyl, tosyl), a sulfinyl group (preferably having 1 to 30 carbon atoms, more preferably 1 to 20 carbon atoms, particularly preferably 1 to 12 carbon atoms, for example methanesulfinyl, benzenesulfinyl), a ureido group (preferably having 1 to 30 carbon atoms, more preferably 1 to 20 carbon atoms, particularly preferably 1 to 12 carbon atoms, for example ureido, methylureido, phenylureido), a phosphoric amide group (preferably having 1 to 30 carbon atoms, more preferably 1 to 20 carbon atoms, particularly preferably 1 to 12 carbon atoms, for example diethylphosphoric amide, phenylphosphoric amide), a hydroxy group, a mercapto group, a halogen atom (for example a fluorine atom, chlorine atom, bromine atom, and iodine atom), a cyano group, a sulfo group, a carboxyl group, a nitro group, a hydroxamic acid group, a sulfino group, a hydrazino group, an imino group, a heterocyclic group (preferably having 1 to 30 carbon atoms, more preferably 1 to 20 carbon atoms, particularly preferably 1 to 12 carbon atoms containing a heteroatom such as a nitrogen atom, oxygen atom or sulfur atom, specifically imidazolyl, pyridyl, quinolyl, furyl, thienyl, piperidyl, morpholino, benzoxazolyl, benzimidazolyl, benzthiazolyl, carbazolyl group, azepinyl group), a silyl group (preferably having 3 to 40 carbon atoms, more preferably 3 to 30 carbon atoms, particularly preferably 3 to 24 carbon atoms, for example trimethylsilyl, triphenylsilyl) or a silyloxy group (preferably having 3 to 40 carbon atoms, more preferably 3 to 30 carbon atoms, particularly preferably 3 to 24 carbon atoms, for example trimethylsilyloxy, triphenylsilyloxy).

These substituents may be further substituted. Substituents which can be introduced to these substituents are each preferably selected from an alkyl group, an aryl group, a heterocyclic group, a halogen atom or a silyl group, more preferably an alkyl group, an aryl group, a heterocyclic group or a halogen atom, and still more preferably an alkyl group, an aryl group, an aromatic heterocyclic group or a fluorine atom.

Q^{A11} and Q^{A12} each independently represent a partial structure containing an atom bonded to M^{A1}. The bond between the atom in the partial structure and M^{A1} may be, for example, a covalent bond. Q^{A11} and Q^{A12} each independently represent preferably a group having a carbon atom bonded to M^{A1}, a group having a nitrogen atom bonded to M^{A1}, a group having a silicon atom bonded to M^{A1}, a group having a phosphorus atom bonded to M^{A1}, a group having an oxygen atom bonded to M^{A1} or a group having a sulfur atom bonded to M^{A1}, more preferably a group having a carbon, nitrogen, oxygen or sulfur atom bonded to M^{A1}, still more preferably a group having a carbon or nitrogen atom bonded to M^{A1}, and further more preferably a group having a carbon atom bonded to M^{A1}.

The group bonded via a carbon atom is preferably an aryl group having a carbon atom bonded to M^{A1}, a 5-membered heteroaryl group having a carbon atom bonded to M^{A1} or a 6-membered heteroaryl group having a carbon atom bonded to M^{A1}, more preferably an aryl group having a carbon atom bonded to M^{A1}, a nitrogen-containing 5-membered heteroaryl group having a carbon atom bonded to M^{A1}, or a nitrogen-containing 6-membered heteroaryl group having a carbon atom bonded to M^{A1}, and still more preferably an aryl group having a carbon atom bonded to M^{A1}.

The group bonded via a nitrogen atom is preferably a substituted amino group or a nitrogen-containing 5-membered heteroaryl group having a nitrogen atom bonded to M^{A1}, more preferably a nitrogen-containing 5-membered heteroaryl group having a nitrogen atom bonded to M^{A1}.

The group having a phosphorus atom bonded to M^{A1} is preferably a substituted phosphino group. The group having a silicon atom bonded to M^{A1} is preferably a substituted silyl group. The group having an oxygen atom bonded to M^{A1} is preferably an oxy group, and the group having a sulfur atom bonded to M^{A1} is preferably a sulfide group.

The compound represented by the formula (A-1) is more preferably a compound represented by the following formula (A-2), (A-3) or (A-4).

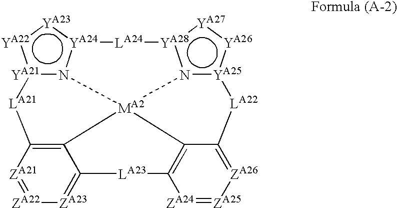

In formula (A-2), M^{A2} represents a metal ion. Y^{A21}, Y^{A24}, Y^{A25} and Y^{A28} each independently represent a carbon atom or a nitrogen atom. Y^{A22}, Y^{A23}, Y^{A26} and Y^{A27} each independently represent a substituted or unsubstituted carbon atom, a substituted or unsubstituted nitrogen atom, an oxygen atom or a sulfur atom. L^{A21}, L^{A22}, L^{A23} and L^{A24} each independently represent a connecting group. Z^{A21}, Z^{A22}, Z^{A23}, Z^{A24}, Z^{A25} and Z^{A26} each independently represent a nitrogen atom or a substituted or unsubstituted carbon atom.

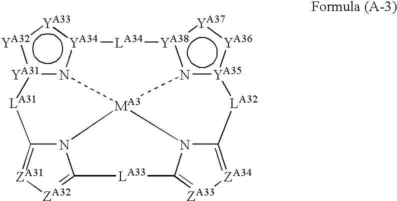

In formula (A-3), M^{A3} represents a metal ion. Y^{A31}, Y^{A34}, Y^{A35} and Y^{A38} each independently represent a carbon atom or a nitrogen atom. Y^{A32}, Y^{A33}, Y^{A36} and Y^{A37} each independently represent a substituted or unsubstituted carbon atom, a substituted or unsubstituted nitrogen atom, an oxygen atom or a sulfur atom. L^{A31}, L^{A32}, L^{A33} and L^{A34} each independently represent a connecting group. Z^{A31}, Z^{A32}, Z^{A33} and Z^{A34} each independently represent a nitrogen atom or a substituted or unsubstituted carbon atom.

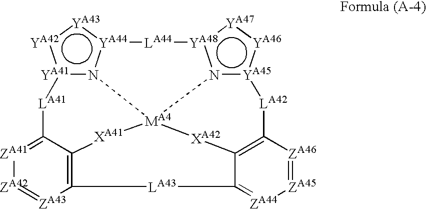

In formula (A-4), M^{A4} represents a metal ion. Y^{A41}, Y^{A44}, Y^{A45} and Y^{A48} each independently represent a carbon atom or a nitrogen atom. Y^{A42}, Y^{A43}, Y^{A46} and Y^{A47} each independently represent a substituted or unsubstituted carbon atom, a substituted or unsubstituted nitrogen atom, an oxygen atom or a sulfur atom. L^{A41}, L^{A42}, L^{A43} and L^{A44} each independently represent a connecting group. Z^{A41}, Z^{A42}, Z^{A43}, Z^{A44}, Z^{A45} and Z^{A46} each independently represent a nitrogen atom or a substituted or unsubstituted carbon atom. X^{A41} and X^{A42} each independently represent an oxygen atom, a sulfur atom or a substituted or unsubstituted nitrogen atom.

The compound represented by the formula (A-2) is described in detail.

M^{A2}, Y^{A21}, Y^{A24}, Y^{A25}, Y^{A28}, Y^{A22}, Y^{A23}, Y^{A26}, Y^{A27}, L^{A21}, L^{A22}, L^{A23} and L^{A24} have the same definitions as corresponding M^{A1}, Y^{A11}, Y^{A14}, Y^{A15}, Y^{A18}, Y^{A12}, Y¹³, Y^{A16}, Y^{A17}, L^{A11}, L^{A12}, L^{A13} and L^{A14} in formula (A-1) respectively, and their preferable examples are also the same.

Z^{A21}, Z^{A22}, Z^{A23}, Z^{A24}, Z^{A25} and Z^{A26} each independently represent a nitrogen atom or a substituted or unsubstituted carbon atom. Z^{A21}, Z^{A22}, Z^{A23}, Z^{A24}, Z^{A25} and Z^{A26} each independently represent preferably a substituted or unsubstituted carbon atom, and more preferably an unsubstituted carbon atom. When the carbon atom is substituted, the substituent may be selected from the above-mentioned examples of the substituent on the divalent connecting group represented by L^{A11}, L^{A12}, L^{A13} or L^{A14} in formula (A-1).

The compound represented by the formula (A-3) will be described in detail.

M^{A3}, Y^{A31}, Y^{A34}, Y^{A35}, Y^{A38}, Y^{A32}, Y^{A33}, Y^{A36}, Y^{A37}, L^{A31}, L^{A32}, L^{A33} and L^{A34} have the same definitions as corresponding M^{A1}, Y^{A11}, Y^{A14}, Y^{A15}, Y^{A18}, Y^{A12}, Y^{A13}, Y^{A16}, Y^{A17}, L^{A11}, L^{A12}, L^{A13} and L^{A14} in formula (A-1) respectively, and their preferable examples are also the same.

Z^{A31}, Z^{A32}, Z^{A33} and Z^{A34} each independently represent a nitrogen atom or a substituted or unsubstituted carbon atom. Each of Z^{A31}, Z^{A32}, Z^{A33} and Z^{A34} is preferably a substituted or unsubstituted carbon atom, and more preferably an unsubstituted carbon atom. When the carbon atom is substituted, the substituent may be selected from the above-mentioned examples of the substituent on the divalent connecting group represented by L^{A11}, L^{A12}, L^{A13} or L^{A14} in formula (A-1).

The compound represented by the formula (A-4) will be described in detail.

M^{A4}, Y^{A41}, Y^{A44}, Y^{A45}, Y^{A48}, Y^{A42}, Y^{A43}, Y^{A46}, Y^{A47}, L^{A41}, L^{A42}, L^{A43} and L^{A44} have the same definitions as corresponding M^{A1}, Y^{A11}, Y^{A14}, Y^{A15}, Y^{A18}, Y^{A12}, Y^{A13}, Y^{A16}, Y^{A17}, L^{A11}, L¹², L^{A13} and L^{A14} in formula (A-1) respectively, and their preferable examples are also the same.

Z^{A41}, Z^{A42}, Z^{A43}, Z^{A44}, Z^{A45} and Z^{A46} each independently represent a nitrogen atom or a substituted or unsubstituted carbon atom. Each of Z^{A41}, Z^{A42}, Z^{A43}, Z^{A44}, Z^{A45} and Z^{A46} is preferably a substituted or unsubstituted carbon atom, and more preferably an unsubstituted carbon atom. When the carbon atom is substituted, the substituent may be selected from the above-mentioned examples of the substituent on the divalent connecting group represented by L^{A11}, L^{A12}, L^{A13} or L^{A14} in formula (A-1)

X^{A41} and X^{A42} each independently represent an oxygen atom, a sulfur atom or a substituted or unsubstituted nitrogen atom. Each of X^{A41} and X^{A42} is preferably an oxygen atom or a sulfur atom, and more preferably an oxygen atom.

Specific examples of the compound represented by the formula (A-1) are shown below. However, the specific examples should not be construed as limiting the invention.

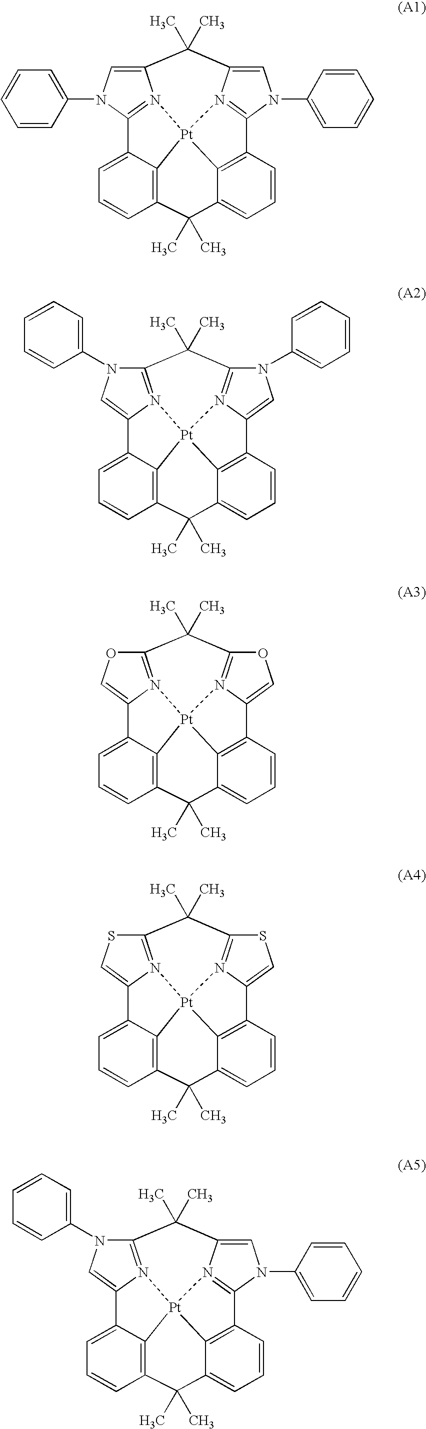

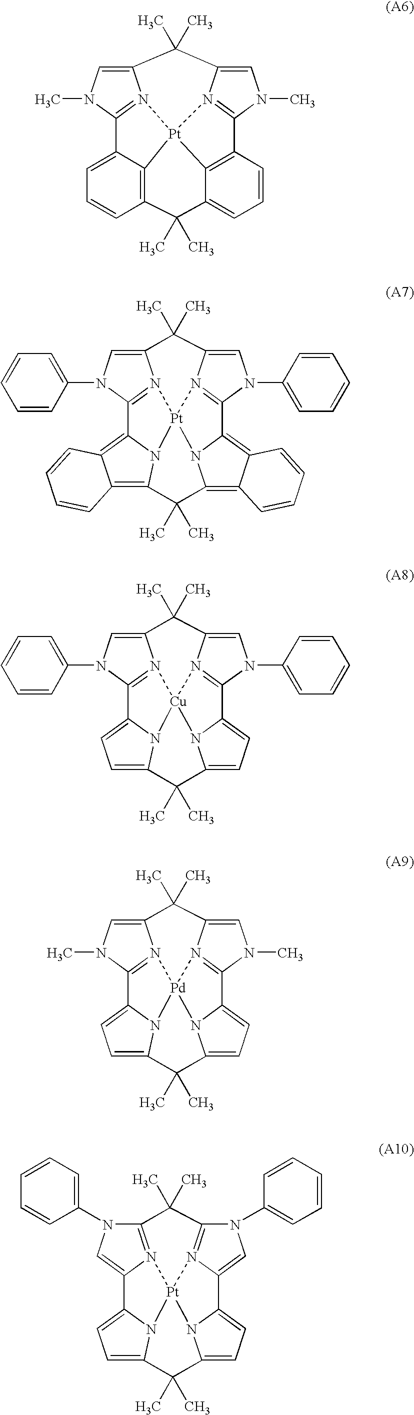

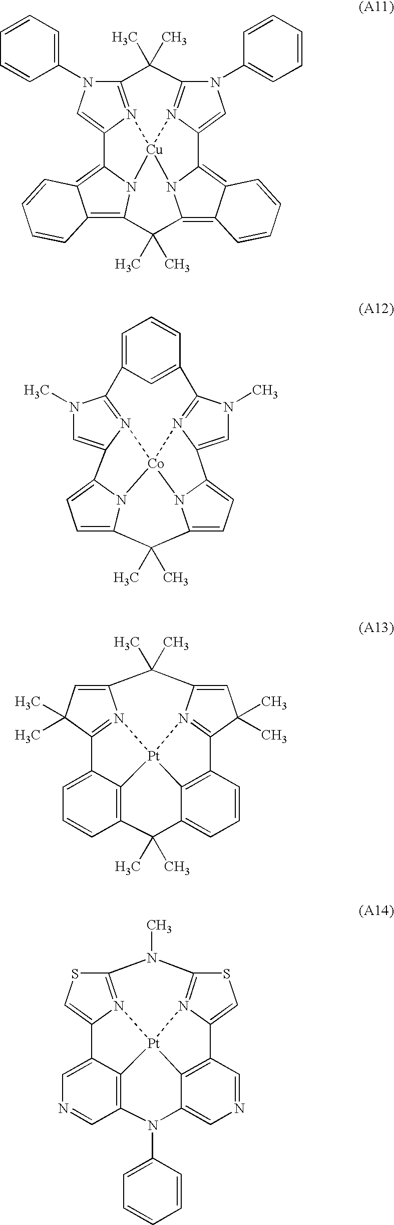

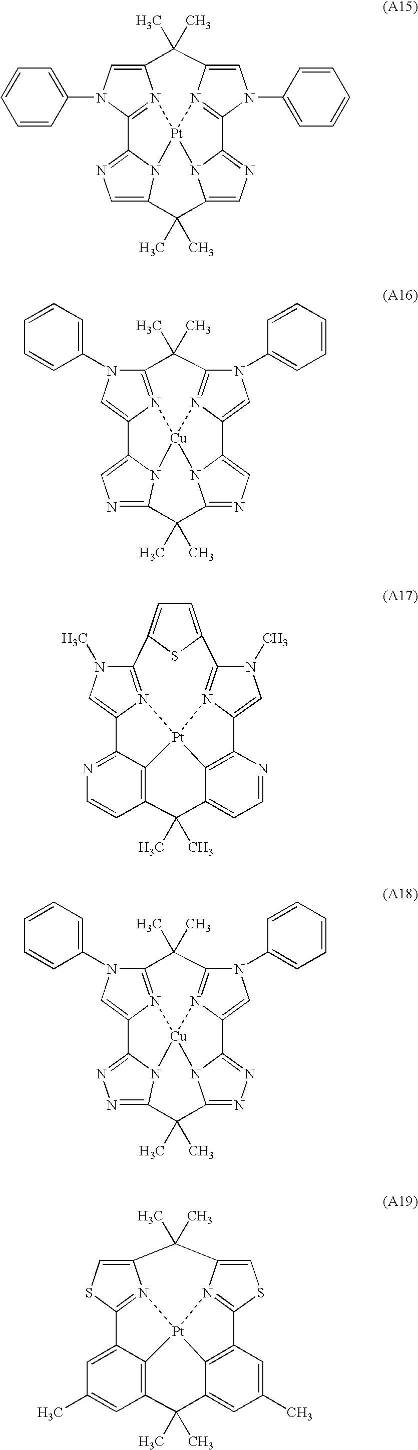

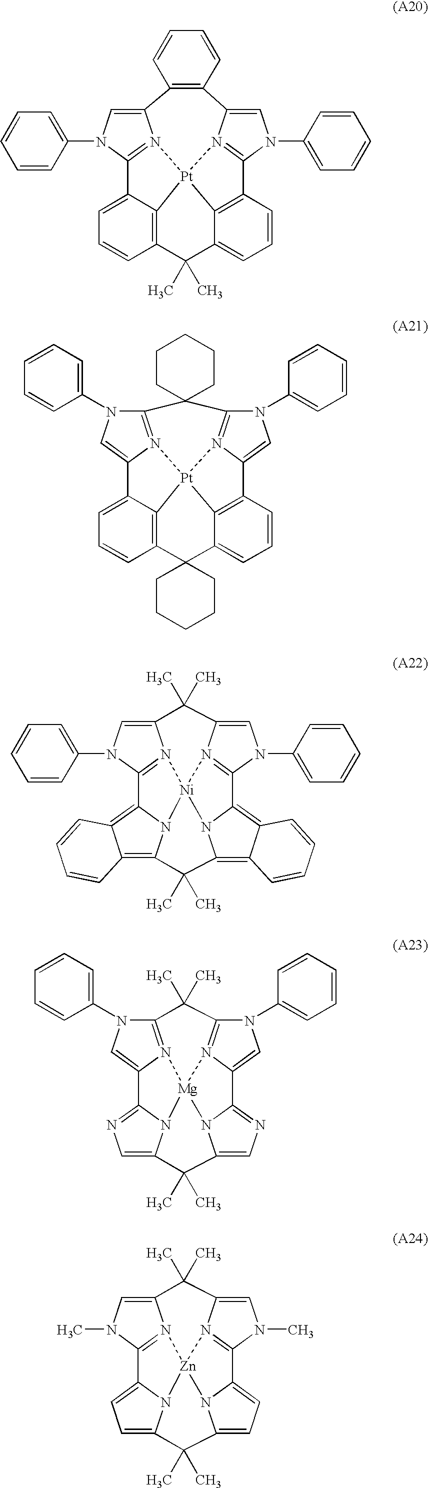

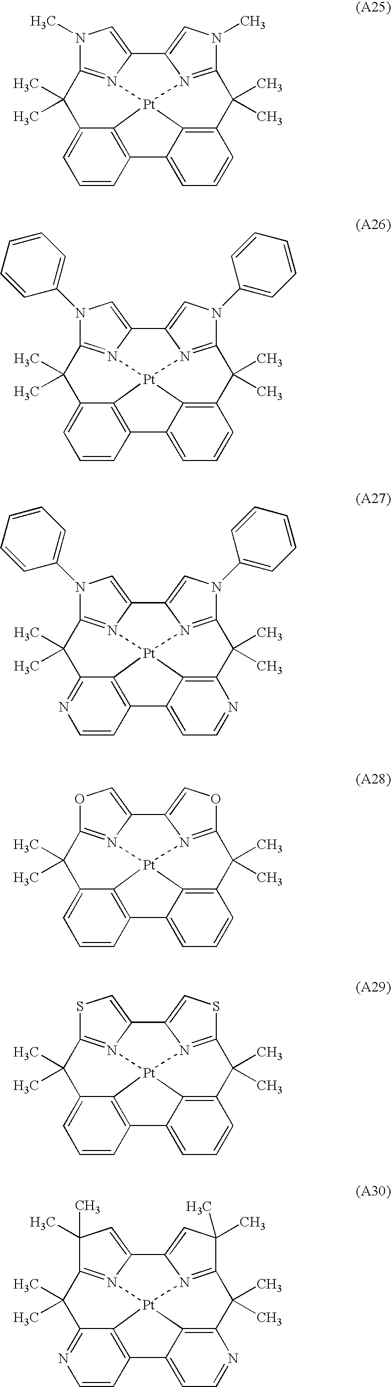

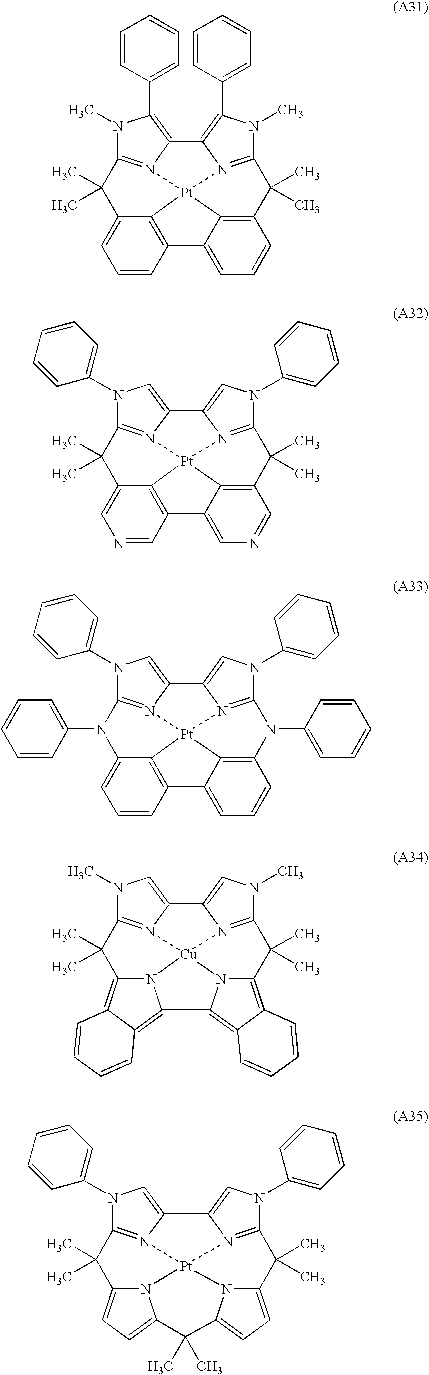

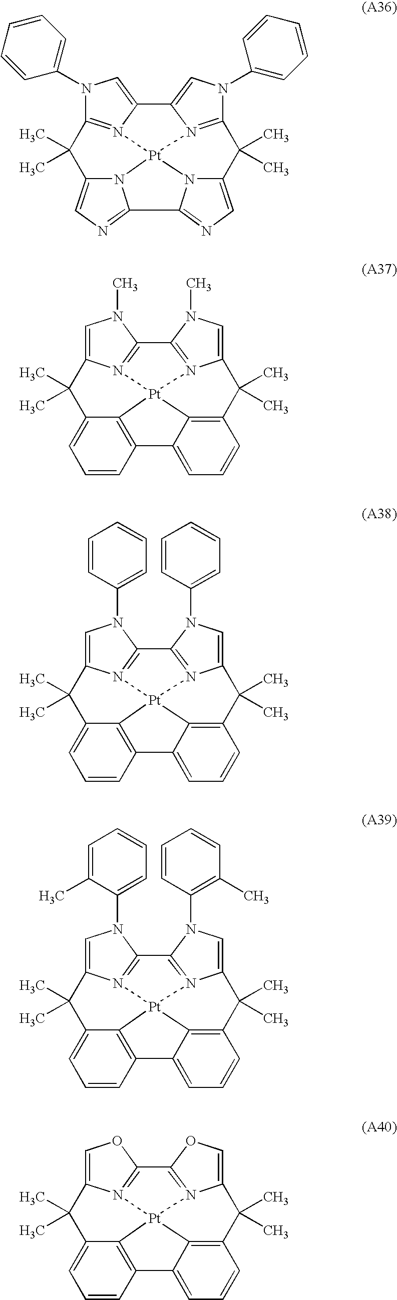

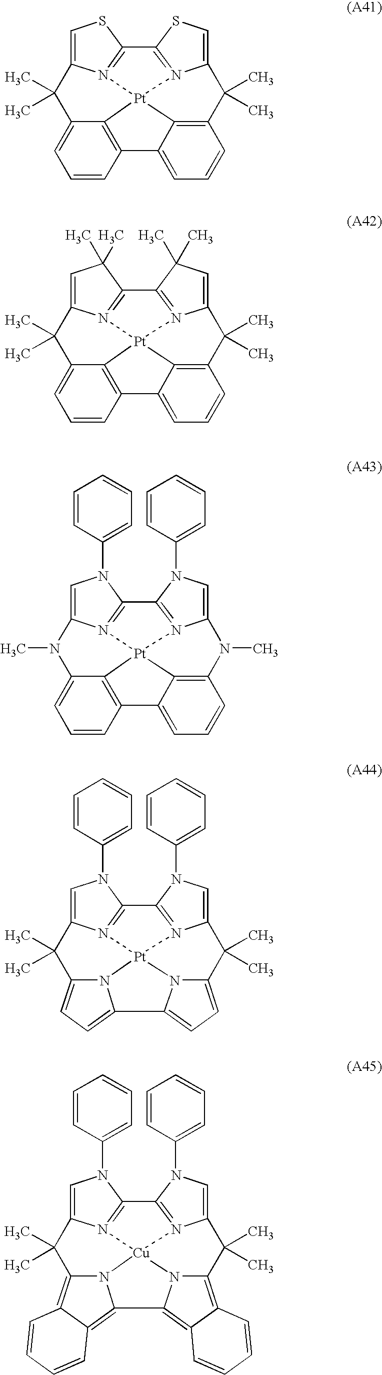

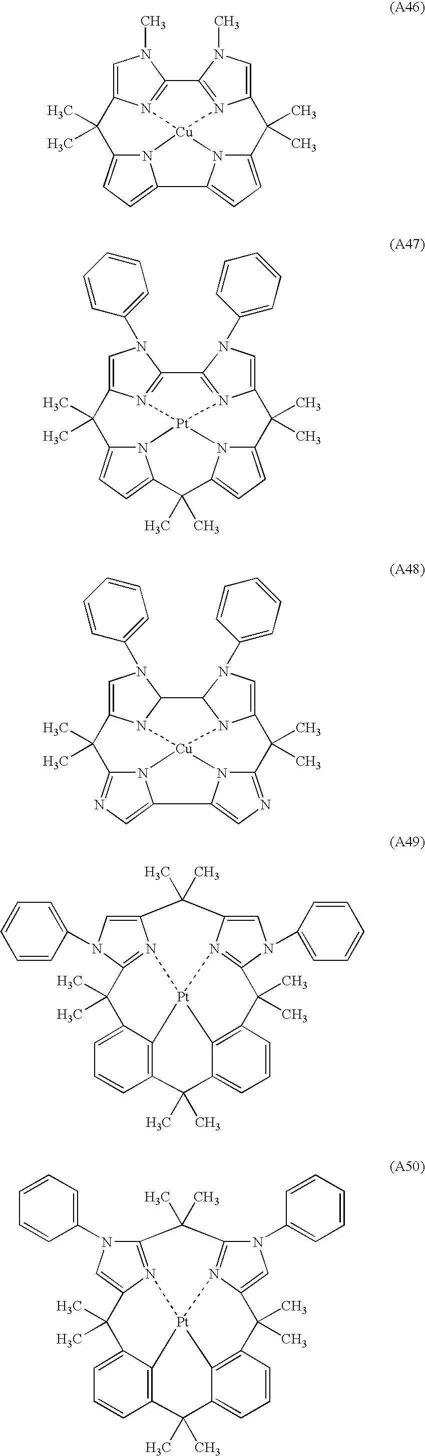

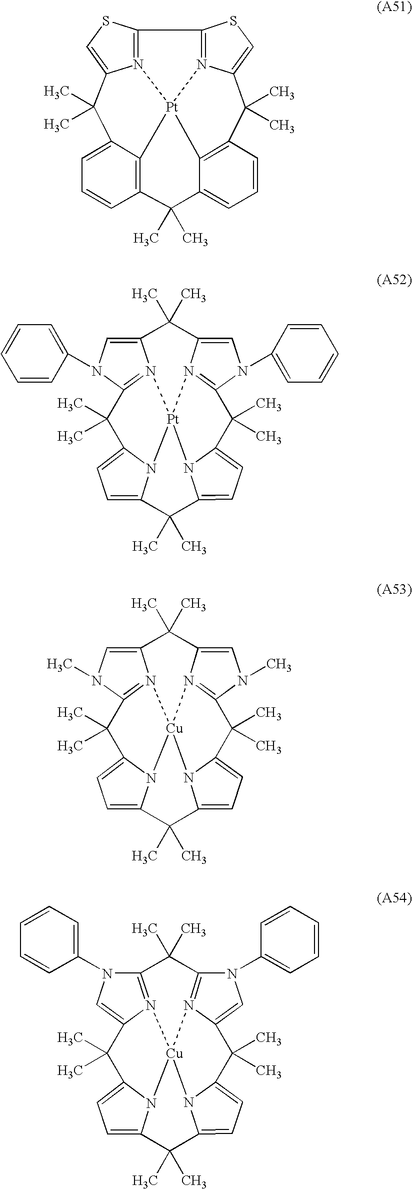

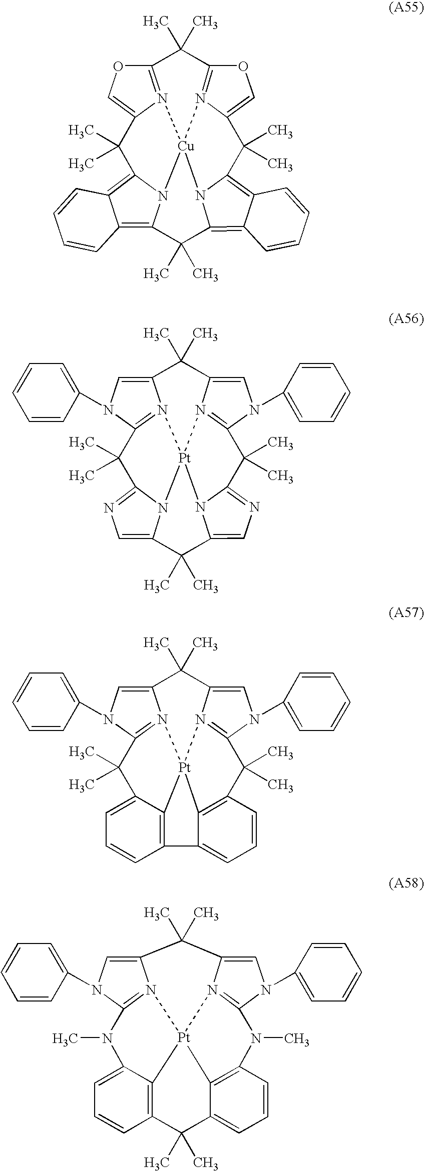

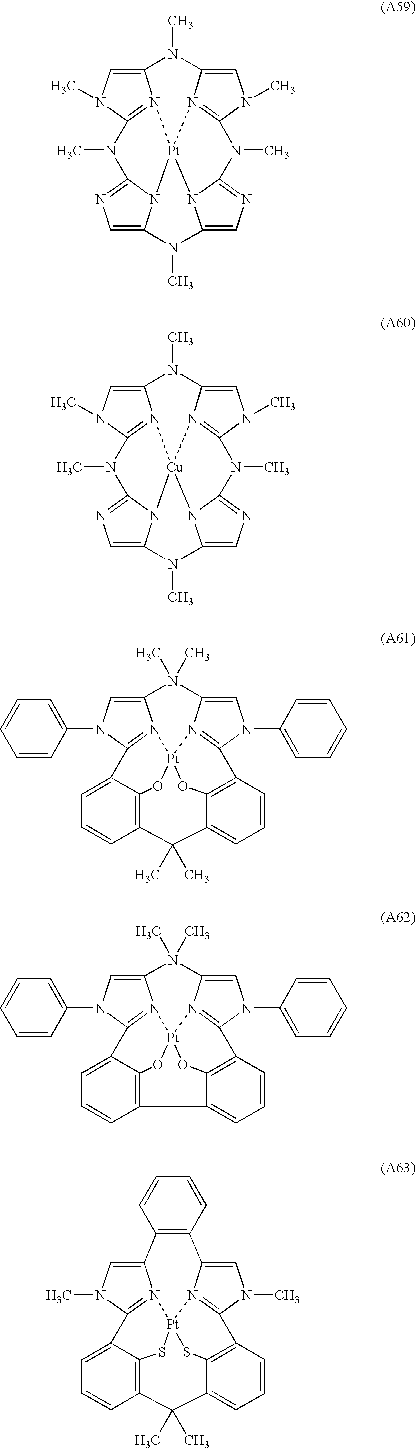

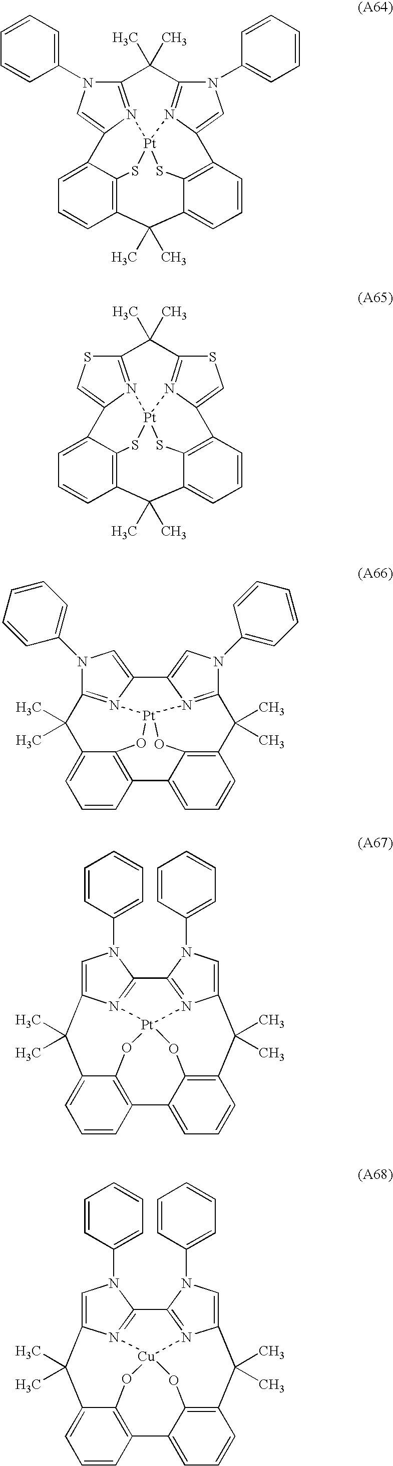

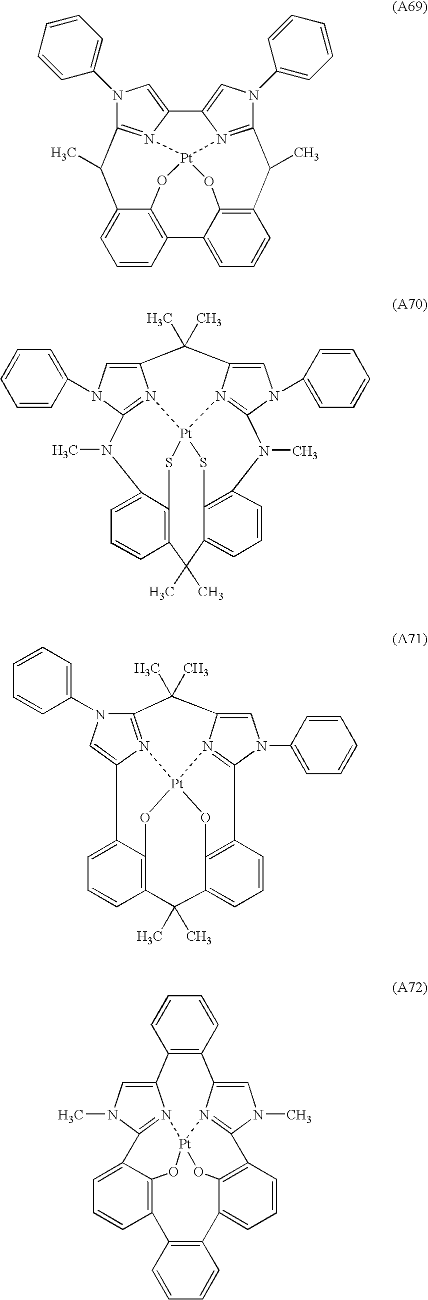

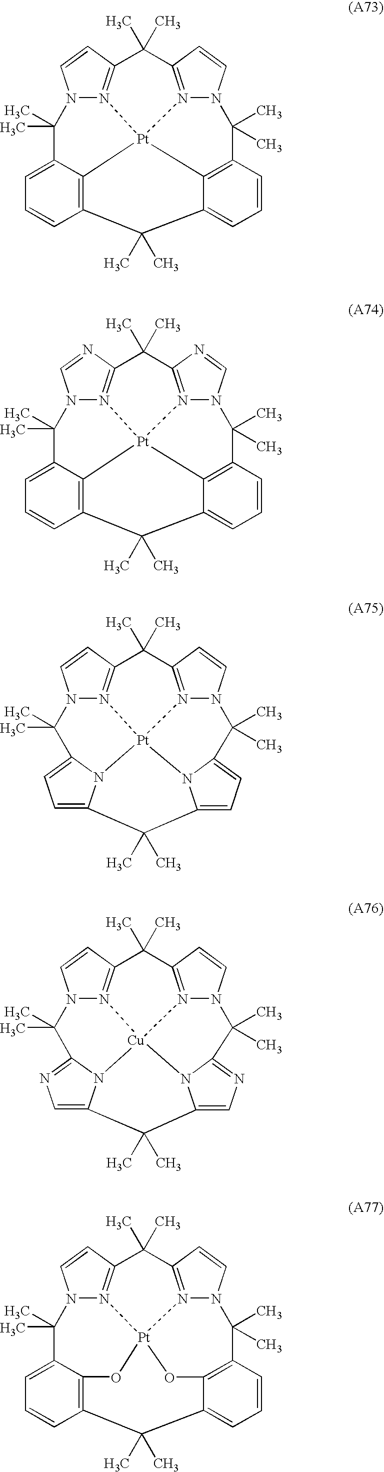

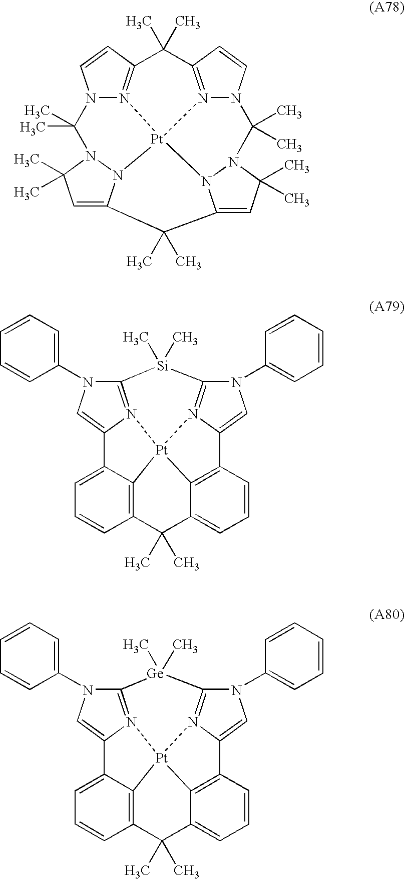

Compound represented by the formula (B-1) shown below are also preferable as metal complexes usable in the invention.

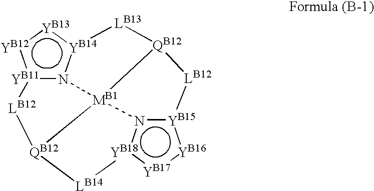

In formula (B-1), M^{B1} represents a metal ion. Y^{B11}, Y^{B14}, Y^{B15} and Y^{B18} each independently represent a carbon atom or a nitrogen atom. Y^{B12}, Y^{B13}, Y^{B16} and Y^{B17} each independently represent a substituted or unsubstituted carbon atom, a substituted or unsubstituted nitrogen atom, an oxygen atom or a sulfur atom. L^{B11}, L^{B12}, L^{B13} and L^{B14} each independently represent a connecting group. Q^{B11} and Q^{B12} each independently represent a partial structure containing an atom bonded to M^{B1}. The bond between the atom in the partial structure and M^{B1} may be, for example, a covalent bond.

The compound represented by the formula (B-1) will be described in detail.

In formula (B-1), M^{B1}, Y^{B11}, Y^{B14}, Y^{B15}, Y^{B18}, Y^{B12}, Y^{B13}, Y^{B16}, Y^{B17}, L^{B11}, L^{B12}, L^{B13}, L^{B14}, Q^{B11} and Q^{B12} have the same definitions as corresponding M^{A1}, Y^{A11}, Y^{A14}, Y^{A15}, Y^{A18}, Y^{A12}, Y^{A13}, Y^{A16}, Y^{A17}, L^{A11}, L^{A12}, L^{A13}, L^{A14}, Q^{A11} and Q^{A12} in formula (A-1) respectively, and their preferable examples are also the same.

The compound represented by formula (B-1) is more preferably a compound represented by the following formulae (B-2), (B-3) or (B-4).

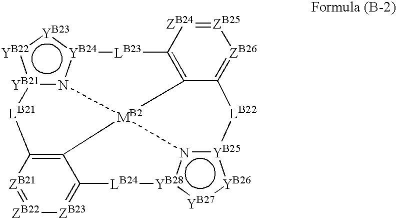

In formula (B-2), M^{B2} represents a metal ion. Y^{B21}, Y^{B24}, Y^{B25} and Y^{B28} each independently represent a carbon atom or a nitrogen atom. Y^{B22}, Y^{B23}, Y^{B26} and Y^{B27} each independently represent a substituted or unsubstituted carbon atom, a substituted or unsubstituted nitrogen atom, an oxygen atom or a sulfur atom. L^{B21}, L^{B22}, L^{B23} and L^{B24} each independently represent a connecting group. Z^{B21}, Z^{B22}, Z^{B23}, Z^{B24}, Z^{B25} and Z^{B26} each independently represent a nitrogen atom or a substituted or unsubstituted carbon atom.

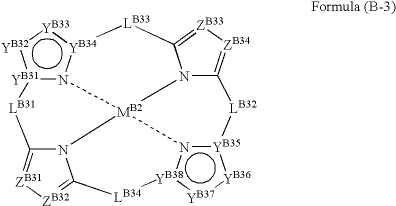

In formula (B-3), M^{B3} represents a metal ion. Y^{B31}, Y^{B34}, Y^{B35} and Y^{B38} each independently represent a carbon atom or a nitrogen atom. Y^{B32}, Y^{B33}, Y^{B36} and Y^{B37} each independently represent a substituted or unsubstituted carbon atom, a substituted or unsubstituted nitrogen atom, an oxygen atom or a sulfur atom. L^{B31}, L^{B32}, L^{B33} and L^{B34} each independently represent a connecting group. Z^{B31}, Z^{B32}, Z^{B33} and Z^{B34} each independently represent a nitrogen atom or a substituted or unsubstituted carbon atom.

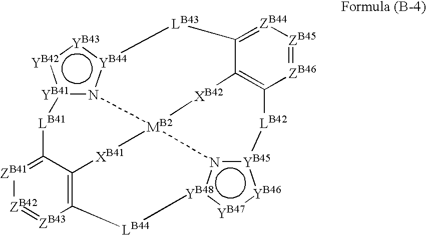

In formula (B-4), M^{B4} represents a metal ion. Y^{B41}, Y^{B44}, Y^{B45} and Y^{B48} each independently represent a carbon atom or a nitrogen atom. Y^{B42}, Y^{B43}, Y^{B46} and Y^{B47} each independently represent a substituted or unsubstituted carbon atom, a substituted or unsubstituted nitrogen atom, an oxygen atom or a sulfur atom. L^{B41}, L^{B42}, L^{B43} and L^{B44} each independently represent a connecting group. Z^{B41}, Z^{B42}, Z^{B43}, Z^{B44}, Z^{B45} and Z^{B46} each independently represent a nitrogen atom or a substituted or unsubstituted carbon atom. X^{B41} and X^{B42} each independently represent an oxygen atom, a sulfur atom or a substituted or unsubstituted nitrogen atom.

The compound represented by the formula (B-2) will be described in detail.

In formula (B-2), M^{B2}, Y^{B21}, Y^{B24}, Y^{B25}, Y^{B28}, Y^{B22}, Y^{B23}, Y^{B26}, Y^{B27}, L^{B21}, L^{B22}, L^{B23} and L^{B24} have the same definitions as corresponding M^{B1}, Y^{B11}, Y^{B14}, Y^{B15}, Y^{B18}, Y^{B12}, Y^{B13}, Y^{B16}, Y^{B17}, L^{B11}, L^{B12}, L^{B13} and L^{B14} in formula (B-1) respectively, and their preferable examples are also the same.

Z^{B21}, Z^{B22}, Z^{B23}, Z^{B24}, Z^{B25} and Z^{B26} each independently represent a nitrogen atom or a substituted or unsubstituted carbon atom. Each of Z^{B21}, Z^{B22}, Z^{B23}, Z^{B24}, Z^{B25} and Z^{B26} is preferably a substituted or unsubstituted carbon atom, and more preferably an unsubstituted carbon atom. When the carbon atom is substituted, the substituent may be selected from the above-mentioned examples of the substituent on the divalent connecting group represented by L^{A11}, L^{A12}, L^{A13} or L^{A14} in formula (A-1).

The compound represented by the formula (B-3) will be described in detail.

In formula (B-3), M^{B3}, Y^{B31}, Y^{B34}, Y^{B35}, Y^{B38}, Y^{B32}, Y^{B33}, Y^{B36}, Y^{B37}, L^{B31}, L^{B32}, L^{B33} and L^{B34} have the same definitions as corresponding M^{B1}, Y^{B11}, Y^{B14}, Y^{B15}, Y^{B18}, Y^{B12}, Y^{B13}, Y^{B16}, Y^{B17}, L^{B11}, L^{B12}, L^{B13} and L^{B14} in formula (B-1) respectively, and their preferable examples are also the same.

Z^{B31}, Z^{B32}, Z^{B33} and Z^{B34} each independently represent a nitrogen atom or a substituted or unsubstituted carbon atom. Each of Z^{B31}, Z^{B32}, Z^{B33} and Z^{B34} is preferably a substituted or unsubstituted carbon atom, and more preferably an unsubstituted carbon atom. When the carbon atom is substituted, the substituent may be selected from the above-mentioned examples of the substituent on the divalent connecting group represented by L^{A11}, L^{A12}, L^{A13} or L^{A14} in formula (A-1).

The compound represented by the formula (B-4) will be described in detail.

In formula (B-4), M^{B4}, Y^{B41}, Y^{B44}, Y^{B45}, Y^{B48}, Y^{B42}, Y^{B43}, Y^{B46}, Y^{B47}, L^{B41}, L^{B42}, L^{B43} and L^{B44} have the same definitions as corresponding M^{B1}, Y^{B11}, Y^{B14}, Y^{B15}, Y^{B18}, Y^{B12}, Y^{B13}, Y^{B16}, Y^{B17}, L^{B11}, L^{B12}, L^{B13} and L^{B14} in formula (B-1) respectively, and their preferable examples are also the same.

Z^{B41}, Z^{B42}, Z^{B43}, Z^{B44}, Z^{B45} and Z^{B46} each independently represent a nitrogen atom or a substituted or unsubstituted carbon atom. Each of Z^{B41}, Z^{B42}, Z^{B43}, Z^{B44}, Z^{B45} and Z^{B46} is preferably a substituted or unsubstituted carbon atom, and more preferably an unsubstituted carbon atom. When the carbon atom is substituted, the substituent may be selected from the above-mentioned examples of the substituent on the divalent connecting group represented by L^{A11}, L^{A12}, L^{A13} or L^{A14} in formula (A-1)

X^{B41} and X^{B42} each independently represent an oxygen atom, a sulfur atom or a substituted or unsubstituted nitrogen atom. Each of X^{B41} and X^{B42} is preferably an oxygen atom or a sulfur atom, and more preferably an oxygen atom.

Specific examples of the compounds represented by the formula (B-1) are illustrated below, but the invention is not limited thereto.

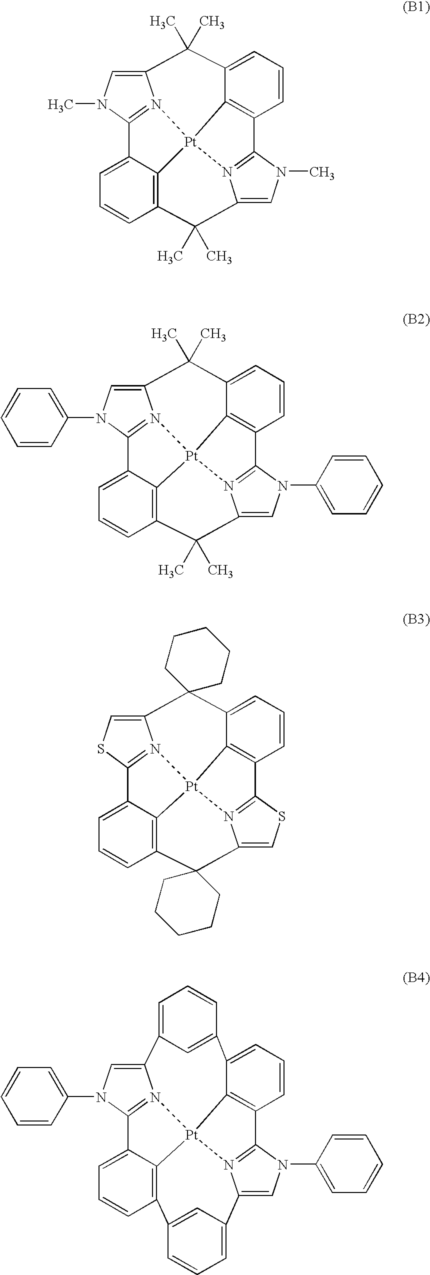

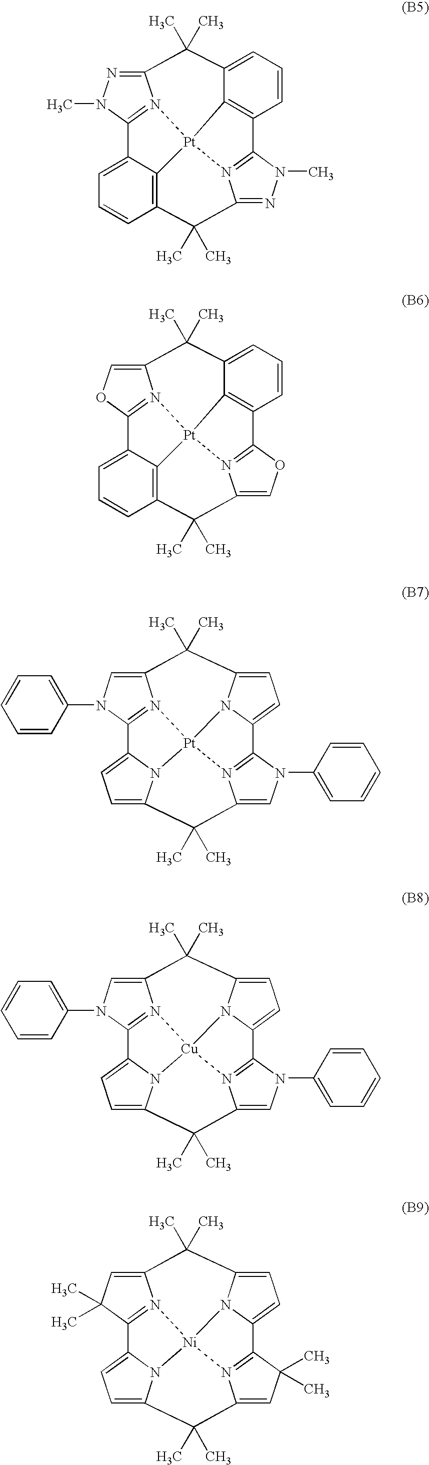

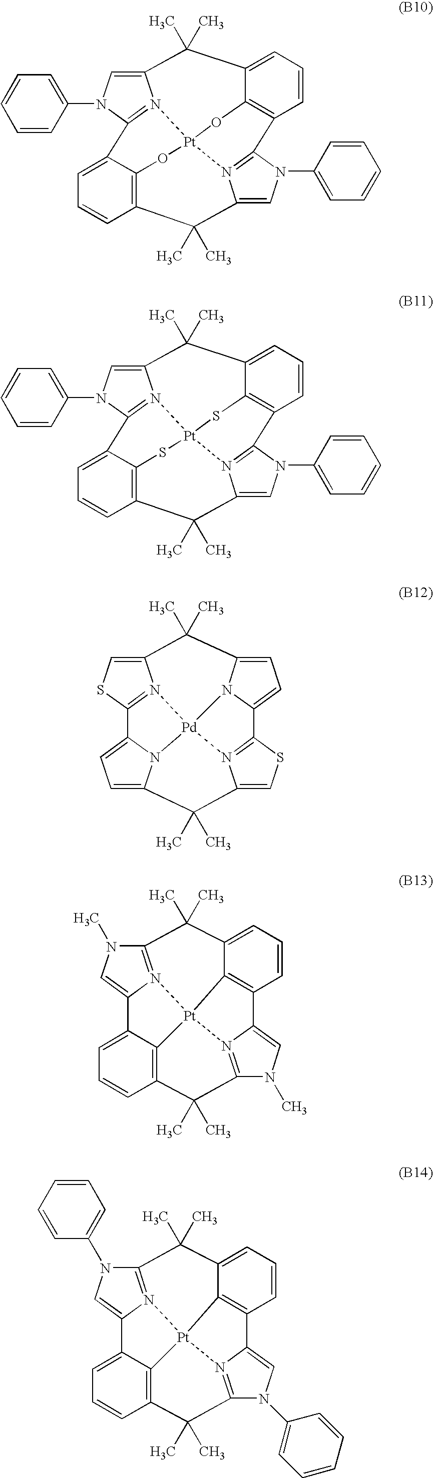

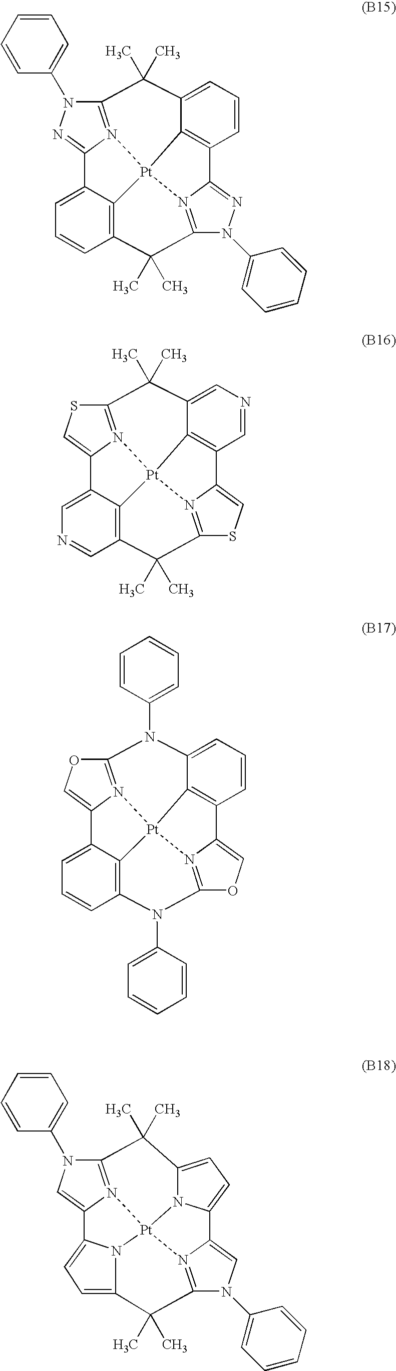

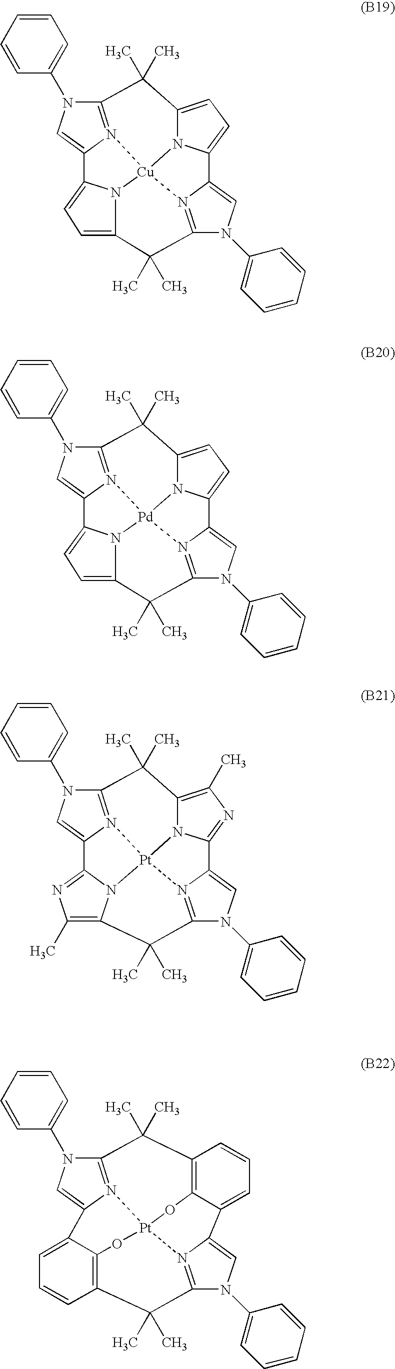

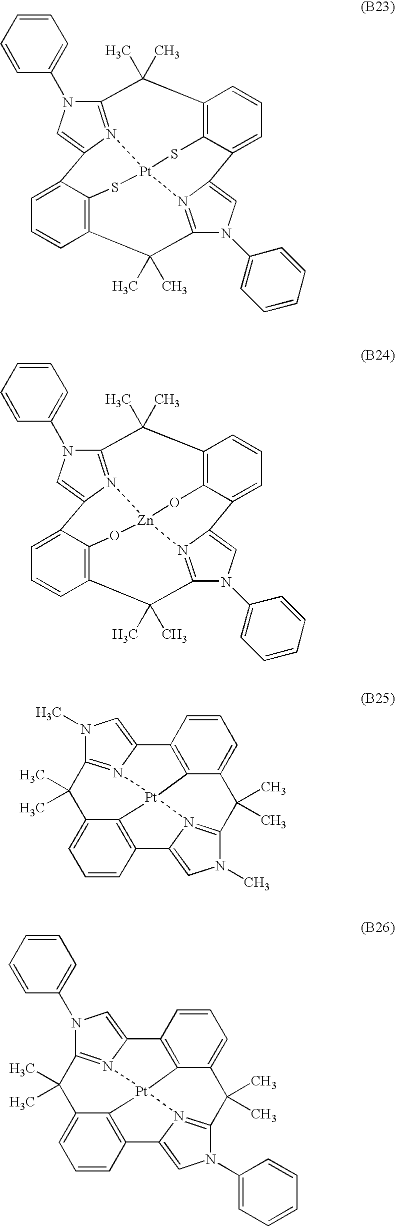

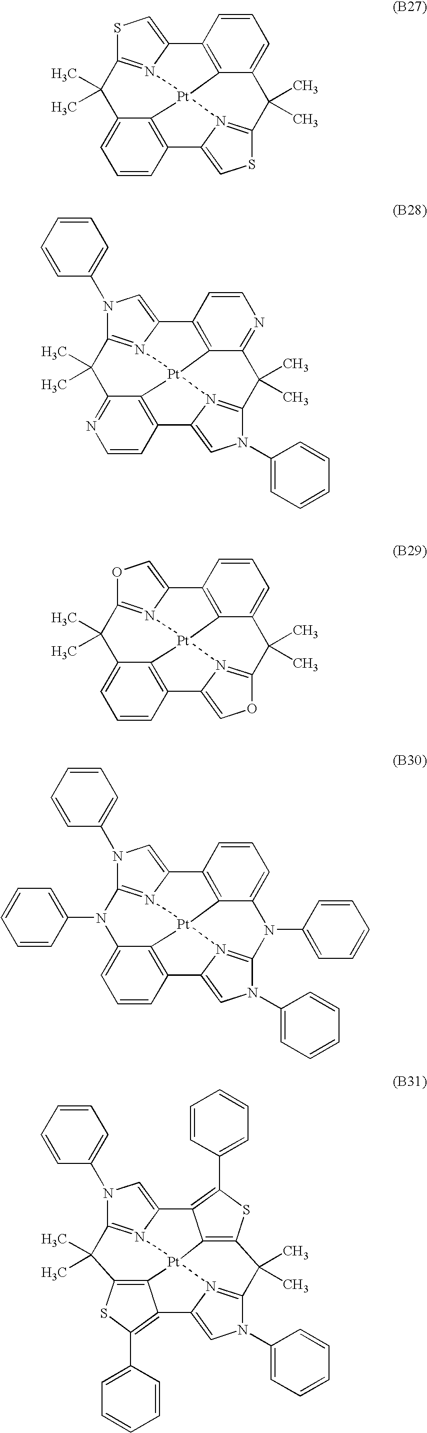

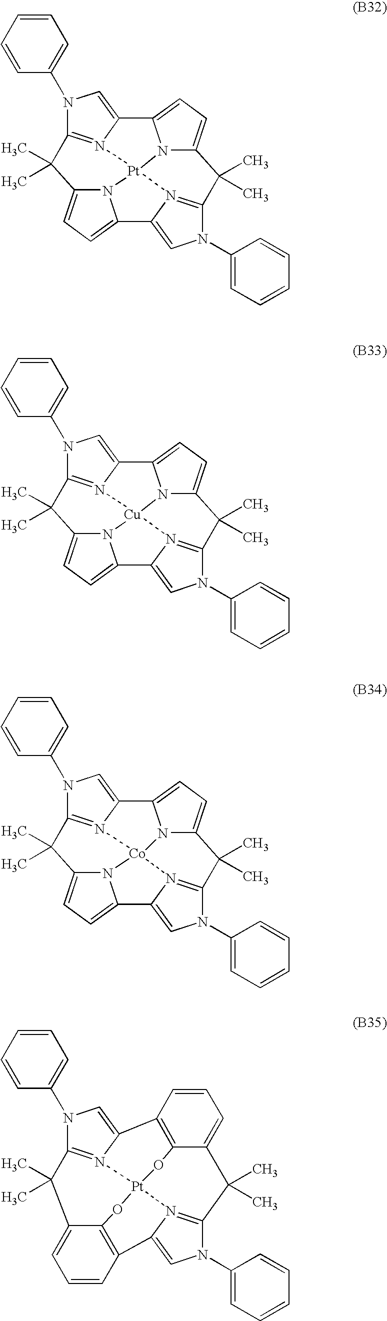

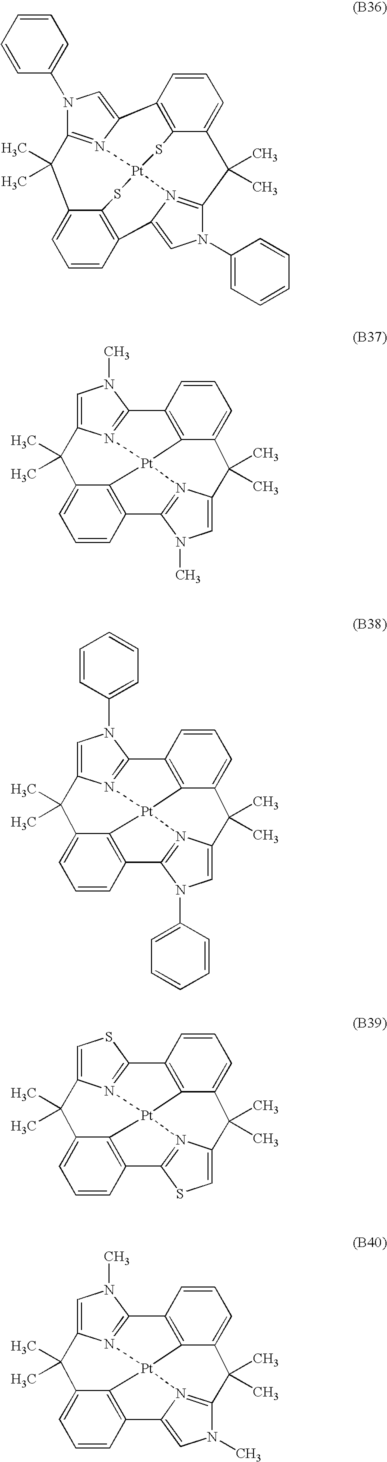

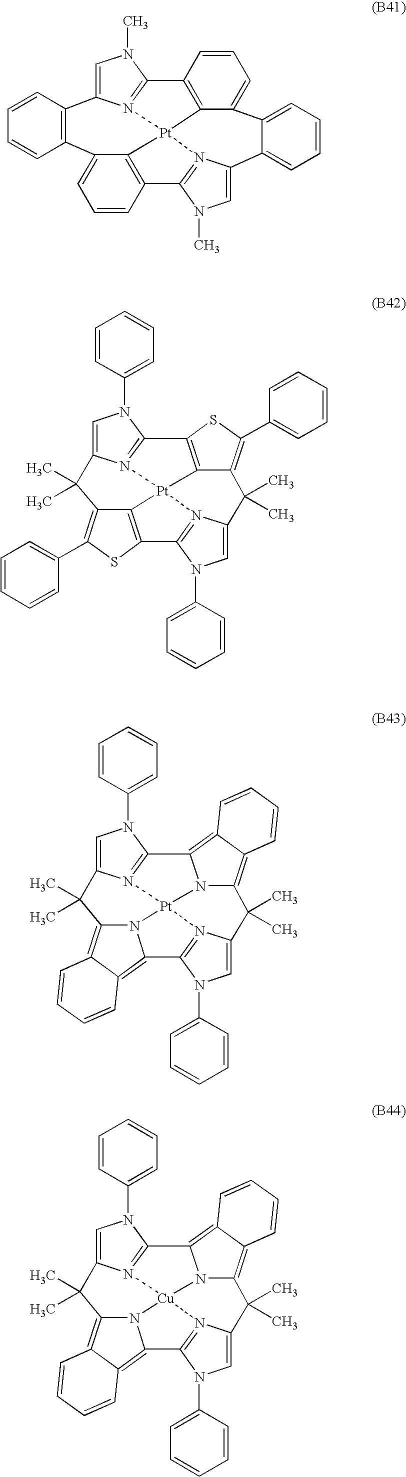

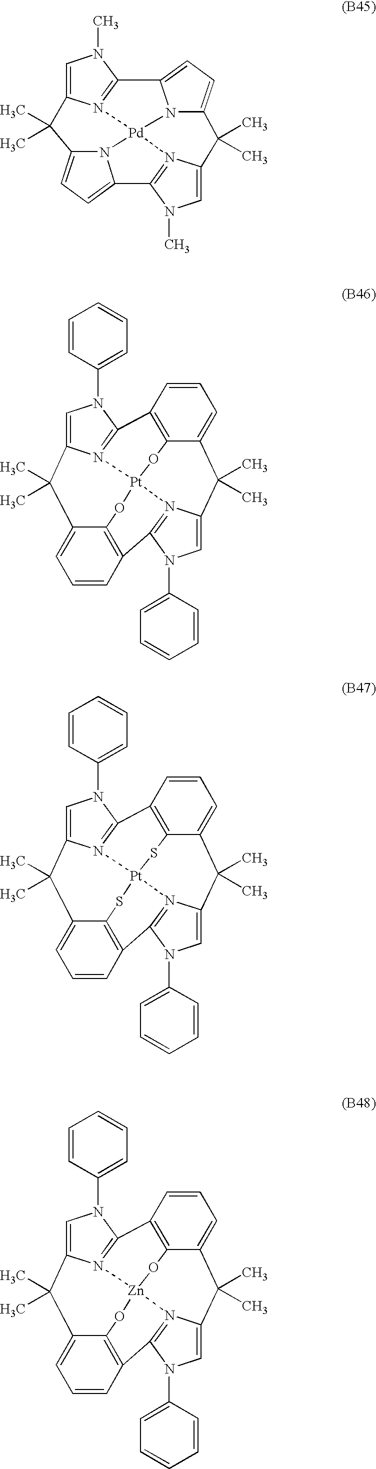

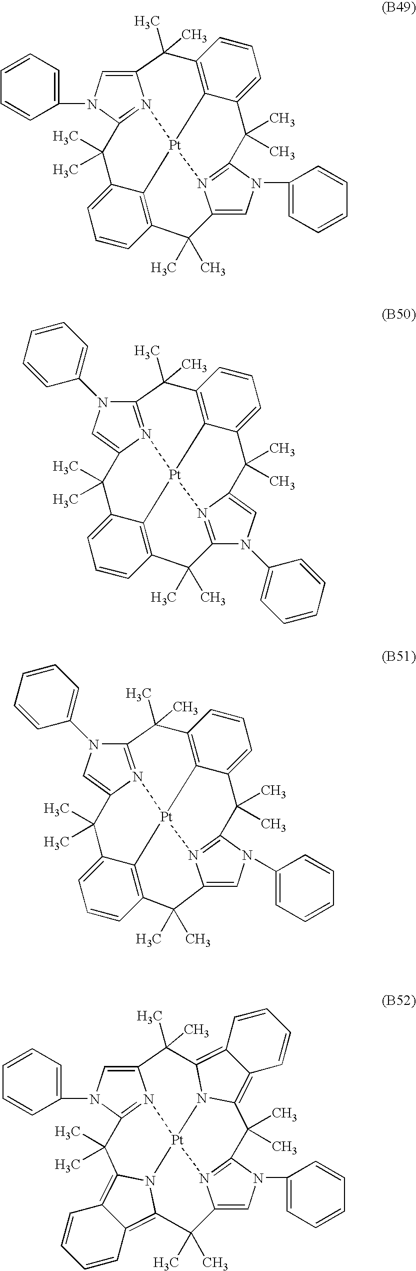

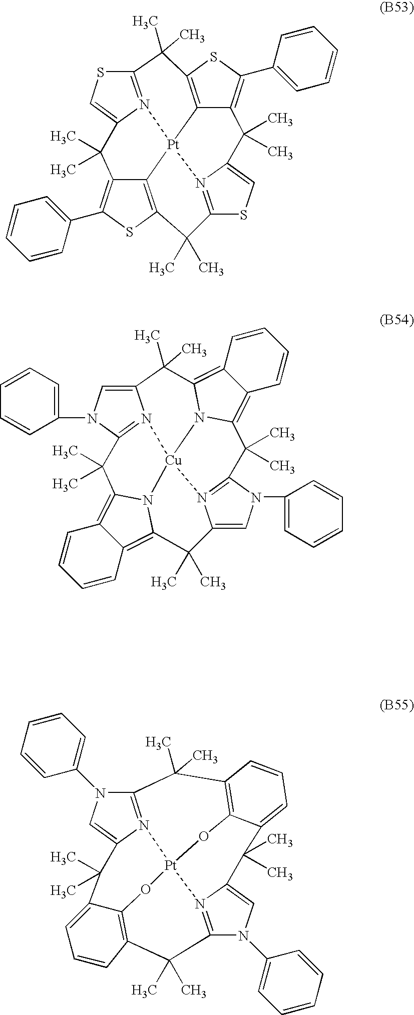

An example of preferable metal complexes usable in the invention is a compound represented by the following formula (C-1):

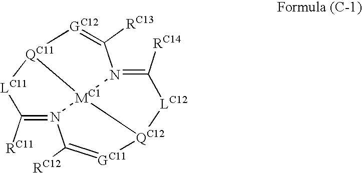

In formula (C-1), M^{C1} represents a metal ion. R^{C11} and R^{C12} each independently represent a hydrogen atom or a substituent. When R^{C11} and R^{C12} represent substituents, the substituents may be bonded to each other to form a 5-membered ring. R^{C13} and R^{C14} each independently represent a hydrogen atom or a substituent. When R^{C13} and R^{C14} represent substituents, the substituents may be bonded to each other to form a 5-membered ring. G^{C11} and G^{C12} each independently represent a nitrogen atom or a substituted or unsubstituted carbon atom. L^{C11} and L^{C12} each independently represent a connecting group. Q^{C11} and Q^{C12} each independently represent a partial structure containing an atom bonded to M^{C1}. The bond between the atom in the partial structure and M^{C1} may be, for example, a covalent bond.

The formula (C-1) will be described in detail.

In formula (C-1), M^{C1}, L^{C11}, L^{C12}, Q^{C11} and Q^{C12} have the same definitions as corresponding M^{A1}, L^{A11}, L^{A12}, Q^{A11} and Q^{A12} in formula (A-1) respectively, and their preferable examples are also the same.

G^{C11} and G^{C12} each independently represent a nitrogen atom or a substituted or unsubstituted carbon atom, preferably a nitrogen atom or an unsubstituted carbon atom, and more preferably a nitrogen atom.

R^{C11} and R^{C12} each independently represent a hydrogen atom or a substituent. R^{C11} and R^{C12} may be bonded to each other to form a 5-membered ring. R^{C13} and R^{C14} each independently represent a hydrogen atom or a substituent. R^{C13} and R^{C14} may be bonded to each other to form a 5-membered ring.

The substituent represented by R^{C11}, R^{C12}, R^{C13} or R^{C14} may be, for example, an alkyl group (preferably having 1 to 30 carbon atoms, more preferably 1 to 20 carbon atoms, particularly preferably 1 to 10 carbon atoms, for example methyl, ethyl, iso-propyl, tert-butyl, n-octyl, n-decyl, n-hexadecyl, cyclopropyl, cyclopentyl, cyclohexyl), an alkenyl group (preferably having 2 to 30 carbon atoms, more preferably 2 to 20 carbon atoms, particularly preferably 2 to 10 carbon atoms, for example vinyl, allyl, 2-butenyl, 3-pentenyl), an alkynyl group (preferably having 2 to 30 carbon atoms, more preferably 2 to 20 carbon atoms, particularly preferably 2 to 10 carbon atoms, for example propargyl, 3-pentynyl), an aryl group (preferably having 6 to 30 carbon atoms, more preferably 6 to 20 carbon atoms, particularly preferably 6 to 12 carbon atoms, for example phenyl, p-methylphenyl, naphthyl, anthranyl), an amino group (preferably a 0 to 30 carbon atoms, more preferably 0 to 20 carbon atoms, particularly preferably 0 to 10 carbon atoms, for example amino, methylamino, dimethylamino, diethylamino, dibenzylamino, diphenylamino, ditolylamino), an alkoxy group (preferably having 1 to 30 carbon atoms, more preferably 1 to 20 carbon atoms, particularly preferably 1 to 10 carbon atoms, for example methoxy, ethoxy, butoxy, 2-ethylhexyloxy), an aryloxy group (preferably a 6 to 30 carbon atoms, more preferably 6 to 20 carbon atoms, particularly preferably 6 to 12 carbon atoms, for example phenyloxy, 1-naphthyloxy, 2-naphthyloxy), a heterocyclic oxy group (preferably having 1 to 30 carbon atoms, more preferably 1 to 20 carbon atoms, particularly preferably 1 to 12 carbon atoms, for example pyridyloxy, pyrazyloxy, pyrimidyloxy, quinolyloxy), an acyl group (preferably having 1 to 30 carbon atoms, more preferably 1 to 20 carbon atoms, particularly preferably 1 to 12 carbon atoms, for example acetyl, benzoyl, formyl, pivaloyl), an alkoxycarbonyl group (preferably a 2 to 30 carbon atoms, more preferably 2 to 20 carbon atoms, particularly preferably 2 to 12 carbon atoms, for example methoxycarbonyl, ethoxycarbonyl), an aryloxycarbonyl group (preferably having 7 to 30 carbon atoms, more preferably 7 to 20 carbon atoms, particularly preferably 7 to 12 carbon atoms, for example phenyloxycarbonyl), an acyloxy group (preferably having 2 to 30 carbon atoms, more preferably 2 to 20 carbon atoms, particularly preferably 2 to 10 carbon atoms, for example acetoxy, benzoyloxy), an acylamino group (preferably having 2 to 30 carbon atoms, more preferably 2 to 20 carbon atoms, particularly preferably 2 to 10 carbon atoms, for example acetylamino, benzoylamino), an alkoxycarbonylamino group (preferably having 2 to 30 carbon atoms, more preferably 2 to 20 carbon atoms, particularly preferably 2 to 12 carbon atoms, for example methoxycarbonylamino), an aryloxycarbonylamino group (preferably having 7 to 30 carbon atoms, more preferably 7 to 20 carbon atoms, particularly preferably 7 to 12 carbon atoms, for example phenyloxycarbonylamino), an alkylthio group (preferably having 1 to 30 carbon atoms, more preferably 1 to 20 carbon atoms, particularly preferably 1 to 12 carbon atoms, for example methylthio, ethylthio), an arylthio group (preferably having 6 to 30 carbon atoms, more preferably 6 to 20 carbon atoms, particularly preferably 6 to 12 carbon atoms, for example phenylthio), a heterocyclic thio group (preferably having 1 to 30 carbon atoms, more preferably 1 to 20 carbon atoms, particularly preferably 1 to 12 carbon atoms, for example pyridylthio, 2-benzimidazolylthio, 2-benzoxazolylthio, 2-benzthiazolylthio), a halogen atom (for example a fluorine atom, chlorine atom, bromine atom, and iodine atom), a cyano group, a heterocyclic group (preferably having 1 to 30 carbon atoms, more preferably 1 to 20 carbon atoms, particularly preferably 1 to 12 carbon atoms containing a heteroatom such as a nitrogen atom, oxygen atom and sulfur atom, specifically imidazolyl, pyridyl, quinolyl, furyl, thienyl, piperidyl, morpholino, benzoxazolyl, benzimidazolyl, benzthiazolyl, carbazolyl group, azepinyl group), a silyl group (preferably having 3 to 40 carbon atoms, more preferably 3 to 30 carbon atoms, particularly preferably 3 to 24 carbon atoms, for example trimethylsilyl, triphenylsilyl) or a silyloxy group (preferably having 3 to 40 carbon atoms, more preferably 3 to 30 carbon atoms, particularly preferably 3 to 24 carbon atoms, for example trimethylsilyloxy, triphenylsilyloxy).

The substituent represented by R^{C11}, R^{C12}, R^{C13} or R^{C14} is preferably an alkyl group, an aryl group, or such a group that R^{C11} and R^{C12}, or R^{C13} and R^{C14}, are bonded to each other to form a 5-membered ring. In a particularly preferable embodiment, R^{C11} and R^{C12}, or R^{C13} and R^{C14}, are bonded to each other to form a 5-membered ring.

The compound represented by the formula (C-1) is more preferably a compound represented by formula (C-2):

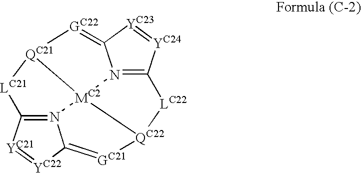

In formula (C-2), M^{C2} represents a metal ion.

Y^{C21}, Y^{C22}, Y^{C23} and Y^{C24} each independently represent a nitrogen atom or a substituted or unsubstituted carbon atom. G^{C21} and G^{C22} each independently represent a nitrogen atom or a substituted or unsubstituted carbon atom. L^{C21} and L^{C22} each independently represent a connecting group. Q^{C21} and Q^{C22} each independently represent a partial structure containing an atom bonded to M^{C2}. The bond between the atom in the partial structure and M^{C2} may be, for example, a covalent bond.

The formula (C-2) will be described in detail.

In formula (C-2), M^{C2}, L^{C21}, L^{C22}, Q^{C21}, Q^{C22}, G^{C21} and G^{C22} have the same definitions as corresponding M^{C1}, L^{C11}, L^{C12}, Q^{C11}, Q^{C12}, G^{C11} and G^{C12} in formula (C-1) respectively, and their preferable examples are also the same.

Y^{C21}, Y^{C22}, Y^{C23} and Y^{C24} each independently represent a nitrogen atom or a substituted or unsubstituted carbon atom, preferably a substituted or unsubstituted carbon atom, and more preferably an unsubstituted carbon atom.

The compound represented by formula (C-2) is more preferably a compound represented by the following formula (C-3), (C-4) or (C-5).

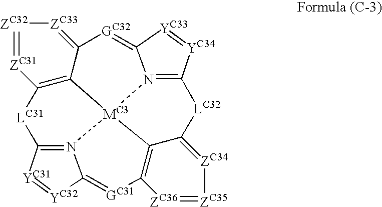

In formula (C-3), M^{C3} represents a metal ion.

Y^{C31}, Y^{C32}, Y^{C33} and Y^{C34} each independently represent a nitrogen atom or a substituted or unsubstituted carbon atom. G^{C31} and G^{C32} each independently represent a nitrogen atom or a substituted or unsubstituted carbon atom. L^{C31} and L^{C32} each independently represent a connecting group. Z^{C31}, Z^{C32}, Z^{C33}, Z³⁴, Z^{C35} and Z³⁶ each independently represent a nitrogen atom or a substituted or unsubstituted carbon atom.

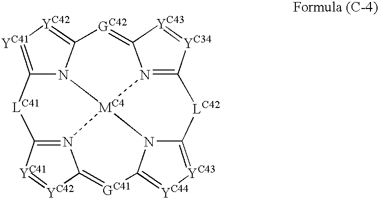

In formula (C-4), M^{C4} represents a metal ion.

Y^{C41}, Y^{C42}, Y^{C43} and Y^{C44} each independently represent a nitrogen atom or a substituted or unsubstituted carbon atom. G^{C41} and G^{C42} each independently represent a nitrogen atom or a substituted or unsubstituted carbon atom. L^{C41} and L^{C42} each independently represent a connecting group. Z^{C41}, Z^{C42}, Z^{C43} and Z^{C44} each independently represent a nitrogen atom or a substituted or unsubstituted carbon atom.

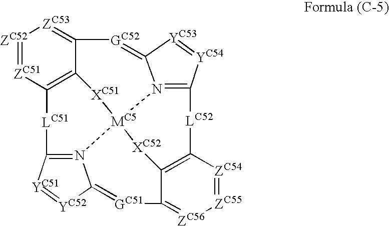

In formula (C-5), M^{C5} represents a metal ion.

Y^{C51}, Y^{C52}, Y^{C53} and Y^{C54} each independently represent a nitrogen atom or a substituted or unsubstituted carbon atom. G^{C51} and G^{C52} each independently represent a nitrogen atom or a substituted or unsubstituted carbon atom. L^{C51} and L^{C52} each independently represent a connecting group. Z^{C51}, Z^{C52}, Z^{C53}, Z^{C54}, Z^{C55} and Z^{C56} each independently represent a nitrogen atom or a substituted or unsubstituted carbon atom. X^{C51} and X^{C52} each independently represent an oxygen atom, a sulfur atom or a substituted or unsubstituted nitrogen atom.

The compound represented by the formula (C-3) will be described in detail.

In formula (C-3), M^{C3}, L^{C31}, L^{C32}, G^{C31} and G^{C32} have the same definitions as corresponding M^{C1}, L^{C11}, L^{C12}, G^{C11} and G^{C12} in formula (C-1) respectively, and their preferable examples are also the same.

Z^{C31}, Z^{C32}, Z^{C33}, Z^{C34}, Z^{C35} and Z^{C36} each independently represent a nitrogen atom or a substituted or unsubstituted carbon atom. Each of Z^{C31}, Z^{C32}, Z^{C33}, Z^{C34}, Z^{C35} and Z^{C36} is preferably a substituted or unsubstituted carbon atom, and more preferably an unsubstituted carbon atom.

The compound represented by the formula (C-4) will be described in more detail.

In formula (C-4), M^{C4}, L^{C41}, L^{C42}, G^{C41} and G^{C42} have the same definitions as corresponding M^{C1}, L^{C11}, L^{C12}, G^{C11} and G^{C12} in formula (C-1) respectively, and their preferable examples are also the same.

Z^{C41}, Z^{C42}, Z^{C43}, and Z^{C44} each independently represent a nitrogen atom or a substituted or unsubstituted carbon atom. Each of Z^{C41}, Z^{C42}, Z^{C43} and Z^{C44} is preferably a substituted or unsubstituted carbon atom, and more preferably an unsubstituted carbon atom.

The compound represented by the formula (C-5) will be described in more detail.

M^{C5}, L^{C5}, L^{C52}, G^{C51} and G^{C52} have the same definitions as corresponding M^{C1}, L^{C11}, L^{C12}, G^{C11} and G^{C12} in formula (C-1) respectively, and their preferable examples are also the same.

Z^{C51}, Z^{C52}, Z^{C53}, Z^{C54}, Z^{C55} and Z^{C56} each independently represent a nitrogen atom or a substituted or unsubstituted carbon atom. Each of Z^{C51}, Z^{C52}, Z^{C53}, Z^{C54}, Z^{C55} and Z^{C56} is preferably a substituted or unsubstituted carbon atom, and more preferably an unsubstituted carbon atom.

X^{C51} and X^{C52} each independently represent an oxygen atom, a sulfur atom or a substituted or unsubstituted nitrogen atom. Each of X^{C5} and X^{C52} is preferably an oxygen atom or a sulfur atom, and more preferably an oxygen atom.

Specific examples of the compounds represented by the formula (C-1) are illustrated below, but the invention is not limited thereto.

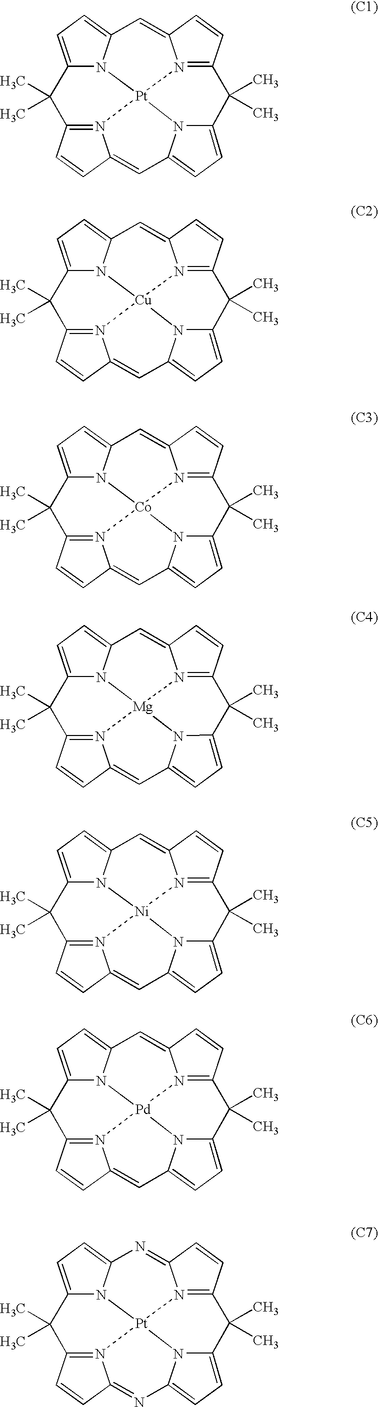

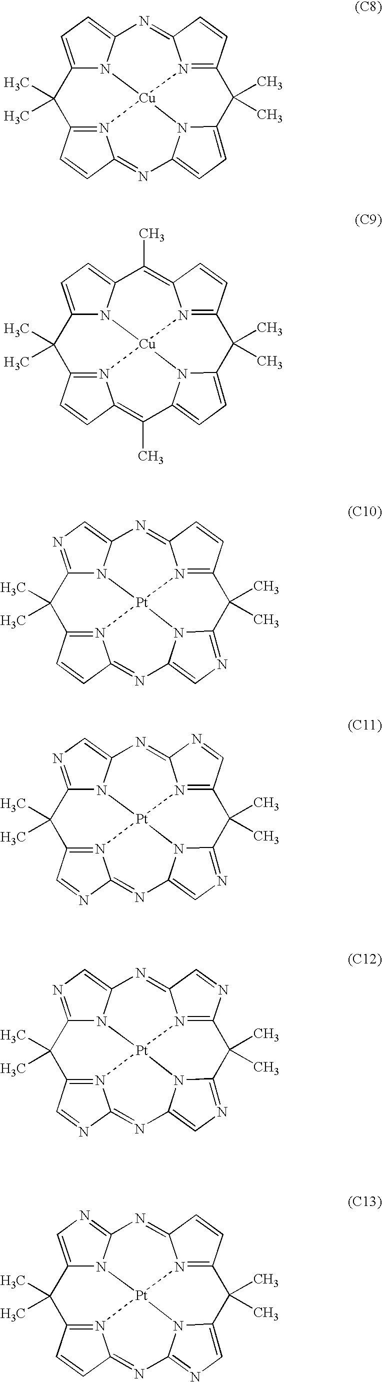

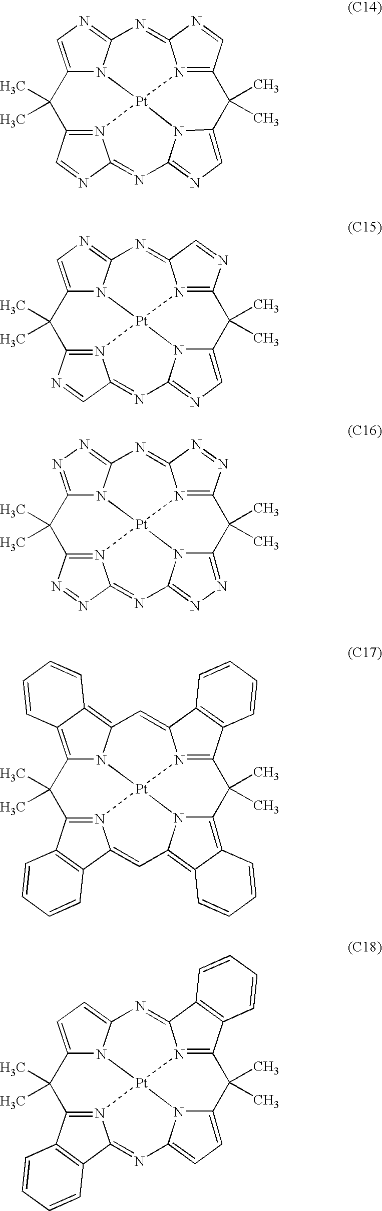

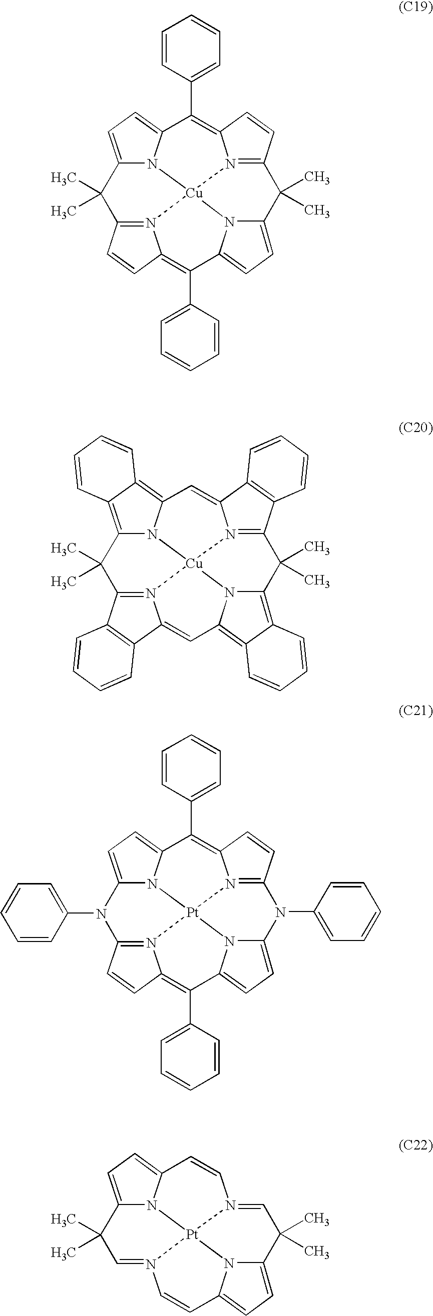

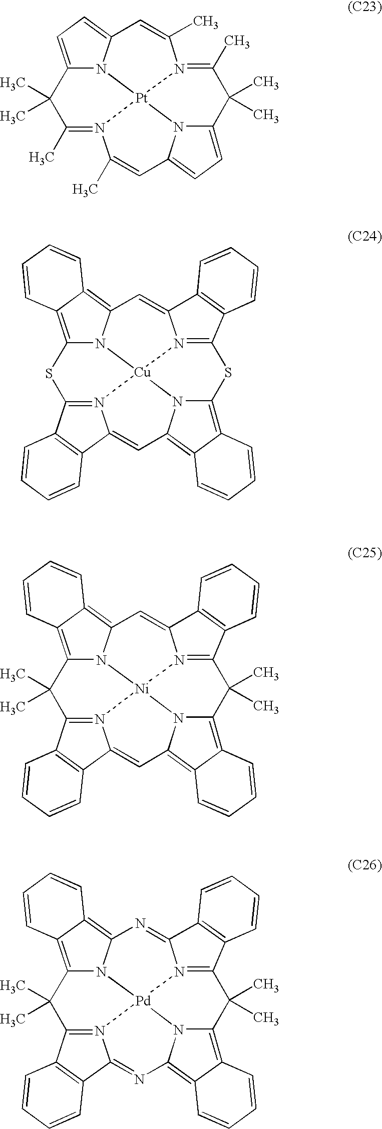

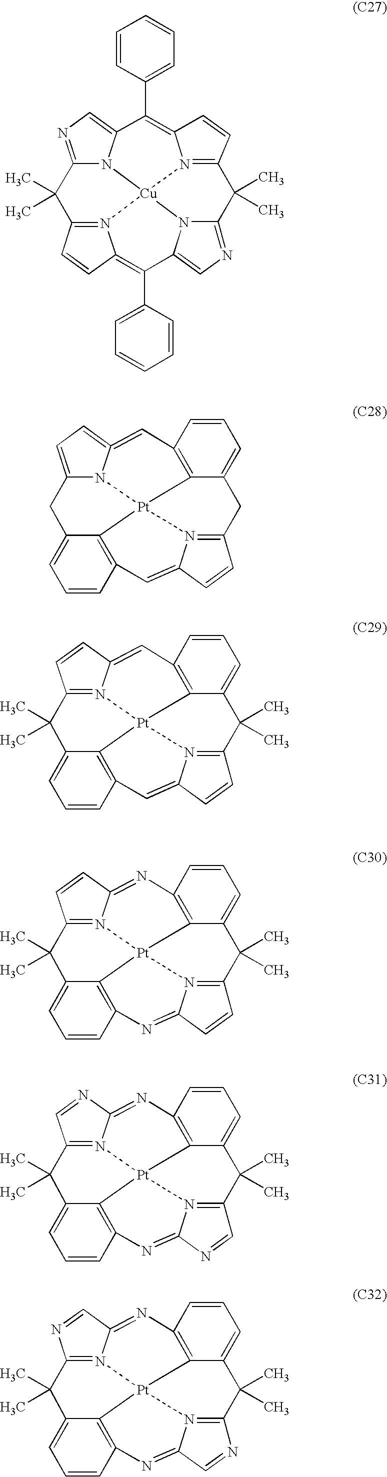

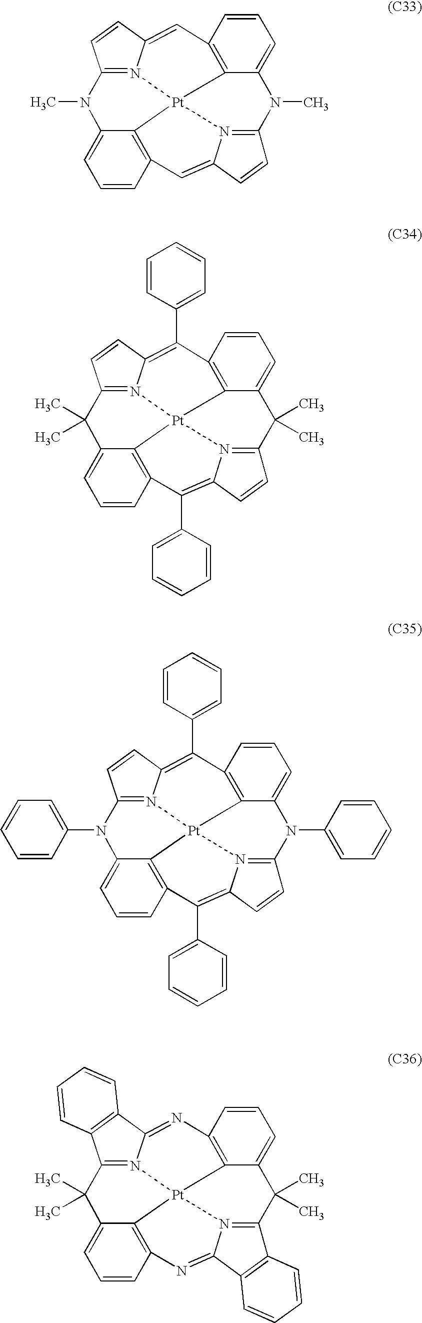

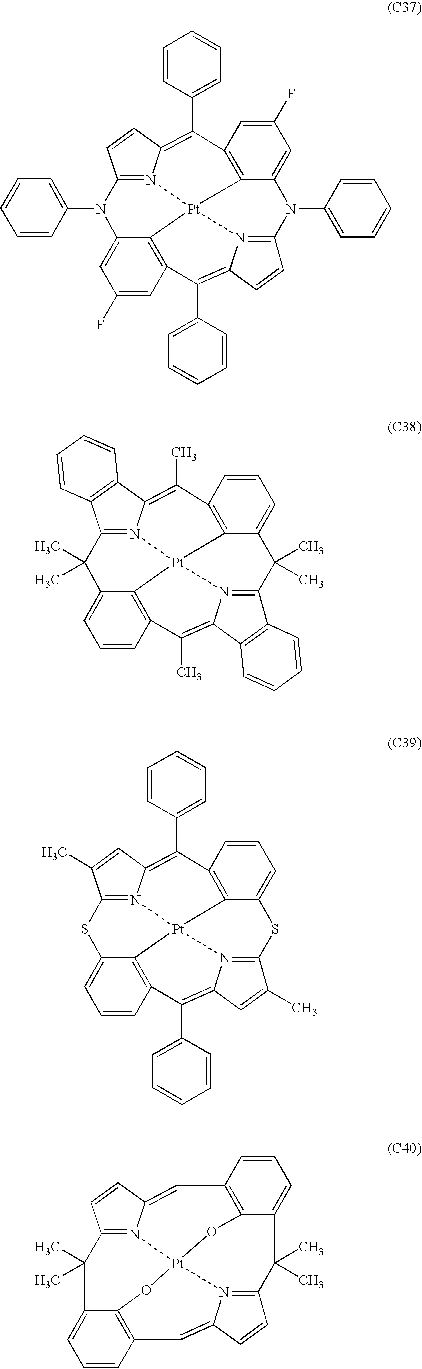

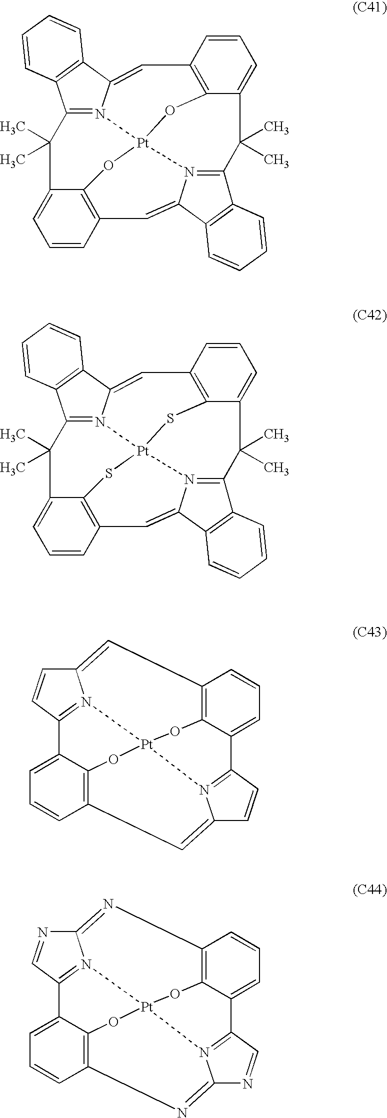

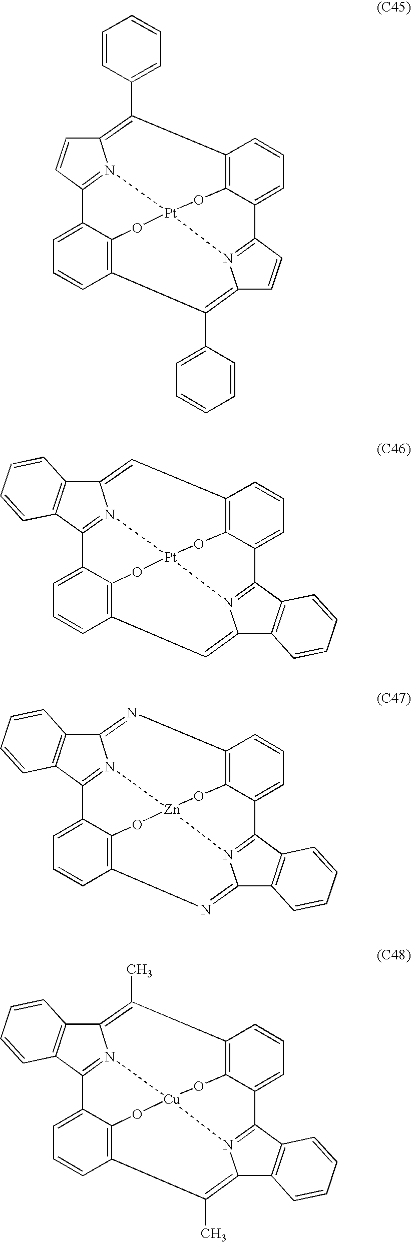

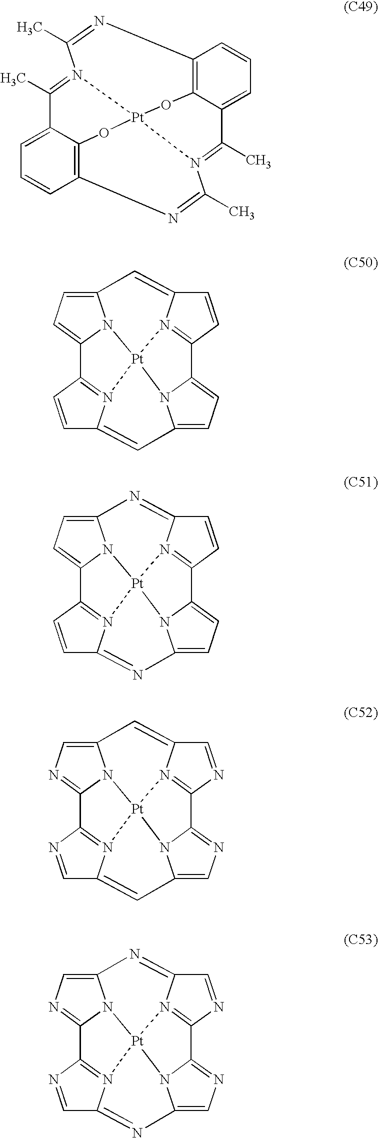

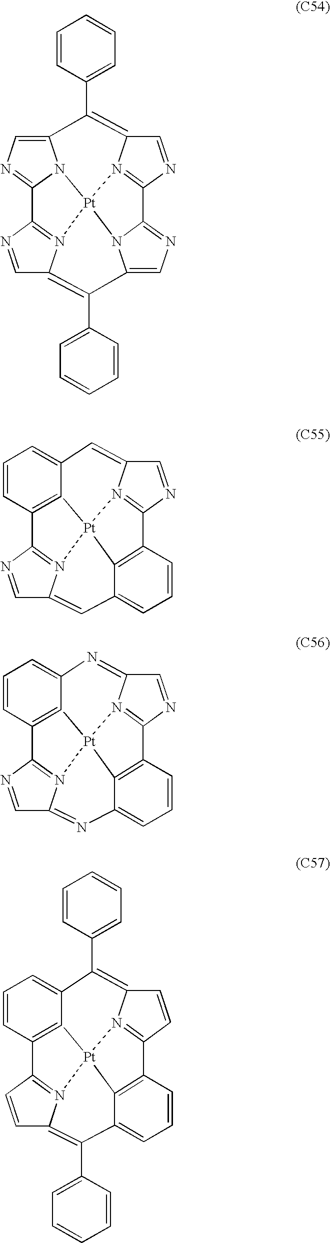

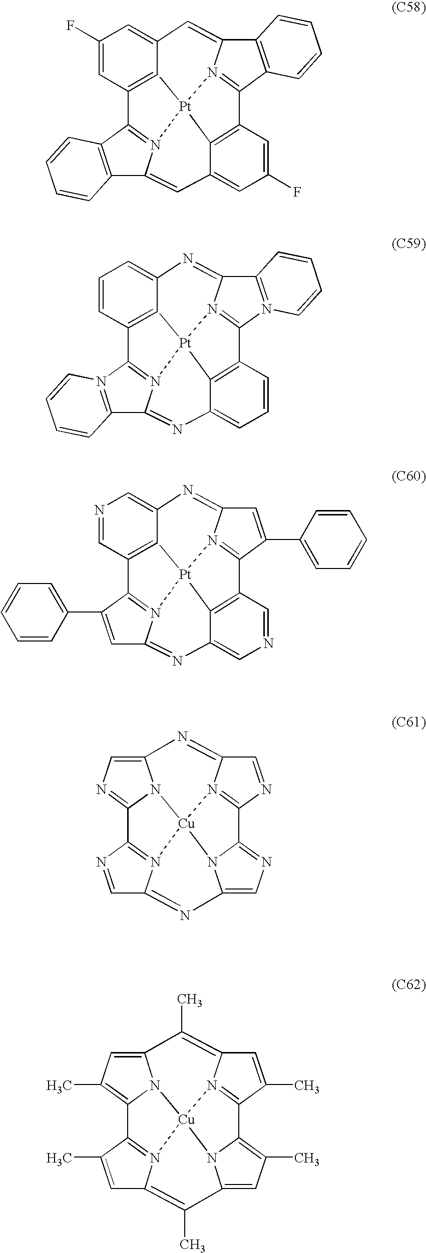

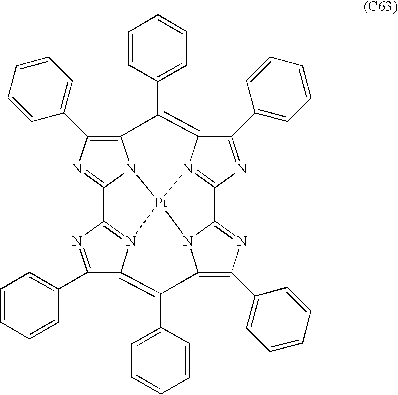

An example of preferable metal complexes usable in the invention is a compound represented by the following formula (D-1):

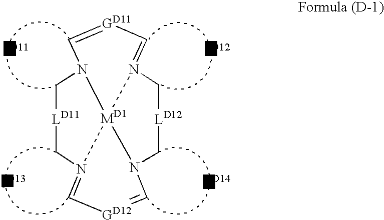

In formula (D-1), M^{D1} represents a metal ion.

G^{D11} and GD¹² each independently represent a nitrogen atom or a substituted or unsubstituted carbon atom. J^{D11}, J^{D12}, J^{D13} and J^{D14} each independently represent an atomic group necessary for forming a 5-membered ring. L^{D11} and L^{D12} each independently represent a connecting group.

The formula (D-1) will be described in detail.

In formula (D-1), M^{D1}, L^{D11} and L^{D12} have the same definitions as corresponding M^{A1}, L^{A11} and L^{A12} in formula (A-1) respectively, and their preferable examples are also the same.

G^{D11} and G^{D12} have the same definitions as corresponding G^{C11} and G^{C12} in formula (C-1) respectively, and their preferable examples are also the same.

J^{D11}, J^{D12}, J^{D13} and J^{D14} each independently represent such an atomic group that a nitrogen-containing 5-membered heterocyclic ring containing the atomic group is formed.

The compound represented by the formula (D-1) is more preferably a compound represented by the following formula (D-2), (D-3) or (D-4).

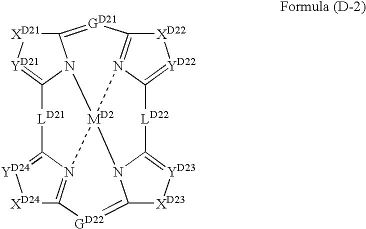

In formula (D-2), M^{D2} represents a metal ion.

G^{D21} and G^{D22} each independently represent a nitrogen atom or a substituted or unsubstituted carbon atom.

Y^{D21}, Y^{D22}, Y^{D23} and Y^{D24} each independently represent a nitrogen atom or a substituted or unsubstituted carbon atom.

X^{D21}, X^{D22}, X^{D23} and X^{D24} each independently represent an oxygen atom, a sulfur atom, —NR^{D21}— or —C(R^{D22})R^{D23}—.

R^{D21}, R^{D22} and R^{D23} each independently represent a hydrogen atom or a substituent. L^{D21} and L^{D22} each independently represent a connecting group.

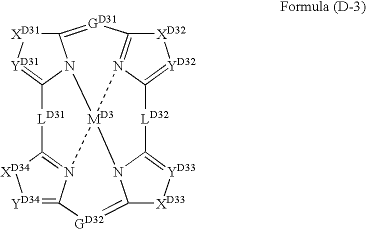

In formula (D-3), M^{D3} represents a metal ion.

G^{D31} and G^{D32} each independently represent a nitrogen atom or a substituted or unsubstituted carbon atom.

Y^{D31}, Y^{D32}, Y^{D33} and Y^{D34} each independently represent a nitrogen atom or a substituted or unsubstituted carbon atom.

X^{D31}, X^{D32}, X^{D33} and X^{D34} each independently represent an oxygen atom, a sulfur atom, —NR^{D31}— or —C(R^{D32})R^{D33}—.

R^{D31}, R^{D32} and R^{D33} each independently represent a hydrogen atom or a substituent. L^{D31} and L^{D32} each independently represent a connecting group.

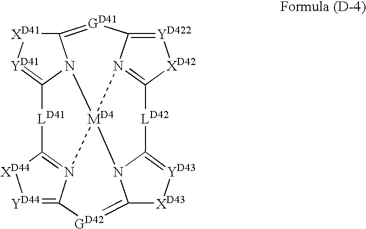

In formula (D-4), M^{D4} represents a metal ion.

G^{D41} and G^{D42} each independently represent a nitrogen atom or a substituted or unsubstituted carbon atom.

Y^{D41}, Y^{D42}, Y^{D43} and Y^{D44} each independently represent a nitrogen atom or a substituted or unsubstituted carbon atom.

X^{D41}, X^{D42}, X^{D43} and X^{D44} each independently represent an oxygen atom, a sulfur atom, —NR^{D41}— or —C(R^{D42})R^{D43}—.R^{D41}, R^{D42} and R^{D43} each independently represent a hydrogen atom or a substituent. L^{D41} and L^{D42} each independently represent a connecting group.

The formula (D-2) will be described in detail.

In formula (D-2), M^{D2}, L^{D21}, L^{D22}, G^{D21} and G^{D22} have the same definitions as corresponding M^{D1}, L^{D11}, L^{D12}, G^{D11} and G^{D12} in formula (D-1) respectively, and their preferable examples are also the same.

Y^{D21}, Y^{D22}, Y^{D23} and Y^{D24} each independently represent a nitrogen atom or a substituted or unsubstituted carbon atom, preferably a substituted or unsubstituted carbon atom, and more preferably an unsubstituted carbon atom.

X^{D21}, X^{D22}, X^{D23} and X^{D24} each independently represent an oxygen atom, a sulfur atom, —NR^{D21}— or —C(R^{D22})R^{D23}—, preferably a sulfur atom, —NR^{D21}— or —C(R^{D22})R^{D23} —, more preferably —NR^{D21}— or —C(R^{D22})R^{D23}—, and further more preferably —NR^{D21}—.

R^{D21}, R^{D22} and R^{D23} each independently represent a hydrogen atom or a substituent. The substituent represented by R^{D21}, R^{D22} or R^{D23} may be, for example, an alkyl group (preferably having 1 to 20 carbon atoms, more preferably 1 to 12 carbon atoms, particularly preferably 1 to 8 carbon atoms, for example methyl, ethyl, iso-propyl, tert-butyl, n-octyl, n-decyl, n-hexadecyl, cyclopropyl, cyclopentyl, cyclohexyl), an alkenyl group (preferably having 2 to 20 carbon atoms, more preferably 2 to 12 carbon atoms, particularly preferably 2 to 8 carbon atoms, for example vinyl, allyl, 2-butenyl, 3-pentenyl), an alkynyl group (preferably having 2 to 20 carbon atoms, more preferably 2 to 12 carbon atoms, particularly preferably 2 to 8 carbon atoms, for example propargyl, 3-pentynyl), an aryl group (preferably having 6 to 30 carbon atoms, more preferably 6 to 20 carbon atoms, particularly preferably 6 to 12 carbon atoms, for example phenyl, p-methylphenyl, naphthyl), a substituted carbonyl group (preferably haviang 1 to 20 carbon atoms, more preferably 1 to 16 carbon atoms, particularly preferably 1 to 12 carbon atoms, for example acetyl, benzoyl, methoxycarbonyl, phenyloxycarbonyl, dimethylaminocarbonyl, phenylaminocarbonyl), a substituted sulfonyl group (preferably having 1 to 20 carbon atoms, more preferably 1 to 16 carbon atoms, particularly preferably 1 to 12 carbon atoms, for example mesyl, tosyl), or a heterocyclic group (including an aliphatic heterocyclic group and aromatic heterocyclic group, preferably having 1 to 50 carbon atoms, more preferably 1 to 30 carbon atoms, more preferably 2 to 12 carbon atoms, preferably containing an oxygen atom, a sulfur atom or a nitrogen atom, for example imidazolyl, pyridyl, furyl, piperidyl, morpholino, benzoxazolyl, triazolyl groups). Each of R^{D21}, R^{D22} and R^{D23} is preferably an alkyl group, aryl group or aromatic heterocyclic group, more preferably an alkyl or aryl group, and still more preferably an aryl group.

The formula (D-3) will be described in detail.

In formula (D-3), M^{D3}, L^{D31}, L^{D32}, G^{D31} and G^{D32} have the same definitions as corresponding M^{D1}, L^{D11}, L^{D12}, G^{D11} and G^{D12} in formula (D-1) respectively, and their preferable examples are also the same.

X^{D31}, X^{D32}, X^{D33} and X^{D34} have the same definitions as corresponding X^{D21}, X^{D22}, X^{D23} and X^{D24} in formula (D-2) respectively, and their preferable examples are also the same.

Y^{D31}, Y^{D32}, Y^{D33} and Y^{D34} have the same definitions as corresponding Y^{D21}, Y^{D22}, Y^{D23} and Y^{D24} in formula (D-2) respectively, and their preferable examples are also the same.

The formula (D-4) will be described in detail.

In formula (D-4), M^{D4}, L^{D41}, L^{D42}, G^{D41} and G^{D42} have the same definitions as corresponding M^{D1}, L^{D11}, L^{D12}, G^{D11} and G^{D12} in formula (D-1) respectively, and their preferable examples are also the same.

X^{D41}, X^{D42} , X^{D43} and X^{D44} have the same definitions as corresponding X^{D21}, X^{D22}, X^{D23} and X^{D24} in formula (D-2) respectively, and their preferable examples are also the same. Y^{D41}, Y^{D42}, Y^{D43} and Y^{D44} have the same definitions as corresponding Y^{D21}, Y^{D22}, Y^{D23} and Y^{D24} in formula (D-2) respectively, and their preferable examples are also the same.

Specific examples of the compounds represented by the formula (D-1) are illustrated below, but the invention is not limited thereto.

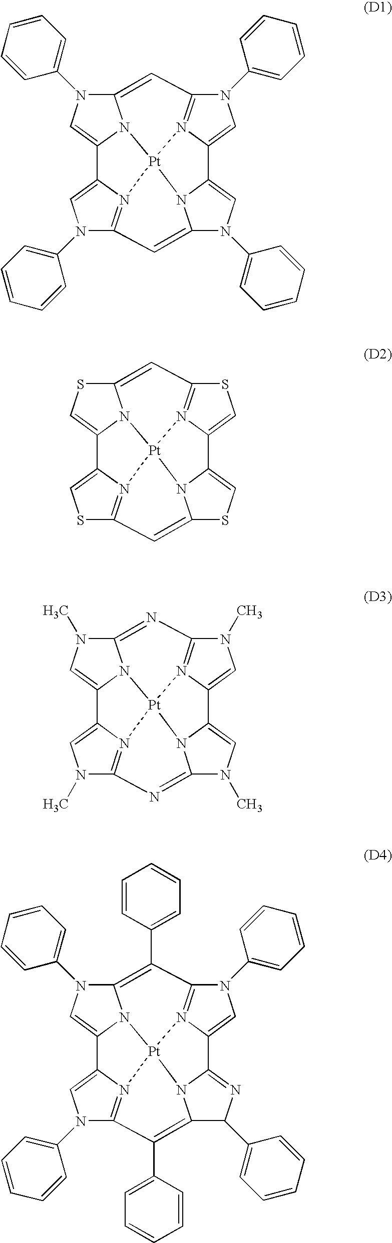

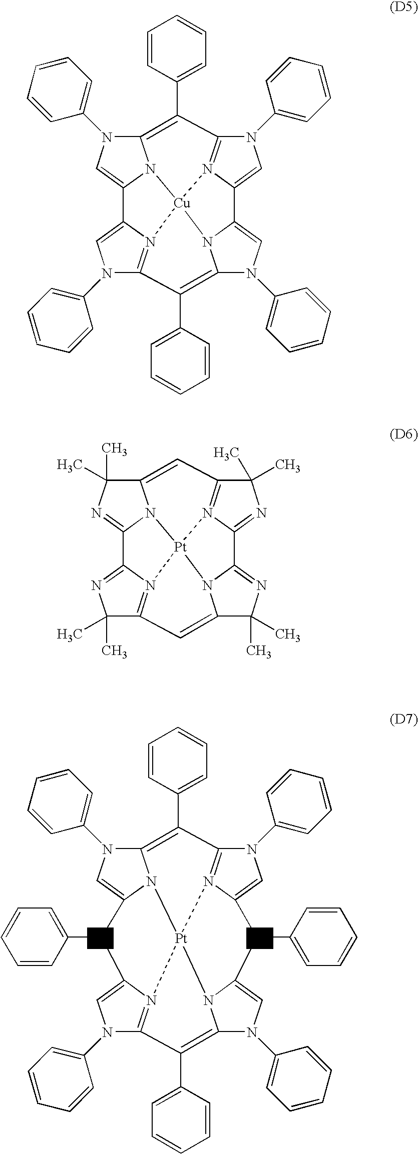

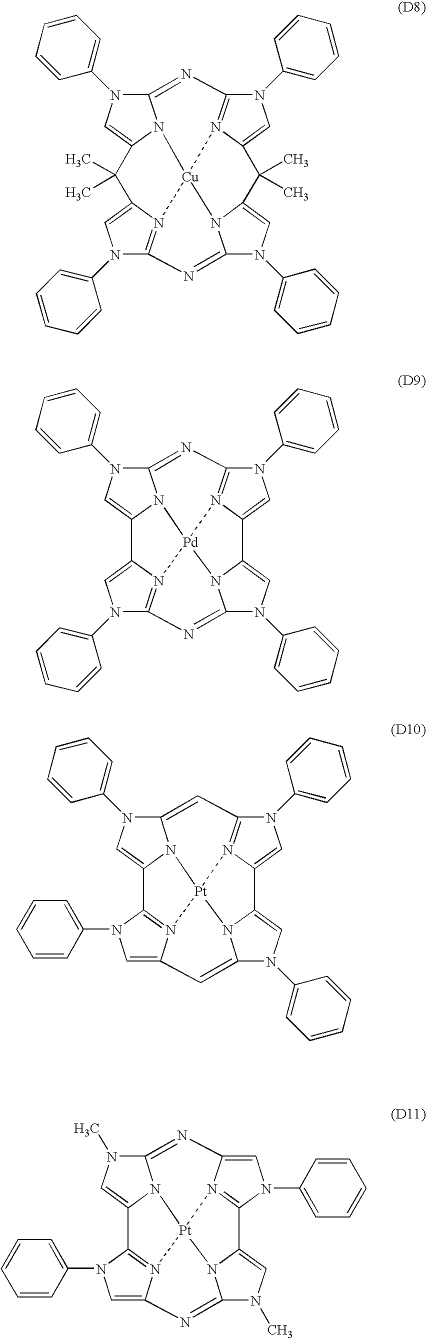

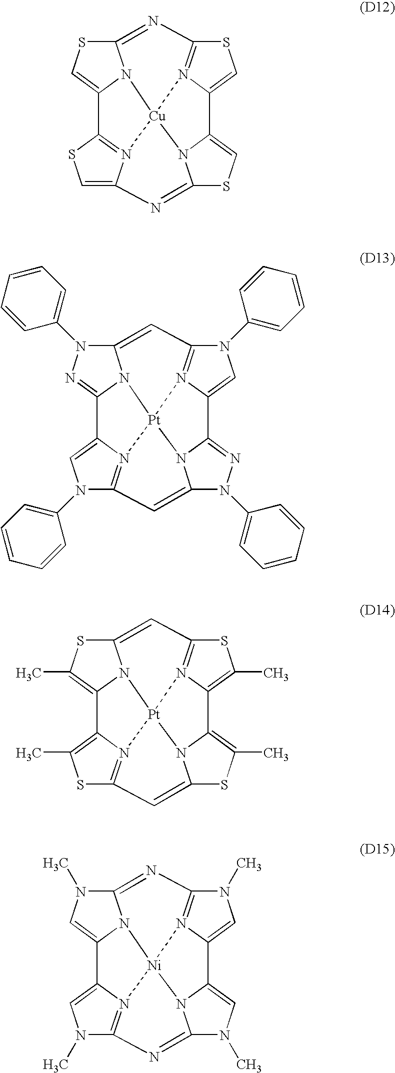

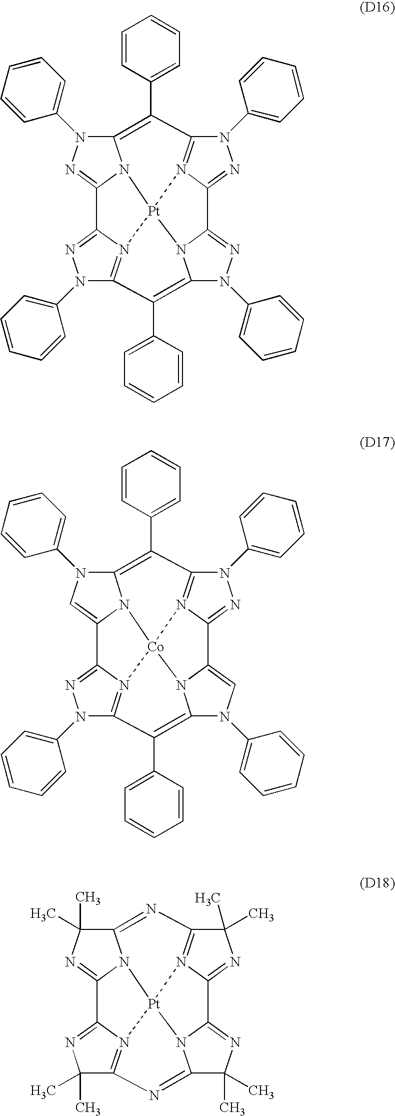

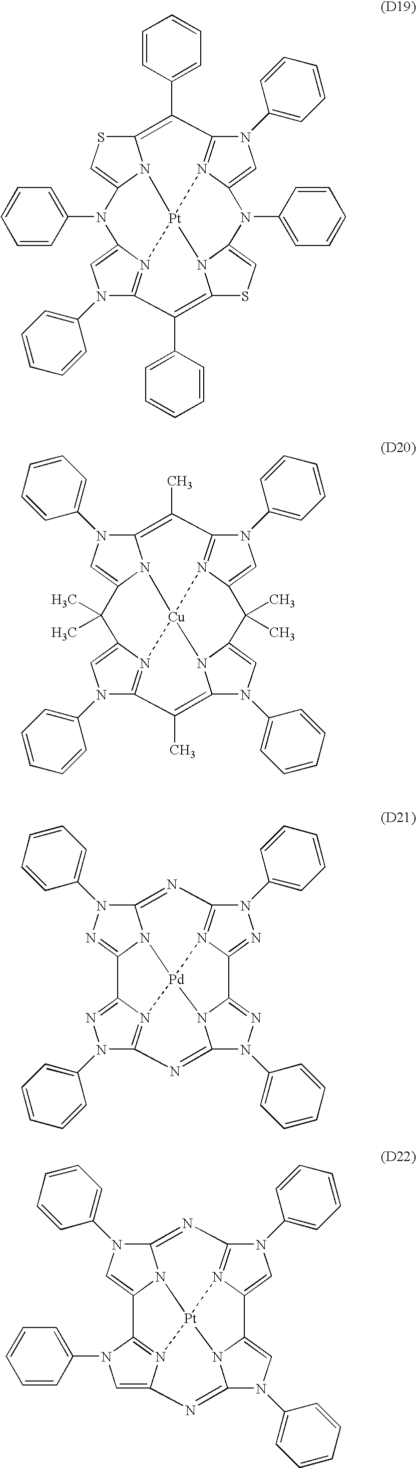

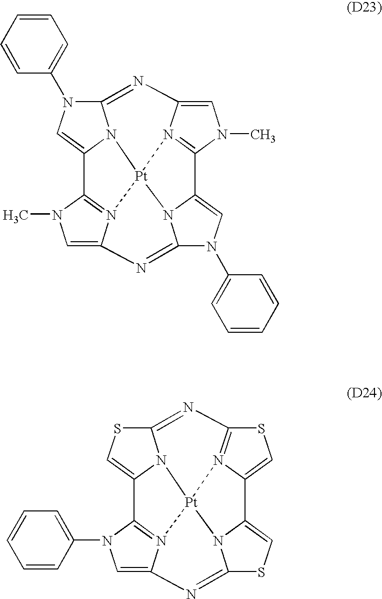

An example of preferable metal complexes usable in the invention is a compound represented by the following formula (E-1):

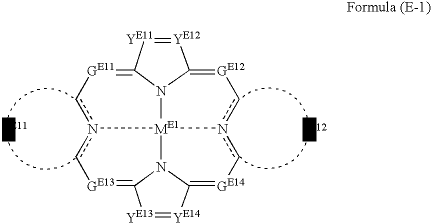

In formula (E-1), M^{E1} represents a metal ion. J^{E11} and J^{E12} each independently represent an atomic group necessary for forming a 5-membered ring. G^{E11}, G^{E12}, G^{E13} and G^{E14} each independently represent a nitrogen atom or a substituted or unsubstituted carbon atom. Y^{E11}, Y^{E12}, Y^{E13} and Y^{E14} each independently represent a nitrogen atom or a substituted or unsubstituted carbon atom.

The formula (E-1) will be described in detail.

In the formula (E-1), M^{E1} has the same definition as M^{A1} in formula (A-1), and its preferable examples are also the same. G^{E11}, G^{E12}, G^{E13} and G^{E14} have the same definitions as G^{C11} and G^{C12} in formula (C-1), and their preferable examples are also the same.

J^{E11} and J^{E12} have the same definitions as J^{D11} to J^{D14} in formula (D-1), and their preferable examples are also the same. Y^{E11}, Y^{E12}, H^{E13}, Y^{E14} have the same definitions as corresponding Y^{C21} to Y^{C24} in formula (C-2) respectively, and their preferable examples are also the same.

The compound represented by the formula (E-1) is more preferably a compound represented by the following formula (E-2) or (E-3).

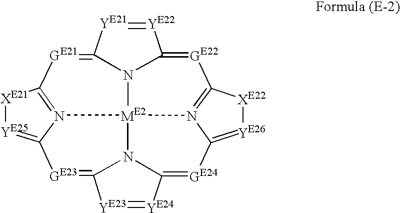

In formula (E-2), M^{E2} represents a metal ion. G^{E21}, G^{E22}, G^{E23} and G^{E24} each independently represent a nitrogen atom or a substituted or unsubstituted carbon atom. Y^{E21}, Y^{E22}, Y^{E23}, Y^{E24}, Y^{E25} and Y^{E26} each independently represent a nitrogen atom or a substituted or unsubstituted carbon atom.

X^{E21} and X^{E22} each independently represent an oxygen atom, a sulfur atom, —NR^{E21}— or —C(R^{E22})R^{E23}—.R^{E21}, R^{E22} and R^{E23} each independently represent a hydrogen atom or a substituent.

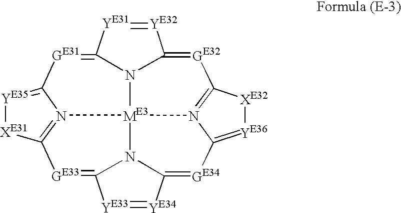

In formula (E-3), M^{E3} represents a metal ion. G^{E31}, G^{E32}, G^{E33} and G^{E34} each independently represent a nitrogen atom or a substituted or unsubstituted carbon atom. Y^{E31}, Y^{E32}, Y^{E33}, Y^{E34}, Y^{E35} and Y^{E36} each independently represent a nitrogen atom or a substituted or unsubstituted carbon atom. X^{E31} and X^{E32} each independently represent an oxygen atom, a sulfur atom, —NR^{E31}— or —C(R^{E32})R^{E33}—.R^{E31}, R^{E32} and R^{E33} each independently represent a hydrogen atom or a substituent.

The formula (E-2) will be described in detail.

In formula (E-2), M^{E2}, G^{E21}, G^{E22}, G^{E23}, G^{E24}, Y^{E21}, Y^{E22}, Y^{E23} and Y^{E24} have the same definitions as corresponding M^{E1}, G^{E11}, G^{E12}, G^{E13}, G^{E14}, Y^{E11}, Y^{E12}, Y¹³ and Y^{E14} in formula (E-1) respectively, and their preferable examples are also the same. X^{E21} and X^{E22} have the same definitions corresponding X^{D21} and X^{D22} in formula (D-2) respectively, and their preferable examples are also the same.

The formula (E-3) will be described in detail.

In formula (E-3), M^{E3}, G^{E31}, G^{E32}, G^{E33}, G^{E34}, Y^{E31}, Y^{E32}, Y^{E33} and Y^{E34} have the same definitions as corresponding M^{E1}, G^{E11}, G^{E12}, G^{E13}, G^{E14}, Y^{E11}, Y^{E12}, Y^{E13} and Y^{E14} in formula (E-1) respectively, and their preferable examples are also the same. X^{E31} and X^{E32} have the same definitions as corresponding X^{E21} and X^{E22} in formula (E-2) respectively, and their preferable examples are also the same.

Specific examples of the compounds represented by the formula (E-1) are illustrated below, but the invention is not limited thereto.

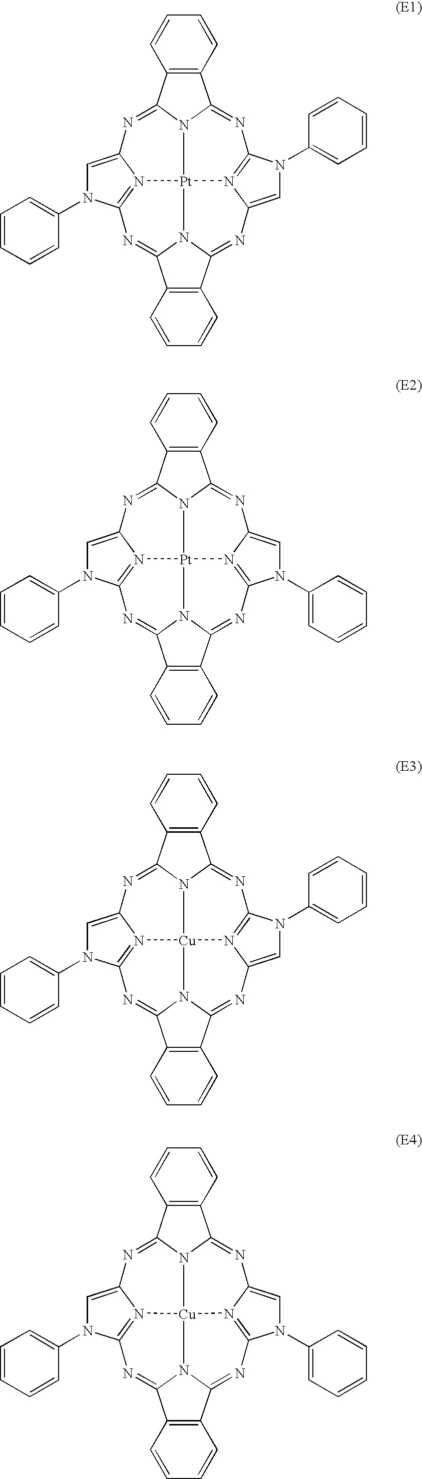

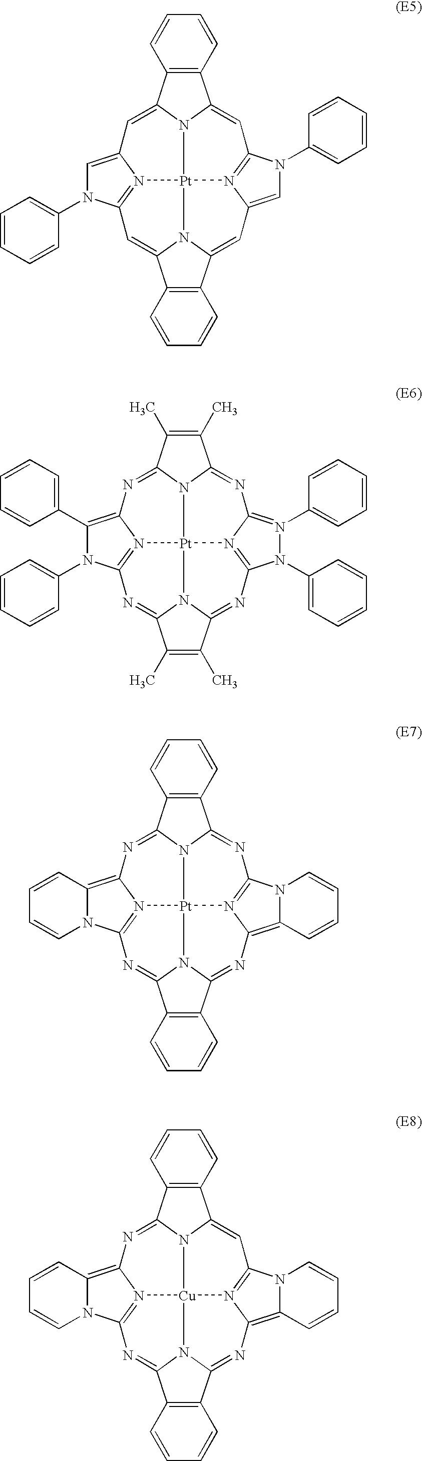

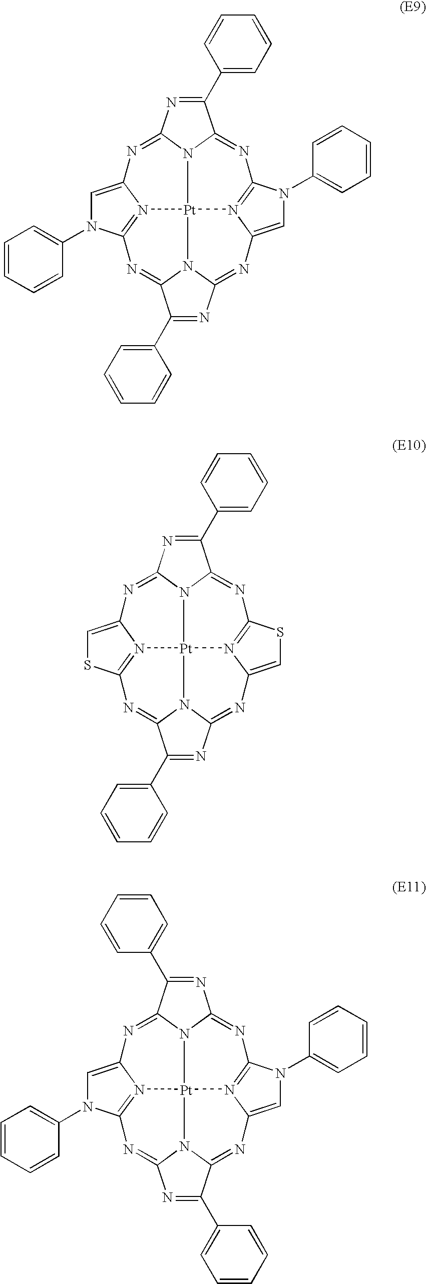

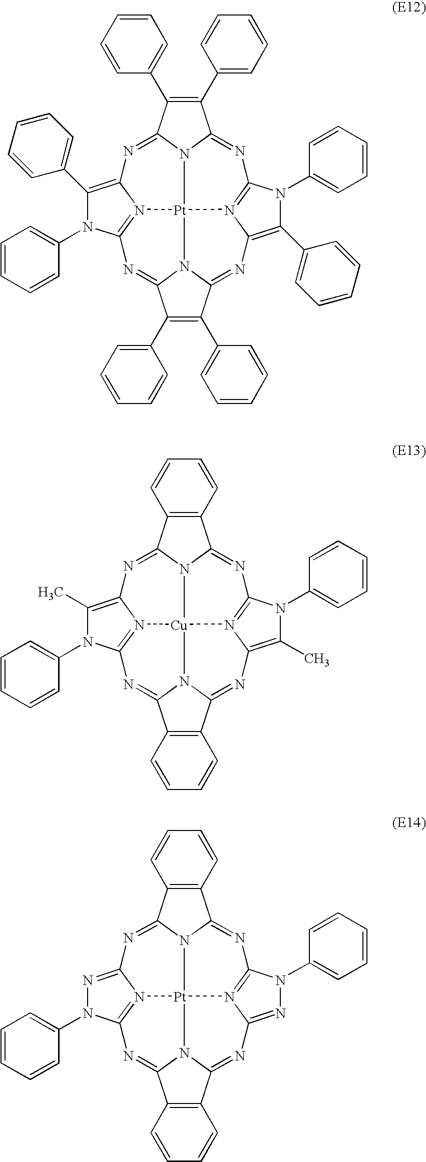

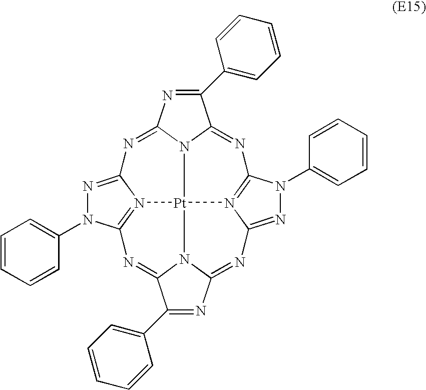

An example of metal complexes usable in the invention is a compound represented by the following formula (F-1):

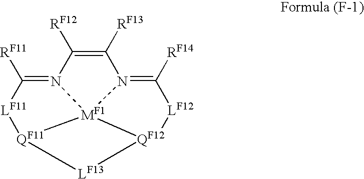

In formula (F-1), M^{F1} represents a metal ion. L^{F11}, L^{F12} and L^{F13} each independently represent a connecting group. R^{F11}, R^{F12}, R^{F13} and R^{F14} each independently represent a hydrogen atom or a substituent. R^{F11} and R^{F12} may, if possible, be bonded to each other to form a 5-membered ring. R^{F12} and R^{F13} may, if possible, be bonded to each other to form a ring. R^{F13} and R^{F14} may, if possible, be bonded to each other to form a 5-membered ring. Q^{F11} and Q^{F12} each independently represent a partial structure containing an atom bonded to M^{F1}. The bond between the atom in the partial structure and M^{F1} may be, for example, a covalent bond.

The compound represented by the formula (F-1) will be described in detail.

In formula (F-1), M^{F1}, L^{F11}, L^{F12}, L^{F13}, Q^{F11} and Q^{F12} have the same definitions as corresponding M^{A1}, L^{A11}, L^{A12}, L^{A13}, Q^{A11} and Q^{A12} in formula (A-1) respectively, and their preferable examples are also the same. R^{F11}, R^{F12}, R¹³ and R^{F14} each independently represent a hydrogen atom or a substituent. R^{F11} and R^{F12} may, if possible, be bonded to each other to form a 5-membered ring. R^{F12} and R^{F13} may, if possible, be bonded to each other to form a ring. R^{F13} and R^{F14} may, if possible, be bonded to each other to form a 5-membered ring. The substituent represented by R^{F11}, R^{F12}, R^{F13} or R^{F14} may be selected from the above-mentioned examples of the substituent represented by R^{C11} to R^{C14} in formula (C-1). In a preferable embodiment, R^{F11} and R^{F12} are bonded to each other to form a 5-membered ring, and R^{F13} and R^{F14} are bonded to each other to form a 5-membered ring. In another preferable embodiment, R^{F12} and R^{F13} are bonded to each other to form an aromatic ring.

The compound represented by the formula (F-1) is more preferably a 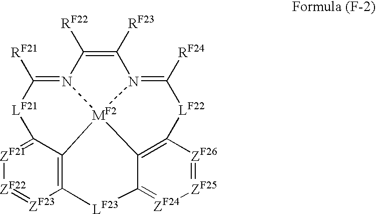
compound represented by formula (F-2), (F-3) or (F-4).

In formula (F-2), M^{F2} represents a metal ion. L^{F21}, L^{F22} and L^{F23} each independently represent a connecting group. R^{F21}, R^{F22}, R^{F23} and R^{F24} each independently represent a substituent R^{F21} and R^{F23} may, if possible, be bonded to each other to form a 5-membered ring. R^{F22} and R^{F23} may, if possible, be bonded to each other to form a ring. R^{F23} and R^{F24} may, if possible, be bonded to each other to form a 5-membered ring. Z^{F21}, Z^{F22}, Z^{F23}, Z^{F24}, Z^{F25} and Z^{F26} each independently represent a nitrogen atom or a substituted or unsubstituted carbon atom.

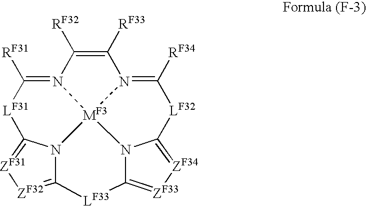

In formula (F-3), M^{F3} represents a metal ion. L^{F31}, L^{F32} and L^{F33} each independently represent a connecting group. R^{F31}, R^{F32}, R^{F33} and R^{F34} each independently represent a substituent. R^{F31} and R^{F32} may, if possible, be bonded to each other to form a 5-membered ring. R^{F32} and R^{F33} may, if possible, be bonded to each other to form a ring. R^{F33} and R^{F34} may, if possible, be bonded to each other to form a 5-membered ring. Z^{F31}, Z^{F32}, Z^{F33} and Z^{F34} each independently represent a nitrogen atom or a substituted or unsubstituted carbon atom.

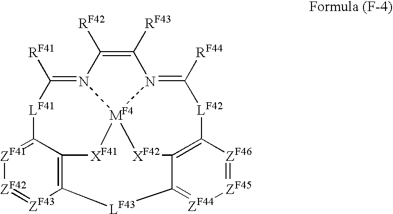

In formula (F-4), M^{F4} represents a metal ion. L^{F41}, L^{F42} and L^{F43} each independently represent a connecting group. R^{F41}, R^{F42}, R^{F43} and R^{F44} each independently represent a substituent. R^{F41} and R^{F42} may, if possible, be bonded to each other to form a 5-membered ring. R^{F42} and R^{F43} may, if possible, be bonded to each other to form a ring. R^{F43} and R^{F44} may, if possible, be bonded to each other to form a 5-membered ring. Z^{F41}, Z^{F42}, Z^{F43}, Z^{F44}, Z^{F45} and Z^{F46} each independently represent a nitrogen atom or a substituted or unsubstituted carbon atom. X^{F41} and X^{F42} each independently represent an oxygen atom, a sulfur atom or a substituted or unsubstituted nitrogen atom.

The compound represented by the formula (F-2) will be described in detail.

M^{F2}, L^{F21}, L^{F22}, L^{F23}, R^{F21}, R^{F22}, R^{F23} and R^{F24} have the same definitions as corresponding M^{F1}, L^{F11}, L^{F12}, L^{F13}, R^{F11}, R^{F12}, R^{F13} and R^{F14} in formula (F-1) respectively, and their preferable examples are also the same.

Z^{F21}, Z^{F22}, Z^{F23}, Z^{F24}, Z^{F25} and Z^{F26} each independently represent a nitrogen atom or a substituted or unsubstituted carbon atom. Each of Z^{F21}, Z^{F22}, Z^{F23}, Z^{F24}, Z^{F25} and Z^{F26} is preferably a substituted or unsubstituted carbon atom, and more preferably an unsubstituted carbon atom. When the carbon atom is substituted, the substituent may be selected from the above-mentioned examples of the substituent on the divalent connecting group represented by L^{A11}, L^{A12}, L^{A13} or L^{A14} in formula (A-1).

The compound represented by the formula (F-3) will be described in detail.

In formula (F-3), M^{F3}, L^{F31}, L^{F32}, L^{F33}, R^{F31}, R^{F32}, R^{F33} and R^{F34} have the same definitions as corresponding M^{F1}, L^{F11}, L^{F12}, L^{F13}, R^{F11}, R^{F12}, R^{F13} and R^{F14} in formula (F-1) respectively, and their preferable examples are also the same. Z^{F31}, Z^{F32}, Z^{F33} and Z^{F34} each independently represent a nitrogen atom or a substituted or unsubstituted carbon atom. Each of Z^{F31}, Z^{F32}, Z^{F33} and Z^{F34} is preferably a substituted or unsubstituted carbon atom, and more preferably an unsubstituted carbon atom. When the carbon atom is substituted, the substituent may be selected from the above-mentioned examples of the substituent on the divalent connecting group represented by L^{A11}, L^{A12}, L^{A13} or L^{A14} in formula (A-1).

The compound represented by the formula (F-4) will be described in detail.

In formula (F-4), M^{F4}, L^{F41}, L^{F42}, L^{F43}, R^{F41}, R^{F42}, R⁴³ and R^{F44} have the same definitions as corresponding M^{F1}, L^{F11}, L^{F12}, L^{F13}, R^{F11}, R^{F12}, R^{F13} and R^{F14} in formula (F-1) respectively, and their preferable examples are also the same.

Z^{F41}, Z^{F42}, Z^{F43}, Z^{F44}, Z^{F45} and Z^{F46} each independently represent a nitrogen atom or a substituted or unsubstituted carbon atom. Each of Z^{F41}, Z^{F42}, Z^{F43}, Z^{F44}, Z^{F45} and Z^{F46} is preferably a substituted or unsubstituted carbon atom, and more preferably an unsubstituted carbon atom. When the carbon atom is substituted, the substituent may be selected from the above-mentioned examples of the substituent on the divalent connecting group represented by L^{A11}, L^{A12}, L^{A13} or L^{A14} in formula (A-1)

X^{F41} and X^{F42} each independently represent an oxygen atom, a sulfur atom or a substituted or unsubstituted nitrogen atom. Each of X^{F41} and X^{F42} is preferably an oxygen atom or a sulfur atom, and more preferably an oxygen atom.

Specific examples of the compounds represented by the formula (F-1) are illustrated below, but the invention is not limited thereto.

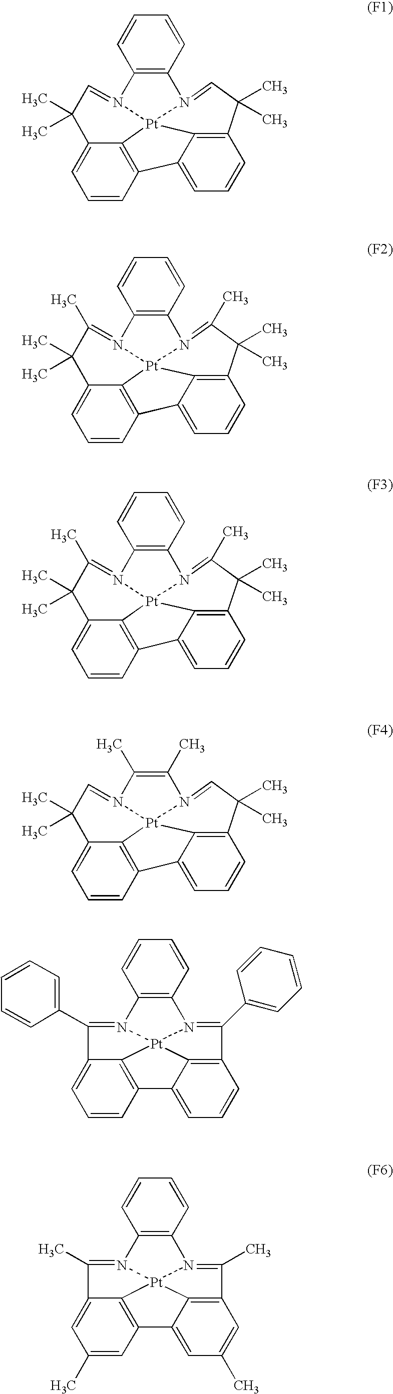

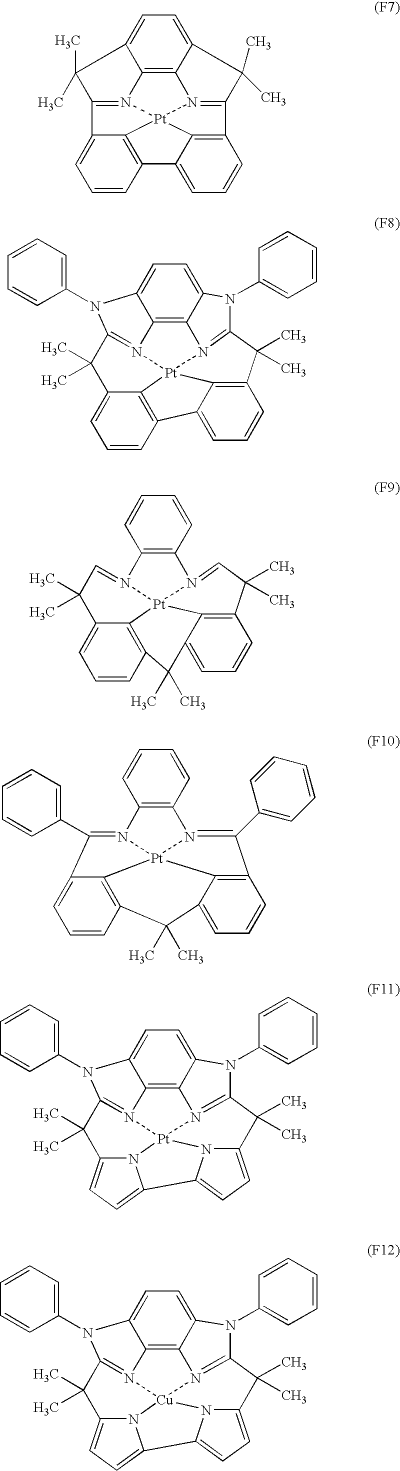

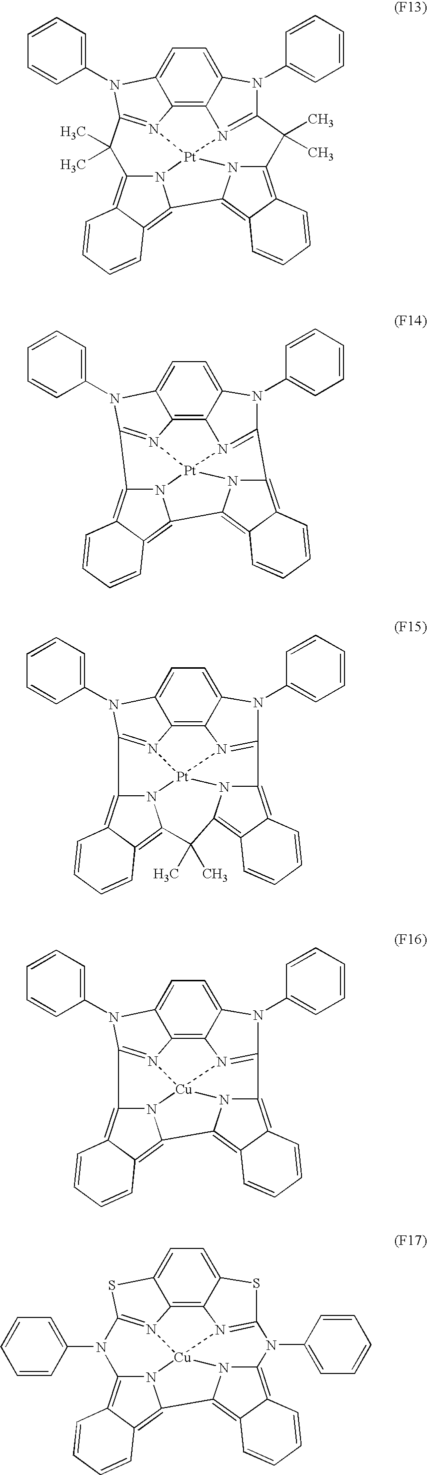

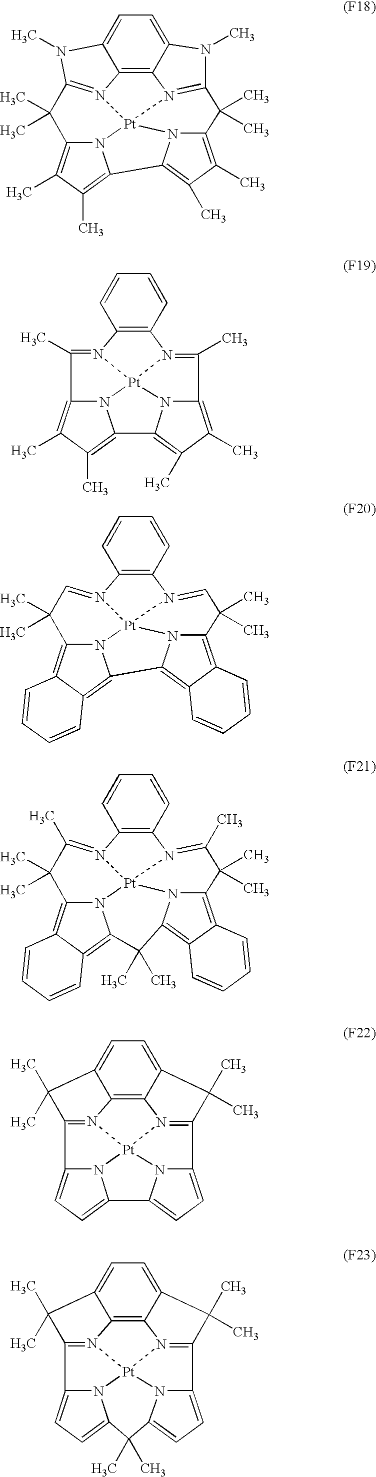

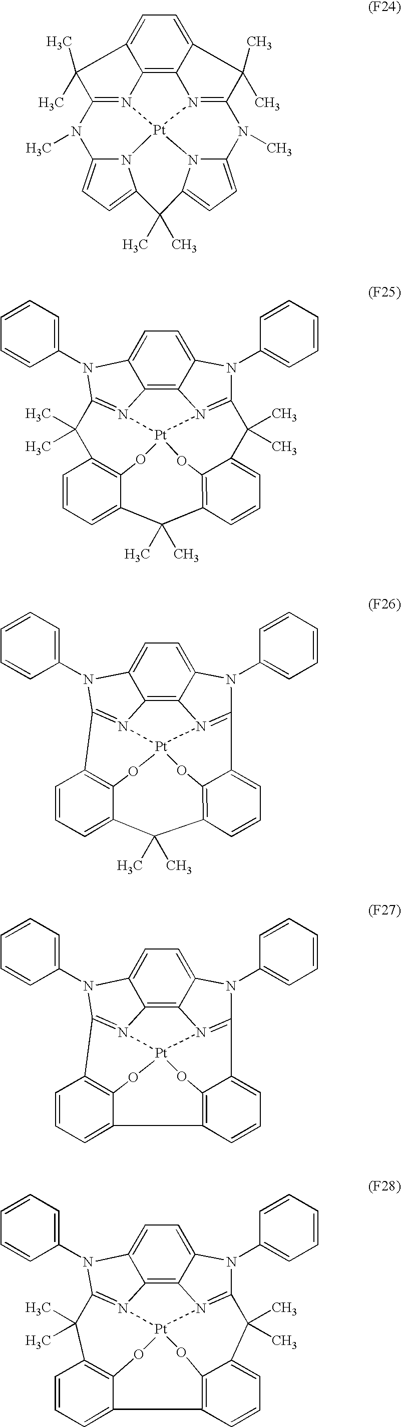

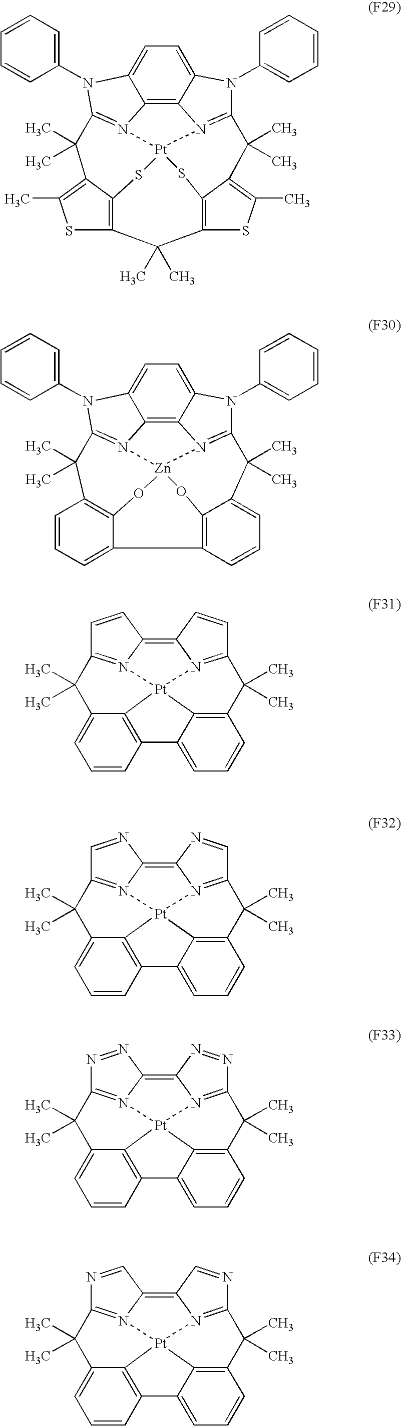

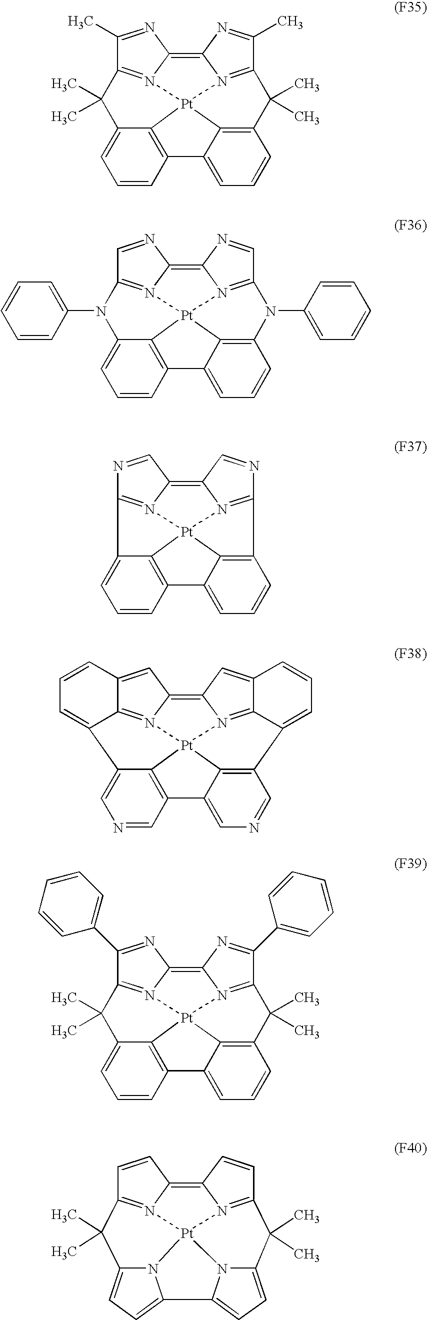

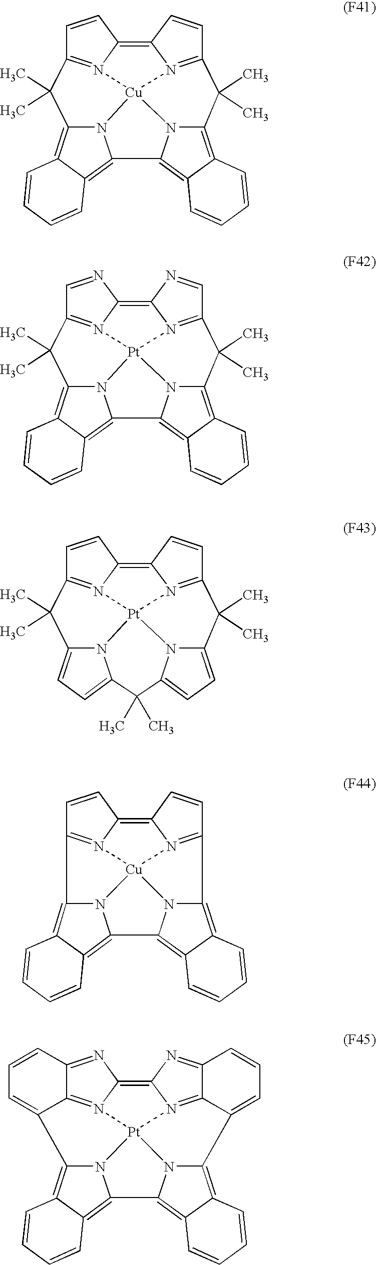

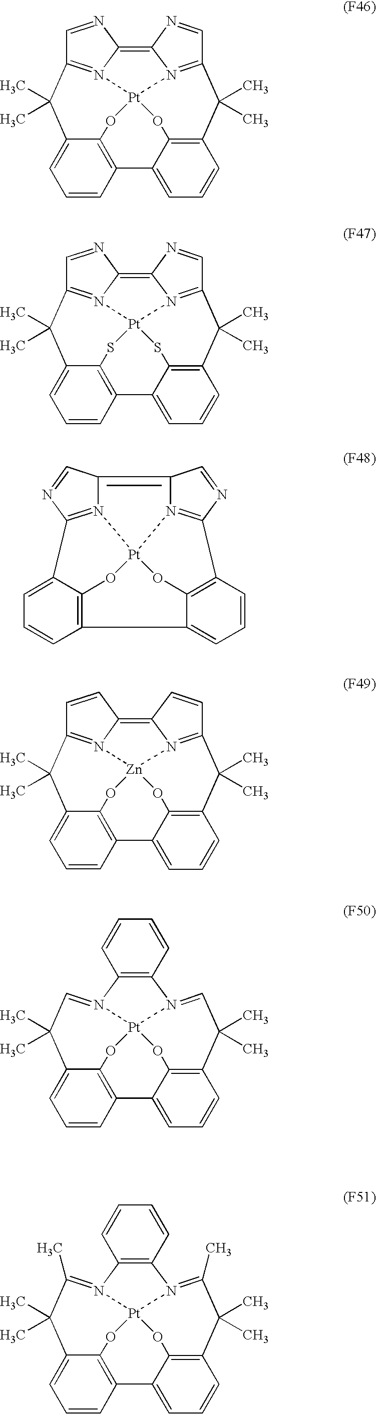

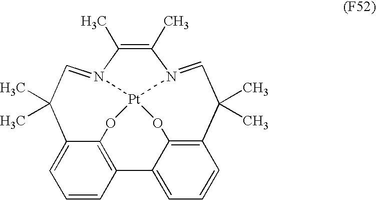

Compounds represented by the formulae (A-1) to (F-1) can be synthesized by known methods.

The phosphorescent quantum yield of the amplifying agent in the invention (metal complex) is preferably 20% or more, more preferably 40% or more, still more preferably, 50% or more, and particularly more preferably 60% or more, from the viewpoint of efficiency and durability.

The phosphorescent quantum yield of the amplifying agent can be determined, for example, by freeze-deaerating a solution containing the amplifying agent (e.g., a toluene solution at 1×10⁻⁵ mol/l), photoexciting the agent at the maximum absorption wavelength of the amplifying agent with laser beam at 20° C., and comparing the emission with those of the samples with a known emission quantum yield by using a time-of-flight apparatus.

In the luminescent device according to the invention, the phosphorescence lifetime of the amplifying agent is preferably 10 μs or less, more preferably 5 μs or less, still more preferably 2 μs or less, and particularly preferably 1 μs or less, from the viewpoints of efficiency and durability. The phosphorescence lifetime of the amplifying agent can be determined by photoexciting the amplifying agent in a solution (e.g., a toluene solution at 1×10⁻⁵ mol/l) at 20° C. at the maximum absorption wavelength thereof with laser beam and measuring attenuation of the emission.

In the luminescent device according to the invention, the maximum phosphorescence wavelength of the amplifying agent is preferably 500 nm or less, more preferably 500 nm or less and 350 nm or more, still more preferably 480 nm or less and 380 nm or more, further more preferably, 470 nm or less and 390 nm or more, and particularly preferably 460 nm or less and 400 nm or more, from the viewpoints of efficiency and durability.

The concentration of the amplifying agent in the luminescent layer is not particularly limited, but preferably from 0.1 wt % to 9 wt %, more preferably from 1 wt % to 8 wt %, still more preferably from 2 wt % to 7 wt %, and particularly preferably from 3 wt % to 6 wt %. A concentration in the range above is preferable, for improvement in the efficiency and durability of device.

The luminescent device according to the invention preferably contains at least one host material in the luminescent layer, from the viewpoints of efficiency and durability. The host material may be contained in the layer containing a fluorescence-emitting compound or in the layer containing an amplifying agent in the luminescent layer, and more preferably both in the layer containing a fluorescence-emitting compound and the layer containing an amplifying agent.

The T, level (energy level of lowest excited triplet state) of the host material contained in the luminescent device according to the invention is preferably from 50 Kcal/mol (209.2 KJ/mol) to 90 Kcalmol (377.1 KJ/mol), more preferably from 52 Kcal/mol (217.6 KJ/mol) to 80 Kcal/mol (335.2 KJ/mol), and still more preferably from 55 Kcal/mol (230.1 KJ/mol) to 70 Kcal/mol (293.3 KJ/mol), from the viewpoints of efficiency and durability. The T₁ level can be determined from the short-wavelength edge of the emission in the phosphorescence spectrum of a thin film of host material.

In the luminescent device according to the invention, the T₁ level (energy level of lowest excited triplet state) of the layer in the luminescent layer close to the cathode (e.g., electron-transporting layer, hole-blocking layer, exciton-blocking layer, or the like) is preferably from 50 Kcal/mol (209.2 KJ/mol) to 90 Kcal/mol (377.1 KJ/mol), more preferably from 52 Kcal/mol (217.6 KJ/mol) to 80 Kcalmol (335.2 KJ/mol), and still more preferably from 55 Kcal/mol (230.1 KJ/mol) to 70 Kcal/mol (293.3 KJ/mol), from the viewpoints of efficiency and durability. The T₁ level can be determined in a similar manner to the method of determining that of the host material.

In the luminescent device according to the invention, the T₁ level (energy level of lowest excited triplet state) of the layer in the luminescent layer close to the anode (e.g., hole-transporting layer or the like) is preferably from 50 Kcal/mol (209.2 KJ/mol) to 90 Kcal/mol (377.1 KJ/mol), more preferably from 52 Kcal/mol (217.6 KJ/mol) to 80 Kcal/mol (335.2 KJ/mol), and still more preferably from 55 Kcal/mol (230.1 KJ/mol) to 70 Kcal/mol (293.3 KJ/mol), from the viewpoints of efficiency and durability. The T₁ level can be determined in a similar manner to the method of determining that of the host material.

The luminescent device according to the invention preferably contains at least two fluorescence-emitting compounds from the viewpoints of efficiency, durability, and color density, and the multiple compounds may emit light at the same time, emitting white light.

The concentration of the fluorescence-emitting compounds in the luminescent layer in the luminescent device according to the invention is preferably from 0.1% to 10%, more preferably from 0.2% to 8%, still more preferably from 0.3% to 5%, and particularly preferably from 0.5% to 3%, from the viewpoints of efficiency and durability.

In the luminescent device according to the invention, the fluorescent quantum yield of the fluorescence-emitting compounds in the luminescent layer is preferably 50% or more, more preferably 70% or more, still more preferably 80% or more, further more preferably 90% or more, and particularly preferably 95% or more.

The fluorescent quantum yield can be determined by photoexciting the fluorescence-emitting compounds in a solid film or a solution (e.g., toluene solution at 1×10⁻⁵ mol/l) at 20° C. with laser beam at the maximum absorption wavelength thereof and comparing the emission with those of the samples with a known emission quantum yield.

In the luminescent device according to the invention, the emission spectrum of the amplifying agent and the absorption spectrum of the fluorescence-emitting compound preferably overlap at least partially from the viewpoint of the Forster-type excitation energy transfer, and greater overlap is more preferable.

The values of the maximum emission wavelength of the amplifying agent and the maximum absorption wavelength of the fluorescence-emitting compound are preferably closer to each other, and the difference in absolute value is preferably 50 nm or less, more preferably 30 nm or less, still more preferably 20 nm or less, and particularly preferably 10 nm or less.

In the luminescent device according to the invention, one or more fluorescence-emitting compounds are contained in the luminescent layer, and favorable examples of the fluorescence-emitting compounds include distyrylarylene derivatives, oligoarylene derivatives, aromatic nitrogen-containing heterocyclic compounds, sulfur-containing heterocyclic compounds, metal complexes, oxo-substituted heterocyclic compounds, organic silicon compounds, triarylamine derivatives, and condensed aromatic compounds, from the viewpoints of efficiency and durability; more preferable are distyrylarylene derivatives, oligoarylene derivatives, aromatic nitrogen-containing heterocyclic compounds, triarylamine derivatives, and condensed aromatic compounds; still more preferable are distyrylarylene derivatives and condensed aromatic compounds; and particularly preferable are condensed aromatic compounds.

The distyrylarylene derivatives for use as a fluorescence-emitting compound in the invention will be described below.

The distyrylarylene derivative is a compound having two or more styryl groups connected via an arylene connecting group.

The arylene group is not particularly limited, but examples thereof include phenylene, naphthylene, anthrylene, pyrenylene, and perylenylene groups, and the connecting groups in combination thereof (e.g., biphenylene, terphenylene, tetraphenylene, and diphenyl anthracene group), and the like; preferable are phenylene, naphthylene, and anthrylene groups, and the compounds in combination thereof; and more preferable are compounds having two to four phenylene, naphthylene, or anthrylene groups connected to each other.

The styryl group or the arylene connecting group may have an additional substituent. Examples of the substituent include alkyl groups (preferably, having 1 to 30 carbon atoms, more preferably 1 to 20 carbon atoms, and particularly preferably 1 to 10 carbon atoms, such as methyl, ethyl, iso-propyl, tert-butyl, n-octyl, n-decyl, n-hexadecyl, cyclopropyl, cyclopentyl, and cyclohexyl), alkenyl groups (preferably, having 2 to 30 carbon atoms, more preferably 2 to 20 carbon atoms, and particularly preferably 2 to 10 carbon atoms, such as vinyl, allyl, 2-butenyl, and 3-penteny), alkynyl groups (preferably, having 2 to 30 carbon atoms, more preferably 2 to 20 carbon atoms, and particularly preferably 2 to 10 carbon atoms, such as propargyl and 3-pentynyl), aryl groups (preferably, having 6 to 30 carbon atoms, more preferably 6 to 20 carbon atoms, and particularly preferably 6 to 12 carbon atoms, such as phenyl, p-methylphenyl, naphthyl, and anthranyl), amino groups (preferably, having 0 to 30 carbon atoms, more preferably 0 to 20 carbon atoms, and particularly preferably 0 to 10 carbon atoms, such as amino, methylamino, dimethylamino, diethylamino, dibenzylamino, diphenylamino, and ditolylamino), alkoxy groups (preferably, having 1 to 30 carbon atoms, more preferably 1 to 20 carbon atoms, and particularly preferably 1 to 10 carbon atoms, such as methoxy, ethoxy, butoxy, and 2-ethylhexyloxy), aryloxy group (preferably, having 6 to 30 carbon atoms, more preferably 6 to 20 carbon atoms, and particularly preferably 6 to 12 carbon atoms, such as phenyloxy, 1-naphthyloxy, and 2-naphthyloxy), heterocyclic oxy groups (preferably, having 1 to 30 carbon atoms, more preferably 1 to 20 carbon atoms, and particularly preferably 1 to 12 carbon atoms, such as pyridyloxy, pyrazyloxy, pyrimidyloxy, and quinolyloxy), acyl groups (preferably, having 1 to 30 carbon atoms, more preferably 1 to 20 carbon atoms, and particularly preferably 1 to 12 carbon atoms, such as acetyl, benzoyl, formyl, and pivaloyl), alkoxycarbonyl groups (preferably, having 2 to 30 carbon atoms, more preferably 2 to 20 carbon atoms, and particularly preferably 2 to 12 carbon atoms, such as methoxycarbonyl and ethoxycarbonyl), aryloxycarbonyl groups (preferably, having 7 to 30 carbon atoms, more preferably 7 to 20 carbon atoms, and particularly preferably 7 to 12 carbon atoms, such as phenyloxycarbonyl), acyloxy groups (preferably, having 2 to 30 carbon atoms, more preferably 2 to 20 carbon atoms, and particularly preferably 2 to 10 carbon atoms, such as acetoxy and benzoyloxy), acylamino groups (preferably, having 2 to 30 carbon atoms, more preferably 2 to 20 carbon atoms, and particularly preferably 2 to 10 carbon atoms, such as acetylamino and benzoylamino), alkoxycarbonylamino groups (preferably, having 2 to 30 carbon atoms, more preferably 2 to 20 carbon atoms, and particularly preferably 2 to 12 carbon atoms, such as methoxycarbonylamino), aryloxycarbonylamino groups (preferably, having 7 to 30 carbon atoms, more preferably 7 to 20 carbon atoms, and particularly preferably 7 to 12 carbon atoms, such as phenyloxycarbonylamino), sulfonylamino groups (preferably, having 1 to 30 carbon atoms, more preferably 1 to 20 carbon atoms, and particularly preferably 1 to 12 carbon atoms, such as methanesulfonylamino and benzenesulfonylamino), sulfamoyl groups (preferably, having 0 to 30 carbon atoms, more preferably 0 to 20 carbon atoms, and particularly preferably 0 to 12 carbon atoms, such as sulfamoyl, methylsulfamoyl, dimethylsulfamoyl, and phenylsulfamoyl), carbamoyl groups (preferably, having 1 to 30 carbon atoms, more preferably 1 to 20 carbon atoms, and particularly preferably 1 to 12 carbon atoms, such as carbamoyl, methylcarbamoyl, diethylcarbamoyl, and phenylcarbamoyl), alkylthio groups (preferably, having 1 to 30 carbon atoms, more preferably 1 to 20 carbon atoms, and particularly preferably 1 to 12 carbon atoms, such as methylthio and ethylthio), arylthio groups (preferably, having 6 to 30 carbon atoms, more preferably 6 to 20 carbon atoms, and particularly preferably 6 to 12 carbon atoms, such as phenylthio), heterocyclic thio groups (preferably, having 1 to 30 carbon atoms, more preferably 1 to 20 carbon atoms, and particularly preferably 1 to 12 carbon atoms, such as pyridylthio, 2-benzimidazolylthio, 2-benzoxazolylthio, and 2-benzothiazolylthio), sulfonyl groups (preferably, having 1 to 30 carbon atoms, more preferably 1 to 20 carbon atoms, and particularly preferably 1 to 12 carbon atoms, such as mesyl and tosyl), sulfinyl groups (preferably, having 1 to 30 carbon atoms, more preferably 1 to 20 carbon atoms, and particularly preferably 1 to 12 carbon atoms, such as methanesulfinyl and benzenesulfinyl), ureido groups (preferably, having 1 to 30 carbon atoms, more preferably 1 to 20 carbon atoms, and particularly preferably 1 to 12 carbon atoms, such as ureido, methylureido, and phenylureido), phosphoric arnido groups (preferably, having 1 to 30 carbon atoms, more preferably 1 to 20 carbon atoms, and particularly preferably 1 to 12 carbon atoms, such as diethylphosphoric amido, and phenylphosphoric amido), a hydroxy group, a mercapto group, halogen atoms (e.g., fluorine, chlorine, bromine, and iodine), a cyano group, a sulfo group, a carboxyl group, a nitro group, a hydroxamic acid group, sulfino groups, hydrazino groups, imino groups, heterocyclic groups (preferably, having 1 to 30 carbon atoms, more preferably 1 to 20 carbon atoms, and particularly preferably 1 to 12 carbon atoms and one or more heteroatoms such as nitrogen, oxygen, and sulfur, such as imidazolyl, pyridyl, quinolyl, furyl, thienyl, pyperidyl, morpholino, benzoxaolyl, benzimidazolyl, benzthiazolyl, carbazolyl, and azepinyl), silyl groups (preferably, having 3 to 40 carbon atoms, more preferably 3 to 30 carbon atoms, and particularly preferably 3 to 24 carbon atoms, such as trimethylsilyl and triphenylsilyl), silyloxy groups (preferably, having 3 to 40 carbon atoms, more preferably 3 to 30 carbon atoms, and particularly preferably 3 to 24 carbon atoms, such as trimethylsilyloxy and triphenylsilyloxy), and the like. These substituents may be further substituted.

Among them, favorable substituent on the styryl group is an alkyl, aryl, heteroaryl or vinyl group, or a group having substituents that bind to each other forming a ring structure (an alicyclic or heterocyclic ring such as benzene or pyrrole); more preferably is an alkyl or aryl group, or a group having substituents that bind to each other forming a ring structure.

Among them, favorable substituent on the aryl connecting group is an alkyl, aryl, heteroaryl or vinyl group, or a group having substituents that bind to each other forming a ring structure (an alicyclic or heterocyclic ring such as benzene or pyrrole), and more preferable is an alkyl or aryl group.

The aromatic nitrogen-containing heterocyclic compound for use as the fluorescence-ermitting compound in the invention will be described below.

The aromatic nitrogen-containing heterocyclic ring derivative is preferably a compound that is not a complex (such as boron complex or metal complex).

The nitrogen-containing heterocyclic ring in the aromatic nitrogen-containing heterocyclic compound is not particularly limited, but examples thereof include pyrrole, pyrazole, imidazole, triazole, oxazole, thiazole, pyridine, pyrimidine, pyrazine, pyridazine, and triazine rings, and the condensed rings thereof (e.g., benzimidazole, benzoxazole, quinoline, quinoxaline, carbazole, and imidazopyridine). These heterocyclic rings may have additionally one or more substituents. The substituents include the groups described as the substituent on the styryl group described above.

The aromatic nitrogen-containing heterocyclic compound is favorably a pyrrole, imidazole, oxazole, or thiazole ring derivative, and more preferably a carbazole or benzothiazole derivative.

The oligoarylene derivative for use as the fluorescence-emitting compound in the invention will be described below.

The oligoarylene derivative is a compound having two or more aryl groups connected to each other. The number of the aryl groups connected is preferably from 2 to 8, more preferably from 2 to 6, and still more preferably 3 or 4.

The aryl group is not particularly limited, but is, for example, a phenyl, naphthyl, anthryl, pyrenyl, perylenyl, or triphenylenyl group, or the like. The aryl group may have one or more substituents, and the substituents include the groups described as the substituent on the styryl group.

Favorable examples of the oligoarylene derivatives include biphenylene, terphenylene, tetraphenylene, diphenylanthracene, binaphthylene, bianthrylene, and teranthrylene derivatives.

The sulfur-containing heterocyclic compound for use as the fluorescence-emitting compound in the invention will be described below.

The sulfur-containing heterocyclic compound is a heterocyclic compound having a sulfur atom, and is preferably a sulfur-containing heterocyclic ring derivative having a five- or six-membered ring and more preferably a thiophene derivative.

The metal complex for use as the fluorescence-emitting compound in the invention will be described below.

The metal ion in the metal complex is not particularly limited, but preferably a beryllium, magnesium, aluminum, zinc, or gallium ion, more preferably an aluminum, zinc or gallium ion, and still more preferably an aluminum ion.

The ligand in the metal complex is not particularly limited, but preferably is a bidentate ligand, more preferably, a bidentate ligand coordinating with an oxygen-nitrogen, oxygen-oxygen, or nitrogen-nitrogen interaction, still more preferably a bidentate ligand coordinating with an oxygen-nitrogen or nitrogen-nitrogen interaction, and particularly preferably a bidentate ligand coordinating with an oxygen-nitrogen interaction.

The oxo-substituted heterocyclic compound for use as the fluorescence-emitting compound in the invention will be described below.

The oxo-substituted heterocyclic compound is a compound having a carbonyl group in the ring of a heterocyclic ring and is preferably a pyrrone (pyranone) or pyridone derivative.

The organic silicon compound for use as the fluorescence-emitting compound in the invention will be described below.

The organic silicon compound is an organic compound containing a silicon atom, and is preferably an arylsilane, alkenylsilane or alkynylsilane group, or a silicon-containing heterocyclic compound such as a silole derivative.

The triarylamine derivative for use as the fluorescence-emitting compound in the invention will be described.

The triarylamine derivative is a compound having three aryl groups bound to a nitrogen atom, and the aryl group may have one or more substituents. The substituents include the groups described as the substituent on the styryl group, and the preferable examples thereof are also the same. The substituents may be bonded to each other to form a ring structure.

The aryl group is preferably a phenyl, naphthyl, pyrenyl, anthryl, perylenyl, or triphenylenyl group, more preferably a phenyl, naphthyl, pyrenyl, anthryl, or perylenyl group, and still more preferably a phenyl, naphthyl, pyrenyl, or perylenyl group.

The condensed aromatic compound for use as the fluorescence-emitting compound in the invention will be described below.

Examples of the condensed aromatic compounds include compounds having one or more condensed aromatic hydrocarbon rings [e.g., naphthalene, anthracene, phenanthrene, acenaphthylene, pyrene, perylene, fluoranthene, tetracene, chrysene, pentacene, coronene, and the derivatives thereof (such as tetra-t-butylpyrene, binaphthyl, rubrene, benzopyrene, and benzanthracene)], compounds having a condensed aromatic heterocyclic ring [e.g., quinoline, quinoxaline, benzimidazole, benzoxazole, imidazopyridine, azaindole, and the derivatives thereof (e.g., bis benzoxylazolylbenzene and benzoquinoline)], and the like; and preferable are compounds having one or more condensed aromatic hydrocarbon rings.

The compound having a condensed aromatic hydrocarbon ring is preferably naphthalene, anthracene, phenanthrene, acenaphthylene, pyrene, perylene, fluoranthene, or, the derivative thereof, more preferably anthracene, fluoranthene, pyrene, perylene or the derivative thereof, and still more preferably an anthracene, fluoranthene, pyrene, or perylene derivative.

In the luminescent device according to the invention, the maximum emission wavelength of the fluorescence-emitting compound is preferably 580 nm or less, more preferably 500 nm or less and 350 nm or more, still more preferably 480 nm or less and 380 nm or more, further more preferably 470 nm or less and 390 nm or more, and particularly preferably 460 nm or less and 400 nm or more.

In the luminescent device according to the invention, the fluorescence-emitting compound preferably contains a substituent that lowers efficiency of the Dexter-type energy transfer from a triplet exciton of amplifying agent to a triplet exciton of fluorescence-emitting compound, from the viewpoints of efficiency and durability.

The substituent is preferably an alkyl or aryl group, more preferably a branched alkyl group, and still more preferably an alkyl group having a quaternary carbon.

As described above, the luminescent device according to the invention preferably contains the host material in the luminescent layer, but the host material is preferably at least one compounds selected from complexes, nitrogen-containing heterocyclic compounds, and aromatic hydrocarbon compounds, more preferably a complex or a nitrogen-containing heterocyclic compound; and still more preferably a complex.

The complex used as the host material is preferably an aluminum, zinc, or gallium complex, more preferably an aluminum or zinc complex, and still more preferably an aluminum complex.

The nitrogen-containing heterocyclic compound used as the host material is preferably a monocyclic or 5,6-condensed ring compound and more preferably a 5,6-condensed ring compound.

The aromatic hydrocarbon compound used as the host material is preferably a monocyclic compound or a two- to four-ring condensed compound, more preferably a monocyclic compound or two-ring condensed compound, and still more preferably a monocyclic compound.

The organic compound layer in the luminescent device according to the invention preferably contains an electron-transporting layer, which in turn contains a complex compound or a nitrogen-containing heterocyclic compound, more preferably a nitrogen-containing heterocyclic compound, from the viewpoints of efficiency and durability.

The external quantum efficiency of the luminescent device according to the invention is preferably 6% or more, more preferably 10% or more, still more preferably 13% or more, further more preferably 15% or more, and particularly preferably 18% or more, from the viewpoints of efficiency and durability.

(1) The maximum value of the external quantum efficiency when the device is driven at 20° C., or (2) the value of the external quantum efficiency at around 100 to 300 cd/m² when the device, is driven at 20° C. can be used as the value of the external quantum efficiency, and the value used in the invention is the value of (1) above.

The internal quantum efficiency of the luminescent device according to the invention is preferably 30% or more, more preferably 50% or more, still more preferably 70% or more further more preferably 80% or more, and particularly preferably 90% or more, from the viewpoints of efficiency and durability.

The internal quantum efficiency of device is calculated by the following Formula:
“Internal quantum efficiency=External quantum efficiency/Light output efficiency”.

In normal organic EL devices, the light output efficiency is about 20%, but it is possible to improve the light output efficiency to 20% or more by adjusting the shape of substrate and electrode, the thickness of organic and inorganic layers, the refractive index of the organic and inorganic layers, and the like.

The ionization potential of the host material contained in the luminescent layer according to the invention is preferably from 5.8 eV to 6.3 eV, more preferably from 5.95 eV to 6.25 eV, and still more preferably from 6.0 eV to 6.2 eV, from the viewpoints of driving voltage and luminous efficiency.

The ionization potential (Ip) was determined by using an ultraviolet photoelectron analyzer AC-1 (manufactured by Riken Keiki Co., Ltd.).

The electron mobility of the host material in the luminescent device according to the invention is preferably from 1×10⁻⁶ Vs/cm to 1×10⁻¹ Vs/cm, more preferably from 5×10⁻⁶ Vs/cm to 1×10⁻² Vs/cm, still more preferably from 1×10⁻⁵ Vs/cm to 1×10⁻² Vs/cm, and particularly preferably from 5×10⁻⁵ Vs/cm to 1×10⁻² Vs/cm, from the viewpoints of driving voltage and luminous efficiency.

The electron mobility can be determined by the time-of-flight method.

The hole mobility of the host material in the luminescent device according to the invention is preferably from 1×10⁻⁶ Vs/cm to 1×10⁻¹ Vs/cm, more preferably from 5×10⁻⁶ V/cm to 1×10⁻² Vs/cm, still more preferably from 1×10⁻⁵ Vs/cm to 1×10⁻² Vs/cm, and particularly preferably from 5×10⁻⁵ Vs/cm to 1×10⁻² Vs/cm, from the viewpoints of driving voltage and luminous efficiency.

The hole mobility can be determined by the time-of-flight method.

Each of the glass transition viewpoints of the host material, electron-transporting material, and hole. transport material contained in the luminescent layer according to the invention is preferably 90° C. to 400° C., more preferably 100° C. to 380° C., still more preferably 120° C. to 370° C., and particularly preferably 140° C. to 360° C., from the viewpoint of heat resistance.

The luminescent layer preferably has at least one alternate laminated structure of a layer having at least one the fluorescence-emitting compounds emitting fluorescence when voltage is applied and a layer having at least one of the amplifying agents above, from the viewpoints of driving voltage and luminous efficiency; and preferably, the luminescent layer has an alternate laminated structure having four or more layers; and still more preferably, of 12 layers or more, and still more preferably, of 16 layers.

In the luminescent device according to the invention having an alternate-layer film, the alternate-layer film is preferably prepared by the steps comprising the following procedures (a) to (c). (a) A fluorescence-emitting compound or a mixture thereof is deposited. Deposition of an amplifying agent or the mixture thereof then is prevented by placing a shutter in the vicinity of the vapor deposition source for the amplifying agent or the mixture thereof. (b) An amplifying agent or the mixture thereof is deposited. Deposition of the fluorescence-emitting compound or the mixture thereof then is prevented by placing a shutter in the vicinity of the vapor deposition source for the fluorescence-emitting compound or the mixture thereof. (c) Steps of (a) and (b) are repeated. The steps are switched by opening or closing the shutters placed respectively in the vicinity of the vapor deposition sources. The step described in Example 1 below is such an example. the invention is preferably prepared by the process comprising the following steps (a) to (c). (a) An amplifying agent or the mixture thereof is deposited. Deposition of the fluorescence-emitting compound or the mixture thereof then is prevented by placing a shutter in the vicinity of the vapor deposition source for the fluorescence-emitting compound or the mixture thereof. (b) A fluorescence-emitting compound or the mixture thereof is deposited. Deposition of an amplifying agent or the mixture thereof then is prevented by placing a shutter in the vicinity of the vapor deposition source for the amplifying agent or the mixture thereof. (c) Steps of (a) and (b) are repeated. The steps are switched by opening or closing the shutters placed respectively in the vicinity of the vapor deposition sources.

The metal complex, the amplifying agent in the invention, may be a low-molecular weight compound, an oligomer compound, or a polymer compound (weight-average molecular weight (expressed by polystyrene): preferably 1,000 to 5,000,000, more preferably 2,000 to 1,000,000, more preferably 3,000 to 100,000), but is preferably a low-molecular weight compound.

The luminescent device according to the invention will be described hereinafter.

The luminescent device according to the invention is not particularly limited in its system, driving method, application, or the like.

It is possible to improve the light output efficiency of the luminescent device according to the invention by various known methods. For example, it is possible to improve the light-output efficiency and the external quantum efficiency, for example, by modifying the substrate surface (e.g., by forming a fine irregular pattern), adjusting the refractive index of the substrate, ITO layer, and organic layer, or adjusting the thickness of the substrate, ITO layer, and organic layer.

The luminescent device according to the invention may be a so-called top emission system, in which the light is emitted from the anode-side face.

The substrate material for the luminescent device according to the invention is not particularly limited, and examples thereof include inorganic materials such as yttrium-stabilized zirconia (YSZ) and glass; high-molecular weight materials such as polyesters (e.g., polyethylene terephthalate, polybutylene terephthalate, and polyethylene naphthalate), polyethylene, polycarbonates, polyether sulfones, polyarylates, allyl diglycol carbonate, polyimides, polycycloolefins, norbornene resins, poly(chlorotrifluoroethylene), Teflon (registered trade name), and polytetrafluoroethylene-polyethylene copolymers; and the like.

The luminescent device according to the invention may be used in combination with a singlet blue luminescent device.

As described above, the luminescent layer in the luminescent device according to the invention preferably has an alternate layer structure, but may have a laminated structure other than the alternate layer structure, and the number of laminated layers is preferably 2 to 50, more preferably 4 to 30 or less, and still more preferably 6 to 20.

The thickness of each layer in the laminated layers is not particularly limited, but preferably 0.2 nm to 20 nm, more preferably 0.4 nm to 15 nm, still more preferably 0.5 nm to 10 nm, and particularly preferably 1 nm to 5 nm.

The luminescent layer in the organic electroluminescent device according to the invention may have multiple domain structures. The luminescent layer may have other domain structures therein. The diameter of each domain is preferably 0.2 nm to 10 nm, more preferably 0.3 nm to 5 nm, still more preferably 0.5 nm to 3 nm, and particularly preferably 0.7 nm to 2 nm.

The method of forming the organic compound layer of the luminescent device containing the fluorescence-emitting compound and amplifying agent according to the invention is not particularly limited, and examples thereof include resistance-heating vapor deposition, electron beam, sputtering, molecular lamination, coating (spray coating, dip coating, impregnation, roll coating, gravure coating, reverse coating, roll-brush coating, air knife coating, curtain coating, spin coating, flow coating, bar coating, microgravure coating, air doctor coating, blade coating, squeeze coating, transfer roll coating, kiss coating, cast coating, extrusion coating, wire bar coating, screen coating), inkjet ejection, printing, transferring, and the like; and resistance-heating deposition, coating, and transferring methods are preferable in consideration of the characteristics of the device and productivity.

The luminescent device according to the invention is a device having at least one organic compound layer containing a luminescent layer or a luminescent layer between a pair of electrodes, anode and cathode, and as described above, the luminescent device preferably has an electron-transporting layer, more preferably a hole-transporting layer, additionally.

The luminescent device may also have a hole-injecting layer,. an electron-injecting layer, a hole-blocking layer, an exciton-blocking layer, or the like additionally as needed, and each of these layers may have a different function.

When the luminescent device according to the invention has at least three layers, a hole-transporting layer, a luminescent layer, and an electron-transporting layer,. the device more preferably have no hole-blocking layer or exciton-blocking layer between the luminescent layer and the electron-transporting layer. In addition, more preferably, there is only an electron-transporting layer between the luminescent layer and the electrode.

A protective layer and the like may be formed as needed as an additional layer. Various materials may be used for forming each layer.

The hole-blocking layer is a layer having a function to block the holes injected from the anode, and the exciton-blocking layer is a layer having a function to block the excitons generated in the luminescent layer and restrict the emission range as it is present between the electrodes and the luminescent layer, and the BCPs described in WO No. 01/0,08230 and Comparative Example 1 of the present specification are the examples thereof.

The material contained in the luminescent layer is not particularly limited as long as the material is, upon application of electric field, capable of accepting holes from the anode, or from the hole injection layer, or from the hole transport layer, capable of accepting electrons from the cathode, or from the electron injection layer, or from the electron transport layer, capable of transporting the injected charges, and capable of providing a site for recombination of holes and electrons to emit light.

Examples of the substances contained in the luminescent layer include not only the metal complexes of the invention, but also various metal complexes (such as metal complexes and rare earth complexes of benzoxazole, benzimidazole, benzothiazole, styryl benzene, polyphenyl, diphenyl butadiene, tetraphenyl butadiene, naphthalimide, coumarin, perylene, perinone, oxadiazole, aldazine, pyralizine, cyclopentadiene, bis-styryl anthracene, quinacridone, pyrrolopyridine, thiadiazolopyridine, cyclopentadiene, styryl amine, aromatic dimethylidene compounds and 8-quinolinol), polymer compounds (such as polythiophene, polyphenylene, and polyphenylene vinylene), organic silane, iridium trisphenyl pyridine complex, and transition metal complexes such as platinum porphyrin complex, and derivatives thereof.

The thickness of the luminescent layer is not particularly limited, and usually the thickness is preferably in the range of 1 nm to 5 μm, more preferably 5 nm to 1 μm, still more preferably 10 nm to 500 nm.

The method of forming the luminescent layer is not particularly limited, and methods such as resistance heating deposition, electron beam, sputtering, a molecular deposition method, a coating method, an ink-jet method, a printing method, an LB method, a transfer method, and the like may be used, among which resistance heating deposition and a coating method are preferable.

The luminescent layer may be formed from a single substance or a plurality of substances. There may be only one luminescent layer or may be a plurality of luminescent layers, and such luminescent layers may emit lights with respectively different colors (for example, white light may be emitted based on the combination of the respective lights). In an embodiment, white light is emitted from a single luminescent layer. When there are a plurality of luminescent layers, the luminescent layers each may be formed from a single substance or a plurality of substances.

The materials contained in the hole injection layer and the hole transport layer are not limited insofar as: the hole injection layer has a function of being injected with holes; and the hole transport layer has a function of transporting holes. The hole injection layer and hole transport layer each may optionally have a function of blocking electrons migrating from the cathode.

Specific examples of the materials include: electroconductive high-molecular oligomers of carbazole, triazole, oxazole, oxadiazole, imidazole, polyaryl alkane, pyrazoline, pyrazolone, phenylene diamine, aryl amine, amino-substituted chalcone, styryl anthracene, fluorenone, hydrazone, stilbene, silazane, aromatic tertiary amine compounds, styryl amine compounds, aromatic dimethylidene compounds, porphyrin compounds, polysilane compounds, poly(N-vinyl carbazole), aniline copolymers, thiophene oligomers, polythiophene, and the like; organic silane; carbon films; the compounds of the invention; and derivatives thereof.

The thickness of the hole injection layer or hole transport layer is not particularly limited, and usually the thickness is preferably in the range of 1 nm to 5 μm, more preferably 5 nm to 1 μm, still more preferably 10 nm to 500 nm.

There may be a single hole injection layer comprising one of the above substances or two or more of the above substances, or there may be provided two or more hole injection layers each having same or different composition. Similarly, there may be a single hole transport layer comprising one of the above substances or two or more of the above substances, or there may be provided or more hole transport layers each having the same or different composition.

The method of forming the hole injection layer or the hole transport layer may be a vacuum deposition method, an LB method, a method of applying a solution or dispersion of the hole injection transfer substance in a solvent, an ink-jet method, a printing method, or a transfer method. In the coating method, the substances can be dissolved or dispersed together with a resin component, and examples of the resin component include polyvinyl chloride, polycarbonate, polystyrene, polymethyl methacrylate, polybutyl methacrylate, polyester, polysulfone, polyphenylene oxide, polybutadiene, poly(N-vinyl carbazole), hydrocarbon resin, ketone resin, phenoxy resin, polyamide, ethyl cellulose, vinyl acetate, ABS resin, polyurethane, melamine resin, unsaturated polyester resin, alkyd resin, epoxy resin, and silicon resin.

The materials contained in the electron injection layer and electron transport layer are not limited insofar as: the electron injection layer has a function of being injected with electrons; and the electron transport layer has a function of transporting electrons. The electron injection layer and electron transport layer each may have a function of blocking holes migrating from the anode. Specific examples thereof include: various metal complexes such as metal complexes of triazole, oxazole, oxadiazole, imidazole, fluorenone, anthraquinodimethane, anthrone, diphenyl quinone, thiopyran dioxide, carbodiimide, fluorenylidene methane, distyryl pyrazine, aromatic tetracarboxylic acid anhydrides (such as naphthalene tetracarboxylic acid anhydride and perylene tetracarboxylic acid anhydride), phthalocyanine and 8-quinolinol, metal phthalocyanine, and metal complexes whose typical examples are metal complexes comprising ligands selected from benzoxazole and benzothiazole; organic silane; and derivatives thereof.

The thickness of the electron injection layer or electron transport layer is not particularly limited, but usually the thickness is preferably in the range of 1 nm to 5 μm, more preferably 5 nm to 1 μm, still more preferably 10 nm to 500 nm.

There may be a single electron injection layer comprising one of the above substances or two or more of the above substances, or there may be provided two or more electron injection layers each having the same or different composition. Similarly, there may be a single electron transport layer comprising one of the above substances or two or more of the above substances, or there may be provided two or more electron transport layers each having the same or different composition.

The method of forming the electron injection layer or the electron transport layer may be a vacuum deposition method, an LB method, a method of applying a solution or dispersion of the electron injection transfer materials in a solvent, an ink-jet method, a printing method, and a transfer method. In the coating method, the materials can be dissolved or dispersed together with a resin component, and the resin component may be selected from the resin components listed as examples in the explanation of hole injection layer and hole transfer layer.

The organic EL device of the invention may further comprise a protective layer so as to prevent the incorporation of moisture or oxygen. The material of the protective layer is not limited insofar as it has a function of preventing substances (such as water and oxygen) which cause deterioration of the device from entering the device.

Specific examples of the protective layer material include metals such as In, Sn, Pb, Au,Cu, Ag, Al, Ti, and Ni, metal oxides such as MgO, SiO, SiO₂, Al₂O₃, GeO, NiO, CaO, BaO, Fe₂O₃, Y₂O₃, and TiO₂, metal fluorides such as MgF₂, LiF, AlF₃, and CaF₂, nitrides such as SiNₓ and SiOₓN_{y}, polyethylene, polypropylene, polymethyl methacrylate, polyimide, polyurea, polytetrafluoroethylene, polychlorotrifluoroethylene, polydichlorodifluoroethylene, a chlorotrifluoroethylene-dichlorodifluoroethylene copolymer, a copolymer obtained by copolymerizing a monomer mixture containing tetrafluoroethylene and at least one kind of comonomer, a fluorine-containing copolymer having a cyclic structure on a main chain of thereof, a water-absorbing substance having a water absorption of 1% or higher, and a dampproof substance having a water absorption of 0.1% or lower.

The method of forming the protective layer is not particularly limited, either. Examples of usable methods include a vacuum deposition method, a sputtering method, a reactive sputtering method, an MBE (molecular beam epitaxy) method, a cluster ion beam method, an ion plating method, a plasma polymerization method (high-frequency excitation ion plating method), a plasma CVD method, a laser CVD method, a thermal CVD method, a gas source CVD method, a coating method, a printing method, and a transfer method.

Systems, driving methods, and applications to which the organic EL device of the invention is applied are not particularly limited. The organic EL device of the invention can be used preferably in the fields of display devices, displays, backlight, electrophotography, lighting, recording light sources, exposure light sources, reading light sources, labels, signboards, interiors, optical communication, and the like.

### EXAMPLES

Hereinafter, the organic EL device of the present invention is described with reference to Examples. However, the Examples should not be construed as limiting the invention.

### Comparative Example 1

(Element described in WO No. 01/0,08230)

A cleaned ITO substrate was placed in a vapor-deposition apparatus, and TPD (N,N′-diphenyl-N,N′-di(m-tolyl)-benzidine) was deposited thereon to a thickness of 60 nm. CBP and DCM2 at a ratio of 99:1 (by weight) were deposited thereon to a thickness of 1 nm, and CBP and Ir(ppy)₃ at a ratio of 90:10 were deposited thereon to a thickness of 1 nm, and the processes were repeated five times, to give a 10-alternate-layer film having a total thickness of 10 nm. BCP was deposited thereon to a thickness of 20 nm, and Alq₃ thereon to a thickness of 30 nm. After a patterned mask (mask having a luminescent area of 4 mm×5 mm in size) was placed on the obtained organic thin film, magnesium and silver at a ratio of 25:1 were deposited thereon to a thickness of 100 nm and then silver to a thickness of 50 nm in the vapor-deposition apparatus.

A constant direct-current voltage was applied to the EL device and the EL device was allowed to emit light in Source Measure Unit 2400 manufactured by Toyo Corporation, and the brightness thereof was determined by using a brightness meter BM-8 manufactured by Topcon Corporation. The emission spectrum of the device was obtained by using a photonic multi-channel analyzer PMA-11 manufactured by Hamamatsu Photonics K.K.

As a result, red emission was observed, and the external quantum efficiency at 200 cd/m² was 2.6%. The maximum brightness was approximately 5,000 cd/m². In addition, in the emission spectrum, there were emission from DCM2 as well as from Ir(ppy)₃ and CBP (similarly to the results in WO No. 01/0,08230).

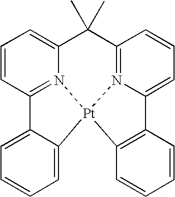

Complex A (tetradentate linear coordination complex) (compound described in Japanese Patent Application No. 2004-162849)

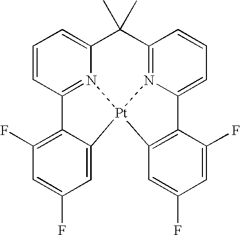

Complex B (tetradentate linear coordination complex) (compound described in Japanese Patent Application No. 2004-162849) 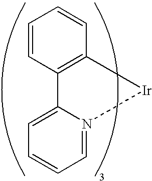
IR(pp)₃ bidentate coordination complex

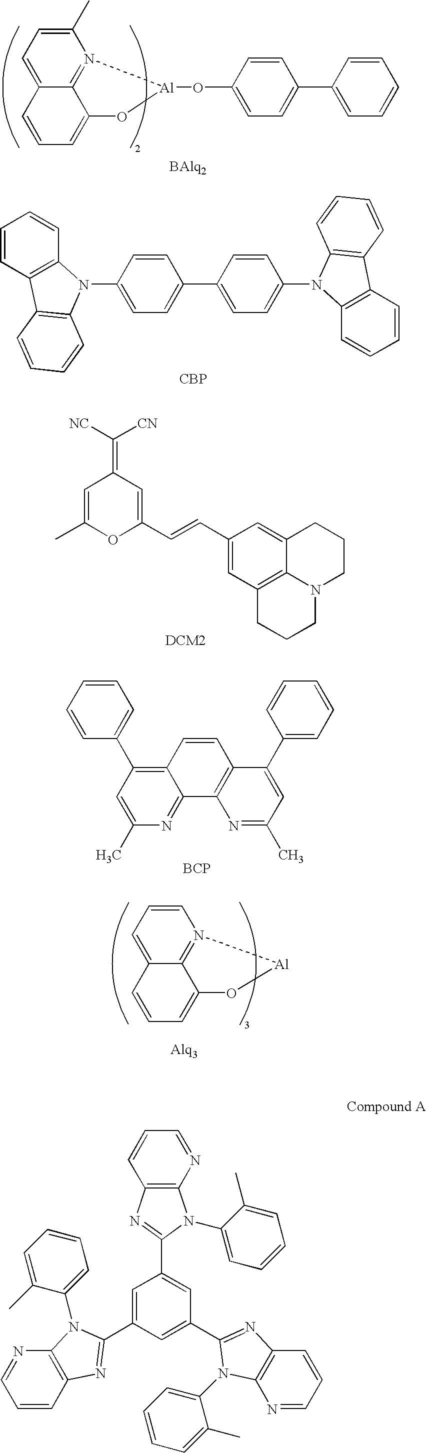

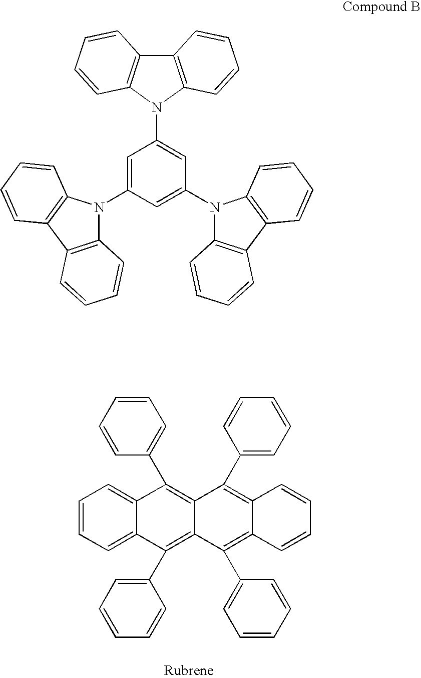

### Example 1

An device was prepared and evaluated in a similar manner to Comparative Example 1, except that Ir(ppy)₃ used in Comparative Example 1 was replaced with the complex A according to the invention.

As a result, red emission at a maximum brightness of approximately 10,000 cd/m² was observed. The driving durability at 1,000 cd/m² was evaluated, revealing that the half life of the device was three times longer than that of the device of Comparative Example 1.

### Example 2

An device was prepared and evaluated in a similar manner to Comparative Example 1, except that Ir(ppy)₃ used in Comparative Example 1 was replaced with the complex A according to the invention and DCM2 with rubrene.

As a result, yellow emission at a maximum brightness of approximately 40,000 cd/m² was observed. The driving durability at 1,000 cd/m² was evaluated, revealing that the half life of the device was four times longer than that of the device of Comparative Example 1.

### Example 3

An device was prepared and evaluated in a similar manner to Comparative Example 1, except that Ir(ppy)₃ used in Comparative Example 1 was replaced with the complex A according to the invention, DCM2 with rubrene, and BCP with the compound A.

As a result, yellow emission at a maximum brightness of approximately 40,000 cd/m² was observed. The driving durability at 1,000 cd/m² was evaluated, revealing that the half life of the device was six times longer than that of the device of Comparative Example 1.

### Example 4

A cleaned ITO substrate was placed in a vapor-deposition apparatus, and copper phthalocyanine was deposited thereon to a thickness of 10 nm and α-NPD (N,N′-di(α-naphthyl)-N,N′-diphenylbenzidine) to a thickness of 50 nm. CBP and rubrene at a ratio of 99:1 (by weight) were deposited thereon to a thickness of 1 nm and CBP and complex B at a ratio of 93:7 to a thickness of 1 nm, and the processes were repeated five times, to give a 10-alternate-layer film having a total thickness of 10 nm. BAlq₂ was deposited thereon to a thickness of 10 nm and then Alq₃ to a thickness of 30 nm. After a patterned mask (mask having a luminescent area of 4 mm×5 mm in size) was placed on the obtained organic thin film, lithium fluoride was deposited to a thickness of 3 nm and then aluminum thereon to a thickness of 200 nm in the vapor-deposition apparatus.

In evaluation in a similar manner to Comparative Example 1, yellow emission at a maximum brightness of approximately 60,000 cd/m² was observed. The driving durability at 1,000 cd/m² was evaluated, revealing that the half life of the device was longer approximately 10 times than that of the device in Comparative Example 1.

### Example 5

A device was prepared and evaluated in a similar manner to Example 4, except that CBP used in Example 4 was replaced with the compound B above.

As a result, green emission at a maximum brightness of approximately 40,000 cd/m² was observed. The driving durability at 1,000 cd/m² was evaluated, revealing that the half life of the device was approximately five times longer than that of the device of Comparative Example 1.

### Example 6

A cleaned ITO substrate was placed in a vapor-deposition apparatus, copper phthalocyanine was deposited thereon to a thickness of 10 nm and α-NPD (N,N′-di(α-naphthyl)-N,N′-diphenylbenzidine) to a thickness of 50 nm. CBP, complex A, and rubrene at a ratio of 92.5:7:0.5 (by weight) were deposited to a thickness of 36 nm and then, compound A to a thickness of 36 nm. After a patterned mask (mask having a luminescent area of 4 mm×5 mm in size) was placed on the obtained organic thin film, and lithium fluoride was deposited to a thickness of 3 nm and then aluminum thereon to a thickness of 200 nm in the vapor-deposition apparatus.

In evaluation in a similar manner to Comparative Example 1, yellow emission at a maximum brightness of approximately 30,000 cd/m² was observed. The driving durability at 1,000 cd/m² was evaluated, revealing that the half life of the device was approximately five times longer than that of the device in Comparative Example 1.

Luminescent devices employing, as the amplifying agent, a metal complex having a tridentate or higher ligand according to the invention other than those described in the Examples above have similar advantageous effects.

The invention provides a luminescent device superior in luminous efficiency and durability. It also provides a luminescent device that can emit light in different color such as blue, green, white, or the like.

We claim:

1. An organic electroluminescent device, comprising at least one organic compound layer containing a luminescent layer between a pair of electrodes, wherein the luminescent layer contains a fluorescence-emitting compound emitting fluorescence when voltage is applied thereto, the emission when voltage is applied is mainly derived from the fluorescence-emitting compound, and wherein the luminescent layer further comprises an amplifying agent functioning to increase the number of singlet excitons generated and thus amplifying the light intensity when voltage is applied, and the amplifying agent is a metal complex having a tridentate or higher ligand.

2. The organic electroluminescent device according to claim 1, wherein the ligand contained in the metal complex is a chained ligand.

3. The organic electroluminescent device according to claim 2, wherein the metal complex is a compound represented by the following Formula (I): 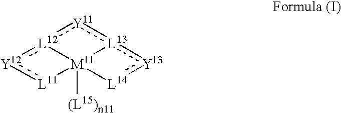
wherein, M¹¹ represents a metal ion; L¹¹ to L¹⁵ each represent a ligand coordinating to M¹¹; there is no additional atom group forming a cyclic ligand between L¹¹ and L¹⁴; L¹⁵ does not bind to both L¹¹ and L¹⁴ to form a cyclic ligand; Y¹¹, Y¹², and Y¹³ each represent a connecting group or a single or double bond; when Y¹¹, Y¹², or Y¹³ is a connecting group, the bonds between L¹¹ and Y¹², Y¹² and L¹², L¹² and Y¹¹, Y¹¹ and L¹³, L¹³ and Y¹³, and Y¹³ and L¹⁴ each independently represent a single or double bond; and n¹¹ is a number of 0 to 4.

4. The organic electroluminescent device according to claim 2, wherein the metal complex is a compound represented by the following Formula (II): 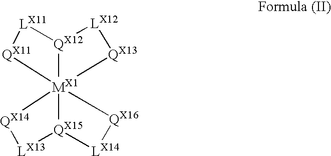
wherein, M^{X1} represents a metal ion; Q^{X11} to Q^{X16} each represent an atom coordinating to M^{X1} or an atom group containing an atom coordinating to M^{X1}; L^{X11} to L¹⁴ each represent a single or double bond or a connecting group, i.e., each of the atom group of Q^{X11}-L^{X11}-Q^{X12}-L^{X12}-Q^{X13} and the atom group of Q^{X14}-L^{X13}-Q^{X15}-L^{X14}-Q^{X16} is a tridentate ligand; and each of the bonds of M^{X1} and Q^{X11} to Q^{X16} may be a coordination or covalent bond.

5. The organic electroluminescent device according to claim 1, wherein the ligand contained in the metal complex is a cyclic ligand.

6. The organic electroluminescent device according to claim 5, wherein the metal complex is represented by the following Formula (III): 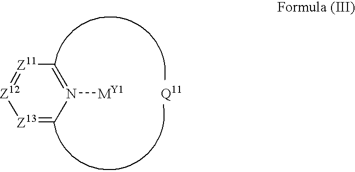
wherein, Q¹¹ represents an atom group forming a nitrogen-containing heterocyclic ring; Z¹¹, Z¹², and Z¹³ each represent a substituted or unsubstituted carbon or nitrogen atom; and M^{Y1} represents a metal ion that may have a ligand additionally.

7. The organic electroluminescent device according to claim 1, wherein the luminescent layer contains at least two fluorescence-emitting compounds.

8. The organic electroluminescent device according to claim 1, wherein the concentration of the fluorescence-emitting compound in the luminescent layer is from 0.1% to 10%.

9. The organic electroluminescent device according to claim 1, wherein the fluorescent quantum yield of the fluorescence-emitting compound in the luminescent layer is 50% or more.

10. The organic electroluminescent device according to claim 1, wherein the emission spectrum of the amplifying agent and the absorption spectrum of the fluorescence-emitting compound overlap at least partially.

11. The organic electroluminescent device according to claim 1, wherein the phosphorescent quantum yield of the amplifying agent is 20% or more.

12. The organic electroluminescent device according to claim 1, wherein the phosphorescence lifetime of the amplifying agent is 10 μs or less.

13. The organic electroluminescent device according to claim 1, wherein the T₁ level (energy level of lowest excited triplet state) of the layer in the luminescent layer close to the cathode is from 50 Kcal/mol (209.2 KJ/mol) to 90 Kcal/mol (377.1 KJ/mol).

14. The organic electroluminescent device according to claim 1, wherein the T₁ level (energy level of lowest excited triplet state) of the layer in the luminescent layer close to the anode is from 50 Kcal/mol (209.2 KJ/mol) to 90 Kcal/mol (377.1 KJ/mol).

15. The organic electroluminescent device according to claim 1, wherein the fluorescence-emitting compound is a distyrylarylene derivative, oligoarylene derivative, aromatic nitrogen-containing heterocyclic compound, sulfur-containing heterocyclic ring compound, metal complex, oxo-substituted heterocyclic ring compound, organic silicon compound, triarylamine derivative, or condensed aromatic compound.

16. The organic electroluminescent device according to claim 1, wherein the external quantum efficiency of the device is 6% or more.

17. The organic electroluminescent device according to claim 1, wherein the internal quantum efficiency of the device is 30% or more.

18. The organic electroluminescent device according to claim 1, wherein the maximum emission wavelength of the light emitted from the fluorescence-emitting compound is 580 nm or less.

19. The organic electroluminescent device according to claim 1, wherein the luminescent layer contains at least one host material, and the host material is one or more compounds selected from metal complexes, nitrogen-containing heterocyclic ring compounds, and aromatic hydrocarbon compounds.

20. The organic eleciroluminescent device according to claim 1, wherein the organic compound layer contains an electron-transporting layer and the electron-transporting layer contains a metal complex or a nitrogen-containing heterocyclic ring compound.

21. The organic electroluminescent device according to claim 1, wherein the fluorescence-emitting compound has a substituent that lowers the effeciency of the Dexter-type energy transfer from a triplet exciton of the amplifying agent to a triplet exciton of the fluorescence-emitting compound.

22. The organic electroluminescent device according to claim 1, wherein the maximum phosphorescence wavelength of the amplifying agent is 500 nm or less.
